(19) United States
(12) Patent Application Publication
(10) Pub. No.: US 2025/0126968 A1
(43) Pub. Date: Apr. 17, 2025

(54) Light-Emitting Device

(71) Applicant: Semiconductor Energy Laboratory Co., Ltd., Kanagawa-ken (JP)

(72) Inventors: Nobuharu OHSAWA, Zama (JP); Toshiki SASAKI, Kawasaki (JP); Shinya FUKUZAKI, Atsugi (JP); Hiromi SEO, Sagamihara (JP)

(73) Assignee: Semiconductor Energy Laboratory Co., Ltd., Kanagawa-ken (JP)

(21) Appl. No.: 18/906,491

(22) Filed: Oct. 4, 2024

(30) Foreign Application Priority Data
Oct. 13, 2023 (JP) 2023-177524
Nov. 17, 2023 (JP) 2023-195699
Feb. 22, 2024 (JP) 2024-025418
Mar. 1, 2024 (JP) 2024-031584
Mar. 14, 2024 (JP) 2024-039587

(51) Int. Cl. H10K 50/17; H10K 50/19; H10K 85/60; H10K 101/40

(52) U.S. Cl. CPC H10K 50/171; H10K 50/19; H10K 85/654; H10K 85/6572; H10K 2101/40

(57) ABSTRACT

A light-emitting device with favorable characteristics is provided. In a plurality of light-emitting devices each including an organic compound layer formed over the same insulating surface, the organic compound layer includes a first light-emitting layer, a second light-emitting layer, and an intermediate layer. The intermediate layer includes a first layer. The first layer includes a metal or metal compound, a first organic compound, and a second organic compound. The first organic compound includes a π-electron deficient heteroaromatic ring. The second organic compound includes two or more heteroaromatic rings that are bonded or condensed to each other and include three or more heteroatoms in total. The second organic compound interacts with the metal or metal compound by two or more of the three or more heteroatoms as a multidentate ligand.

### BACKGROUND OF THE INVENTION

### 1. Field of the Invention

One embodiment of the present invention relates to a light-emitting device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting apparatus, a lighting device, a power storage device, a memory device, an imaging device, an electronic appliance, a driving method thereof, and a manufacturing method thereof.

### 2. Description of the Related Art

Recently, display devices have been expected to be applied to a variety of uses. Usage examples of large-sized display devices include a television device for home use (also referred to as TV or television receiver), digital signage, and a public information display (PID). In addition, a smartphone and a tablet terminal each including a touch panel, for example, are being developed as portable information terminals.

Higher-resolution display devices have been required. For example, devices for virtual reality (VR), augmented reality (AR), substitutional reality (SR), or mixed reality (MR) are given as devices requiring high-resolution display devices and have been actively developed.

Light-emitting apparatuses that include light-emitting devices (also referred to as light-emitting elements) have been developed as display devices, for example. Light-emitting devices utilizing electroluminescence (hereinafter referred to as EL; such devices are also referred to as EL devices or EL elements) have features such as ease of reduction in thickness and weight, high-speed response to input signals, and driving with a constant DC voltage power source, and have been widely used in display devices.

Patent Document 1 discloses a display device for VR that includes an organic EL device (also referred to as organic EL element).

### REFERENCE

[Patent Document 1] International Publication No. WO2018/087625

### SUMMARY OF THE INVENTION

As a method for forming an organic semiconductor film in a predetermined shape, a vacuum evaporation method with a metal mask (mask vapor deposition) is widely used. However, in these days of higher density and higher resolution, mask vapor deposition has come close to the limit of the resolution for various reasons such as the alignment accuracy and the distance between the mask and the substrate. By contrast, a finer pattern can be formed by shape processing of an organic semiconductor film by a lithography method. Moreover, because of the ease of large-area processing in this method, the processing of an organic semiconductor film by a lithography method is being researched.

At the time of processing an organic semiconductor film by a lithography method, the influence of oxygen or water in the air and a chemical solution or water used during the process has sometimes caused a significant increase of driving voltage or a great reduction of current efficiency of a light-emitting device.

An object of one embodiment of the present invention is to provide a light-emitting device with favorable characteristics. Another object of one embodiment of the present invention is to provide a light-emitting device with high reliability. Another object of one embodiment of the present invention is to provide a novel light-emitting device.

Note that the description of these objects does not preclude the presence of other objects. In one embodiment of the present invention, there is no need to achieve all of these objects. Other objects will be apparent from and can be derived from the description of the specification, the drawings, the claims, and the like.

One embodiment of the present invention is a light-emitting device including a first electrode, a second electrode, and an organic compound layer. The organic compound layer includes a first light-emitting layer, a second light-emitting layer, and an intermediate layer. The intermediate layer is located between the first light-emitting layer and the second light-emitting layer. The intermediate layer includes a metal or a metal compound, a first organic compound, and a second organic compound different from the first organic compound, The first organic compound includes a π-electron deficient heteroaromatic ring. The second organic compound includes two or more heteroaromatic rings that are bonded or condensed to each other and include three or more heteroatoms in total, and the second organic compound interacts with the metal or the metal compound by two or more of the three or more heteroatoms as a multidentate ligand.

One embodiment of the present invention is a light-emitting device including a first electrode, a second electrode, and an organic compound layer. The organic compound layer includes a first light-emitting layer, a second light-emitting layer, and an intermediate layer. The intermediate layer is located between the first light-emitting layer and the second light-emitting layer. The intermediate layer includes a metal or a metal compound, a first organic compound, and a second organic compound different from the first organic compound. The first organic compound includes a π-electron deficient heteroaromatic ring. The second organic compound includes two or more heteroaromatic rings that are bonded or condensed to each other and include three or more heteroatoms in total. The second organic compound interacts with the metal or the metal compound by two or more of the three or more heteroatoms as a multidentate ligand, and the first organic compound and the metal or the metal compound form a donor level by interaction and function as an electron donor to the second organic compound.

One embodiment of the present invention is a light-emitting device including a first electrode, a second electrode, and an organic compound layer. The organic compound layer includes a first light-emitting layer, a second light-emitting layer, and an intermediate layer. The intermediate layer is located between the first light-emitting layer and the second light-emitting layer. The intermediate layer includes a metal or a metal compound, a first organic compound, and a second organic compound different from the first organic compound. The first organic compound includes a π-electron deficient heteroaromatic ring. The second organic compound includes two or more heteroaromatic rings that are bonded or condensed to each other and include three or more heteroatoms in total. In the intermediate layer, a mass-to-charge ratio corresponding to a sum of a mass number of the first organic compound, a mass number of the second organic compound, and a mass number of the metal or the metal compound is detected by ToF-SIMS measurement.

One embodiment of the present invention is a light-emitting device including a first electrode, a second electrode, and an organic compound layer. The organic compound layer is located between the first electrode and the second electrode. The organic compound layer includes a first light-emitting layer, a second light-emitting layer, and an intermediate layer. The intermediate layer is located between the first light-emitting layer and the second light-emitting layer. The intermediate layer includes a metal or a metal compound, a first organic compound, and a second organic compound different from the first organic compound. The first organic compound includes a π-electron deficient heteroaromatic ring. The second organic compound is an organic compound represented by General Formula (GH). In the intermediate layer, a mass-to-charge ratio corresponding to a sum of a mass number of the first organic compound, a mass number of the second organic compound, and a mass number of the metal or the metal compound is detected by ToF-SIMS measurement.

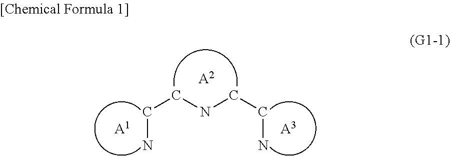

In General Formula (GH), A¹, A², and A³ each independently represent a substituted or unsubstituted heteroaromatic ring having 1 to 30 carbon atoms, and A¹, A², and A³ may form a condensed ring with each other.

One embodiment of the present invention is a light-emitting device including a first electrode, a second electrode, and an organic compound layer. The organic compound layer is located the first electrode and the second electrode. The organic compound layer includes a first light-emitting layer, a second light-emitting layer, and an intermediate layer. The intermediate layer is located between the first light-emitting layer and the second light-emitting layer. The intermediate layer includes a metal or a metal compound, a first organic compound, and a second organic compound different from the first organic compound. The first organic compound includes a π-electron deficient heteroaromatic ring. The second organic compound is an organic compound represented by General Formula (G1-2). In the intermediate layer, a mass-to-charge ratio corresponding to a sum of a mass number of the first organic compound, a mass number of the second organic compound, and a mass number of the metal or the metal compound is detected by ToF-SIMS measurement.

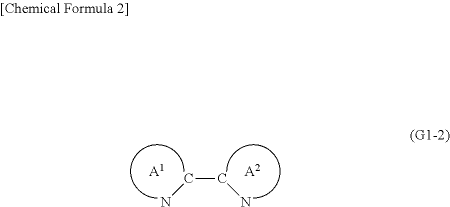

In General Formula (G1-2), A¹ and A² independently represent a substituted or unsubstituted heteroaromatic ring having 1 to 30 carbon atoms, A¹ and A² may form a condensed ring with each other, and A¹ includes two or more nitrogen atoms.

One embodiment of the present invention is a light-emitting device, which is one of a plurality of light-emitting devices formed over the same insulating surface, including a first electrode, a second electrode, and an organic compound layer. The first electrode is independently provided in each of adjacent light-emitting devices. The second electrode is shared by the adjacent light-emitting devices. The organic compound layer is located between the first electrode and the second electrode. The organic compound layer includes a first light-emitting layer, a second light-emitting layer, and an intermediate layer. The intermediate layer is located between the first light-emitting layer and the second light-emitting layer. The first light-emitting layer, the intermediate layer, and the second light-emitting layer are independently provided in each of the adjacent light-emitting devices and have the same or substantially the same outline. The intermediate layer includes a first layer. The first layer includes a metal or a metal compound, a first organic compound, and a second organic compound. The first organic compound includes a π-electron deficient heteroaromatic ring. The second organic compound includes two or more heteroaromatic rings that are bonded or condensed to each other and include three or more heteroatoms in total, and the second organic compound interacts with the metal or the metal compound by two or more of the three or more heteroatoms as a multidentate ligand.

In the above light-emitting device, the second organic compound interacts with the metal or the metal compound by two or more of the three or more heteroatoms as a bidentate or a tridentate ligand.

In the above light-emitting device, the heteroatoms are each a nitrogen atom.

One embodiment of the present invention is a light-emitting device, which is one of a plurality of light-emitting devices formed over the same insulating surface, including a first electrode; a second electrode; and an organic compound layer. The first electrode is independently provided in each of adjacent light-emitting devices. The second electrode is shared by the adjacent light-emitting devices. The organic compound layer is located between the first electrode and the second electrode. The organic compound layer includes a first light-emitting layer, a second light-emitting layer, and an intermediate layer. The intermediate layer is located between the first light-emitting layer and the second light-emitting layer, The first light-emitting layer, the intermediate layer, and the second light-emitting layer are independently provided in each of the adjacent light-emitting devices and have the same or substantially the same outline. The intermediate layer includes a first layer. The first layer includes a metal or a metal compound, a first organic compound, and a second organic compound. The first organic compound includes a π-electron deficient heteroaromatic ring. The second organic compound is an organic compound represented by General Formula (GH).

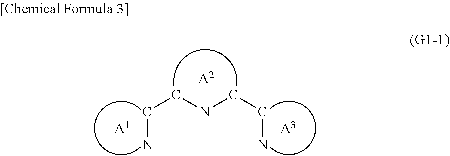

In General Formula (GH), A¹, A², and A³ independently represent a substituted or unsubstituted heteroaromatic ring having 1 to 30 carbon atoms, and A¹, A², and A³ may form a condensed ring with each other.

In the above light-emitting device, the second organic compound interacts with the metal or the metal compound by nitrogen atoms as a tridentate ligand.

One embodiment of the present invention is a light-emitting device, which is one of a plurality of light-emitting devices formed over the same insulating surface, including a first electrode, a second electrode, and an organic compound layer. The first electrode is independently provided in each of adjacent light-emitting devices. The second electrode is shared by the adjacent light-emitting devices. The organic compound layer is located between the first electrode and the second electrode. The organic compound layer includes a first light-emitting layer, a second light-emitting layer, and an intermediate layer. The intermediate layer is located between the first light-emitting layer and the second light-emitting layer. The first light-emitting layer, the intermediate layer, and the second light-emitting layer are independently provided in each of the adjacent light-emitting devices and have the same or substantially the same outline. The intermediate layer includes a first layer. The first layer includes a metal or a metal compound, a first organic compound, and a second organic compound. The first organic compound includes a π-electron deficient heteroaromatic ring. The second organic compound is an organic compound represented by General Formula (G1-2).

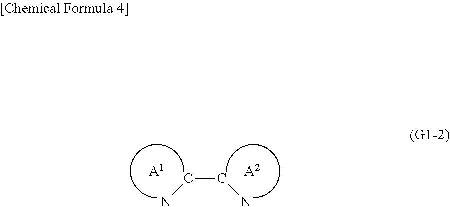

In General Formula (G1-2), A¹ and A² independently represent a substituted or unsubstituted heteroaromatic ring having 1 to 30 carbon atoms, A¹ and A² may form a condensed ring with each other, and A¹ includes two or more nitrogen atoms.

In the above light-emitting device, the second organic compound interacts with the metal or the metal compound by the nitrogen atoms as a bidentate ligand.

In any of the above light-emitting devices, the heteroaromatic ring is a π-electron deficient heteroaromatic ring.

In any of the above light-emitting devices, the heteroaromatic ring includes at least one of a pyridine ring, a diazine ring (a pyrazine ring, a pyrimidine ring, or a pyridazine ring), a triazine ring, an azole ring (an imidazole ring, a pyrazole ring, an oxazole ring, or a thiazole ring), and a triazole ring.

In any of the above light-emitting devices, at least one of the two or more heteroaromatic rings includes a diazine ring (a pyrazine ring, a pyrimidine ring, or a pyridazine ring) or a triazine ring.

In any of the above light-emitting devices, the two or more heteroaromatic rings include three or more pyridine rings in total.

In any of the above light-emitting devices, the first organic compound includes an electron-donating group.

In any of the above light-emitting devices, the electron-donating group includes at least one of an alkyl group, an alkoxy group, an aryloxy group, an alkylamino group, an arylamino group, and a heterocyclic amino group.

In any of the above light-emitting devices, the first organic compound has an acid dissociation constant pKₐ of 8 or more.

In any of the above light-emitting devices, the first organic compound includes a phenanthroline ring.

In any of the above light-emitting devices, the second organic compound has a glass transition temperature T_{g} of 100° C. or higher.

In any of the above light-emitting devices, the LUMO level of the second organic compound is lower than the LUMO level of the first organic compound.

In any of the above light-emitting devices, the metal is a metal belonging to Group 1, Group 3, Group 11, or Group 13 of the periodic table.

In any of the above light-emitting devices, the first layer is a mixture of the metal, the second organic compound, and the first organic compound.

In any of the above light-emitting devices, the first layer has a stacked-layer structure of a layer containing the metal and a layer containing the second organic compound or the first organic compound.

In any of the above light-emitting devices, in the first layer of the intermediate layer, a mass-to-charge ratio corresponding to a sum of a mass number of the first organic compound, a mass number of the second organic compound, and a mass number of the metal is detected by ToF-SIMS measurement.

Another embodiment of the present invention is a light-emitting apparatus that includes a light-emitting device with any of the above structures and a transistor or a substrate.

Another embodiment of the present invention is an electronic appliance including the above light-emitting apparatus, and a sensing portion, an input unit, or a communication unit.

Note that the light-emitting apparatus in this specification includes, in its category, an image display device that uses a light-emitting device. The light-emitting apparatus may also include a module in which a light-emitting device over a substrate is provided with a connector such as an anisotropic conductive film or a tape carrier package (TCP), a module in which a printed wiring board is further provided at the end of the TCP, and a module in which an integrated circuit (IC) is directly mounted on a light-emitting device by a chip on glass (COG) method. Furthermore, a lighting device or the like may include the light-emitting apparatus.

One embodiment of the present invention can provide a light-emitting device with favorable characteristics. Another embodiment of the present invention can provide a light-emitting device with high reliability. Another embodiment of the present invention can provide a novel light-emitting device.

Note that the description of these effects does not preclude the presence of other effects. One embodiment of the present invention does not need to have all of these effects. Other effects can be derived from the description of the specification, the drawings, and the claims.

### BRIEF DESCRIPTION OF THE DRAWINGS

In the accompanying drawings:

FIG. 1 illustrates light-emitting devices;

FIG. 2 shows an analysis result of spin density distribution of a composite material in the ground state;

FIG. 3 shows a result of analyzing an electrostatic potential map of a composite material in the ground state;

FIG. 4 is a conceptual diagram illustrating a light-emitting device used in an example;

FIGS. 5A to 5D each illustrate a light-emitting device;

FIGS. 6A and 6B are a top view and a cross-sectional view of a light-emitting apparatus;

FIGS. 7A to 7D illustrate a light-emitting device;

FIGS. 8A to 8E are cross-sectional views illustrating an example of a method for manufacturing a display device;

FIGS. 9A and 9B are cross-sectional views illustrating an example of a method for manufacturing a display device;

FIGS. 10A to 10D are cross-sectional views illustrating an example of a method for manufacturing a display device;

FIGS. 11A to 11C are cross-sectional views illustrating an example of a method for manufacturing a display device;

FIGS. 12A to 12C are cross-sectional views illustrating an example of a method for manufacturing a display device;

FIGS. 13A to 13C are cross-sectional views illustrating an example of a method for manufacturing a display device.

FIGS. 14A and 14B are perspective views illustrating a structure example of a display module;

FIGS. 15A and 15B are cross-sectional views illustrating structure examples of a display device;

FIGS. 16A to 16D illustrate examples of electronic appliances;

FIGS. 17A to 17F illustrate examples of electronic appliances;

FIG. 18 is a diagram illustrating a structure of a light-emitting device;

FIG. 19 is a diagram showing luminance-current density characteristics of light-emitting devices;

FIG. 20 is a diagram showing luminance-voltage characteristics of the light-emitting devices;

FIG. 21 is a diagram showing current efficiency—current density characteristics of the light-emitting devices;

FIG. 22 is a diagram showing current density-voltage characteristics of the light-emitting devices;

FIG. 23 is a diagram showing electroluminescence spectra of the light-emitting devices;

FIG. 24 is a diagram showing luminance-current density characteristics of light-emitting devices;

FIG. 25 is a diagram showing luminance-voltage characteristics of the light-emitting devices;

FIG. 26 is a diagram showing current efficiency—current density characteristics of the light-emitting devices;

FIG. 27 is a diagram showing current density-voltage characteristics of the light-emitting devices;

FIG. 28 is a diagram showing electroluminescence spectra of light-emitting devices;

FIG. 29 is a diagram showing an ESR measurement result of a light-emitting device;

FIG. 30 is a diagram showing an ESR measurement result of a light-emitting device;

FIG. 31 is a diagram showing reliability measurement results of light-emitting devices;

FIG. 32 is a diagram showing luminance-current density characteristics of light-emitting devices;

FIG. 33 is a diagram showing luminance-voltage characteristics of the light-emitting devices;

FIG. 34 is a diagram showing current efficiency-current density characteristics of the light-emitting devices;

FIG. 35 is a diagram showing current density-voltage characteristics of the light-emitting devices;

FIG. 36 is a diagram showing electroluminescence spectra of the light-emitting devices;

FIGS. 37A and 37B each illustrate a structure of a measurement device;

FIG. 38A is a diagram showing the current density-voltage characteristics of Device 4A(H1) and Device 4A(H2), FIG. 38B is a diagram showing the current density-voltage characteristics of Device 4B(I-1l) and Device 4B(H2), and FIG. 38C is a diagram showing the current density-voltage characteristics of Device 4C(H1) and Device 4C(H2);

FIG. 39A is a diagram showing the current density-voltage characteristics of Device 4A(E1) and Device 4A(E2), FIG. 39B is a diagram showing the current density-voltage characteristics of Device 4B(E1) and Device 4B(E2), and FIG. 39C is a diagram showing the current density-voltage characteristics of Device 4C(E1) and Device 4C(E2);

FIG. 40 is a diagram showing current density-voltage characteristics of light-emitting devices 5A and 5B;

FIG. 41 is a diagram showing current density-voltage characteristics of the light-emitting devices 5A and 5B;

FIG. 42 is a diagram showing current efficiency—current density characteristics of the light-emitting devices 5A and 5B;

FIG. 43 is a diagram showing external quantum efficiency-current density characteristics of the light-emitting devices 5A and 5B;

FIG. 44 is a diagram showing electroluminescence spectra of the light-emitting devices 5A and 5B;

FIG. 45 is a diagram showing time dependence of normalized luminance of the light-emitting device 5A at a current density of 46.4 mA/cm²;

FIGS. 46A and 46B are diagrams showing ToF-SIMS measurement results described in Example;

FIGS. 47A and 47B are diagrams showing ToF-SIMS measurement results described in Example.

FIG. 48 is a diagram showing a ToF-SIMS measurement result;

FIG. 49 is a diagram showing a ToF-SIMS measurement result;

FIG. 50 is a diagram showing a ToF-SIMS measurement result;

FIG. 51 is a diagram showing absorption spectra of samples;

FIG. 52 illustrates a structure of a sample of a light-emitting device;

FIG. 53 is a diagram showing luminance-current density characteristics of light-emitting devices;

FIG. 54 is a diagram showing luminance-voltage characteristics of the light-emitting devices;

FIG. 55 is a diagram showing current efficiency-current density characteristics of the light-emitting devices;

FIG. 56 is a diagram showing current density-voltage characteristics of the light-emitting devices: FIG. 57 is a diagram showing external quantum efficiency-current density characteristics of the light-emitting devices;

FIG. 58 is a diagram showing electroluminescence spectra of the light-emitting devices;

FIG. 59 is a diagram showing capacitance-voltage characteristics of the light-emitting devices;

FIG. 60 is a diagram showing luminance-current density characteristics of light-emitting devices.

FIG. 61 is a diagram showing luminance-voltage characteristics of the light-emitting devices;

FIG. 62 is a diagram showing current efficiency—current density characteristics of the light-emitting devices;

FIG. 63 is a diagram showing current density-voltage characteristics of the light-emitting devices;

FIG. 64 is a diagram showing electroluminescence spectra of the light-emitting devices;

FIG. 65 is a diagram showing luminance-current density characteristics of light-emitting devices;

FIG. 66 is a diagram showing luminance-voltage characteristics of the light-emitting devices.

FIG. 67 is a diagram showing current efficiency-current density characteristics of the light-emitting devices

FIG. 68 is a diagram showing current density-voltage characteristics of the light-emitting devices;

FIG. 69 is a diagram showing electroluminescence spectra of the light-emitting devices;

FIG. 70 is a diagram showing luminance-current density characteristics of light-emitting devices;

FIG. 71 is a diagram showing luminance-voltage characteristics of the light-emitting devices;

FIG. 72 is a diagram showing current efficiency-current density characteristics of the light-emitting devices;

FIG. 73 is a diagram showing current density-voltage characteristics of the light-emitting devices;

FIG. 74 is a diagram showing electroluminescence spectra of the light-emitting devices;

FIG. 75 is a diagram showing blue index-current density characteristics of the light-emitting devices;

FIG. 76 is a diagram showing reliability measurement results of light-emitting devices;

FIG. 77 is a diagram showing reliability measurement results of light-emitting devices;

FIG. 78 is a diagram showing reliability measurement results of light-emitting devices;

FIG. 79 is a conceptual diagram of a stacked-layer structure of a display device;

FIG. 80 is a photograph of a light-emission state of a display device;

FIGS. 81A and 81B are optical micrographs of pixels of a display device;

FIG. 82 is a diagram showing CIE 1931 chromaticity coordinates of a display device;

FIG. 83 is a diagram showing measurement results of electroluminescence spectra of the display device;

FIG. 84 is a diagram showing luminance-current density characteristics of a light-emitting device.

FIG. 85 is a diagram showing luminance-voltage characteristics of the light-emitting device:

FIG. 86 is a diagram showing current efficiency-current density characteristics of the light-emitting device;

FIG. 87 is a diagram showing current density-voltage characteristics of the light-emitting device;

FIG. 88 is a diagram showing an electroluminescence spectrum of the light-emitting device;

FIG. 89 shows blue index-current density characteristics of the light-emitting device;

FIG. 90 is a diagram showing luminance-current density characteristics of a light-emitting device.

FIG. 91 is a diagram showing luminance-voltage characteristics of the light-emitting device;

FIG. 92 is a diagram showing current efficiency—current density characteristics of the light-emitting device;

FIG. 93 is a diagram showing current density-voltage characteristics of the light-emitting device;

FIG. 94 is a diagram showing an electroluminescence spectrum of the light-emitting device;

FIG. 95 is a diagram showing luminance-current density characteristics of a light-emitting device.

FIG. 96 is a diagram showing luminance-voltage characteristics of the light-emitting device.

FIG. 97 is a diagram showing current efficiency-current density characteristics of the light-emitting device.

FIG. 98 is a diagram showing current density-voltage characteristics of the light-emitting device;

FIG. 99 is a diagram showing an electroluminescence spectrum of the light-emitting device;

FIG. 100 is a diagram showing luminance-current density characteristics of light-emitting devices;

FIG. 101 is a diagram showing luminance-voltage characteristics of the light-emitting devices;

FIG. 102 is a diagram showing current efficiency-current density characteristics of the light-emitting devices

FIG. 103 is a diagram showing current density-voltage characteristics of the light-emitting devices;

FIG. 104 is a diagram showing electroluminescence spectra of the light-emitting devices;

FIG. 105 is a diagram showing luminance-current density characteristics of light-emitting devices

FIG. 106 is a diagram showing luminance-voltage characteristics of the light-emitting devices;

FIG. 107 is a diagram showing current efficiency-current density characteristics of the light-emitting devices

FIG. 108 is a diagram showing current density-voltage characteristics of the light-emitting devices;

FIG. 109 is a diagram showing electroluminescence spectra of the light-emitting devices; and

FIG. 110 is a diagram showing reliability measurement results of light-emitting devices.

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, a device formed using a metal mask or a fine metal mask (FMM) is sometimes referred to as a device having a metal mask (MM) structure. In this specification and the like, a device formed without using a metal mask or an FMM is sometimes referred to as a device having a metal maskless (MML) structure.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that the above-described carrier-injection layer, carrier-transport layer, and carrier-blocking layer cannot be clearly distinguished from each other on the basis of the cross-sectional shape or properties in some cases. One layer may have two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. In this specification and the like, a light-receiving device (also referred to as a light-receiving element) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a tapered shape indicates a shape in which at least part of a side surface of a structure is inclined to a substrate surface. For example, a tapered shape preferably includes a region where the angle between the inclined side surface and the substrate surface (such an angle is also referred to as a taper angle) is less than 90°. Note that the side surface of a component and the substrate surface are not necessarily completely flat, and may have a substantially planar shape with a small curvature or slight unevenness.

Note that the light-emitting apparatus in this specification includes, in its category, an image display device that uses an organic EL device. The light-emitting apparatus may also include a module in which an organic EL device is provided with a connector such as an anisotropic conductive film or a tape carrier package (TCP), a module in which a printed wiring board is further provided at the end of the TCP, and a module in which an integrated circuit (IC) is directly mounted on an organic EL device by a chip on glass (COG) method. Furthermore, a lighting device or the like may include the light-emitting apparatus.

### Embodiment 1

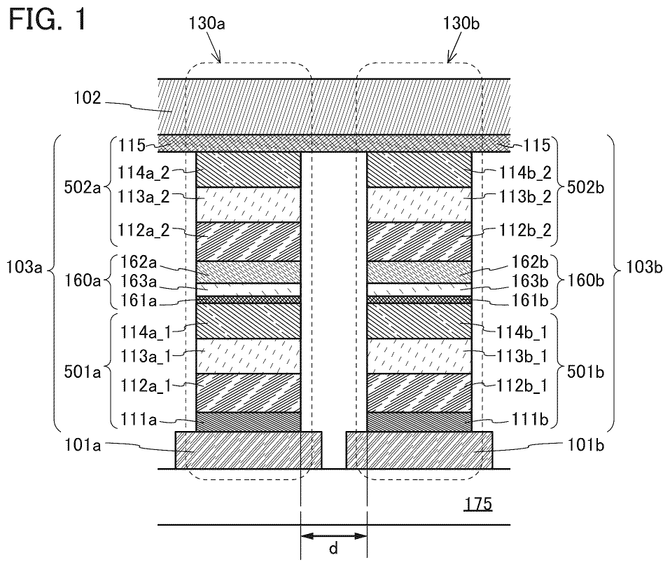

In this embodiment, a light-emitting device of one embodiment of the present invention will be described with reference to FIG. 1.

For description of a light-emitting device of one embodiment of the present invention, FIG. 1 schematically illustrates light-emitting devices 130a and 130b included in a light-emitting apparatus, which are formed over one insulating surface to be adjacent to each other. In each of the light-emitting devices 130a and 130b, part of an organic compound layer is formed through processing by a lithography method.

The light-emitting device 130a is located over an insulating layer 175 and includes a first electrode 101a that includes an anode, a second electrode 102 that includes a cathode, and an organic compound layer 103a. The organic compound layer 103a is located between the first electrode 101a and the second electrode 102. In the organic compound layer 103a, a first light-emitting unit 501a and a second light-emitting unit 502a are stacked with an intermediate layer 160a sandwiched therebetween. The first light-emitting unit 501a includes a first light-emitting layer 113a_1. The intermediate layer 160a includes a first layer 161a and a second layer 162a. The second light-emitting unit 502a includes a second light-emitting layer 113a_2 and an electron-injection layer 115. The above structure can be regarded as a structure in which the intermediate layer 160a is located between the first light-emitting layer 113a_1 and the second light-emitting layer 113a_2.

The light-emitting device 130b is located over the insulating layer 175 and includes a first electrode 101b that includes an anode, the second electrode 102 that includes the cathode, and an organic compound layer 103b. The organic compound layer 103b is located between the first electrode 101b and the second electrode 102. In the organic compound layer 103b, a first light-emitting unit 501b and a second light-emitting unit 502b are stacked with the intermediate layer 160b sandwiched therebetween. The first light-emitting unit 501b includes the first light-emitting layer 113b_1. The intermediate layer 160b includes the first layer 161b and the second layer 162b. The second light-emitting unit 502b includes the second light-emitting layer 113b_2 and the electron-injection layer 115. The above structure can be regarded as a structure in which the intermediate layer 160b is located between the first light-emitting layer 113b_1 and the second light-emitting layer 113b_2.

In the organic compound layers 103a and 103b of the light-emitting devices 130a and 130b, layers other than the electron-injection layer 115 are formed through processing by a lithography method. Thus, the layers other than the electron-injection layer 115 in the organic compound layer 103a are isolated from those in the organic compound layer 103b.

End portions (contours) of the layers other than the electron-injection layer 115 in the organic compound layers 103a and 103b are aligned or substantially aligned with each other in a direction perpendicular to a substrate. In other words, the first light-emitting layer 113a_I, the intermediate layer 160a (the first layer 161a and the second layer 162a), and the second light-emitting layer 113a_2 are separate from a first light-emitting layer 113b_1, an intermediate layer 160b (a first layer 161b and a second layer 162b), and a second light-emitting layer 113b_2. End portions (contours) of the first light-emitting layer 113a_1, the intermediate layer 160a (the first layer 161a and the second layer 162a), and the second light-emitting layer 113a_2 are aligned or substantially aligned with each other in a direction perpendicular to the substrate. Similarly, the first light-emitting layer 113b_1, the intermediate layer 160b (the first layer 161b and the second layer 162b), and the second light-emitting layer 113b_2 are separate from the first light-emitting layer 113a_1, the intermediate layer 160a (the first layer 161a and the second layer 162a), and the second light-emitting layer 113a_2. End portions (contours) of the first light-emitting layer 113b_1, the intermediate layer 160b (the first layer 161b and the second layer 162b), and the second light-emitting layer 113b_2 are aligned or substantially aligned with each other in a direction perpendicular to the substrate.

The electron-injection layer 115 and the second electrode 102 are preferably formed after the layers of the organic compound layer 103a other than the electron-injection layer 115 and the layers of the organic compound layer 103b other than the electron-injection layer 115 are formed through processing by a lithography method. In other words, the electron-injection layer 115 and the second electrode 102 are each preferably a continuous layer shared by the light-emitting devices 130a and 130b.

The electron-injection layer 115 is preferably formed using a donor substance (also referred to as an electron donor), in which case the voltages of the light-emitting devices can be reduced. Typical examples of the donor substance include alkali metals such as lithium (Li), which have a low work function, and compounds of the alkali metals.

In the case where processing by a lithography method is performed in a state where an electron-injection layer including such a donor substance serves as an interface of an organic compound layer, the influence of oxygen or water in the air and a chemical solution or water used during the process sometimes may cause a significant increase of driving voltage or a great reduction of current efficiency in a light-emitting device. However, in one embodiment of the present invention, since the electron-injection layer 115 is formed after the layers other than the electron-injection layer 115 are formed through processing by a lithography method, deterioration of the characteristics of the light-emitting devices cannot not be caused even when a donor substance is used for the electron-injection layer 115.

Note that processing the organic compound layers by a lithography method can make the distance d between the layers other than the electron-injection layer 115 of the organic compound layer 103a and the layers other than the electron-injection layer 115 of the organic compound layer 103b shorter than the distance d in the case of depositing the layers with use of a mask; for example, the processing the organic compound layers by a lithography method can shorten the distance d to less than 10 μm, less than or equal to 8 μm, less than or equal to 5 μm, less than or equal to 3 μm, less than or equal to 2 μm, less than or equal to 1.5 μm, less than or equal to 1 μm, or less than or equal to 0.5 μm. Using a light exposure apparatus for LSI can further shorten the distance d to less than or equal to 500 nm, less than or equal to 200 nm, less than or equal to 100 nm, or even less than or equal to 50 nm, for example, in a process over a Si wafer.

It is preferable that an insulating layer be provided in the gap between the layers of the organic compound layer 103a other than the electron-injection layer 115 and the layers of the organic compound layer 103b other than the electron-injection layer 115 to separate the layers of the organic compound layer 103a other than the electron-injection layer 115 from the layers of the organic compound layer 103b other than the electron-injection layer 115. In that case, in a region, the insulating layer is in contact with the electron-injection layer 115 or the second electrode 102.

In the light-emitting device 130a, the first light-emitting unit 501a preferably includes a hole-injection layer 111a, a first hole-transport layer 112a_1, and a first electron-transport layer 114a_1 in addition to the first light-emitting layer 113a_1. The second light-emitting unit 502a preferably includes a second hole-transport layer 112a_2 and a second electron-transport layer 114a_2 in addition to the second light-emitting layer 113a_2 and the electron-injection layer 115. The intermediate layer 160a can include a third layer 163a between the first layer 161a and the second layer 162a. In the case where the surface of the light-emitting unit on the anode side is in contact with the intermediate layer 160a as in the second light-emitting unit 502a, the second layer 162a of the intermediate layer 160a, which is located on the cathode side, can also function as a hole-injection layer of the second light-emitting unit 502a, and thus, providing a hole-injection layer in such a light-emitting unit is optional.

In the light-emitting device 130b, the first light-emitting unit 501b preferably includes a hole-injection layer 111b, a first hole-transport layer 112b_1, and a first electron-transport layer 114b_1 in addition to the first light-emitting layer 113b_1. The second light-emitting unit 502b preferably includes a second hole-transport layer 112b_2 and a second electron-transport layer 114b_2 in addition to the second light-emitting layer 113b_2 and the electron-injection layer 115. The intermediate layer 160b can include a third layer 163b between the first layer 161b and the second layer 162b. In the case where the surface of the light-emitting unit on the anode side is in contact with the intermediate layer 160b as in the second light-emitting unit 502b, the second layer 162b of the intermediate layer 160b, which is located on the cathode side, can also function as a hole-injection layer of the second light-emitting unit 502b, and thus, providing a hole-injection layer in such a light-emitting unit is optional.

As illustrated in FIG. 1, the uppermost one of the layers of the organic compound layer 103a other than the electron-injection layer 115 is preferably the second electron-transport layer 114a_2. Similarly, the uppermost one of the layers of the organic compound layer 103b other than the electron-injection layer 115 is preferably the second electron-transport layer 114b_2. The influence of oxygen or water in the air and a chemical solution or water used during the process can be smaller in the case where processing by a lithography method is performed at the interface on the second electron-transport layer 114a_2 and the second electron-transport layer 114b_2 than in the case where processing is performed at the interface on the second light-emitting layer 113a_2 and the second light-emitting layer 113b_2. Therefore, when the uppermost one of the layers of each organic compound layer other than the electron-injection layer 115 is the electron-transport layer, deterioration of the characteristics of the light-emitting devices due to the fabrication by a lithography method can be more easily avoided; processing by a lithography method is preferably performed at least above the second light-emitting layer 113a_2 and the second light-emitting layer 113b_2.

Although FIG. 1 illustrates an example in which each of the organic compound layers includes two light-emitting units, one embodiment of the present invention is not limited to this example. Each of the organic compound layers may include three or more light-emitting units. When a plurality of light-emitting units are stacked between a pair of electrodes with an intermediate layer sandwiched between the plurality of light-emitting units, the light-emitting device can perform high-luminance light emission with the current density kept low and can have high reliability. In addition, the light-emitting device can have low power consumption. Although not illustrated in FIG. 1, each of the light-emitting units may include a hole-injection layer, a hole-transport layer, an electron-blocking layer, a hole-blocking layer, an electron-transport layer, an electron-injection layer, or the like in addition to the above-described components. Each layer may have a stacked-layer structure of two or more layers.

Note that in this specification, description referring to the structure of one of the light-emitting devices 130a and 130b can apply to the structure of the other of the light-emitting devices 130a and 130b.

The intermediate layer 160a sandwiched between the first light-emitting unit 501a and the second light-emitting unit 502a preferably injects electrons into one of the first light-emitting unit 501a and the second light-emitting unit 502a and injects holes into the other of the first light-emitting unit 501a and the second light-emitting unit 502a when voltage is applied between the first electrode 101a and the second electrode 102, for example. When voltage is applied so that the potential of the second electrode 102 is higher than that of the first electrode 101a in FIG. 1, for example, the intermediate layer 160a injects electrons into the first light-emitting unit 501a and injects holes into the second light-emitting unit 502a.

In the light-emitting device 130a illustrated as an example in FIG. 1, when voltage is applied between a pair of electrodes (the first electrode 101a and the second electrode 102), electrons are injected from the cathode into the electron-injection layer 115 and holes are injected from the anode into the hole-injection layer 111a, so that current flows. Furthermore, electrons are injected from the first layer 161a of the intermediate layer 160a located on the anode side into the first electron-transport layer 114a_1 of the first light-emitting unit 501a, and holes are injected from the second layer 162a of the intermediate layer 160a located on the cathode side into the second hole-transport layer 112a_2 of the second light-emitting unit 502a. By recombination of the injected carriers (electrons and holes), excitons are formed. When carriers (electrons and holes) recombine and excitons are formed in the first light-emitting layer 113a_1 and the second light-emitting layer 113a_2 including light-emitting materials, the light-emitting materials included in the first light-emitting layer 113a_1 and the second light-emitting layer 113a_2 are brought into an excited state, causing light emission from the light-emitting materials.

In a preferable structure, the first layer 161a of the intermediate layer 160a located on the anode side is adjacent to the first electron-transport layer 114a_1 and is provided between the first electron-transport layer 114a_1 and the second light-emitting unit 502a as illustrated in FIG. 1. The structure enables electrons to efficiently injected into the first light-emitting unit 501a.

In a preferable structure for a lower driving voltage and more efficient light emission of the light-emitting device, a barrier against electron injection from the intermediate layer 160a into the first electron-transport layer 114a_1 is lowered and electrons generated in the intermediate layer 160a are smoothly injected and transported into the first electron-transport layer 114a_l. In view of this, an alkali metal or an alkaline earth metal, which has a low work function, or a compound of an alkali metal or an alkaline earth metal is generally used for the intermediate layer 160a. However, the metal and the compound easily deteriorate by oxygen or water in the air and water or a chemical solution used in the process by a lithography method, causing a significantly increased driving voltage or greatly reduced current efficiency in a light-emitting device.

Accordingly, the intermediate layer is preferably formed using a material resistant to oxygen and water in the air and water and a chemical solution used in the process by a lithography method, and accordingly, the intermediate layer 160a is preferably formed using a metal that is stable with respect to oxygen and water in the air and resistant to water and a chemical solution. However, such a metal, which is stable and has a low electron-injection property, may form an electron injection barrier between the intermediate layer 160a and the first electron-transport layer 114a_1, causing an increased driving voltage and reduced emission efficiency in the light-emitting device, for example.

In view of the above, in one embodiment of the present invention, a metal or metal compound, a first organic compound having a π-electron deficient heteroaromatic ring, and a second organic compound having two or more heteroaromatic rings that are bonded or condensed to each other and include three or more heteroatoms in total are used for the first layer 161 (the first layer 161a and the first layer 161b) positioned on the anode side of the intermediate layer 160a. With this structure, in the first layer 161, the first organic compound functions as an electron donor (donating electrons) to the second organic compound, and the first organic compound, the metal or metal compound, and the second organic compound interact with each other to form a donor level (a singly occupied molecular orbital (SOMO) level or a highest occupied molecular orbital (HOMO) level). When the first organic compound, the metal or metal compound, and the second organic compound interact with each other, the donor level (SOMO level or HOMO level) becomes high and a barrier against electron injection from the intermediate layer 160a to the first electron-transport layer 114a_1 can be lowered. The interaction enables electrons generated in the intermediate layer 160a to be injected and transported smoothly to the first electron-transport layer 114a_1. Accordingly, a light-emitting device with a low driving voltage can be fabricated.

Note that the lowest unoccupied molecular orbital (LUMO) level and the HOMO level of an organic compound are generally estimated by cyclic voltammetry (CV), photoelectron spectroscopy, optical absorption spectroscopy, inverse photoelectron spectroscopy, or the like. When values of different compounds are compared with each other, it is preferable that values estimated by the same measurement be used.

The SOMO level is an orbital derived from an unpaired electron of a metal, and when the metal or metal compound, the first organic compound, and the second organic compound interact with each other, the SOMO level can also be distributed on the orbitals of the first organic compound and the second organic compound. In other words, the electron orbital of the metal or metal compound and the electron orbitals of the organic compounds interact with each other.

Note that an organic compound containing a large number of atoms that enable an interaction can interact more stably with a metal or metal compound. Thus, the second organic compound used in one embodiment of the present invention is preferably a material that interacts with a metal or metal compound as a multidentate ligand of a bi-, tri- or higher dentate ligand. An organic compound interacting with a metal or metal compound as a multidentate ligand is stabilized when interacting with the metal or metal compound; thus, an intermediate layer having resistance to oxygen and water in the air and water and a chemical solution used in the process by a lithography method can be formed.

Examples of the atom that enables an interaction include a heteroatom having an unshared electron pair in an organic compound. For example, oxygen (O), nitrogen (N), sulfur (S), and phosphorus (P) are given, and nitrogen is preferable. Nitrogen has high electronegativity and thus easily interacts with a metal or metal compound. Here, since nitrogen can form a conjugated bond in an organic compound, nitrogen enables the organic compound to have a high carrier-transport property when used in the molecule, particularly in a heteroaromatic ring. It is further preferable that the heteroarornatic ring be an even-numbered ring such as a six-membered ring or an eight-membered ring. Since the unshared electron pair of nitrogen does not contribute to the conjugation in this structure, nitrogen is likely to interact with a metal or metal compound.

By the interaction between the metal or metal compound, the first organic compound, and the second organic compound, a donor level (SOMO level or HOMO level) can be formed, a barrier against electron injection to the electron-transport layer can be lowered, and electrons generated in the intermediate layer can be injected and transported smoothly to the electron-transport layer. The heteroaromatic ring included in the second organic compound is preferably a π-electron deficient heteroaromatic ring. With this structure, the second organic compound can have an electron-transport property, and electrons can be injected and transported smoothly from the intermediate layer to the electron-transport layer. When the second organic compound includes two or more heteroaromatic rings that are bonded or condensed to each other and include three or more nitrogen atoms in total, the LUMO level of the second organic compound can be easily lower than that of the first organic compound. When a material whose LUMO level is lower than that of the first organic compound is used for the second organic compound, the intermediate layer can be stabilized when the metal or metal compound, the first organic compound, and the second organic compound interact with each other, and the intermediate layer is less likely to deteriorate even through a photolithography process involving exposure to the air. Thus, electrons generated in the intermediate layer can be smoothly injected and transported to an adjacent electron-transport layer even through a photolithography process involving exposure of the EL layer to the air, so that a tandem light-emitting device in which an increase in driving voltage can be inhibited and which has high emission efficiency and high reliability can be fabricated by a photolithography process.

The second organic compound preferably includes a π-electron deficient heteroaromatic ring having an unshared electron pair. This structure enables a stable interaction with the metal or metal compound. The second organic compound is preferably a material that includes two or more π-electron deficient heteroaromatic rings each having an unshared electron pair and interacts with a metal or metal compound as a multidentate ligand such as a bi- or higher dentate ligand. An organic compound that interacts with a metal or metal compound as a multidentate ligand such as a bi- or higher dentate ligand is stabilized when interacting with the metal or metal compound; thus, an intermediate layer having resistance to oxygen and water in the air and water and a chemical solution used in a lithography process can be formed.

In the above structure, the first organic compound preferably includes an electron-donating group. With this structure, the first organic compound can have a high HOMO level and a high LUMO level; thus, the difference between the LUMO level of the first organic compound and the LUMO level of the second organic compound can be increased. Thus, it is possible to form an intermediate layer that can be stabilized by the interaction between the metal or metal compound, the first organic compound, and the second organic compound and that is thus less likely to deteriorate even through a photolithography process involving exposure to the air. Thus, electrons generated in the intermediate layer can be smoothly injected and transported to an adjacent electron-transport layer even through a photolithography process involving exposure of the EL layer to the air, so that and a tandem light-emitting device in which an increase in driving voltage can be inhibited and which has high emission efficiency and high reliability can be fabricated by a photolithography process.

Since a metal with a low work function typified by an alkali metal and an alkaline earth metal and a compound of such a metal have high reactivity with oxygen or water, using the metal or the compound for a light-emitting device fabricated through processing by a lithography method may cause a reduction in emission efficiency, an increase in driving voltage, a reduction in driving lifetime, generation of shrinkage (a non-emission region at an end portion of a light-emitting portion), or the like, leading to deterioration in the characteristics or a reduction in the reliability of the light-emitting device. However, in one embodiment of the present invention, even when an alkali metal, an alkaline earth metal, or a compound thereof is used, the alkali metal, the alkaline earth metal, or the compound thereof interacts with the first organic compound having a π-electron deficient heteroaromatic ring and the second organic compound having two or more heteroaromatic rings that are bonded or condensed to each other and include three or more heteroatoms in total, resulting in stabilization; thus, an intermediate layer having resistance to oxygen and water in the air and water and a chemical solution used in a lithography process can be formed.

When an alkali metal, an alkaline earth metal, or a compound of an alkali metal or an alkaline earth metal is used as the metal or metal compound in one embodiment of the present invention, the donor level (SOMO level or HOMO level) that is formed by interaction between the alkali metal, the alkaline earth metal, or the compound thereof and the first organic compound having a π-electron deficient heteroaromatic ring can be a high energy level, facilitating electron donation to the second organic compound. This structure is preferable because it lowers a barrier against electron injection from the intermediate layer 160a into the first electron-transport layer 114a_1 and enables electrons generated in the intermediate layer 160a to be injected and transported smoothly into the first electron-transport layer 114a_1.

Furthermore, since transition metals (metal elements belonging to Group 3 to Group 11) and metal elements belonging to Group 12 to Group 14 of the typical metal elements have low reactivity with oxygen and water in the air and water and a chemical solution used in a lithography process, the use of such a metal in a light-emitting device hardly causes deterioration due to water and oxygen, which might occur when a metal having a low work function is used. By contrast, such metals are stable and have a low electron-injection property, which may cause a reduction in emission efficiency, an increase in driving voltage, a reduction in driving lifetime, and the like of the light-emitting device.

In one embodiment of the present invention, even when any of transition metals (metal elements belonging to Group 3 to Group 11), metal elements belonging to Group 12 to Group 14 of the typical metal elements, or metal compounds thereof is used, it interacts with the first organic compound including a π-electron deficient heteroaromatic ring to form a donor level (SOMO level or HOMO level), so that electrons are easily donated to the second organic compound having two or more heteroaromatic rings that are bonded or condensed to each other and include three or more heteroatoms in total. This lowers a barrier against electron injection from the intermediate layer 160a into the first electron-transport layer 114a_1 and enables electrons generated in the intermediate layer 160a to be injected and transported smoothly into the first electron-transport layer 114a_1. The above structure is preferably employed, in which case an intermediate layer that has resistance to oxygen and water in the air and water and a chemical solution used in the process by a lithography method can be formed. Thus, one embodiment of the present invention can provide a light-emitting device having high moisture resistance, high water resistance, high oxygen resistance, high chemical resistance, a low driving voltage, and high emission efficiency.

### <Quantum Chemical Calculation Analysis of Interaction Between Metal or Metal Compound and Organic Compound>

Here, quantum chemical calculation analysis is performed on the case where the metal or metal compound, the first organic compound having an electron-donating property and an unshared electron pair, and the second organic compound having an electron-transport property interact with each other.

[Estimation of Interaction Between Metal or Metal Compound and Organic Compound] Here, quantum chemical calculation analysis is performed on the spin density and electrostatic potential (ESP) obtained at the time when the metal or metal compound, the first organic compound having a π-electron deficient heteroaromatic ring, and the second organic compound having two or more heteroaromatic rings that are bonded or condensed to each other and include three or more heteroatoms in total interact with each other. Note that in the calculation, 4,7-di-1-pyrrolidinyl-1,10-phenanthroline (abbreviation: Pyrrd-Phen) is used as the first organic compound, 2,2′-(2,2′-bipyridine-6,6′-diyl)bis(4-phenylbenzo[h]quinazoline (abbreviation: 6,6′(P-Bqn)2BPy) is used as the second organic compound, and lithium (Li) is used as the metal.

As the quantum chemistry computational program, Gaussian 09 is used. The calculation is performed using HPE SGI 8600 (Hewlett Packard Enterprise (HPE)). The most stable structures of the first organic compound alone in a ground state, the second organic compound alone in a ground state, and a composite material in a ground state of the first organic compound, the second organic compound, and the metal or metal compound are calculated by the density functional theory (DFT). As a basis function, 6-311G(d,p) is used, and as a functional, B3LYP is used. In the DFT, the total energy is represented as the sum of potential energy, electrostatic energy between electrons, electronic kinetic energy, and exchange-correlation energy including all the complicated interactions between electrons. Also in the DFT, exchange-correlation interaction is approximated by a functional (a function of another function) of one electron potential represented in terms of electron density to enable highly accurate calculations.

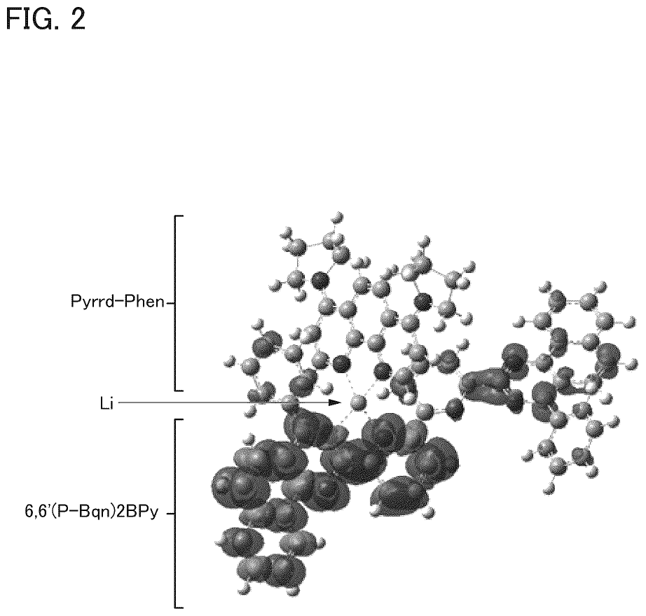

FIG. 2 shows an analysis result of the spin density distribution of the composite material in the ground state of the first organic compound (Pyrrd-Phen), the second organic compound (6,6′(P-Bqn)2BPy), and the metal (Li). In the diagrams, spheres represent atoms included in the compounds, and clouds around some of the atoms represent spin density distribution at the time when the threshold value of electron density distribution in atomic units is 0.0004 e/a₀³ (where e represents elementary charge (1 e=1.60218×10⁻¹⁹ C) and a₀ represents a Bohr radius (1 a₀=5.29177×10⁻¹¹ m)). The clouds represent localization of the doublet ground state of the compounds. Note that no spin density distribution is observed in the first organic compound (Pyrrd-Phen) in a ground state and the second organic compound (6,6′(P-Bqn)2BPy) in a ground state because the ground states of the first organic compound and the second organic compound are singlet ground states.

Meanwhile, in the composite material of the first organic compound (Pyrrd-Phen), the second organic compound (6,6′(P-Bqn)2BPy), and the metal (Li), which is one embodiment of the present invention, in the doublet ground state, the first organic compound (Pyrrd-Phen), the second organic compound (6,6′(P-Bqn)2BPy), and the metal (Li) interact with one another, and the metal (Li) is coordinated to nitrogen atoms (at 1- and 10-positions) having unshared electron pairs in the 1,10-phenanthroline ring of the first organic compound (Pyrrd-Phen) and nitrogen atoms having unshared electron pairs in the pyridine ring and benzo[h]quinazoline ring of the second organic compound (6,6′(P-Bqn)2BPy), which leads to stabilization of the formed composite material. Thus, as shown in FIG. 2, spins derived from unpaired electrons included in the metal (Li) are localized in the second organic compound (6,6′(P-Bqn)2BPy). Furthermore, a spin density distribution is not observed in the metal (Li). This indicates that the second organic compound (6,6′(P-Bqn)2BPy) is in a radical anion state owing to the interaction between the first organic compound (Pyrrd-Phen), the second organic compound (6,6′(P-Bqn)2BPy), and the metal (Li).

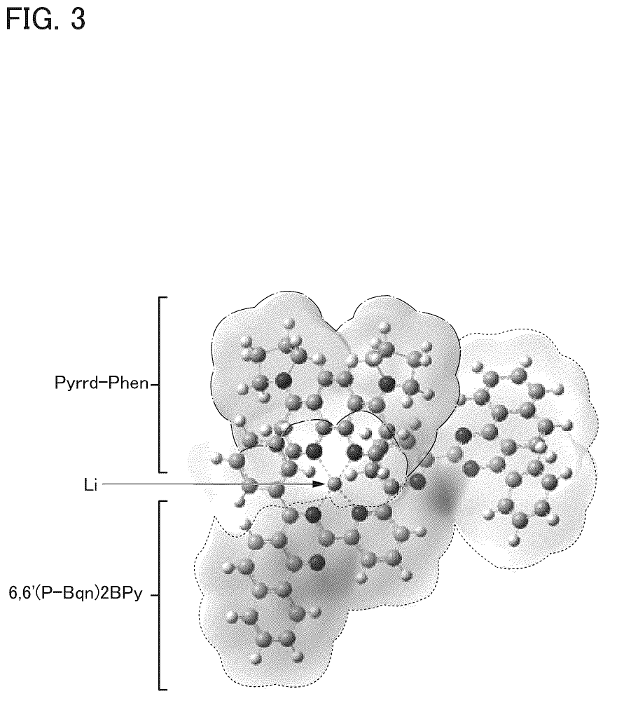

Next, FIG. 3 shows an analysis result of the electrostatic potential map of the composite material in the ground state of the first organic compound (Pyrrd-Phen), the second organic compound (6,6′(P-Bqn)2BPy), and the metal (Li). In the diagram, spheres represent atoms included in the compounds, and clouds around some of the atoms represent electrostatic potentials in electron density distribution at the time when the threshold value of electron density distribution in atomic units is 0.0004 e/a₀³. An electrostatic potential is the energy of interaction between positive point charge with unit quantity of electricity and electron distribution of a molecule. An electrostatic potential map denotes an electrostatic potential on an electron density isosurface in colors; in the map, a region with a negative electrostatic potential is denoted in red, a region with a positive electrostatic potential is denoted in blue, an atom in the region with a negative electrostatic potential has negative charge, and an atom in the region with a positive electrostatic potential has positive charge. FIG. 3 is a grayscale diagram converted from a colored image, and the region with a negative electrostatic potential corresponds to a region surrounded by a dotted line, and the region with a positive electrostatic potential corresponds to a region surrounded by a dashed-dotted line.

Meanwhile, in the composite material of the first organic compound (Pyrrd-Phen), the second organic compound (6,6′(P-Bqn)2BPy), and the metal (Li), which is one embodiment of the present invention, in the doublet ground state, the first organic compound (Pyrrd-Phen), the second organic compound (6,6′(P-Bqn)2BPy), and the metal (Li) interact with one another, and the metal (Li) is coordinated to nitrogen atoms (at 1- and 10-positions) having unshared electron pairs in the 1,10-phenanthroline ring of the first organic compound (Pyrrd-Phen) and nitrogen atoms having unshared electron pairs in the pyridine ring and benzo[h]quinazoline ring of the second organic compound (6,6′(P-Bqn)2BPy), which leads to stabilization of the formed composite material. Accordingly, as shown in FIG. 3, a positive electrostatic potential is mainly distributed in the metal (Li) and the first organic compound (Pyrrd-Phen), and a negative electrostatic potential is mainly distributed in the second organic compound (6,6′(P-Bqn)2BPy). It is also shown that the electrostatic potential of the nitrogen atoms having unshared electron pairs in the pyridine ring and the benzo[h]quinazoline ring of the second organic compound (6,6′(P-Bqn)2BPy) is negative whereas the electrostatic potential of the metal (Li) is positive. The Li atom has a Mulliken partial charge of +0.691 e in atomic units.

### [Estimation of SOMO Level or Stabilization Energy]

Next, a quantum chemical calculation is performed for estimation of the stabilization energy when the metal or metal compound, the first organic compound having a π-electron deficient heteroaromatic ring, and the second organic compound having two or more heteroaromatic rings that are bonded or condensed to each other and include three or more heteroatoms in total interact with each other, and the SOMO level formed at this time.

As the quantum chemistry computational program, Gaussian 09 is used. The calculation is performed using HPE SGI 8600. First, the most stable structures of the first organic compound in a ground state, the second organic compound in a ground state, the metal or metal compound in a ground state, the composite material in a ground state of the first organic compound and the metal or metal compound, the composite material in a ground state of the second organic compound and the metal or metal compound, and the composite material in a ground state of the first organic compound, the second organic compound, and the metal or metal compound are calculated by DFT. As basis functions, 6-311G(d,p) and LanL2DZ are used, and as a functional, B3LYP is used. Next, the stabilization energy is calculated by subtracting the sum of the total energy of the organic compound(s) alone and the total energy of the metal or metal compound alone from the total energy of the composite material of the organic compound(s) and the metal or metal compound. That is, (stabilization energy)=(the total energy of the composite material of the organic compound(s) and the metal or metal compound)−(the total energy of the organic compound(s) alone)−(the total energy of the metal or metal compound alone).

The calculation result of a composite material including lithium (Li) as the metal or metal compound, 4,7-di-1-pyrrolidinyl-1,10-phenanthroline (abbreviation: Pyrrd-Phen) as the first organic compound, and 2,2′-(2,2′-bipyridine-6,6′-diyl)bis(4-phenylbenzo[h]quinazoline) (abbreviation: 6,6′(P-Bqn)2BPy) as the second organic compound is shown below. For comparison, the following also shows the calculation result of a composite material including lithium (Li) as the metal or metal compound, Pyrrd-Phen as the first organic compound, and 2,9-di(naphthalen-2-yl)-4,7-diphenyl-1,10-phenanthroline (abbreviation: NBphen) in place of 6,6′(P-Bqn)2BPy as the second organic compound; the calculation result of a composite material including lithium (Li) and Pyrrd-Phen; the calculation result of a composite material including lithium (Li) and 6,6′(P-Bqn)2Bpy; and the calculation result of a composite material including lithium (Li) and NBphen. Note that 6,6′(P-Bqn)2BPy is the second organic compound having two or more heteroaromatic rings that are bonded or condensed to each other and include three or more heteroatoms in total. NBphen is an organic compound having two or more heteroaromatic rings bonded or condensed to each other and including less than three heteroatoms in total.

TABLE 1

| | Stabilization | |
|---|---|---|
| | energy | SOMO |
| | (eV) | (eV) |
| Pyrrd-Phen + 6,6′(P-Bqn)2BPy + Li | −3.79 | −2.32 |
| Pyrrd-Phen + NBphen + Li | −3.67 | −2.35 |
| Pyrrd-Phen + Li | −2.17 | −2.46 |
| 6,6′(P-Bqn)2BPy + Li | −3.07 | −2.88 |
| NBphen + Li | −2.31 | −2.96 |

TABLE 2

| | LUMO | HOMO |
|---|---|---|
| | (eV) | (eV) |
| Pyrrd-Phen | −1.35 | −5.65 |
| 6,6′(P-Bqn)2BPy | −2.07 | −5.99 |
| tPy2P | −1.65 | −6.37 |
| 2Py3Tzn | −2.20 | −6.89 |
| NBphen | −2.04 | −5.74 |

As shown in the above tables, the stabilization energy of the composite material of lithium (Li), the first organic compound (Pyrrd-Phen), and the second organic compound (6,6′(P-Bqn)2BPy) of one embodiment of the present invention has a negative value having a larger absolute value. This indicates that energy is more stable in the case where the organic compounds and the metal or metal compound interact with each other than in the case where the organic compounds and the metal or metal compound do not interact with each other. The SOMO level formed at this time is higher than the HOMO level of each of the first organic compound (Pyrrd-Phen) and the second organic compound (6,6′(P-Bqn)2BPy) and has a small difference from the LUMO level of each of the first organic compound (Pyrrd-Phen) and the second organic compound (6,6′(P-Bqn)2BPy), and thus the electron-injection property is excellent, which is preferable. Note that the values of the energy levels of the SOMO, HOMO, and LUMO levels in the tables are calculated values and the absolute values of the calculated values are different from those of measured values in some cases.

Although not as much as the composite material of lithium (Li), the first organic compound (Pyrrd-Phen), and the second organic compound (6,6′(P-Bqn)2BPy), the composite material of lithium (Li), the first organic compound (Pyrrd-Phen), and NBphen has a negative value of the stabilization energy, and the energy is more stable in the case where the organic compounds and the metal interact with each other than in the case where the organic compounds and the metal do not interact with each other.

Although the composite material of lithium (Li) and the first organic compound (Pyrrd-Phen) has a negative value of the stabilization energy, the composite material further including the second organic compound is more stable.

In Table 1, the composite material of lithium (Li) and the second organic compound (6,6′(P-Bqn)2BPy) has a low SOMO level of −2.88 eV. On the other hand, the composite material including the first organic compound (Pyrrd-Phen) in addition to lithium (Li) and the second organic compound (6,6′(P-Bqn)2BPy) has a SOMO level of −2.32 eV, which is higher than that of the composite material of lithium (Li) and the second organic compound (6,6′(P-Bqn)2BPy), and has an excellent electron-injection property. Although the composite material of lithium (Li) and the second organic compound (6,6′(P-Bqn)2BPy) has stabilization energy of −3.07 eV, the composite material including the first organic compound (Pyrrd-Phen) in addition to lithium (Li) and the second organic compound (6,6′(P-Bqn)2BPy), and has stabilization energy of −3.79 eV and is more stable.

The composite material of lithium (Li) and NBphen has a SOMO level of −2.96 eV, which is relatively low among organic compounds used in light-emitting devices, On the other hand, the composite material including the first organic compound (Pyrrd-Phen) in addition to lithium (Li) and NBphen has a SOMO level of −2.35 eV, which is higher than that of the composite material of lithium (Li) and NBphen, and thus has an excellent electron-injection property. Although the composite material of lithium (Li) and NBphen has stabilization energy of −2.31 eV, the composite material including the first organic compound (Pyrrd-Phen) in addition to lithium (Li) and NBphen has stabilization energy of −3.67 eV and is more stable,

That is to say, the composite material of one embodiment of the present invention, which includes the metal or metal compound, the first organic compound having a −π-electron deficient heteroaromatic ring, and the second organic compound having two or more heteroaromatic rings that are bonded or condensed to each other and include three or more heteroatoms in total, is stable and has an excellent electron-injection property and is suitable for an intermediate layer accordingly.

Next, the following tables show calculation results of composite materials including a metal belonging to Group 11 or Group 13, specifically silver (Ag) or indium (In), as the metal or metal compound; Pyrrd-Phen as the first organic compound; and 4′,4″-(1,4-phenylene)bis(2,2′:6′,″-terpyridine) (abbreviation: tPy2P) or 2,4,6-tris(2-pyridyl)-1,3,5-triazine (abbreviation: 2Py3Tzn) as the second organic compound. For comparison, the tables also show calculation results of composite materials each including silver (Ag) or indium (In) as the metal or metal compound, Pyrrd-Phen as the first organic compound, and NBphen in place of the second organic compound. Note that tPy2P and 2Py3Tzn are each the second organic compound having two or more heteroaromatic rings that are bonded or condensed to each other and include three or more heteroatoms in total. NBphen is the organic compound having two or more heteroaromatic rings bonded or condensed to each other and including less than three heteroatoms in total.

TABLE 3

| | Stabilization | |
|---|---|---|
| | energy | SOMO |
| | (eV) | (eV) |
| Pyrrd-Phen + tPy2P + In | −2.15 | −3.03 |
| Pyrrd-Phen + NBphen + In | −1.25 | −3.02 |

TABLE 4

| | Stabilization | |
|---|---|---|
| | energy | SOMO |
| | (eV) | (eV) |
| Pyrrd-Phen + 2Py3Tzn + Ag | −1.79 | −2.56 |
| Pyrrd-Phen + NBphen + Ag | −1.26 | −2.50 |

As shown in the above tables, each of the composite materials of the metal belonging to Group 11 or Group 13, the first organic compound, and the second organic compound of one embodiment of the present invention has a high stabilization energy and a stable structure, and thus the composite materials are preferable. The SOMO level formed at this time is high and the electron-injection property is excellent, which is preferable.

In a general fabrication process of a light-emitting device, an EL layer, particularly an intermediate layer, of the light-emitting device is mostly formed by a vacuum evaporation method. Thus, it is preferable to use a material that can be easily deposited by vacuum evaporation, i.e., a material with a low melting point. The metals belonging to Group 11 and Group 13 have low melting points and thus, they can be suitably used for vacuum evaporation. The metals belonging to Group 11 and Group 13 are preferable because they are stable with respect to oxygen and water in the air. A vacuum evaporation method is preferably used, in which case a metal atom and an organic compound can be easily mixed.

Furthermore, Ag and In can be used also as a cathode material. Using the same material for an intermediate layer and a cathode is preferable, in which the fabrication of the light-emitting device can become easier. Moreover, the fabrication cost of the light-emitting device can be reduced.

The above indicates that owing to the interaction between the first organic compound having a π-electron deficient heteroaromatic ring, the metal or metal compound, and the second organic compound having two or more heteroaromatic rings that are bonded or condensed to each other and include three or more heteroatoms in total, the combination of the first organic compound and the metal or metal compound functions as an electron donor to the second organic compound. In one embodiment of the present invention, the intermediate layer formed using the materials included in this combination can have a favorable electron-injection property and resistance to oxygen and water in the air and water and a chemical solution used in the process by a lithography method; thus, the light-emitting device can have a reduced driving voltage and high emission efficiency.

### [Analysis of Composite Material of Metal or Metal Compound and Organic Compounds]

In the light-emitting device of one embodiment of the present invention, the intermediate layer includes a composite material in which the first organic compound, the second organic compound, and the metal or metal compound interact with each other, and the measurement of the composite material is performed.

Specifically, a film in which the first organic compound, the second organic compound, and the metal or metal compound are mixed at the same mixture ratio as that in the intermediate layer used in the light-emitting device is prepared, and the film is measured by mass spectrometry such as time-of-flight secondary ion mass spectrometry (ToF-SIMS), laser desorption/ionization mass spectrometry (LDI-MS), or matrix assisted laser desorption/ionization mass spectrometry (MALDI-MS).

As a result of the mass analysis, in the case where the mass number of the first organic compound is M1, the mass number of the second organic compound is M2, and the mass number of the metal or metal compound is M3, positive ions with a mass-to-charge ratio, m/z, of M1+M2+M3 or M1+M2+M3+1 can be detected. In the case where positive ions are measured by the aforementioned mass spectrometry, detected ions are derived from a compound contained in the film, a substituent desorbed from the compound, a compound from which a substituent has been desorbed, and association thereof. Thus, for example, in the case where the mass number of the metal desorbed from the metal compound is M31, positive ions with n/of M1+M2+M31 or M1+M2+M31+1 can be detected.

### <Structure of Intermediate Layer>

Next, details of the structure of the intermediate layer that can be used for the light-emitting devices 130a and 130b are described.

### <<First Layer>>

As the first layer (the first layer 161a and the first layer 161b) of the intermediate layer, which is located on the anode side, it is preferable to use a mixed layer or a stacked layer including a metal or metal compound, the first organic compound, and the second organic compound (which will be described later in detail). The metal or metal compound and the first organic compound interact with each other and form a donor level (SOMO level or HOMO level), and the combination of the metal or metal compound and the first organic compound can function as an electron donor to the second organic compound with an electron-transport property.

In other words, the metal or metal compound functions as a donor for donating electrons to the second organic compound functioning as an electron acceptor. In the case where the first layer includes only the second organic compound functioning as an electron acceptor and the metal or metal compound functioning as a donor, the metal or metal compound donates electrons, and becomes unstable.

Thus, the first layer of one embodiment of the present invention includes an organic compound including an electron-donating group in addition to the metal or metal compound functioning as a donor and the organic compound functioning as an electron acceptor, whereby interaction occurs and a stable structure is formed. The stable structure inhibits deterioration of the first layer of one embodiment of the present invention even after exposure to the air, a photolithography process, and the like, and thus the first layer of one embodiment of the present invention can be suitably used for the light-emitting device.

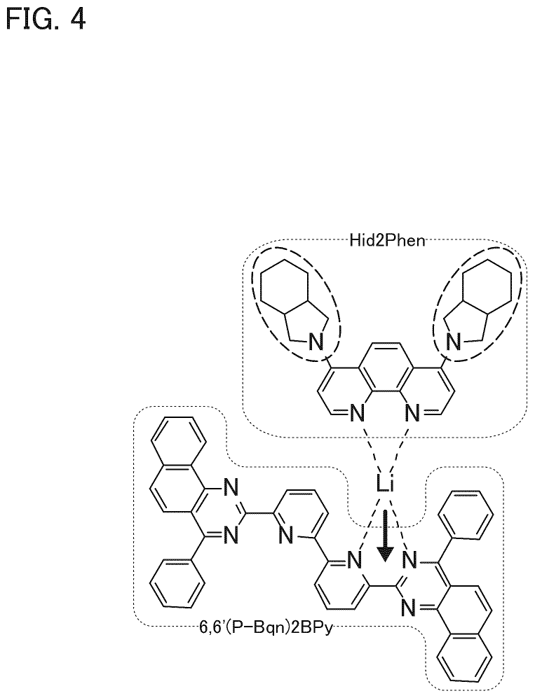

Specifically, as illustrated in FIG. 4, when the first organic compound (Hid2Phen) having an electron-donating group is included in addition to the metal (Li) functioning as a donor and the second organic compound (6,6′(P-Bqn)2BPy) functioning as an electron acceptor, Li that becomes unstable by donating electrons to 6,6′(P-Bqn)2BPy (indicated by an arrow in the drawing) forms a donor level with Hid2Phen, whereby the composite material including 6,6′(P-Bqn)2BPy, Li, and Hid2Phen is stabilized.

When a layer that includes these materials in combination is used as the first layer of the intermediate layer, electrons generated in the first layer can be easily injected into the first light-emitting unit. Alternatively, electrons generated in the second layer (the second layer 162a and the second layer 162b) of the intermediate layer, which is located on the cathode side, can be easily injected into the first light-emitting unit. This facilitation of electron injection into the first light-emitting unit enables a reduced driving voltage and increased emission efficiency of the light-emitting devices,

In the case where a stack-layer structure of the metal or metal compound, the first organic compound, and the second organic compound is used as the first layer positioned on the anode side in the intermediate layer, the layer including the metal or metal compound is preferably closer to the cathode side than the layer including at least one of the first organic compound and the second organic compound is. When the metal is closer to the cathode side than the first organic compound or the second organic compound having a heteroaromatic ring and an electron-transport property is, electrons are easily injected into the first light-emitting unit, whereby the driving voltage of the light-emitting device can be further reduced and the emission efficiency thereof can be further improved. Furthermore, a mixed layer including the metal or metal compound, the first organic compound, and the second organic compound is preferably used as the first layer. The formation of the mixed layer of the metal or metal organic, the first organic compound, and the second organic compound facilitates interaction between these substances, so that the combination of the first organic compound and the metal or metal organic functions as an electron donor (electron donating) to the second organic compound; thus, a barrier against electron injection from the second light-emitting unit side to the first light-emitting unit side can be further lowered. This facilitates electron injection into the first light-emitting unit and accordingly enables the light-emitting device to have a further reduced driving voltage and further increased emission efficiency. When the first layer of the intermediate layer is the mixed layer of the metal or metal organic, the first organic compound, and the second organic compound, the first layer of the intermediate layer is less likely to be crystallized than when having the stacked-layer structure of the metal, the first organic compound, and the second organic compound. Accordingly, the first layer of the intermediate layer is not easily crystallized even when affected by oxygen or water in the air and a chemical solution or water during processing by a lithography method for forming part of the organic compound layer. An increase in driving voltage or a reduction in current efficiency of the light-emitting device due to crystallization of the intermediate layer can be prevented. Thus, the mixed layer can be suitably used for the intermediate layer of the light-emitting device in which part of the organic compound layer is formed by a lithography process, as compared with the case where the stacked-layer structure is employed.

### <Metal or Metal Compound>

As the metal or metal compound, a typical metal, a transition metal, or a compound thereof can be used. Examples of the metal compound include a metal oxide, a metal nitride, a metal oxynitride in which nitrogen is added to a metal oxide, and a metal nitride oxide in which oxygen is added to a metal nitride. Among these, a metal oxide is preferable because it is stable in the air, less likely to deteriorate in the air, and easy to handle. However, even when the metal oxide is used instead of the alkali metal compound or the like in a conventional light-emitting device, characteristics comparable to those offered by the alkali metal compound or the like are hard to obtain because of the stability of the metal oxide. Accordingly, an organic EL device with practical characteristics cannot be obtained. By contrast, in one embodiment of the present invention, an organic EL device with favorable characteristics can be obtained even when a stable metal compound such as a metal oxide is used.

As the main-group metal, an alkali metal (Group 1 element) such as Li, Na, K, or Cs, an alkaline earth metal (Group 2 element) such as Mg, Ca, or Ba, a Group 12 element such as Zn, an earth metal (Group 13 element) such as Al or In, a Group 14 element such as Sn, or a compound of a Group 1, 2, 13, or 14 element can be used.

An alkali metal, an alkaline earth metal, or a compound of an alkali metal or an alkaline earth metal is preferably used as the metal or metal compound, in which case the donor level formed by interaction between the alkali metal, the alkaline earth metal, or the compound and the first organic compound can be a high energy level, facilitating electron donation to the second organic compound; accordingly, electrons generated in the intermediate layer can be smoothly injected and transported into the electron-transport layer, enabling the light-emitting device to have a low driving voltage and emit light with high efficiency.

As the transition metal, any of Group 3 elements, including Y and lanthanoids such as Eu and Yb, Group 7 elements such as Mn, Group 8 elements such as Fe, Group 9 elements such as Co, Group 10 elements such as Ni and Pt, Group 11 elements such as Cu, Ag, and Au, and a compound of a Group 3, 7, 8, 9, 10, or 11 element can be used. The transition metal is preferable because it has low reactivity with components of the air such as water and oxygen.

Among the above-described examples, it is further preferable to use a metal belonging to an odd-numbered group (Group 1, Group 3, Group 5, Group 7, Group 9, Group 11, or Group 13). It is particularly preferable to use a metal having one electron (an unpaired electron) in the orbital of the outermost shell among transition metals belonging to the odd-numbered groups, in which case the metal is likely to form SOMO with the first organic compound.

A metal that has a low melting point and that can be deposited by a vacuum evaporation method is preferably used because a mixed layer of this metal and an organic compound is easy to form. Specifically, for example, the metals belonging to Group 11 and Group 13 have low melting points and thus, they can be suitably used for vacuum evaporation. The metals belonging to Group 11 and Group 13 are preferable because they are stable with respect to oxygen and water in the air.

### <First Organic Compound>

As the first organic compound, an organic compound having a π-electron deficient heteroaromatic ring can be used. In order that the first organic compound and the metal or metal compound interact with each other to function as an electron donor (donating electrons) to the second organic compound, the π-electron deficient heteroaromatic ring preferably includes an unshared electron pair, and the unshared electron pair preferably has an electron-donating property. In other words, the first organic compound preferably includes a basic π-electron deficient heteroaromatic ring. Moreover, nitrogen has high electronegativity and thus easily interacts with a metal or metal compound. In addition, since nitrogen can form a conjugated bond in an organic compound, nitrogen enables the organic compound to have a high carrier-transport property when used in the molecule, particularly in a heteroaromatic ring. Accordingly, the first organic compound preferably includes a heteroaromatic ring containing nitrogen. It is further preferable that the heteroaromatic ring be an even-numbered ring such as a six-membered ring or an eight-membered ring. Since the unshared electron pair of nitrogen does not contribute to the conjugation in this structure, nitrogen is likely to interact with the metal or metal compound. To inject and transport electrons smoothly from the intermediate layer to the electron-transport layer, the first organic compound preferably has an electron-transport property. Specifically, for example, the first organic compound preferably includes a pyridine ring.

It is preferable that the first organic compound include two or more π-electron deficient heteroaromatic rings each having an unshared electron pair, and the two or more π-electron deficient heteroaromatic rings be bonded or condensed to each other. Thus, the intermediate layer is stabilized when the metal or metal compound interacts with the first organic compound and the second organic compound each serving as a bidentate or multidentate ligand; thus, the intermediate layer that is less likely to deteriorate even through a photolithography process involving exposure to the air can be formed. Thus, electrons generated in the intermediate layer can be smoothly injected and transported to the adjacent electron-transport layer even when a photolithography process involving exposure of an EL layer to the air is performed, so that a highly reliable tandem light-emitting device with a suppressed increase in driving voltage and high emission efficiency can be fabricated through a photolithography process. Specifically, for example, the first organic compound preferably includes a heteroaromatic ring having two or more pyridine rings. In particular, an organic compound having a bipyridine skeleton is preferable because its nitrogen atoms are likely to coordinate with a metal and thus the organic compound easily interacts with the metal or metal compound.

Furthermore, a phenanthroline ring is preferable because of its rigidity and high stability. Among organic compounds having a phenanthroline ring, an organic compound having a 1,10-phenanthroline ring, the two nitrogen atoms of which can be coordinated to a metal, is particularly preferably used to facilitate interaction with the metal or metal compound.

The first organic compound may have a structure in which a plurality of phenanthroline rings are bonded to each other via a single bond or a divalent group. Specific examples of the divalent group include an alkylene group and an arylene group.

An alkylene group refers to a divalent group obtained by eliminating two hydrogen atoms from an alkane. Specific examples of an alkylene group include a divalent group having a structure obtained by eliminating one hydrogen atom from any of the above specific examples of an alkyl group.

An arylene group refers to a divalent group obtained by eliminating two hydrogen atoms from an aromatic hydrocarbon. Specific examples of an arylene group include a divalent group having a structure obtained by eliminating one hydrogen atom from any of the above specific examples of an aryl group. Note that the arylene group may further have a substituent, and specific examples of the substituent include an alkyl group, an alkoxy group, and a phenyl group.

The first organic compound preferably has an electron-donating group. Accordingly, the first organic compound can have a high HOMO level and a high LUMO level; thus, the difference between the LUMO level of the first organic compound and the LUMO level of the second organic compound can be increased, in which case the intermediate layer can be stabilized by interaction between the metal or metal compound, the first organic compound, and the second organic compound and is less likely to deteriorate even through a photolithography process involving exposure to the air. Thus, electrons generated in the intermediate layer can be smoothly injected and transported to the adjacent electron-transport layer even through a photolithography process involving exposure of the EL layer to the air, so that a highly reliable tandem light-emitting device with a suppressed increase in driving voltage and high emission efficiency can be fabricated through a photolithography process.

As the first organic compound, an organic compound having a phenanthroline ring with an electron-donating group is further preferably used. Specifically, introducing an electron-donating group to a 1,10-phenanthroline ring can increase the electron density of the phenanthroline ring and the efficiency of the interaction with the metal or metal compound. Furthermore, an electron-donating group is preferably bonded to at least one of the 4- and 7-positions of the 1,10-phenanthroline ring. Introducing electron-donating groups to the 4- and 7-positions can increase the electron density of the nitrogen atoms at the 1- and 10-positions, which are the para-positions with respect to the 4- and 7-positions. In addition, steric congestion around the nitrogen atoms at the 1- and 10-positions can be inhibited, and the electron density around the nitrogen atoms can be increased. This structure facilitates the interaction with the metal or metal compound and is thus preferable.

Specific examples of the electron-donating group include an alkyl group, an alkoxy group, an aryloxy group, an alkylamino group, an arylamino group, and a heterocyclic amino group. Note that the electron-donating group that is preferably introduced to the t-electron deficient heteroaromatic ring such as a phenanthroline ring are not limited to the above examples. As long as a group that is introduced into a π-electron deficient heteroaromatic ring such as a phenanthroline ring can increase the electron density of the π-electron deficient heteroaromatic ring, the group can be used as the electron-donating group. The electron-donating group may be introduced to a π-electron deficient heteroaromatic ring such as a phenanthroline ring via an arylene group such as a phenylene group, and the arylene group is preferably a p-phenylene group.

An alkyl group refers to a monovalent group obtained by eliminating one hydrogen atom from an alkane (CₙH₂ₙ₊₂). Specific examples of an alkyl group include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, and a 2,3-dimethylbutyl group.

An alkoxy group refers to a monovalent group with a structure in which an alkyl group is bonded to an oxygen atom, Specific examples of an alkoxyl group include a methoxy group, an ethoxy group, an n-propoxy group, an isopropoxy group, an n-butoxy group, a sec-butoxy group, an isobutoxy group, a tert-butoxy group, an n-pentyloxy group, an isopentyloxy group, a sec-pentyloxy group, a tert-pentyloxy group, a neopentyloxy group, an n-hexyloxy group, an isohexyloxy group, a sec-hexyloxy group, a tert-hexyloxy group, and a neohexyloxy group.

An aryloxy group refers to a monovalent group with a structure in which an aryl group is bonded to an oxygen atom. An aryl group refers to a monovalent group obtained by eliminating one hydrogen atom from one of carbon atoms forming the ring(s) of a monocyclic or polycyclic aromatic compound. Specific examples of an aryloxy group include a phenoxy group, an o-tolyloxy group, a m-tolyloxy group, a p-tolyloxy group, a mesityloxy group, an o-biphenyloxy group, a m-biphenyloxy group, a p-biphenyoxyl group, a 1-naphthyloxy group, a 2-naphthyloxy group, and a 2-fluorenyloxy group. Note that the aryloxy group may further have a substituent, and specific examples of the substituent include an alkyl group, an alkoxy group, and a phenyl group.

An alkylamino group refers to a monovalent group obtained by eliminating one hydrogen atom from the nitrogen atom of a primary amine in which one alkyl group is bonded to the nitrogen atom, or from the nitrogen atom of a secondary amine in which two alkyl groups are bonded to the nitrogen atom. Specific examples of an alkylamino group include a dimethylamino group and a diethylamino group.

An arylamino group refers to a monovalent group obtained by eliminating one hydrogen atom from the nitrogen atom of a primary amine in which one aryl group is bonded to the nitrogen atom, or from the nitrogen atom of a secondary amine in which two aryl groups are bonded to the nitrogen atom. Specific examples of an arylamino group include a diphenylamino group, a bis(cx-naphthyl)amino group, and a bis(m-tolyl)amino group. Note that the arylamino group may further have a substituent, and specific examples of the substituent include an alkyl group, an alkoxy group, and a phenyl group.

Note that an amino group having a structure in which both an alkyl group and an aryl group are bonded to the nitrogen atom can be regarded as an alkylamino group or an arylamino group. Specific examples of such an amino group include an N-methyl-N-phenylamino group.

A heterocyclic amino group refers to a monovalent group obtained by eliminating one hydrogen atom from one of the nitrogen atoms forming a ring of a heterocyclic amine. Here, the heterocyclic amine refers to a monocyclic or polycyclic heterocyclic compound in which at least one of the atoms forming the ring(s) is a nitrogen atom bonded to a hydrogen atom. Specific examples of a heterocyclic amino group include groups represented by Structural Formulas (R-1) to (R-26) below. Note that the heterocyclic amino group may further have a substituent, and specific examples of the substituent include an alkyl group, an alkoxy group, and a phenyl group.

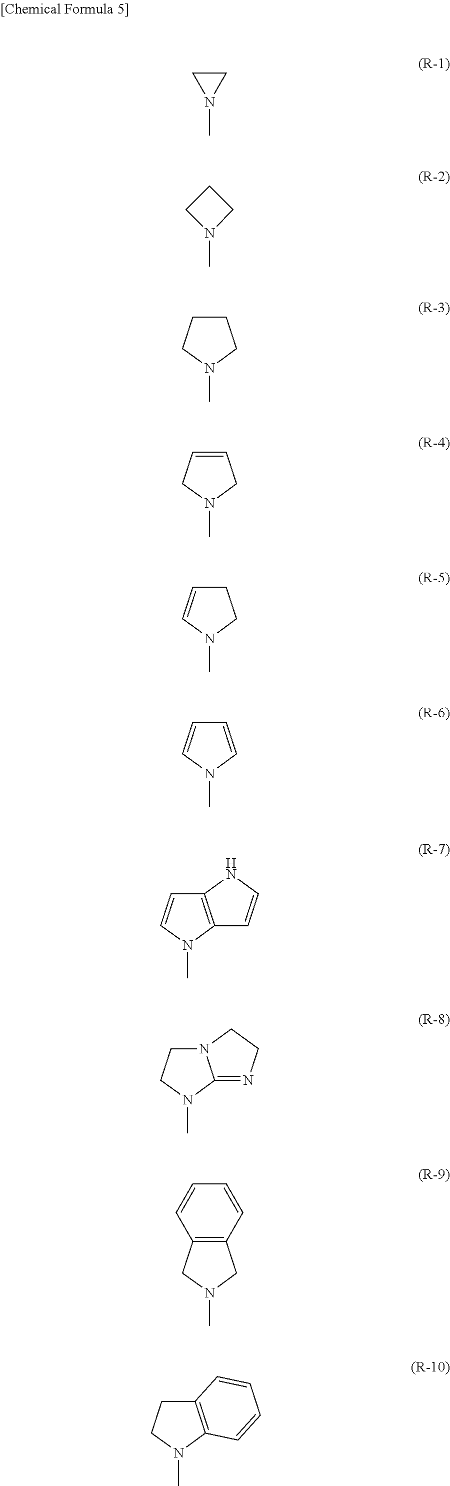

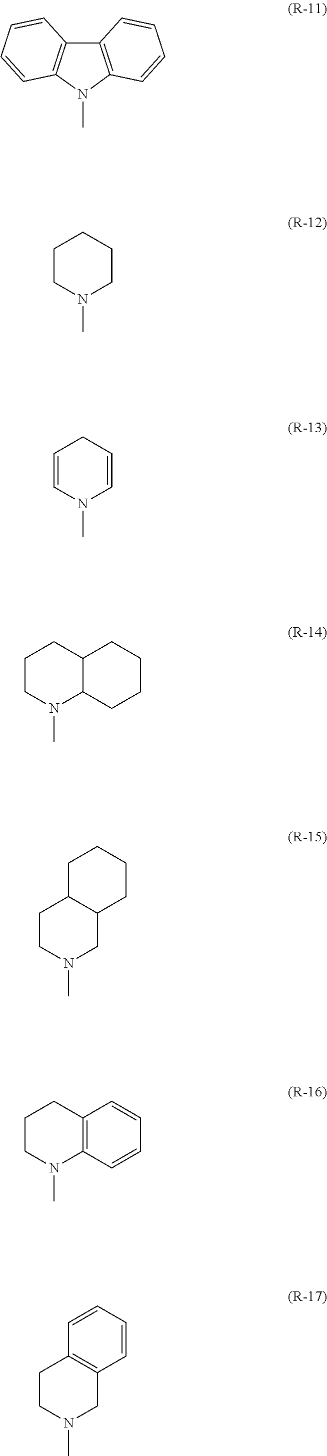

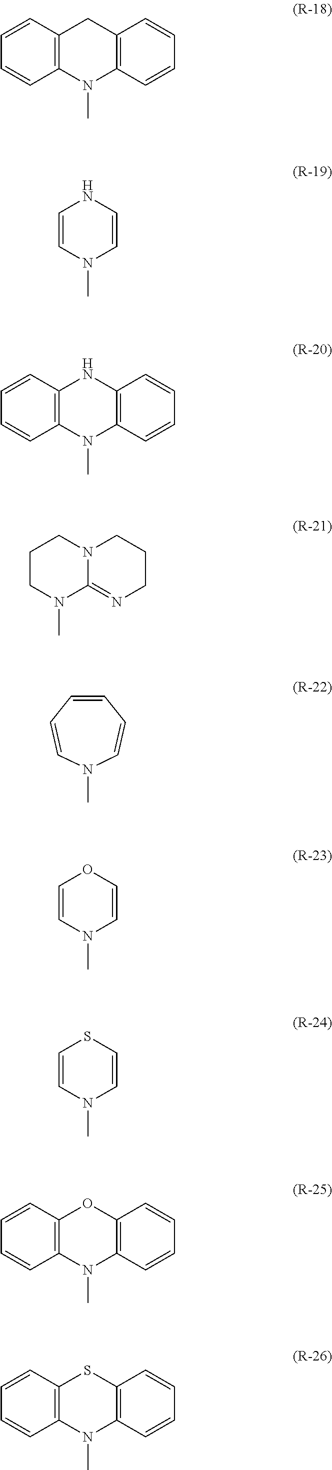

In some cases, the property of donating electrons to the phenanthroline ring is lower in a heterocyclic amino group which has aromaticity and in which an unshared electron pair of the nitrogen atom contributes to the aromaticity than in a heterocyclic amino group which has aromaticity and in which an unshared electron pair of the nitrogen atom does not contribute to the aromaticity. Therefore, among the above heterocyclic amino groups, a heterocyclic amino group which has aromaticity and in which an unshared electron pair of the nitrogen atom does not contribute to the aromaticity is further preferable, Specifically, the group represented by Structural Formula (R-1), (R-2), (R-3), (R-4), (R-5), (R-8), (R-9), (R-10), (R-12), (R-14), (R-15), (R-16), (R-17), or (R-21) is further preferably used as the electron-donating group. Among these groups, the group represented by Structural Formula (R-3), (R-4), (R-8), or (R-21) is preferably used because the group has a high electron-donating property and can further increase the electron density of the phenanthroline ring.

Specific examples of the electron-donating group include groups represented by Structural Formulas (R-27) and (R-28) below.

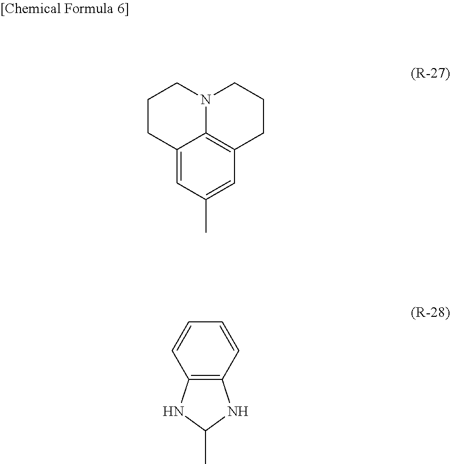

Note that an organic compound with a r-electron deficient heteroaromatic ring that can be used as the first organic compound may have both the above-described electron-donating group and another substituent. Specific examples of the substituent that can be introduced to the r-electron deficient heteroaromatic ring together with the above electron-donating group include an aryl group. Specific examples of the aryl group include a phenyl group, an o-tolyl group, a m-tolyl group, a p-tolyl group, a mesityl group, an o-biphenyl group, a m-biphenyl group, a p-biphenyl group, a 1-naphthyl group, a 2-naphthyl group, and a 2-fluorenyl group, Note that the aryl group may further have a substituent, and specific examples of the substituent include an alkyl group, an alkoxy group, and a phenyl group.

The first organic compound may have a structure in which a plurality of phenanthroline rings are bonded to each other via a single bond or a divalent group. Specific examples of the divalent group include an alkylene group and an arylene group.

Specific examples of an organic compound with a π-electron deficient heteroaromatic ring that can be used as the first organic compound are represented by Structural Formulas (100) to (112). Note that the organic compound that can be used as the first organic compound is not limited to those examples.

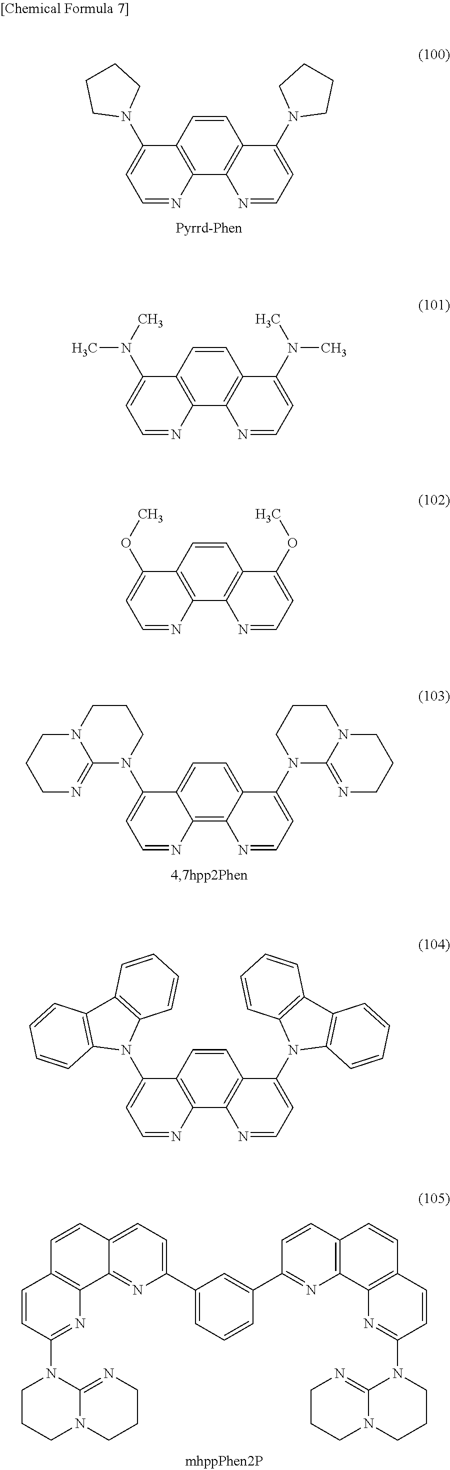

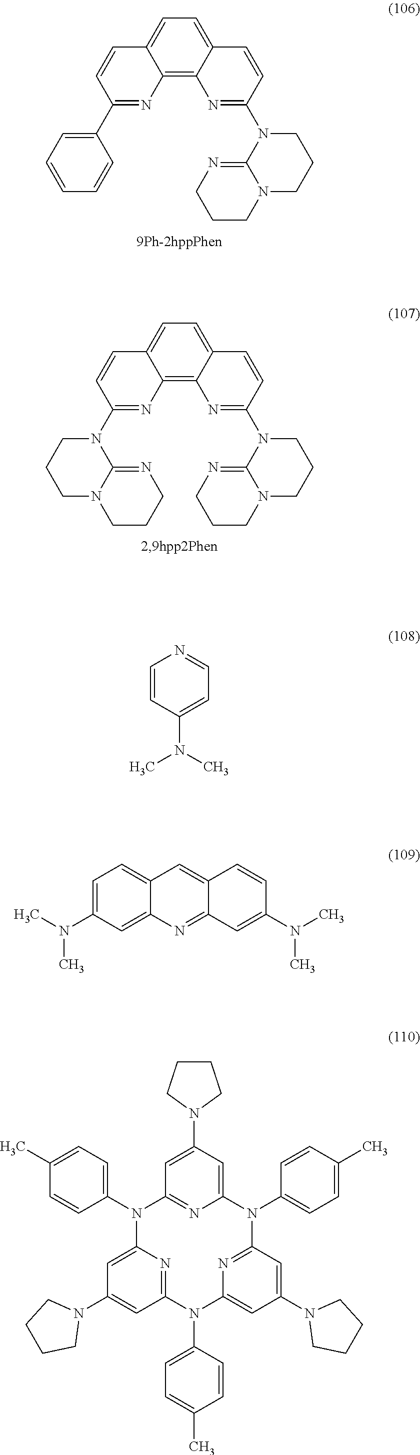

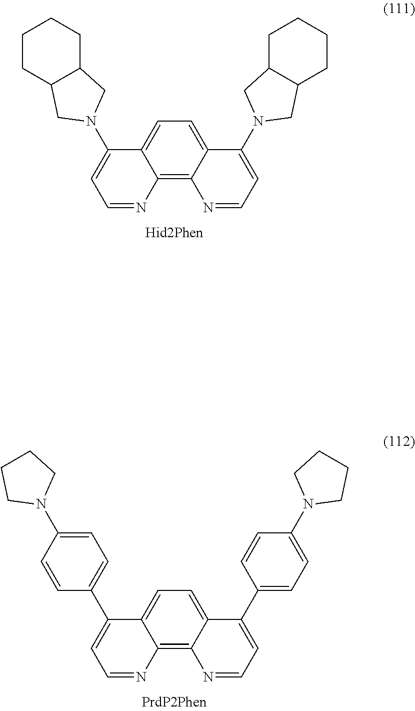 [SMILES: c1cc(N2CC3CCCCC3C2)c2ccc3c(N4CC5CCCCC5C4)ccnc3c2n1 ; c1cc(-c2ccc(N3CCCC3)cc2)c2ccc3c(-c4ccc(N5CCCC5)cc4)ccnc3c2n1]

Structural Formula (100) shows 4,7-di-1-pyrrolidinyl-1,10-phenanthroline (abbreviation: Pyrrd-Phen). Structural Formula (103) shows 4,7-bis(1,3,4,6,7,8-hexahydro-2H-pyrimido[1,2-a]pyrimidin-1-yl)-1,10-phenanthroline (abbreviation: 4,7hpp2Phen). Structural Formula (105) shows 2,2′-(1,3-phenylene)bis[9-(1,3,4,6,7,8-hexahydro-2H-pyrirnido[1,2-a]pyrimidin-1-yl)-1,10-phenanthroline](abbreviation: mhppPhen2P). Structural Formula (106) shows 2-(1,3,4,6,7,8-hexahydro-2H-pyrimido[1,2-a]pyrimidin-1-yl)-9-phenyl-1,10-phenanthroline (abbreviation: 9Ph-2hppPhen). Structural Formula (107) shows 2,9-bis(1,3,4,6,7,8-hexahydro-2H1-pyrimido[1,2-a]pyrimidin-1-yl)-1,10-phenanthroline (abbreviation: 2,9hpp2Phen). Structural Formula (111) shows 4,7-di(2,3,3a,4,5,6,7,7a-octahydro-11H-isoindol-2-yl)-1,10-phenanthroline (abbreviation: -lid2Phen). Structural Formula (112) shows 4,7-bis[4-(1-pyrrolidinyl)phenyl]-1,10-phenanthroline (abbreviation: PrdP2Phen).

The negative minimum value of the electrostatic potential (ESP) of the first organic compound is preferably small (i.e., the negative minimum value preferably has a large absolute value), in which case the stability of the interaction with the metal or metal compound is high. In an organic compound including a π-electron deficient heteroaromatic ring, the electrostatic potential around nitrogen atoms of the π-electron deficient heteroaromatic ring, which is likely to be negative, can be further lowered (i.e., the absolute value of the negative value can be increased) by introduction of an electron-donating group to the ar-electron deficient heteroaromatic ring. Note that an electrostatic potential is the energy of interaction between positive point charge with unit quantity of electricity and electron distribution of a molecule. An electrostatic potential value also depends on the threshold value of electron density distribution. To increase the efficiency of the interaction with the metal or metal compound, the minimum value of the electrostatic potential of the first organic compound is preferably smaller (has a larger absolute value) than the minimum value of the electrostatic potential of a phenanthroline ring having no substituent. Specifically, when the threshold value of electron density distribution in atomic units is 0.0004 e/a₀³, the minimum value of the electrostatic potential is preferably smaller than or equal to −0.085 Eₕ (Eₕ is the Hartree energy (1 Eₕ=27.211 eV)), further preferably smaller than or equal to −0.090 Eₕ. When the threshold value of electron density distribution is 0.003 e/a₀³, the minimum value of the electrostatic potential is preferably smaller than or equal to −0.12 Eₕ, further preferably smaller than or equal to −0.13 Eₕ,

### <<Characteristic Estimation of First Organic Compound by Quantum Chemical Calculation>

The minimum values of the electrostatic potentials (ESP) of the above organic compounds that can be used as the first organic compound are estimated by quantum chemical calculation.

As the quantum chemistry computational program, Gaussian 09 is used. The calculation is performed using HPE SGI 8600. The most stable structure of the first organic compound in a ground state is calculated by DFT. As a basis function, 6-311G(d,p) is used, and as a functional, B3LYP is used.

Table 5 shows the analysis results of the electrostatic potentials of the organic compounds that can be used as the first organic compound in a ground state, Note that an electrostatic potential is the energy of interaction between positive point charge with unit quantity of electricity and electron distribution of a molecule. An electrostatic potential value also depends on the threshold value of electron density distribution. Table 5 shows electrostatic potentials in electron density distribution at the time when the threshold value of electron density distribution in atomic units is 0.0004 e/a₀³ or 0.003 e/a₀³.

TABLE 5

| | ESP minimum value | ESP minimum value |
|---|---|---|
| | (threshold value of | (threshold value of |
| | electron density | electron density |
| | distribution = 0.0004) | distribution = 0.003) |
| Pyrrd-Phen (100) | −0.091 | −0.12 |
| DMeAPhen (101) | −0.089 | −0.12 |
| p-MeO-Phen (102) | −0.089 | −0.12 |
| 4,7hpp2Phen (103) | −0.096 | −0.13 |
| CzPhen (104) | −0.072 | −0.10 |
| mhppPhen2P (105) | −0.057 | −0.096 |
| 9Ph2hppPhen (106) | −0.057 | −0.096 |
| 2,9hpp2Phen (107) | −0.061 | −0.097 |
| Hid2Phen (111) | −0.094 | −0.13 |
| PrdP2Phen (112) | −0.094 | −0.13 |
| Bphen | −0.083 | −0.11 |
| mPPhen2P | −0.057 | −0.094 |
| NBphen | −0.053 | −0.093 |
| Phen | −0.081 | −0.11 |

Note that the organic compounds represented by Structural Formulas (100) to (107), (111), and (112) shown as the organic compounds that can be used as the first organic compound, Bphen, mPPhen2P, NBphen, and Phen in Table 5 are shown below.

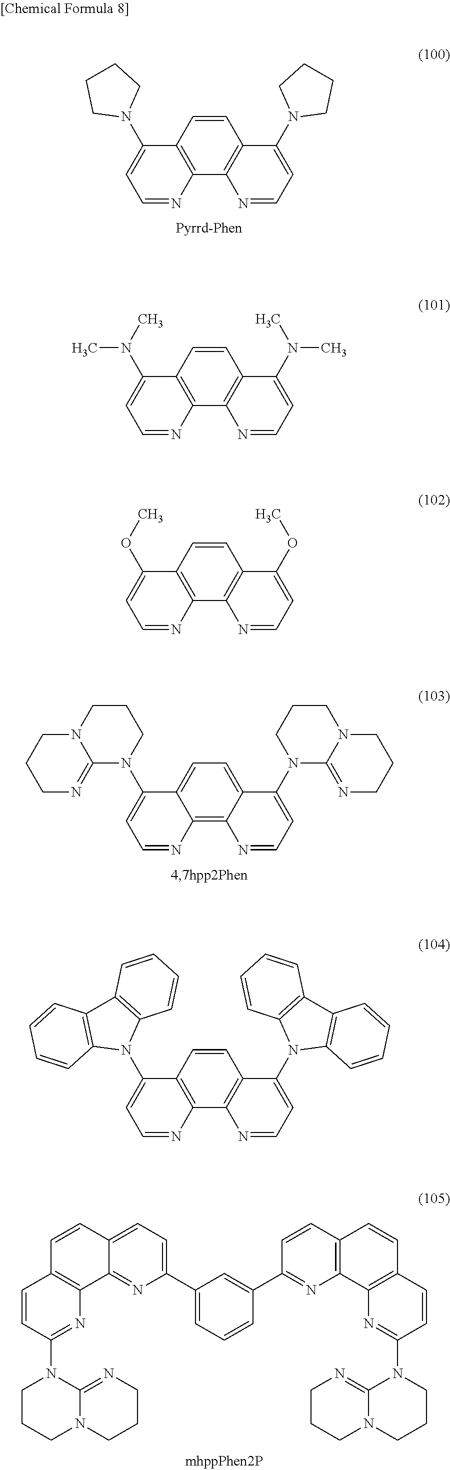

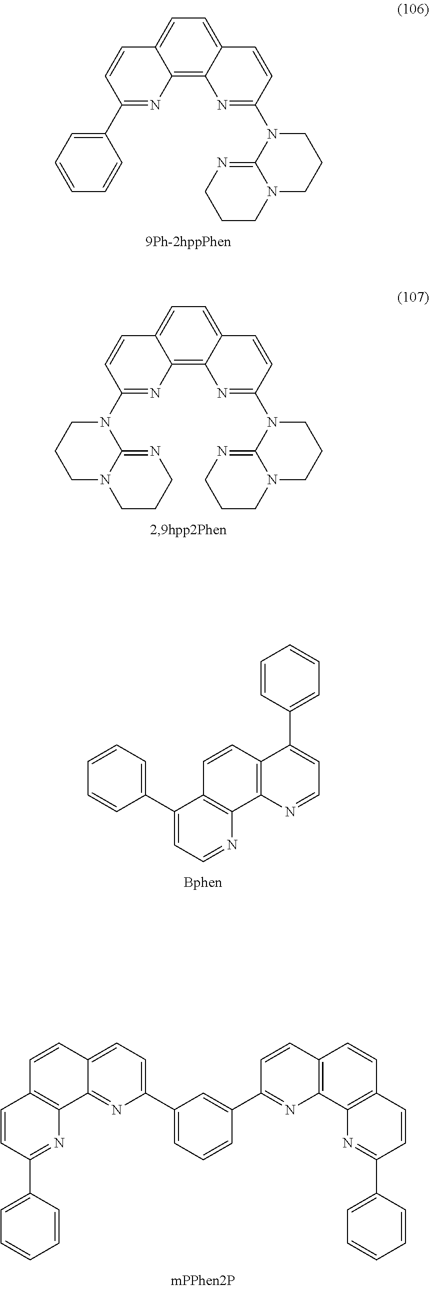 [SMILES: c1ccc(-c2ccc3ccc4ccc(N5CCCN6CCCN=C65)nc4c3n2)cc1 ; c1cc2ccc3ccc(N4CCCN5CCCN=C54)nc3c2nc1N1CCCN2CCCN=C21 ; c1ccc(-c2ccnc3c2ccc2c(-c4ccccc4)ccnc23)cc1 ; c1ccc(-c2ccc3ccc4ccc(-c5cccc(-c6ccc7ccc8ccc(-c9ccccc9)nc8c7n6)c5)nc4c3n2)cc1]

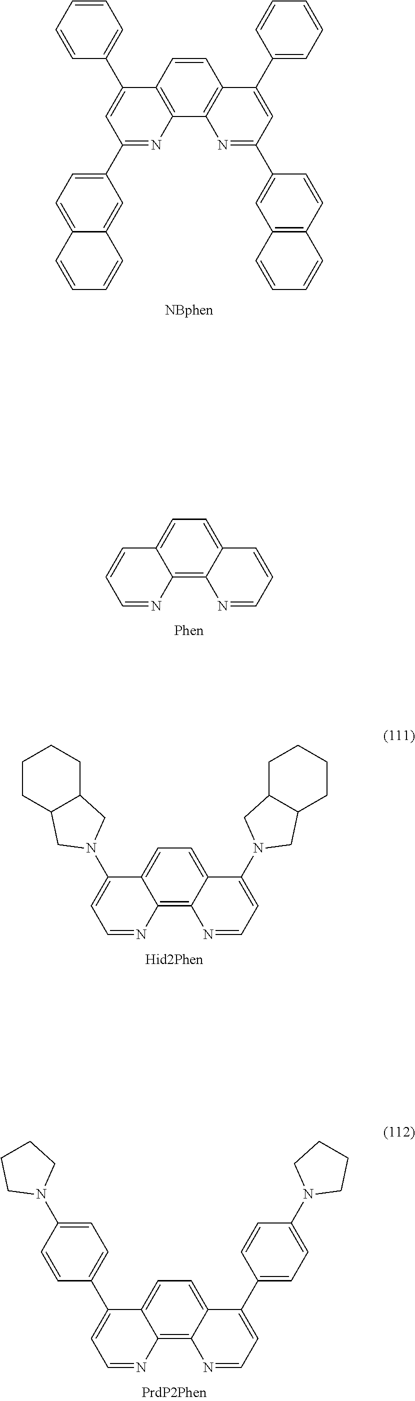 [SMILES: c1ccc(-c2cc(-c3ccc4ccccc4c3)nc3c2ccc2c(-c4ccccc4)cc(-c4ccc5ccccc5c4)nc23)cc1 ; c1cnc2c(c1)ccc1cccnc12 ; c1cc(N2CC3CCCCC3C2)c2ccc3c(N4CC5CCCCC5C4)ccnc3c2n1 ; c1cc(-c2ccc(N3CCCC3)cc2)c2ccc3c(-c4ccc(N5CCCC5)cc4)ccnc3c2n1]

Table 5 above indicates that the minimum values of ESP of the organic compounds represented by Structural Formulas (100) to (103), (111), and (112) are each smaller than or equal to −0.085 Eₕ when the threshold value of electron density distribution in atomic units is 0.0004 e/a₀³ and that using any of these organic compounds as the first organic compound is the most preferable. On the other hand, the minimum values of ESP of the organic compounds represented by Structural Formulas (104) to (107) are each larger than −0.085 Eₕ.

It is shown that the organic compounds represented by Structural Formulas (100) to (103), (111), and (112) have the most favorable values because of having an electron-donating group at each of the 4- and 7-positions of the 1,10-phenanthroline ring.

The organic compound represented by Structural Formula (104) has N-carbazolyl groups as electron-donating groups at the 4- and 7-positions of the 1,10-phenanthroline ring. In the N-carbazolyl group, in which an unshared electron pair of the nitrogen atom contributes to aromaticity, the property of donating electrons to the phenanthroline ring is lower than that in a group in which an unshared electron pair of a nitrogen atom does not contribute to aromaticity, inhibiting a reduction in the minimum value of ESP of the organic compound represented by Structural Formula (104).

The organic compounds represented by Structural Formulas (105) to (107) each have electron-donating groups at the 2- and 9-positions of the 1,10-phenanthroline ring. The electron-donating groups introduced to the 2- and 9-positions have a low property of donating electrons to the nitrogen atoms at the 1- and 10-positions of the phenanthroline ring. It is thus preferable that electron-donating groups be at the 4- and 7-positions of a 1,10-phenanthroline ring.

Note that the LUMO level of the second organic compound is further preferably lower than that of the first organic compound. In that case, electrons can be easily donated from the donor level formed by the first organic compound and the metal or metal compound to the second organic compound. Additionally, the LIMO level of the second organic compound is preferably lower than that of the first organic compound so that the second organic compound can have an electron-transport property.

For example, the LUMO level of the first organic compound is preferably higher than or equal to −3.0 eV and lower than or equal to −2.0 eV, further preferably higher than or equal to −2.7 eV and lower than or equal to −2.0 eV. The LUMO level of the second organic compound is preferably higher than or equal to −3.0 eV and lower than or equal to −2.0 eV, further preferably higher than or equal to −3.0 eV and lower than or equal to −2.5 eV. In the above case, electrons can be easily donated from the donor level formed by the first organic compound and the metal or metal compound to the second organic compound. This facilitates electron transport in the second organic compound.

Note that the HOMO level and the LUMO level of an organic compound are generally estimated by cyclic voltammetry (CV), photoelectron spectroscopy, optical absorption spectroscopy, inverse photoemission spectroscopy, or the like. When values of different compounds are compared with each other, it is preferable that values estimated by the same measurement be used.

The first organic compound is preferably strongly basic, in which case the first organic compound interacts with holes to significantly reduce the hole-transport property in the first layer 161a of the intermediate layer 160a and prevent hole transport from the first layer 161a to the second layer 162a, enabling high efficiency of the light-emitting device. Specifically, the acid dissociation constant pKₐ of the first organic compound is preferably higher than or equal to 8, further preferably higher than or equal to 10, still further preferably higher than or equal to 12.

In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound.

The acid dissociation constant may be obtained by calculation, For example, the acid dissociation constant pKₐ can be obtained by the following calculation method.

The initial structure of a molecule serving as a calculation model is the most stable structure (the singlet ground state) obtained by first-principles calculation.

For the first-principles calculation, Jaguar, which is the quantum chemical computational software (Schrödinger, Inc.) is used, and the most stable structure in the singlet ground state is calculated by DFT. As a basis function, 6-31G**is used, and as a functional, B3LYP-D3 is used. The structure subjected to quantum chemical calculation is sampled by conformational analysis in mixed torsional/low-mode sampling with Maestro GUI (Schradinger, Inc.)

In the calculation of pKₐ, one or more atoms in each molecule are designated as basic sites, MacroModel is used to search for the stable structure of the protonated molecule in water, conformational search is performed with OPLS2005 force field, and a conformational isomer having the lowest energy is used. Jaguar's pKₐ calculation module is used. After structure optimization is performed by B3LYP/6-31G*, single point calculation is performed by cc-pVTZ(+) and the pKₐ value is calculated using empirical correction for functional group(s). In the case where one or more atoms are designated as basic sites in a molecule, the largest of obtained values is used as a pKₐ value. The obtained pKₐ values are shown below.

The acid dissociation constant pKₐ of 2,9hpp2Phen is 13.35, pKₐ of 4,7hpp2Phen is 13.42, pKₐ of Pyrrd-Phen is 11.23, pKₐ of mPPhen2P is 5.16, pKₐ of NBphen is 5.59, and pKₐ of Bphen is 5.62.

### <Second Organic Compound>

The first layer of the intermediate layer includes the second organic compound having two or more heteroaromatic rings that are bonded or condensed to each other and include three or more heteroatoms in total, in addition to the metal or metal compound and the first organic compound. The second organic compound has a function of interacting with the metal or metal compound by two or more of the three or more heteroatoms as a multidentate ligand.

The second organic compound can improve heat resistance, electron-transport properties, and the like. In the case where the π-electron deficient heteroaromatic ring of the first organic compound is referred to as a first −π-electron deficient heteroaromatic ring and the −π-electron deficient heteroaromatic ring of the second organic compound is referred to as a second π-electron deficient heteroaromatic ring in one embodiment of the present invention, the first π-electron deficient heteroaromatic ring and the second π-electron deficient heteroaromatic ring preferably include different rings.

As the second π-electron deficient heteroaromatic ring, a heteroaromatic ring having an azole skeleton (an imidazole ring, a pyrazole ring, an oxazole ring, a thiazole ring, a triazole ring, an oxadiazole ring, or a thiadiazole ring), a heteroaromatic ring having a pyridine skeleton, a heteroaromatic ring having a diazine skeleton, a heteroaromatic ring having a triazine skeleton, or the like is preferable, and a diazine ring (a pyrazine ring, a pyrimidine ring, or a pyridazine ring) and a triazine ring are particularly preferable because they are electrochemically stable and have a high electron-transport property.

For example, an organic compound represented by General Formula (GH) below can be used as the organic compound used for the second organic compound.

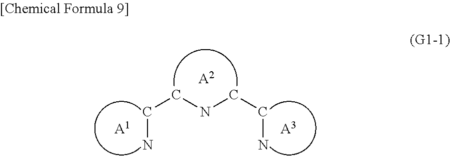

In General Formula (GH) above, A¹, A², and A³ each independently represent a substituted or unsubstituted heteroaromatic ring having 1 to 30 carbon atoms, and A¹, A², and A³ may form a condensed ring with each other.

The organic compound represented by General Formula (GH) includes a conjugated double bond in which N in the heteroaromatic ring are arranged in the order of N—C—C—N, and have a function of interacting with a metal or metal compound as a tri- or higher dentate ligand. An organic compound having such a structure is likely to interact with a metal or metal compound and thus can be suitably used for an intermediate layer.

In General Formula (GH), examples of the substituted or unsubstituted heteroaromatic rings having 1 to 30 carbon atoms, which are represented by A¹, A², and A³, include a heteroaromatic ring having a pyridine skeleton (a pyridine ring, a quinoline ring, an isoquinoline ring, a naphthyridine ring, a bipyridine ring, a phenanthridine ring, a phenanthroline ring, an anthyridine ring, or an azafluoranthene ring), a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Note that the substituted or unsubstituted heteroaromatic rings having 1 to 30 carbon atoms represented by A¹, A², and A³ are not limited to these. A¹, A², and A³ may form a condensed ring with each other, For example, A¹ and A² may be bonded to each other to form a phenanthroline ring.

As the second organic compound, an organic compound represented by Formula (G2-1) can be used.

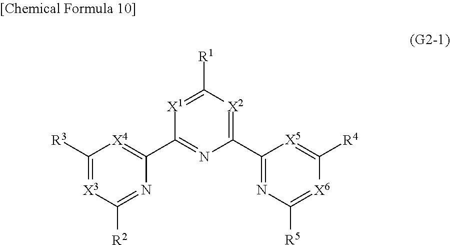

In General Formula (G2-1), X¹ to X⁶ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to carbon atoms; and R¹ to R⁴ each independently represent hydrogen, an alkyl group having 1 to carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms. Alternatively, in General Formula (G2-1), X¹ to X⁶ may be directly bonded to each other or bonded to each other via carbon to form a condensed ring.

As in the organic compound represented by General Formula (G2-1), it is further preferable that the organic compound having a function of interacting with the metal or metal compound as a tri- or higher dentate ligand include at least one of a heteroaromatic ring having a pyridine skeleton, a heteroaromatic ring having a diazine skeleton, and a heteroaromatic ring having a triazine skeleton. A light-emitting device including any of these rings can have high reliability because these rings have high electrochemical stability. Moreover, the driving voltage of the light-emitting device can be reduced because these rings have high electron-transport properties.

As the second organic compound, an organic compound represented by Formula (G3-1) can be used.

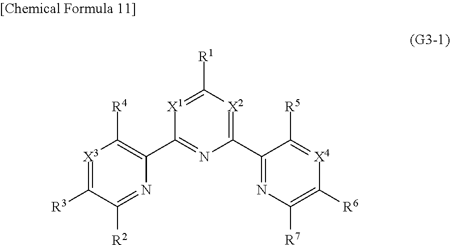

In General Formula (G3-1), X¹ to X⁴ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to carbon atoms; and R¹ to R⁶ each independently represent hydrogen, an alkyl group having 1 to carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

As the second organic compound, an organic compound represented by General Formula (G4-1) below can also be used,

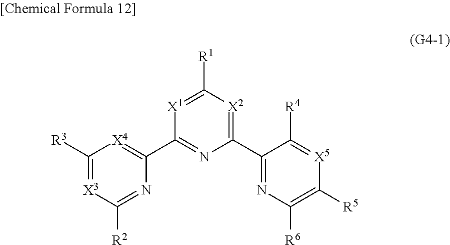

In General Formula (G4-1), X¹ to X⁵ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to carbon atoms; and R¹ to R⁵ each independently represent hydrogen, an alkyl group having 1 to carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

An organic compound having a pyridine skeleton has a high LUMO level, which is preferable. Thus, when X¹ and X² in each of General Formulas (G2-1) to (G4-1) represent carbon, the organic compound represented by each of General Formulas (G2-1) to (G4-1) has a pyridine skeleton; thus, a composite material having a high SOMO level can be formed when any of the organic compounds interact with a metal or metal compound. That is, such an organic compound having a pyridine ring and a function of interacting with a metal as a tri- or higher dentate ligand interacts with a metal or metal compound, so that an intermediate layer having a high electron-injection property can be formed.

An organic compound having a diazine skeleton or a triazine skeleton is preferable because it is electrochemically stable and has a high electron-transport property. Thus, when at least one of X¹ and X² in each of General Formulas (G2-1) to (G4-1) represents nitrogen, the organic compound represented by each of General Formulas (G2-1) to (G4-1) has a diazine skeleton or a triazine skeleton; thus, a stable composite material with a high electron-transport property can be formed when any of the organic compounds interact with a metal or metal compound. That is, such an organic compound having a diazine ring or a triazine ring and a function of interacting with a metal or metal compound as a tri- or higher dentate ligand interacts with a metal or metal compound, so that an intermediate layer having a high electron-injection property can be formed.

As the second organic compound, an organic compound represented by General Formula (G1-2) below can also be used, for example.

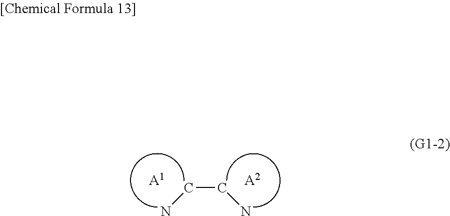

In General Formula (G1-2) above, Aland A² independently represent a substituted or unsubstituted heteroaromatic ring having 1 to 30 carbon atoms, Aland A² may form a condensed ring with each other, and A¹ contains two or more nitrogen atoms.

The organic compound represented by General Formula (G1-2) includes a conjugated double bond in which N in the heteroaromatic ring are arranged in the order of N—C—C—N and has a function of interacting with a metal or metal compound as a bi- or higher dentate ligand. An organic compound having such a structure is likely to interact with a metal or metal compound and thus can be suitably used for an intermediate layer.

In General Formula (G1-2), examples of the substituted or unsubstituted heteroaromatic ring having 1 to 30 carbon atoms, which is represented by A¹, include a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Examples of the substituted or unsubstituted heteroaromatic ring having 1 to 30 carbon atoms, which is represented by A², include a heteroaromatic ring having a pyridine skeleton (a pyridine ring, a quinoline ring, an isoquinoline ring, a naphthridine ring, a bipyridine ring, a phenanthridine ring, a phenanthroline ring, an anthyridine ring, or an azafluoranthene ring), a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Note that the substituted or unsubstituted heteroaromatic rings having 1 to 30 carbon atoms represented by A¹ and A² are not limited to these. A¹ and A² may form a condensed ring with each other. For example, ^{A} and A² may be bonded to each other to form a pyrazinoquinoxaline ring.

As the second organic compound, an organic compound represented by General Formula (G2-2) below can also be used.

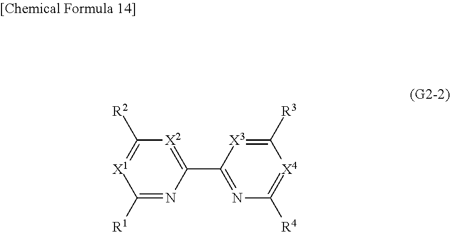

In General Formula (G2-2), at least one of X¹ to X⁴ represents nitrogen (N); the others each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁴ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to carbon atoms. Alternatively, in General Formula (G2-2), X¹ to X⁴ may be directly bonded to each other or bonded via carbon to form a condensed ring.

As in the organic compound represented by General Formula (G2-2), it is further preferable that the organic compound having a function of interacting with the metal or metal compound as a bi- or higher dentate ligand include a heteroaromatic ring having a diazine skeleton or a heteroaromatic ring having a triazine skeleton. A light-emitting device including any of these rings can have high reliability because these rings have high electrochemical stability, Moreover, the driving voltage of the light-emitting device can be reduced because these rings have high electron-transport properties.

As the second organic compound, an organic compound represented by General Formula (G3-2) below can also be used.

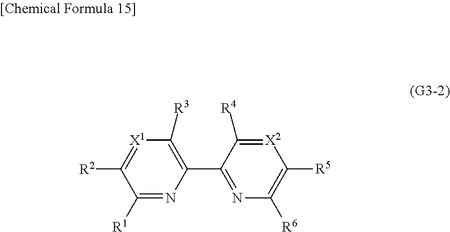

In General Formula (G3-2), one of X¹ and X² represents nitrogen (N); the other represents carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁶ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

As the second organic compound, an organic compound represented by General Formula (G4-2) below can also be used.

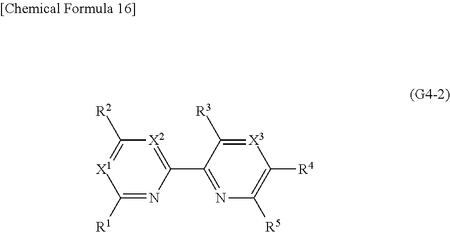

In General Formula (G4-2), at least one of X¹ to X³ represents nitrogen (N); the others each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁵ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to carbon atoms.

An organic compound having a pyridine skeleton is preferable because it has a high LUMO level. Thus, when X¹ and X² represented in General Formulas (G2-2) and (G4-2) and X¹ represented in General Formula (G3-2) represent carbon, the organic compounds represented by General Formulas (G2-2), (G3-2), and (G4-2) each have a pyridine skeleton; thus, a composite material having a high SOMO level can be formed when any of the organic compounds interact with a metal or metal compound. That is, such an organic compound having a pyridine ring and a function of interacting with a metal or metal compound as a bi- or higher dentate ligand interacts with a metal or metal compound, whereby an intermediate layer having a high electron-injection property can be formed.

An organic compound having a diazine skeleton or a triazine skeleton is preferable because it is electrochemically stable and has a high electron-transport property. Thus, when at least one of X¹ and X² represented in General Formulas (G2-2) and (G4-2) and X¹ represented in General Formula (G3-2) represent nitrogen, the organic compounds represented by General Formulas (G2-2), (G3-2), and (G4-2) each have a diazine skeleton or a triazine skeleton; thus, a stable composite material with a high electron-transport property can be formed when any of the organic compounds interact with a metal or metal compound. That is, such an organic compound having a diazine ring or a triazine ring and a function of interacting with a metal or metal compound as a bi- or higher dentate ligand interacts with a metal or metal compound, whereby a highly reliable intermediate layer can be formed.

Specific examples of the organic compounds usable for the second organic compound and the organic compounds having heteroaromatic rings, represented by General Formulas (G1-1) to (G4-2) above, are represented by General Formulas (250) to (267) below.

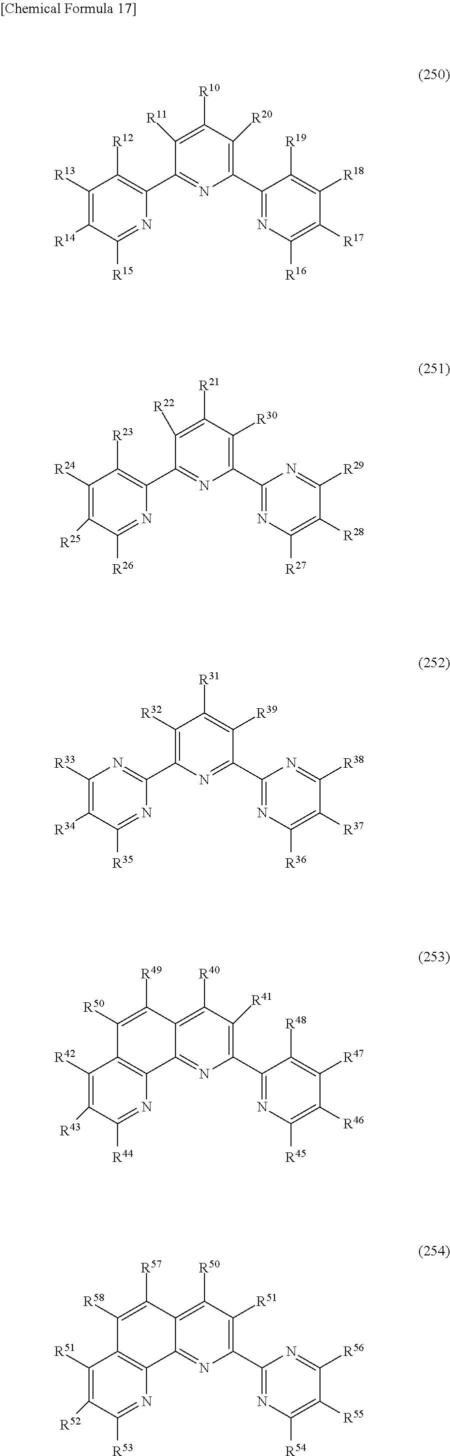

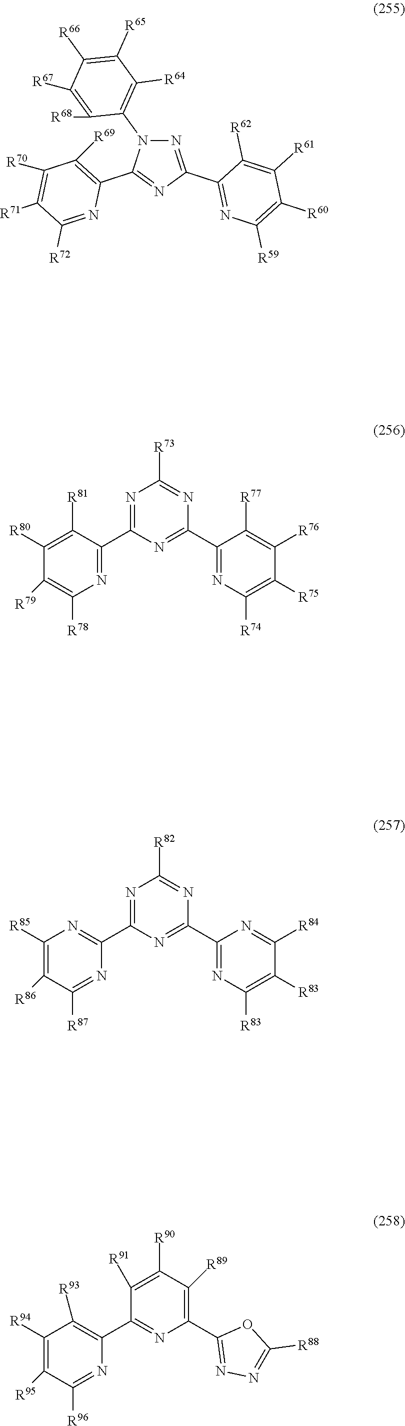

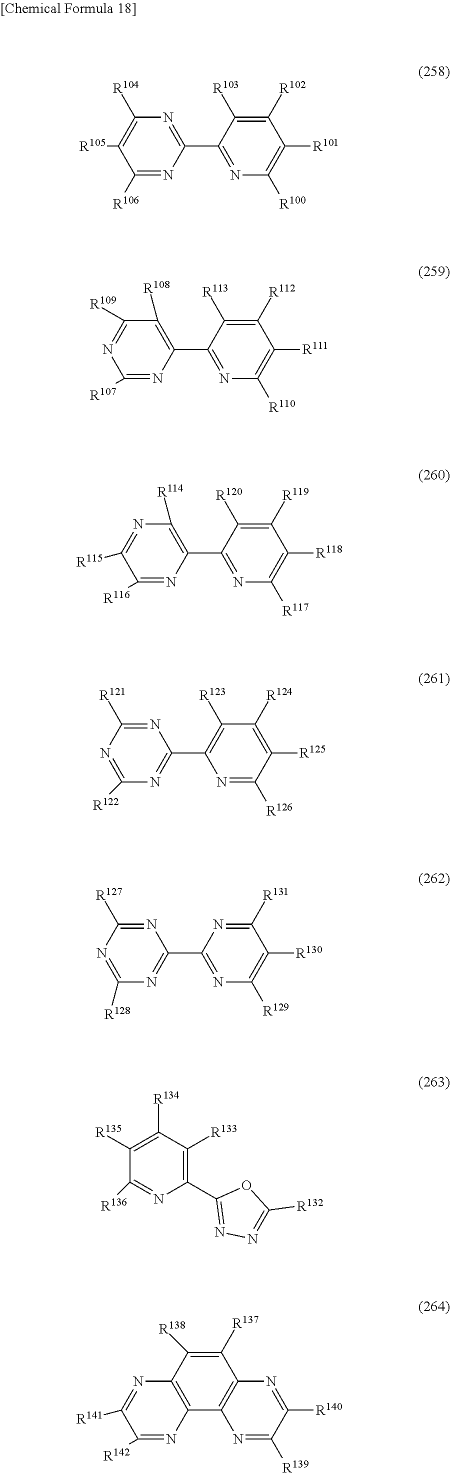

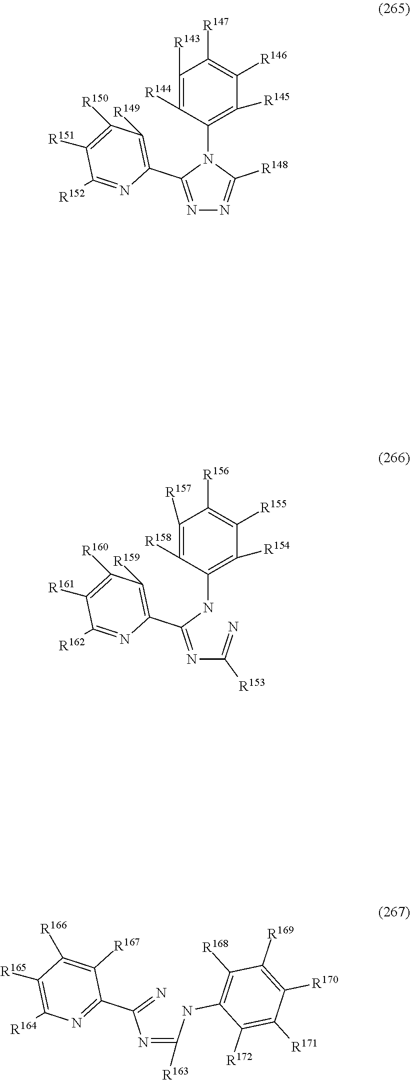

In General Formulas (250) to (267), R¹¹ to R¹⁷ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

Examples of substituents that can be used in General Formulas (GH) to (G4-2) and (250) to (267) above include an alkyl group having 1 to 10 carbon atoms, a cycloalkyl group having 3 to 10 carbon atoms, an aryl group having 6 to 30 carbon atoms, an arylene group having 6 to 30 carbon atoms, and a heteroaryl group having 1 to 30 carbon atoms. Note that some or all of hydrogen atoms may be deuterium atoms. The groups that can be used in General Formulas above are not limited to the following specific examples.

Specific examples of the alkyl group having 1 to 10 carbon atoms include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, a 2,3-dimethylbutyl group, a 1-ethylhexyl group.

Specific examples of a cycloalkyl group having 3 to 10 carbon atoms include a cyclopropyl group, a cyclobutyl group, a methylcyclobutyl group, a cyclopentyl group, a methylcyclopentyl group, an isopropylcyclopentyl group, a tert-butylcyclopropyl group, a cyclohexyl group, a methylcyclohexyl group, an isopropylcyclohexyl group, a tert-butylcyclohexyl group, a cycloheptyl group, a methylcycloheptyl group, an isopropylcycloheptyl group, a cyclooctyl group, a methylcyclooctyl group, an isopropylcyclohexyl group, a cyclononyl group, a methylcyclononyl group, a cyclodecyl group, and an adamantyl group.

Specific examples of the aryl group having 6 to 30 carbon atoms include a phenyl group, an o-tolyl group, an m-tolyl group, a p-tolyl group, a mesityl group, an o-biphenyl group, an m-biphenyl group, a p-biphenyl group, a 1-naphthyl group, a 2-naphthyl group, a fluorenyl group, a 9,9-dimethylfluorenyl group, a spirobifluorenyl group, a phenanthrenyl group, an anthracenyl group, and a fluoranthenyl group. In the case where the aryl group having 6 to 30 carbon atoms includes a substituent, examples of the substituent include an alkyl group having 1 to 10 carbon atoms, a cycloalkyl group having 3 to 10 carbon atoms, and a phenyl group.

Specific examples of the arylene group having 6 to 30 carbon atoms include a phenylene group, a biphenyl-diyl group, a naphthalene-diyl group, a fluorene-diyl group, an acenaphthene-diyl group, an anthracene-diyl group, a phenanthrene-diyl group, a terphenyl-diyl group, a triphenylene-diyl group, a tetracene-diyl group, a benzanthracene-diyl group, a pyrene-diyl group, and a spirobi[9H-fluorene]-diyl group. In the case where the arylene group having 6 to 30 carbon atoms includes a substituent, examples of the substituent include an alkyl group having 1 to 10 carbon atoms, a cycloalkyl group having 3 to 10 carbon atoms, and a phenyl group.

The heteroaryl group having 1 to 30 carbon atoms refers to a monovalent group obtained by eliminating one hydrogen atom from one of carbon atoms forming the ring(s) of a monocyclic or polycyclic heteroaromatic compound having 1 to 30 carbon atoms. Specific examples of the heteroaryl group having 1 to 30 carbon atoms include a 1,3,5-triazin-2-yl group, a 1,2,4-triazin-3-yl group, a pyrimidin-4-yl group, a pyrazin-2-yl group, a 2-pyridyl group, a 3-pyridyl group, a 4-pyridyl group, a carbazolyl group, a dibenzofuranyl group, a dibenzothiophenyl group, a benzonaphthofuranyl group, a benzonaphthothiophenyl group, an indolocarbazolyl group, a benzofurocarbazolyl group, a benzothienocarbazolyl group, an indenocarbazolyl group, and a dibenzocarbazolyl group. In the case where the heteroaryl group has a substituent, examples of the substituent include an alkyl group having 1 to 10 carbon atoms, a cycloalkyl group having 3 to carbon atoms, and a phenyl group.

Specific examples of the organic compounds usable for the second organic compound and the organic compounds represented by General Formulas (G1-1) to (G4-2) above are shown below.

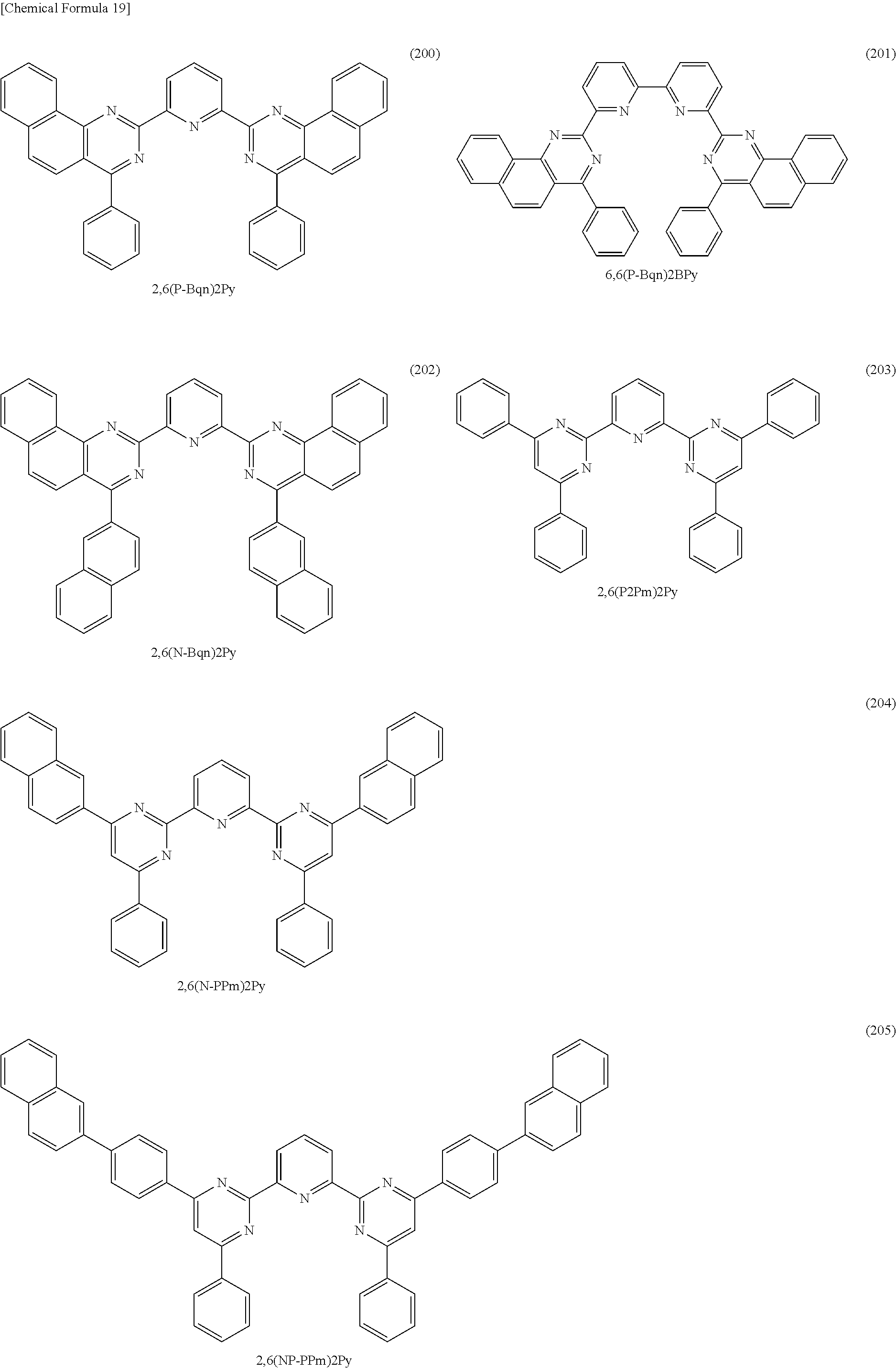

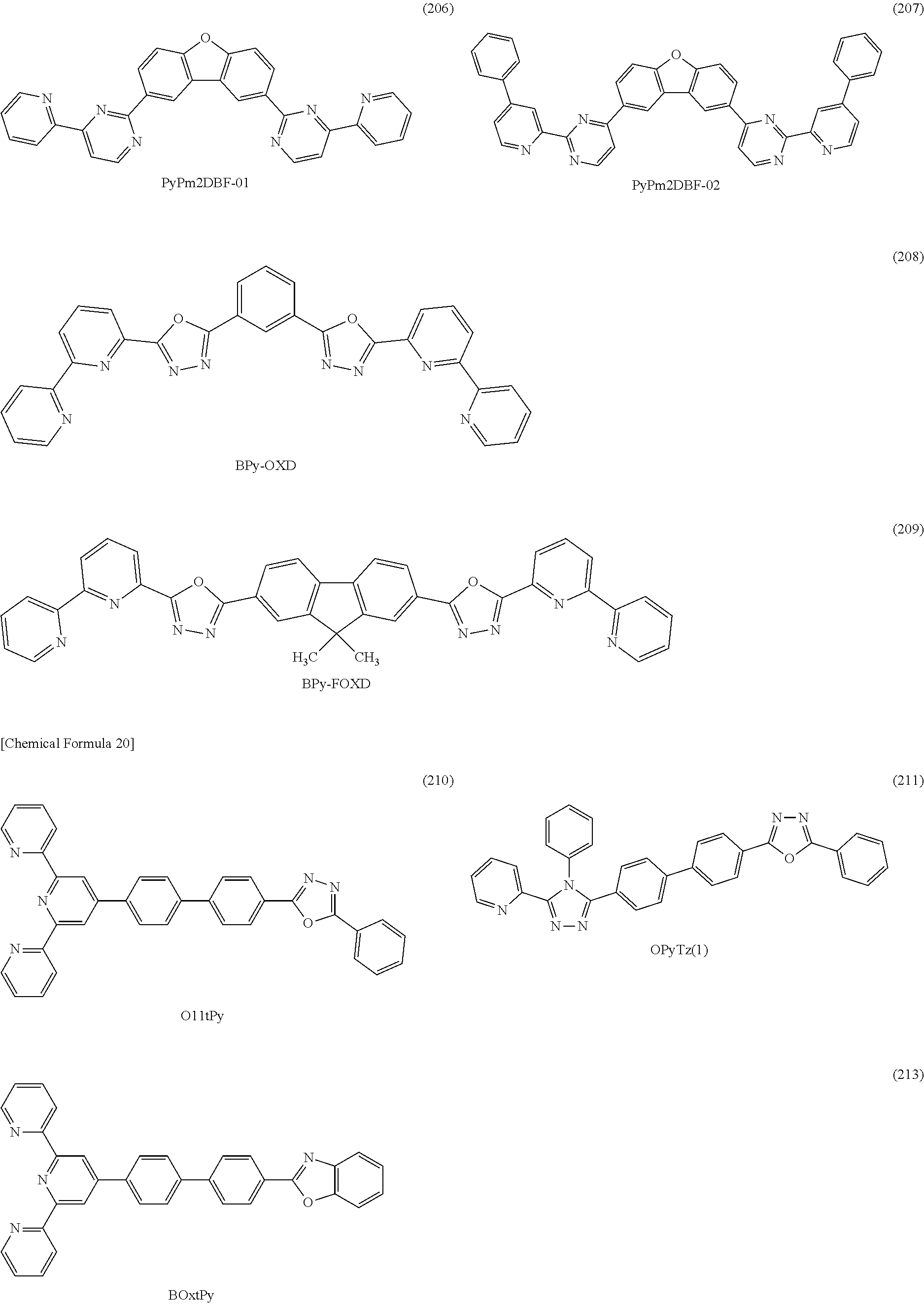

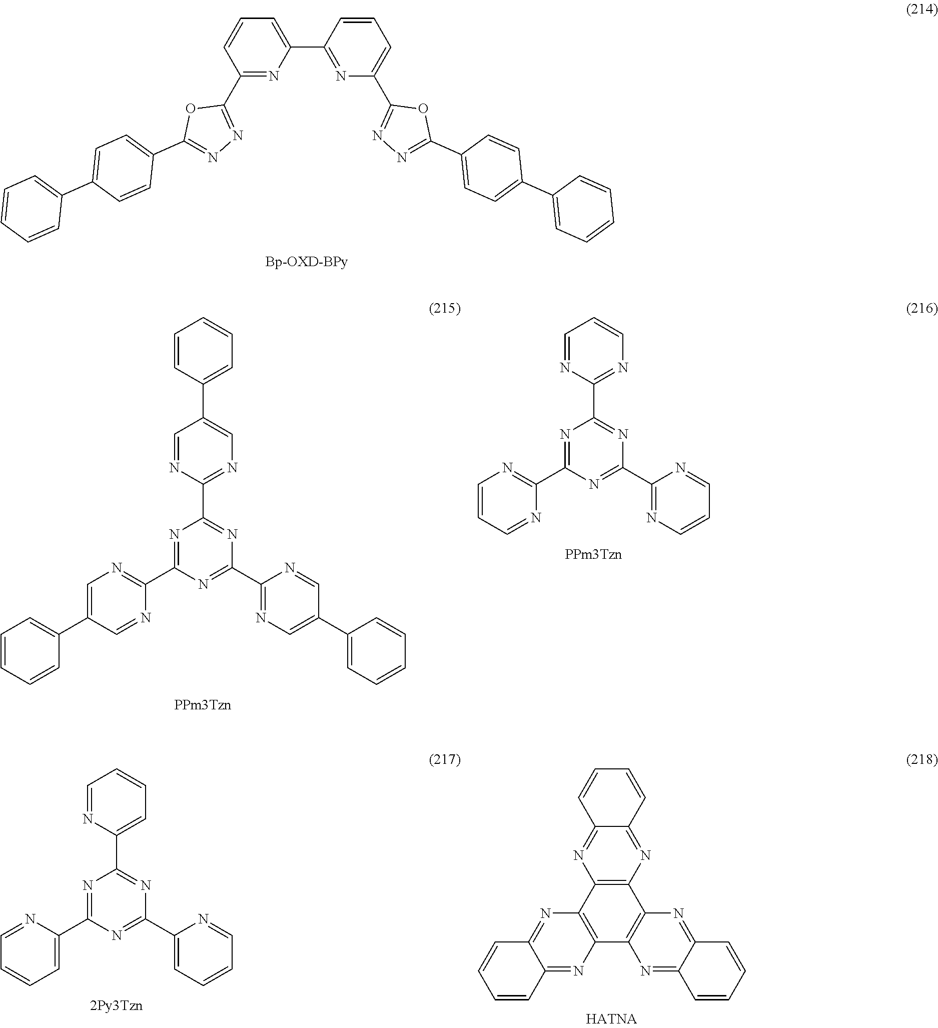

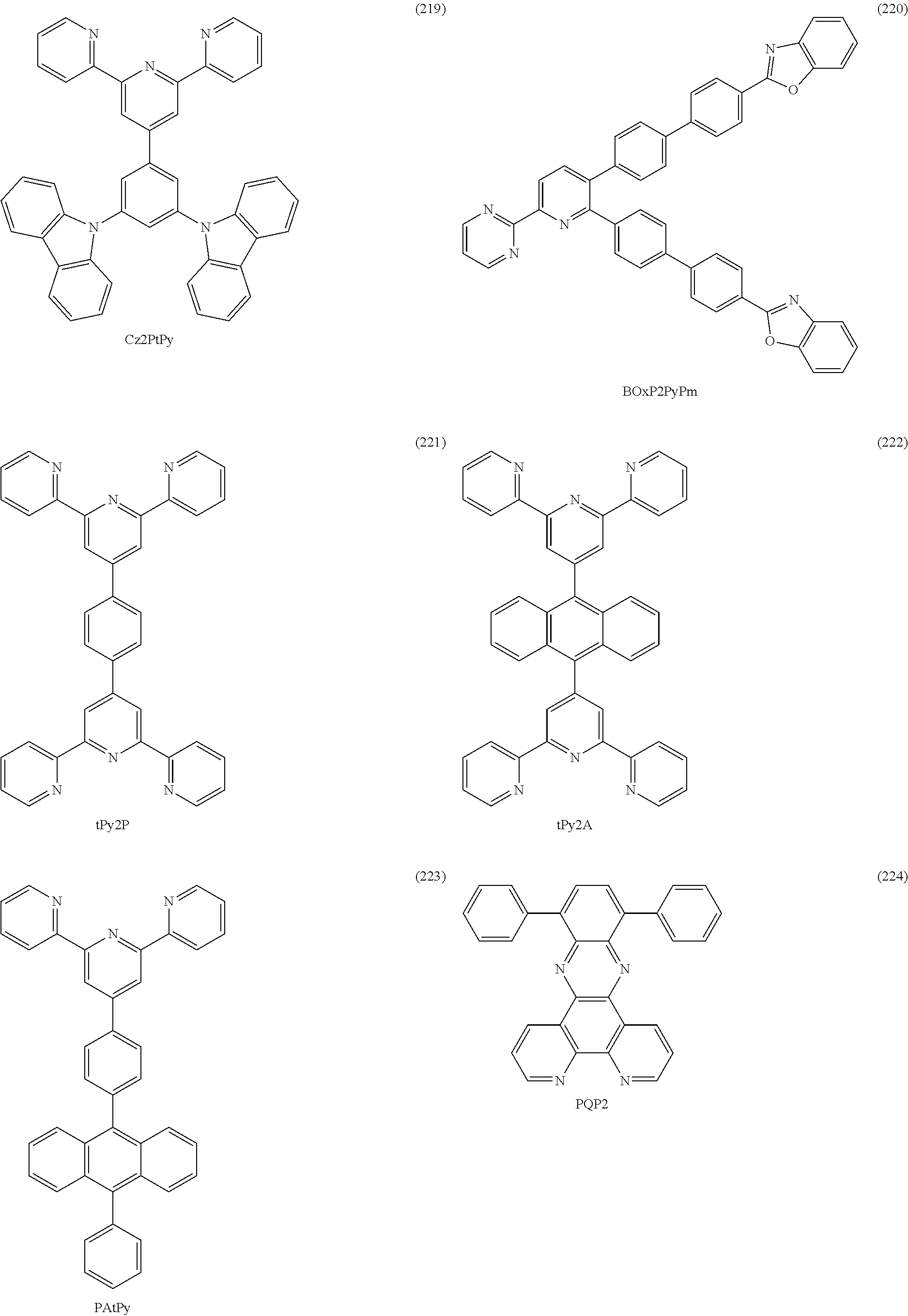

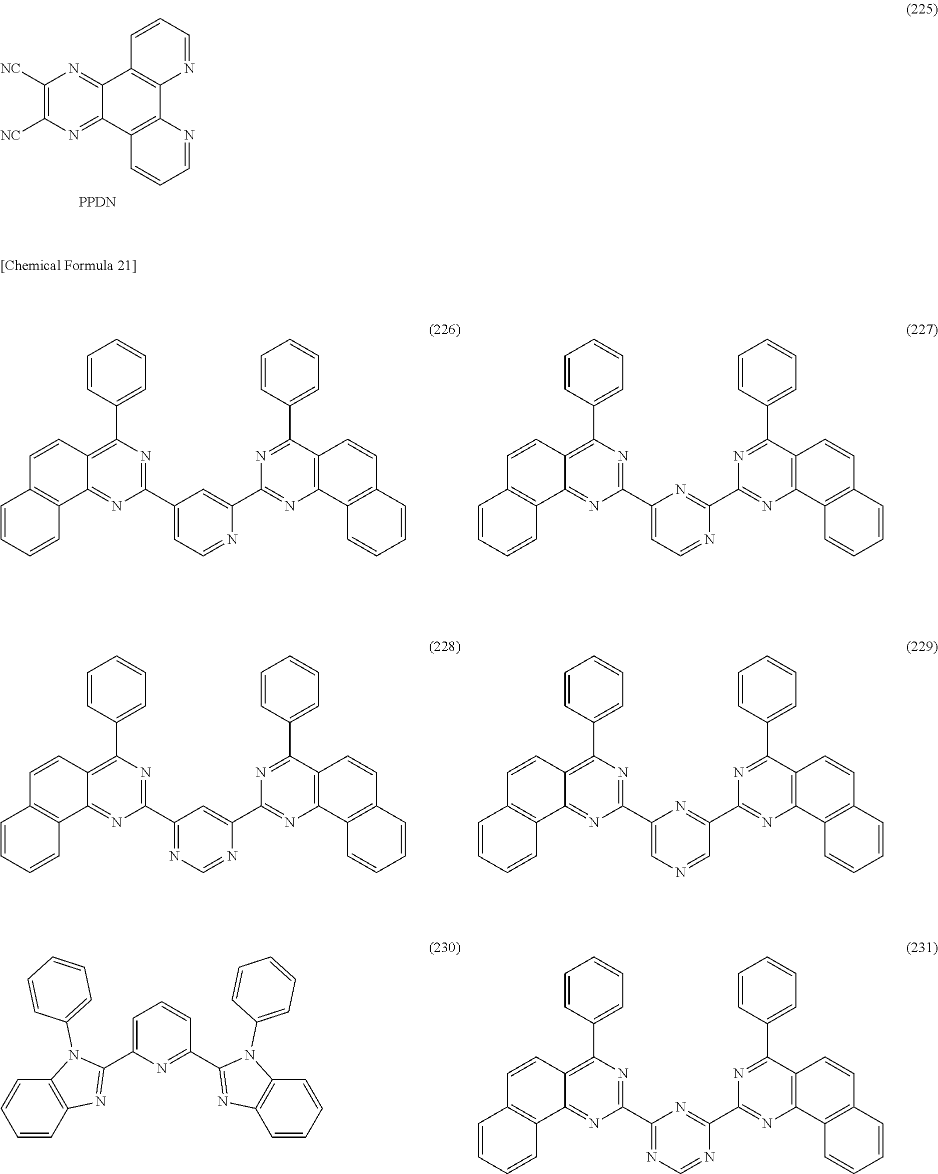

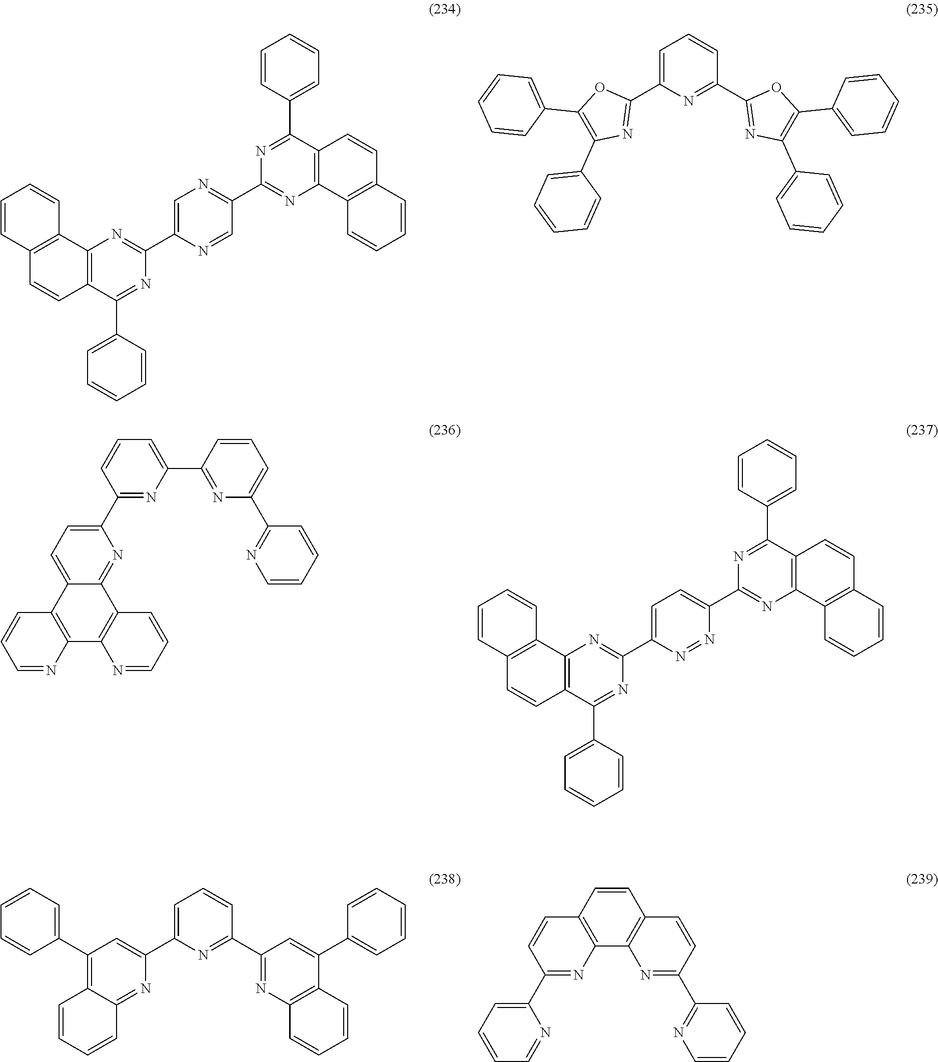

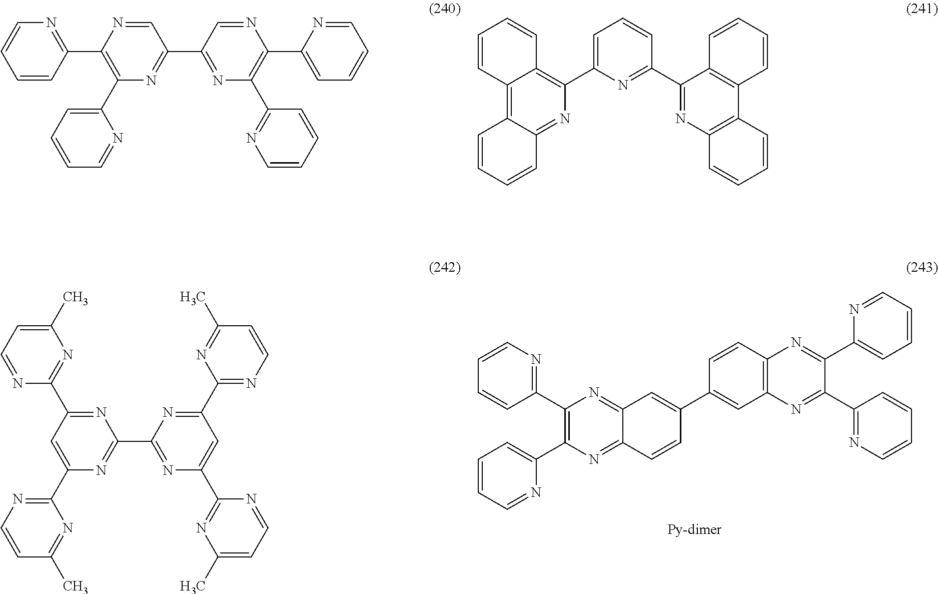

Note that the LUMO level of the second organic compound is further preferably lower than that of the first organic compound. In that case, electrons can be easily donated from the donor level formed by the first organic compound and the metal or metal compound to the second organic compound. The LUMO level of the second organic compound is preferably lower than that of the first organic compound so that the second organic compound can have an electron-transport property.

The LUMO level of the second organic compound is preferably higher than or equal to −3.0 eV and lower than or equal to −2.0 eV, further preferably higher than or equal to −3.0 eV and lower than or equal to −2.5 eV. The LUMO level of the first organic compound is preferably higher than or equal to −3.0 eV and lower than or equal to −2.0 eV, further preferably higher than or equal to −2.7 eV and lower than or equal to −2.0 eV.

In the above case, electrons can be easily donated from the donor level formed by the first organic compound and the metal or metal oxide to the second organic compound. This facilitates electron transport in the second organic compound.

In one embodiment of the present invention, the LUMO level of the second organic compound is preferably lower than the LUMO level of the first organic compound and the absolute value of the difference between the LUMO level of the first organic compound and the LUMO level of the second organic compound is preferably greater than or equal to 0.20 eV and less than or equal to 0.50 eV. The absolute value of the difference between the LUMO level of the first organic compound and the LUMO level of the second organic compound is further preferably greater than or equal to 0.25 eV and less than or equal to 0.50 eV, still further preferably greater than or equal to 0.30 eV and less than or equal to 0.50 eV, yet still further preferably greater than or equal to 0.35 eV and less than or equal to 0.50 eV, yet still further preferably greater than or equal to 0.40 eV and less than or equal to 0.50 eV.

In other words, when the LUMO level of the first organic compound is “LUMO1 (CV)” and the LUMO level of the second organic compound is “LUMO2 (eV)”, LUMO2 preferably satisfies the following inequality (1).

$$L UMO 1 - 0.50 \leq LUMO 2 \leq LUMO 1 - 0 \text{.20} \qquad ( 1 )$$

Further preferably, LUMO2 satisfies the following inequality (2).

$$LUMO 1 - 0.50 \leq LUMO 2 \leq LUMO 1 - 0.25 \qquad ( 2 )$$

Still further preferably, LUMO2 satisfies the following inequality (3).

$$LUMO 1 - 0.50 \leq LUMO 2 \leq LUMO 1 - 0 \text{.30} \qquad ( 3 )$$

Yet still further preferably, LUMO2 satisfies the following inequality (4).

$$LUMO 1 - 0.50 \leq LUMO 2 \leq LUMO 1 - 0.35 \qquad ( 4 )$$

Yet still further preferably, LUMO2 satisfies the following inequality (5).

$$LUMO 1 - 0.50 \leq LUMO 2 \leq LUMO 1 - 0 \text{.40} \qquad ( 5 )$$

When the LUMO2 is in the above range, the tandem light-emitting device of one embodiment of the present invention can have favorable characteristics with low driving voltage, with or without undergoing a photolithography process involving exposure of the EL layer to the air. In addition, the tandem light-emitting device can have high reliability.

As the second organic compound, an organic compound with an electron-transport property can be used. The organic compound with an electron-transport property is preferably a substance having an electron mobility higher than or equal to 1×10⁷ cm²/Vs, further preferably higher than or equal to 1×10⁻⁶ cm²/Vs, when the square root of electric field strength IV/cm] is 600. Note that any other substance can also be used as long as the substance has an electron-transport property higher than a hole-transport property.

The second organic compound preferably has 25 to 100 carbon atoms. When having to 100 carbon atoms, the second organic compound can have excellent sublimability, and thus, thermal decomposition of the organic compound during vacuum evaporation can be inhibited and the efficiency of use of the material can be high.

An organic compound having a glass transition temperature T_{g} higher than or equal to 100° C. is preferably used as the second organic compound. In that case, the intermediate layer can be a layer that has high heat resistance and is not easily crystallized. Thus, the intermediate layer is not easily crystallized even when part of the organic compound layer is processed by a lithography process.

As the second organic compound, an organic compound with an acid dissociation constant pKₐ lower than 4 can be used. Accordingly, the second organic compound can have low solubility in water and thus can be highly resistant to water and a chemical solution used in a lithography process.

An organic compound having an acid dissociation constant pKₐ smaller than 4 has lower solubility in water than an organic compound having an acid dissociation constant pKₐ larger than or equal to 4, for example. The water resistance of the intermediate layer including an organic compound having an acid dissociation constant pKₐ smaller than 4 as the second organic compound can be higher than the intermediate layer including an organic compound having an acid dissociation constant pKₐ larger than or equal to 4 as the second organic compound. Moreover, occurrence of a problem such as peeling of the intermediate layer from another layer in the fabrication process can be inhibited. Accordingly, occurrence of a problem that causes a defect in a light-emitting device can be inhibited. In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound,

The first layer preferably includes the second organic compound in addition to the metal or metal oxide and the first organic compound, in which case interaction between materials occurs efficiently. This can be confirmed by measurement of spin density by electron spin resonance (ESR).

For example, the spin density measured by ESR of a film that includes the metal or metal compound and the first organic compound is preferably higher than that of a film that includes the metal or metal compound and the second organic compound. The spin density measured by ESR of a film that includes the metal or metal compound, the first organic compound, and the second organic compound is preferably higher than that of a film that includes any two of the metal or metal compound, the first organic compound, and the second organic compound. In that case, interaction between the materials can be confirmed to occur efficiently.

Specifically, for example, by an electron spin resonance method, the density of spins attributed to a signal observed at a g-factor of approximately 2.00 in the film including the metal or metal compound and the first organic compound is higher than or equal to 5×10¹⁶ spins/cm³, preferably higher than or equal to 1×10¹⁷ spins/cm³, further preferably higher than or equal to 1×10¹⁸ spins/cm³, still further preferably higher than or equal to 1×10¹⁹ spins/cm³, yet still further preferably higher than or equal to 1×10²⁰ spins/cm³. In such a case, in the layer that includes a combination of the metal or metal compound and the first organic compound, it can be confirmed that the interaction between the materials occurs efficiently. In addition, for example, in an electron spin resonance method, the density of spins attributed to a signal observed at a g-factor of approximately 2.00 in the film including the metal or metal compound, the first organic compound, and the second organic compound is higher than or equal to 5×10¹⁶ spins/cm³, preferably higher than or equal to 1×10⁷ spins/cm³, further preferably higher than or equal to 1×10¹⁸ spins/cm³, still further preferably higher than or equal to 1×10¹⁹ spins/cm³, yet still further preferably higher than or equal to 1×10²⁰ spins/cm³. In such a case, in the layer that includes the combination of the metal or metal compound, the first organic compound, and the second organic compound, it can be confirmed that the interaction between the materials occurs more efficiently than in the layer that includes only two of the metal or metal compound, the first organic compound, and the second organic compound. The density of spins attributed to a signal observed at a g-factor of approximately 2.00 is measured by an electron spin resonance method to be, for example, lower than or equal to 2×10¹⁶ spins/cm³ in a mixed film that includes the metal or metal compound and the second organic compound. The density of spins attributed to a signal observed at a g-factor of approximately 2.00 is measured by an electron spin resonance method to be, for example, lower than or equal to 2×10¹⁶ spins/cm³ in a mixed film that includes the first organic compound and the second organic compound.

In the first layer, the molar ratio of the metal or metal compound to the first organic compound (or the sum of the first organic compound and the second organic compound) is preferably greater than or equal to 0.1 and less than or equal to 10, further preferably greater than or equal to 0.2 and less than or equal to 5, still further preferably greater than or equal to 0.5 and less than or equal to 2. Alternatively, the volume ratio of the metal oxide to the first organic compound (the sum of the first organic compound and the second organic compound) is preferably greater than or equal to 0.01 and less than or equal to 0.3, further preferably greater than or equal to 0.02 and less than or equal to 0.2, still further preferably greater than or equal to 0.05 and less than or equal to 0.1. The first layer including the metal or metal compound and the first organic compound (or the first organic compound and the second organic compound) in such a ratio enables providing the intermediate layer having a favorable electron-injection property. Although the second organic compound is not necessarily used, the volume ratio of the first organic compound to the second organic compound is preferably greater than or equal to 0.1 and less than or equal to 10, further preferably greater than or equal to 0.2 and less than or equal to 5, still further preferably greater than or equal to 0.5 and less than or equal to 2. Mixing the first organic compound and the second organic compound in such a ratio enables providing the intermediate layer having a favorable electron-transport property. When an organic compound with favorable thermophysical properties with high T_{g} is used as the second organic compound, highly reliable organic EL device can be provided.

The thickness of the first layer is preferably greater than or equal to 2 urn and less than or equal to 20 urn, further preferably greater than or equal to 5 nm and less than or equal to 10 nm. In the case where the first layer has a stacked-layer structure of a metal or metal compound layer and a layer containing the first organic compound, the thickness of the metal or metal compound layer is preferably greater than or equal to 0.1 un and less than or equal to 5 nm, further preferably greater than or equal to 0.2 nm and less than or equal to 2 urn. In the case where the first layer has a stacked-layer structure of a metal or metal compound layer and a layer containing the first organic compound, the thickness of the layer containing the first organic compound is preferably greater than or equal to 2 nm and less than or equal to 20 un, further preferably greater than or equal to 5 urn and less than or equal to 10 nm.

The use of the second organic compound enables the composite material in which the metal or metal compound, the first organic compound, and the second organic compound are mixed to favorably function, resulting in high emission efficiency of the light-emitting device.

### <<Second Layer>>

In the case where a mixed layer or a stacked-layer structure that includes the metal or metal compound, the first organic compound, and the second organic compound is used for the first layer of the intermediate layer, a layer that includes a third organic compound and a fourth organic compound (which will be described later in detail) is preferably used for the second layer to enable favorable injection of holes into the light-emitting layer on the upper side.

### <Third Organic Compound>

As the third organic compound, an organic compound with a hole-transport property is preferably used. As the organic compound with a hole-transport property, any of a variety of organic compounds such as aromatic amine compounds, heteroaromatic compounds, aromatic hydrocarbons, and high molecular compounds (e.g., oligorners, dendrimers, and polymers) can be used. Note that the organic compound with a hole-transport property preferably has a hole mobility higher than or equal to 1×10⁻⁶ cm²/Vs. The organic compound with a hole-transport property is preferably a compound having a fused aromatic hydrocarbon ring or π-electron rich heteroarornatic ring. As the fused aromatic hydrocarbon ring, an anthracene ring, a naphthalene ring, or the like is preferable. As the π-electron rich heteroaromatic ring, a fused aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further fused to a carbazole ring or a dibenzothiophene ring is preferable.

Such an organic compound with a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound with a hole-transport property preferably has an N,N-bis(4-biphenyl)amino group to enable fabrication of a light-emitting device with a long lifetime.

Specific examples of the organic compound with a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]ftiran-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBAIBP), 4-(2-naphthyl)-4′, 4″-diphenyltriphenylamine (abbreviation: BBAjpNB), 4-[4-(2-naphthyl)phenyl]-4′, 4″-diphenyltriphenylamine (abbreviation: BBAPNBi), 4,4′-diphenyl-4″-(6;1′-binaphthyl-2-yl)triphenylamine (abbreviation: BBAaN3NB), 4,4′-diphenyl-4″-(7;1′-binaphthyl-2-yl)triphenylamine (abbreviation: BBAcN/PNB-03), 4,4′-diphenyl-4″-(7-phenyl)naphthyl-2-yltriphenylamine (abbreviation: BBAPINB-03), 4,4′-diphenyl-4″-(6;2′-binaphthyl-2-yl)triphenylamine (abbreviation: BBA(f3N2)B), 4,4′-diphenyl-4″-(7;2′-binaphthyl-2-yl)triphenylamine (abbreviation: BBA(PN2)B-03), 4,4′-diphenyl-4″-(4;2′-binaphthyl-1-yl)triphenylamine (abbreviation: BBAPNaNB), 4,4′-diphenyl-4″-(5;2′-binaphthyl-1-yl)triphenylamine (abbreviation: BBAPNcNB-02), 4-(4-biphenylyl)-4′-(2-naphthyl)-4″-phenyltriphenylamine (abbreviation: TPBiApNB), 4-(3-biphenylyl)-4′-[4-(2-naphthyl)phenyl]-4″-phenyltriphenylamine (abbreviation: mTPBiANBi), 4-(4-biphenylyl)-4′-[4-(2-naphthyl)phenyl]-4″-phenyltriphenylamine (abbreviation: TPBiADNBi), 4-phenyl-4′-(1-naphthyl)triphenylamine (abbreviation: αNBAIBP), 4,4′-bis(1-naphthyl)triphenylamine (abbreviation: αNBBIBP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiONB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[91-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N/V-(9,9-dimethyl-91H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofiran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-91-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-91-fluoren-2-amine, and N,N-bis(9,9-dimethyl-91-fluoren-2-yl)-9,9′-spirobi-9H-fluoren-1-amine.

As the material with a hole-transport property, any of the following aromatic amine compounds can be used: N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

### <Fourth Organic Compound>

As the fourth organic compound, a material having an acceptor property with respect to the third organic compound is preferably used. As the substance with an acceptor property, it is preferable to use an organic compound having an electron-withdrawing group (e.g., a halogen group or a cyano group), and it is further preferable to use an organic compound having four or more halogen groups, four or more cyano groups, or a combination of a halogen group and a cyano group the number of which is four or more. Specific examples include 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F₆-TCNNQ), and2-(7-dicyanomethylene-1,3,4,5,6,8,9,10-octafluoro-7H-pyren-2-ylidene)malononitrile. A compound in which electron-withdrawing groups are bonded to a fused aromatic ring having a plurality of heteroatoms, such as HAT-CN, is particularly preferable because it is thermally stable. A [3] radialene derivative having an electron-withdrawing group (in particular, a cyano group, a halogen group such as a fluoro group, or the like) has a very high electron-accepting property and thus is preferable. Specific examples include α,α′,α″-1,2,3-cyclopropanetriylidenetris[4-cyano-2,3,5,6-tetrafluorobenzeneacetonitrile],α′,c-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance with an acceptor property, a metal oxide, especially, a transition metal oxide such as molybdenum oxide, vanadium oxide, ruthenium oxide, tungsten oxide, or manganese oxide can be used, other than the above-described organic compounds.

A signal is preferably observed by electron spin resonance in the second layer. For example, the density of spins attributed to a signal observed at a g-factor of approximately 2.00 is preferably higher than or equal to 1×10¹⁷ spins/cm³, further preferably higher than or equal to 1×10¹⁸ spins/cm³, still further preferably higher than or equal to 1×10¹⁹ spins/cm³. In that case, the second layer can function as a charge-generation layer. Furthermore, the light-emitting device can have a low driving voltage and high efficiency.

### <<Third Layer>>

Between the first layer and the second layer of the intermediate layer, the third layer for enabling smooth electron transfer between the two layers may be provided.

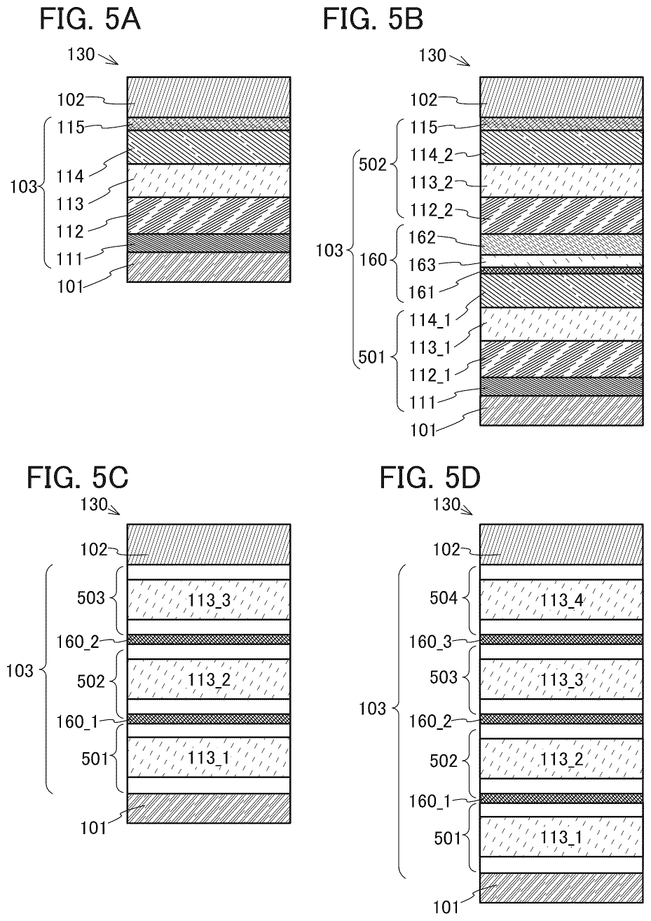

The third layer includes a substance with an electron-transport property and has a function of preventing interaction between the first layer and the second layer and transferring electrons smoothly. The LUMO level of the substance having an electron-transport property included in the third layer 163 is preferably between the LUMO level of the acceptor substance in the second layer 162 and the LUMO level of the organic compound included in a layer (a first electron-transport layer 114_1 in the first light-emitting unit 501 in FIG. 5B) which is included in the light-emitting unit on the first electrode 101 side and is in contact with the intermediate layer 160. As a specific value of the energy level, the LUMO level of the substance with an electron-transport property in the third layer 163 is higher than or equal to −5.0 eV, preferably higher than or equal to −5.0 eV and lower than or equal to −3.0 eV, further preferably higher than or equal to −4.30 eV and lower than or equal to −3.00 eV, still further preferably higher than or equal to −4.30 eV and lower than or equal to −3.30 eV, in which case electrons generated in the second layer 162 can be easily injected into the first layer 161 and accordingly an increase in the driving voltage of the light-emitting device can be inhibited. Note that as the substance with an electron-transport property in the third layer 163, a phthalocyanine-based material or a metal complex having a metal-oxygen bond and an aromatic ligand is preferably used.

Specifically, diquinoxalino[2,3-a:2′, 3′-c]phenazine (abbreviation: HATNA), 2,3,8,9,14,15-hexafluorodiquinoxalino[2,3-a:2′, 3′-c]phenazine (abbreviation: [HATNA-F6), a perylenetetracarboxylic acid derivative such as 3,4,9,10-perylenetetracarboxylicdiimide (abbreviation: PTCDI) or 3,4,9,10-perylenetetracarboxyl-bis-benzimidazole (abbreviation: PTCBI), (C60-Ih)[5,6]fullerene (abbreviation: C60), (C70-D5h)[5,6]fullerene (abbreviation: C70), or the like can be used. In addition, a compound having a heterophane skeleton containing a hetero ring can be used suitably, among materials having a cyclophane skeleton; for example, an organic compound having a phthalocyanine skeleton such as phthalocyanine (abbreviation: I-Pc) can be used. Alternatively, it is possible to use a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use a phthalocyanine-based metal complex such as copper phthalocyanine or zinc phthalocyanine or 2,3,8,9,14,15-hexafluorodiquinoxalino[2,3-a:2′, 3′-c]phenazine. Among these materials, CuPc and ZnPc are preferable because they are inexpensive and have favorable characteristics. Using ZnPc, which has a low diffusion coefficient with respect to silicon, reduces the probability that metal diffusion to a semiconductor adversely affects the semiconductor characteristics; accordingly, ZnPc is particularly suitable for a display device manufactured using a silicon semiconductor.

The thickness of the third layer 163 is greater than or equal to 1 nm and less than or equal to 10 nm, preferably greater than or equal to 2 nm and less than or equal to 5 nm.

The structures described in this embodiment can be used in appropriate combination with any of the structures described in the other embodiments.

### Embodiment 2

In this embodiment, other structures of a light-emitting device of one embodiment of the present invention are described.

FIG. 5A illustrates a light-emitting device 130, which is an example of the light-emitting device of one embodiment of the present invention. The light-emitting device 130 includes the organic compound layer 103 that includes the light-emitting layer 113, between the first electrode 101 that includes an anode and the second electrode 102 that includes a cathode.

FIG. 5B illustrates the light-emitting device 130 that is another example of the light-emitting device of one embodiment of the present invention. The light-emitting device 130 is a tandem light-emitting device. The light-emitting device 130 includes the first light-emitting unit 501 including a first light-emitting layer 113_1, the second light-emitting unit 502 including a second light-emitting layer 1132, and the intermediate layer 160, as the organic compound layer 103.

Although a light-emitting device that includes one intermediate layer 160 and two light-emitting units is described as an example in this embodiment, a light-emitting device that includes n intermediate layer(s) (n is an integer greater than or equal to 1) and n−1 light-emitting units may be employed.

For example, the light-emitting device 130 illustrated in FIG. 5C is an example of a tandem light-emitting device in which n is 2 and which includes the first light-emitting unit 501, a first intermediate layer 160_1, the second light-emitting unit 502, a second intermediate layer 160_2, and a third light-emitting unit 503 including a first light-emitting layer 113_3, as the organic compound layer 103. The color gamut of light emitted by a light-emitting layer in one light-emitting unit may be the same as or different from that of light emitted by a light-emitting layer in another light-emitting unit. In addition, the light-emitting layers may each have a single-layer structure or a stacked-layer structure. For example, the first light-emitting unit and the third light-emitting unit emit light in a blue region and stacked light-emitting layers of the second light-emitting unit emit light in a red region and light in a green region, so that white emission can be obtained.

The light-emitting device 130 illustrated in FIG. 5D is an example of a tandem light-emitting device in which n is 3 and which includes the first light-emitting unit 501, the first intermediate layer 160_1, the second light-emitting unit 502, the second intermediate layer 1602, the third light-emitting unit 503, a third intermediate layer 160_3, and a fourth light-emitting unit 504 including a fourth light-emitting layer 1134, as the organic compound layer 103. The color gamut of light emitted by a light-emitting layer in one light-emitting unit may be the same as or different from that of light emitted by a light-emitting layer in another light-emitting unit. In addition, the light-emitting layers may each have a single-layer structure or a stacked-layer structure. For example, any three of the four light-emitting units can be units for blue (B) light emission, and the other one can be a unit for green (G) light emission; any two of the four light-emitting units can be units for blue (B) light emission, and the other two can be units for yellow (Y) light emission: alternatively, any one of the four light-emitting units can be a unit for red (R) light emission, another one can be a unit for green (G) light emission, the other two can be units for blue (B) light emission.

The light-emitting device 130 may be fabricated using a lithography method, for example. In the case of the light-emitting device fabricated using a lithography method, at least the light-emitting layer 113 or the second light-emitting layer 113_2 and the layer(s) in the organic compound layer that is/are closer to the first electrode 101 than the light-emitting layer or the second light-emitting layer are formed by processing at the same time; consequently, their end portions are substantially aligned in the perpendicular direction.

The organic compound layer 103 may include another functional layer in addition to the light-emitting layer. FIG. 5A illustrates a structure where, in addition to the light-emitting layer 113, the hole-injection layer 111, the hole-transport layer 112, the electron-transport layer 114, and the electron-injection layer 115 are provided in the organic compound layer 103. Furthermore, the first light-emitting unit 501 and the second light-emitting unit 502 may each include another functional layer in addition to the light-emitting layer. FIG. 5B illustrates a structure where the hole-injection layer 111, a first hole-transport layer 112_1, and the first electron-transport layer 114_1, in addition to the first light-emitting layer 113_1, are provided in the first light-emitting unit 501 and a second hole-transport layer 1122, a second electron-transport layer 1142, and the electron-injection layer 115, in addition to the second light-emitting layer 113_2, are provided in the second light-emitting unit 502. The structure of the organic compound layer 103 in the present invention is not limited to these structures; any of the layers may be absent or another layer may be added. A carrier-blocking layer (a hole-blocking layer or an electron-blocking layer), an exciton-blocking layer, or the like may be typically added.

Then, components of the above light-emitting device 130, other than the intermediate layer 160, are described,

### <<Structure of First Electrode>>

The first electrode 101 includes an anode. The first electrode 101 may have a stacked-layer structure where the layer in contact with the organic compound layer 103 functions as the anode. The anode is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide, indium oxide-zinc oxide, and indium oxide containing tungsten oxide and zinc oxide (IWZO). Films of such conductive metal oxides are usually formed by a sputtering method, but may be formed by a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IVZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), a nitride of a metal material (e.g., titanium nitride), or the like can be used for the anode. Graphene can also be used for the anode. Note that an electrode material can be selected regardless of the work function when the second layer 162 in the above intermediate layer 160 is used for the layer (typically the hole-injection layer) in contact with the anode.

### <<Structure of Hole-Injection Layer>>

The hole-injection layer 111 is provided in contact with the anode and has a function of facilitating injection of holes into the organic compound layer 103 (the first light-emitting unit 501). The hole-injection layer 111 can be formed using phthalocyanine (abbreviation: H₂Pc), a phthalocyanine-based compound such as copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N⁷-(3-methylphenyl)-N′-phenylamino]phenyl}-N-phenylamino)biphenyl (abbreviation: DNTPD), or a high molecular compound such as poly(3,4-ethylenedioxythiophene)/poly(styrenesulfonic acid) (abbreviation: PEDOT/PSS).

The hole-injection layer 111 may be formed using a substance with an electron-accepting property. As the substance with an acceptor property, any of the substances described as the substance with an acceptor property used for the second layer 162 of the above intermediate layer 160 can be used similarly,

The hole-injection layer 111 may be formed using the material with a hole-transport property that is used for the second layer 162 of the above intermediate layer 160.

Further preferably, in the hole-injection layer 111, the organic compound with a hole-transport property that is used in the composite material has a relatively low HOMO level higher than or equal to −5.7 eV and lower than or equal to −5.4 eV. When the organic compound having a hole-transport property that is used in the composite material has a relatively low HOMO level, holes can be easily injected into the hole-transport layer and a light-emitting device having a long lifetime can be easily fabricated. In addition, when the organic compound having a hole-transport property that is used in the composite material has a relatively low HOMO level, induction of holes can be inhibited properly, so that the light-emitting device can have a longer lifetime.

The formation of the hole-injection layer 111 can improve the hole-injection property, which allows the light-emitting device to be driven at a low voltage.

Among substances with an acceptor property, an organic compound with an acceptor property is easy to use because the organic compound is easily deposited by evaporation as a film.

The second light-emitting unit 502 includes no hole-injection layer because the second layer 162 of the intermediate layer 160 functions as a hole-injection layer; however, the second light-emitting unit 502 may include a hole-injection layer.

### <<Structure of Hole-Transport Layer>>

The hole-transport layer (the first hole-transport layer 112_1 or the second hole-transport layer 112_2) includes an organic compound with a hole-transport property. The organic compound with a hole-transport property preferably has a hole mobility higher than or equal to 1×10⁻⁶ cm²/Vs.

Examples of the aforementioned organic compound with a hole-transport property include the following compounds: compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBAIBP), 4,4′-diphenyl-4″-(9-phenyl-9H-carbazol-3-yl)triphenylamine (abbreviation: PCBBiIBP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H1-fluoren]-2-amine (abbreviation: PCBASF); compounds having a carbazole skeleton, such as 1,3-bis(IN-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-911,9′1-3,3′-bicarbazole (abbreviation: βNCCP), 9-(3-biphenyl)-9′-(2-naphthyl)-3,3′-bi-9H-carbazole (abbreviation: ONCCmBP), 9-(4-biphenyl)-9′-(2-naphthyl)-3,3′-bi-9H-carbazole (abbreviation: pNCCBP), 9,9′-di-2-naphthyl-3,3′-9H,9′H-bicarbazole (abbreviation: BisβNCz), 9-(2-naphthyl)-9′-[1,1′: 4′, 1″-terphenyl]-3-yl-3,3′-9H,9′H-bicarbazole, 9-(2-naphthyl)-9′-[1,1′: 3′, 1″-terphenyl]-3-yl-3,3′-9H,9′H-bicarbazole, 9-(2-naphthyl)-9′-[1,1′: 3′, 1″-terphenyl]-5′-yl-3,3′-9H,9′H-bicarbazole, 9-(2-naphthyl)-9′-[1,1′: 4′, 1″-terphenyl]-4-yl-3,3′-9H,9′H-bicarbazole, 9-(2-naphthyl)-9′-[1,1′: 3′, 1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′: 3′, 1″-terphenyl]-4-yl-3,3′-9H,9′H-bicarbazole; compounds having a thiophene skeleton, such as 4,4′, 4″-(benzene-1,3,5-triyl)tri(dibenzothiophene) (abbreviation: DBT3P-11), 2,8-diphenyl-4-[4-(9-phenyl-9H-fluoren-9-yl)phenyl]dibenzothiophene (abbreviation: DBTFLP-111), and 4-[4-(9-phenyl-9H-fluoren-9-yl)phenyl]-6-phenyldibenzothiophene (abbreviation: DBTFLP-IV); and compounds having a furan skeleton, such as 4,4′, 4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-J1). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the material having a hole-transport property that is used for the composite material in the hole-injection layer 111 can also be suitably used as the material included in the hole-transport layer.

### <<Structure of Light-Emitting Layer>>

The light-emitting layer (the light-emitting layer 113, the first light-emitting layer 1131, or the second light-emitting layer 113_2) preferably includes a light-emitting substance and a host material. The light-emitting layer may additionally include another material. Alternatively, the light-emitting layer may have a stacked-layer structure of two layers with different compositions.

The light-emitting substance may be a fluorescent substance, a phosphorescent substance, a substance exhibiting thermally activated delayed fluorescence (TADF), or any other light-emitting substance.

Examples of the material that can be used as a fluorescent substance in the light-emitting layer are as follows, Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,-bis(3-methylphenyl)-N,N,-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,AN-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N,N-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), N,N,N,N,N″ N″N″′,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), 9,10-bis(2-biphenyl)-2-(N,N-triphenyl-1,4-phenylenediamin-N-yl)anthracene (abbreviation: 2DPABPhA), 9,10-bis(biphenyl-2-yl)-N-[4-(9H1-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,AN-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,A¹-tetrakis(4-methylphenyl)tetracene-5,11-diamine (abbreviation: p-mPhTD), 7,14-diphenyl-N,N,AN,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1;7,7-tetramethyl-2,3,6,7-tetrahydro-1,51-benzo[ij]quinolizin-9-yl)ethenyl]-4H-pyran-4-ylidene}propanedinitrile (abbreviation: BisDCJTM), N,AN-diphenyl-N,N′-(1,6-pyrene-diyl)bis[(6-phenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,1OPCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Fused aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

Examples of the material that can be used when a phosphorescent substance is used as the light-emitting substance in the light-emitting layer are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-N′²]phenyl-KC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), and tris[4-(3-biphenyl)-5-isopropyl-3-phenyl-4H-1,2,4-triazolato]iridium(III) (abbreviation: [Ir(iPrptz-3b)₃]); an organometallic iridium complex having a 1H-triazole skeleton, such as tris[3-methyl-1-(2-methylphenyl)-5-phenyl-1-1,2,4-triazolato]iridium(III) (abbreviation: [Ir(Mptz1-mp)₃]) andtris(1-methyl-5-phenyl-3-propyl-11H-1,2,4-triazolato)iridium(III) (abbreviation: [Ir(Prptzl-Me)3]); an organometallic iridium complex having an imidazole skeleton, such as fac-tris[1-(2,6-diisopropylphenyl)-2-phenyl-1H-imidazole]iridium(III) (abbreviation: [Iir(iPrpim)₃]) and tris[3-(2,6-dimethylphenyl)-7-methylimidazo[1,2-f]phenanthridinato]iridium(III) (abbreviation: [lr(dmpimpt-Me)₃]); and an organometallic iridium complex in which a phenylpyridine derivative having an electron-withdrawing group is a ligand, such as bis[2-(4′, 6′-difluorophenyl)pyridinato-N,C²]iridium(III) tetrakis(1-pyrazolyl)borate (abbreviation: FIr6), bis[2-(4′, 6′-difluorophenyl)pyridinato-N,C²]iridium(III) picolinate (abbreviation: Ffrpic), bis{2-[3′, 5′-bis(trifluoromethyl)phenyl]pyridinato-N,C)}iridium(III) picolinate (abbreviation: [Ir(CF₃ppy)2(pic)]), and bis[2-(4′, 6′-difluorophenyl)pyridinato-N,C²]iridium(III) acetylacetonate (abbreviation: Firacac). These compounds emit blue phosphorescent light and have an emission peak in the wavelength range from 450 nm to 520 nm.

Other examples include an organometallic iridium complex having a pyrimidine skeleton, such as tris(4-methyl-6-phenylpyrimidinato)iridium(III) (abbreviation: [Lr(mppm)3]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppn)₂(acac)]), (acetylacetonato)bis(6-tert-butyl-4-phenylpyrimidinato)iridium(lii) (abbreviation: [Ir(tBuppm)₂(acac)]), (acetylacetonato)bis[6-(2-norbornyl)-4-phenylpyrimidinato]iridium(I) (abbreviation: [Ir(nbppm)2(acac)]), (acetylacetonato)bis[5-methyl-6-(2-methylphenyl)-4-phenylpyrimidinato]iridium(III) (abbreviation: [Ir(mpmppm)2(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)2(acac)]); an organometallic iridium complex having a pyridine skeleton, such as tris(2-phenylpyridinato-N,C′)iridium(lII) (abbreviation: [Ir(ppy)₃I), bis(2-phenylpyridinato-N,C′)iridium(III) acetylacetonate (abbreviation: [Ir(ppy)₂(acac)]), bis(benzo[h]quinolinato)iridium(Ill) acetylacetonate (abbreviation: [hr(bzq)₂(acac)]), tris(benzo[h]quinolinato)iridium(III) (abbreviation: [Ir(bzq)₃]), tris(2-phenylquinolinato-N,C²)iridium(III) (abbreviation: [Jr(pq)₃]), bis(2-phenylquinolinato-N,C″)iridium(III) acetylacetonate (abbreviation: [Ir(pq)2(acac)]), [2-d3-methyl-8-(2-pyridinyl-KAbenzofuro[2,3-b]pyridine-C]bis[2-(5-d3-methyl-2-pyridinyl-κN2)phenyl-KC]iridium(II) (abbreviation: ir(5rmppy-d₃)2(mbfpypy-d₃)), {2-(rmethyl-d3)-8-[4-(1-methylethyl-1-d)-2-pyridin_{y}l-κN]benzofuiro[2,3-b]pyridin-7-yl-κC}bis{5-(methyl-d3)-2-[5-(methyl-d3)-2-pyridinyl-κN]phenyl-KC}iridium(III) (abbreviation: Ir(5mtpy-d6)2(rbfpypy-iPr-d4)), [2-d3-methyl-(2-pyridinyl-KA)benzofuiro[2,3-b]pyridine-KC]bis[2-(2-pyridinyl-rN)phenyl-κC]iridium(III) (abbreviation: Ir(ppy)2(rbfpypy-d3)), or [2-(4-methyl-5-phenyl-2-pyridinyl-κN)phenyl-iC]bis[2-(2-pyridinyl-κN)phenyl-κC]iridium(III) (abbreviation: Ir(ppy)2(mdppy)); and a rare earth metal complex such as tris(acetylacetonato) (monophenanthroline)terbium(III) (abbreviation: [Tb(acac)3(Phen)]). These are mainly compounds that emit green phosphorescent light and have an emission peak in the wavelength range from 500 nm to 600 nm. Note that organometallic iridium complexes including a pyriridine skeleton have remarkably high reliability or emission efficiency and thus are particularly preferable.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)j), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(dlnpm)2(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)2(acac)]); organometallic iridium complexes having a pyridine skeleton, such as tris(1-phenylisoquinolinato-N,C²)iridium(III) (abbreviation: [Ir(piq)₃]) and bis(1-phenylisoquinolinato-N,C²)iridium(III) acetylacetonate (abbreviation: [lr(piq)₂(acac)]); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europiun(III) (abbreviation: [Eu(DBM)₃(Phen)]) and tris[1-(2-thenoyl)-3,3,3-trifluoroacetonato](rnonophenanthroline)europiur(IIJ) (abbreviation: [Eu(TTA)3(Phen)]). These compounds emit red phosphorescent light and have an emission peak in the wavelength range from 600 nm to 700 nm. Furthermore, the organometallic iridium complexes having a pyrazine skeleton can provide red light emission with favorable chromaticity.

Besides the above phosphorescent compounds, known phosphorescent compounds may be selected and used.

Examples of the TADF material include a fullerene, a derivative thereof, an acridine, a derivative thereof, and an eosin derivative. Other examples include a metal-containing porphyrin, such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (SnF₂(Proto IX)), a mesoporphyrin-tin fluoride complex (SnF₂(Meso LX)), a hematoporphyrin-tin fluoride complex (SnF₂(Hemato IX)), a coproporphyrin tetramethyl ester-tin fluoride complex (SnF2(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtC]₂OEP), which are represented by the following structural Formulas.

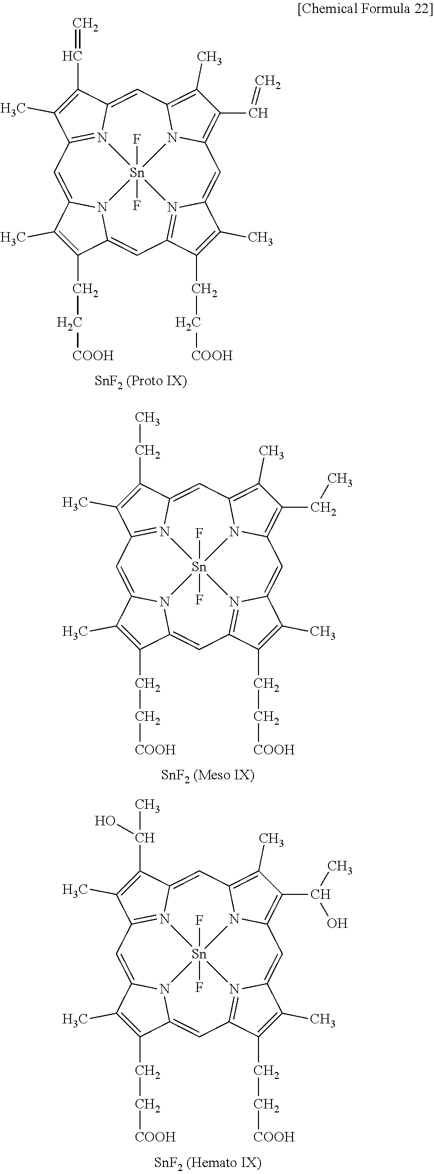

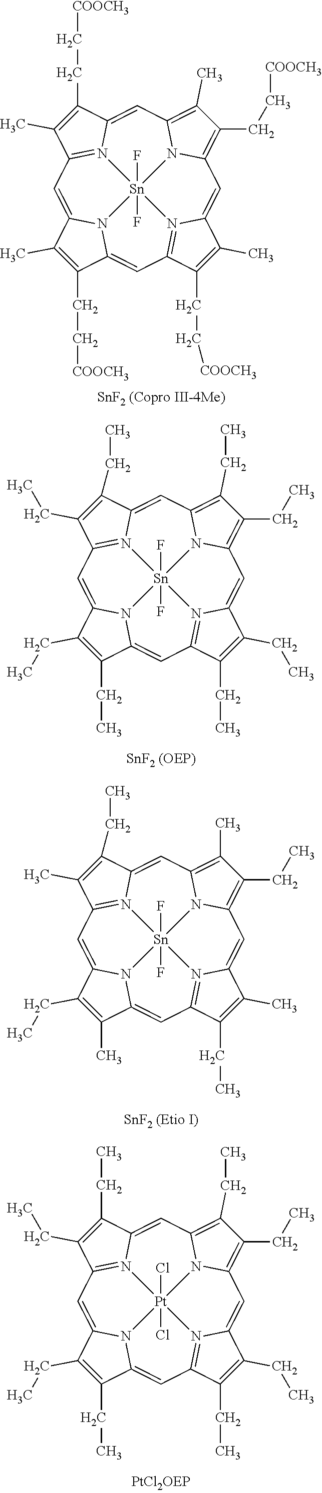

Alternatively, any of heterocyclic compounds each having one or both of a π-electron rich heteroaromatic ring and a π-electron deficient heteroaromatic ring and represented by Structure Formulas below can be used: 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-91H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-diinethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having a π-electron deficient heteroaromatic ring, a pyridine skeleton, a diazine skeleton (a pyrimidine skeleton, a pyrazine skeleton, and a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having a π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which a π-electron rich heteroaromatic ring is directly bonded to a π-electron deficient heteroaromatic ring is particularly preferable because the electron-donating property of the n-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a n-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

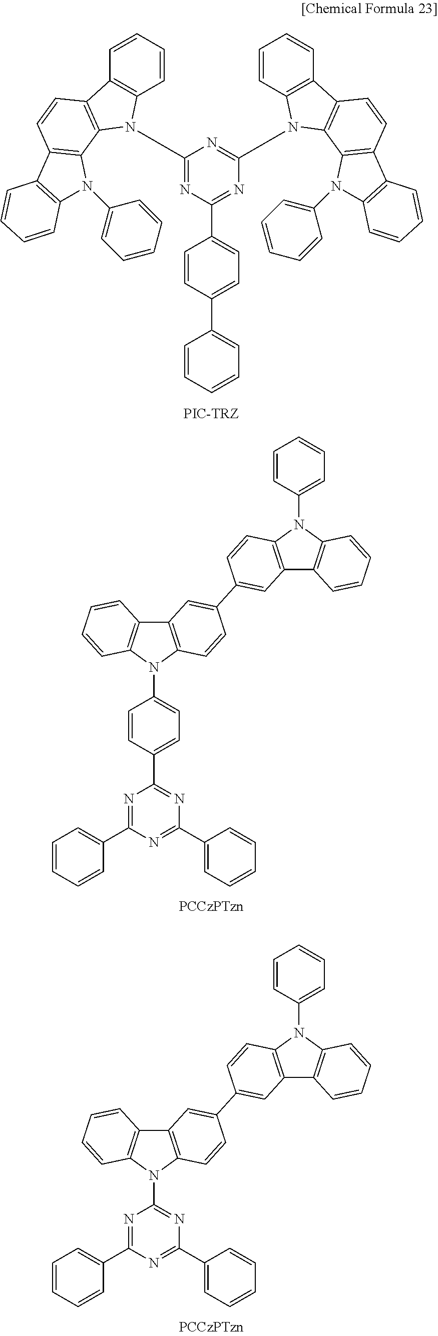 [SMILES: c1ccc(-c2ccc(-c3nc(Cn4c5ccccc5c5ccc6c7ccccc7n(-c7ccccc7)c6c54)nc(Cn4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

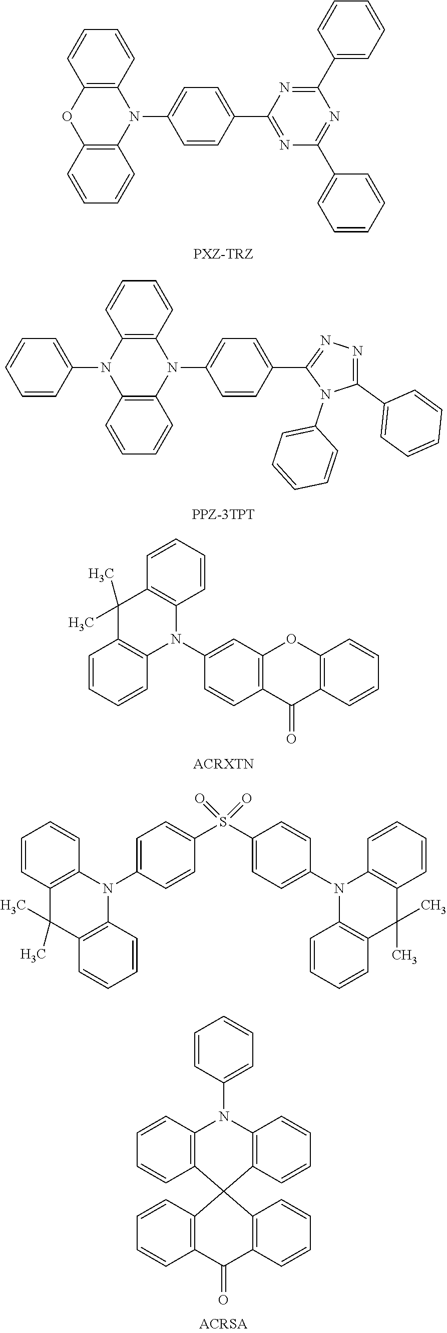 [SMILES: c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Alternatively, a TADF material whose singlet excited state and triplet excited state are in a thermal equilibrium state may be used. Since such a TADF material enables a short emission lifetime (excitation lifetime), the efficiency of a light-emitting device in a high-lurninance region can be less likely to decrease. Specifically, a material having the following molecular structure can be used.

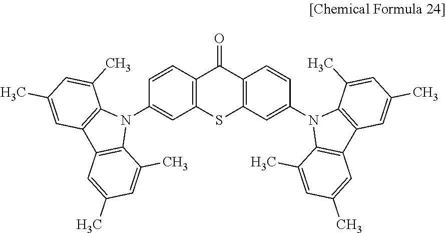

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at a low temperature (e.g., 77 K to 10 K) can be used for an index of the T₁ level. When the level of energy with a wavelength of the line obtained by extrapolating a tangent to the fluorescence spectrum at a tail on the short wavelength side is the S1 level and the level of energy with a wavelength of the line obtained by extrapolating a tangent to the phosphorescence spectrum at a tail on the short wavelength side is the T₁ level, the difference between the S1 level and the T1 level of the TADF material is preferably smaller than or equal to 0.3 eV, further preferably smaller than or equal to 0.2 eV.

When a TADF material is used as the light-emitting substance, the S₁ level of the host material is preferably higher than that of the TADF material. In addition, the T₁ level of the host material is preferably higher than that of the TADF material.

The host material in the light-emitting layer can be selected from various carrier-transport materials such as materials with an electron-transport property and/or materials with a hole-transport property, and the TADF materials.

As the material with a hole-transport property, any of the aforementioned materials given as the material with a hole-transport property can be used similarly.

As the material with an electron-transport property, any of the aforementioned materials given as the material with an electron-transport property can be used similarly.

As the TADF material that can be used as the host material, any of the above materials mentioned as the TADF material can be used similarly. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S₁ level of the TADF material is preferably higher than that of the fluorescent substance in order that high emission efficiency can be achieved. Furthermore, the T₁ level of the TADF material is preferably higher than the S₁ level of the fluorescent substance. Therefore, the T₁ level of the TADF material is preferably higher than that of the fluorescent substance.

It is also preferable to use a TADF material that emits light whose wavelength overlaps with the wavelength on the lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carriers are preferably recombined in the TADF material. It is also preferable that the triplet excitation energy generated in the TADF material not be transferred to the triplet excitation energy of the fluorescent substance. For that purpose, the fluorescent substance preferably has a protective group around a luminophore (a skeleton that causes light emission) of the fluorescent substance. As the protective group, a substituent having no l bond is preferable. For example, a saturated hydrocarbon is preferable. Specific examples thereof include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups, The substituents having no π bond are poor in carrier transport performance, whereby the TADF material and the luminophore of the fluorescent substance can be made away from each other with little influence on carrier transport or carrier recombination. Here, the luminophore refers to an atomic group (skeleton) that causes light emission in a fluorescent substance. The luminophore is preferably a skeleton having a π bond, preferably includes an aromatic ring, or preferably includes a condensed aromatic ring or a condensed heteroaromatic ring. Examples of such a luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to form a light-emitting layer with high emission efficiency and high durability, Among the substances having an anthracene skeleton, a substance having a diphenylanthracene skeleton, especially, a substance having a 9,10-diphenylanthracene skeleton, is chemically stable and thus is preferably used as the host material. The host material preferably has a carbazole skeleton because the hole-injection and hole-transport properties are improved; further preferably, the host material has a benzocarbazole skeleton in which a benzene ring is further fused to the carbazole skeleton because the HOMO level thereof is higher than that of a host material having a carbazole skeleton by approximately 0.1 eV and thus holes enter the host material easily. In particular, the host material preferably has a dibenzocarbazole skeleton because the HOMO level thereof is higher than that of the host material having a carbazole skeleton by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4′-(9-phenyl-9H-fluoren-9-yl)biphenyl-4-yl]anthracene (abbreviation: FLPPA), 9-(1-naphthyl)-10-[4-(2-naphthyl)phenyl]anthracene (abbreviation: αN-βNPAnth), 9-(I-naphthyl)-10-(2-naphthyl)anthracene (abbreviation: α,β-ADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: βN-mPINPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a material with an electron-transport property and a material with a hole-transport property. By mixing the material with an electron-transport property and the material with a hole-transport property, the transport property of the light-emitting layer 113 can be easily adjusted and a recombination region can be easily controlled. The weight ratio of the content of the material with a hole-transport property to the content of the material with an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

These mixed materials may form an exciplex. These mixed materials are preferably selected so as to form an exciplex that exhibits light emission whose wavelength overlaps with the wavelength on the lowest-energy-side absorption band of the light-emitting substance, in which case energy can be transferred smoothly and light emission can be obtained efficiently. Such a structure is preferably used to reduce the driving voltage.

Note that at least one of the materials fornling an exciplex may be a phosphorescent substance. In this case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property. Note that the LUMO levels and the HOMO levels of the materials can be calculated from the electrochemical characteristics (the reduction potentials and the oxidation potentials) of the materials that are measured by cyclic voltammetry (CV).

The formation of an exciplex can be confirmed, for example, in the following manners: when the emission spectrum of the material having a hole-transport property, the emission spectrum of the material having an electron-transport property, and the emission spectrum of a mixed film of these materials are compared, it is observed that the emission spectrum of the mixed film is shifted to the longer wavelength than the emission spectrum of each of the material having a hole-transport property and the material having an electron-transport property (or has another peak on the longer wavelength side). Alternatively, when the transient photoluminescence (PL) of the material having a hole-transport property, the PL of the material having an electron-transport property, and the PL of the mixed film of these materials are compared, a difference in transient response is observed, for example, the transient PL lifetime of the mixed film has a longer lifetime component or has a larger portion of a delayed component than that of each of the material having a hole-transport property and the material having an electron-transport property. The transient PL can be rephrased as transient electroluminescence (EL). That is, the formation of an exciplex can also be confirmed by comparing the transient EL of the material having a hole-transport property, the transient EL of the material having an electron-transport property, and the transient EL of the mixed film of these materials and observing a difference in transient response.

### <<Structure of Electron-Transport Layer>>

The electron-transport layer (the electron-transport layer 114, the first electron-transport layer 114_1, or the second electron-transport layer 114_2) includes a substance with an electron-transport property. The material having an electron-transport property preferably has an electron mobility higher than or equal to 1×10 cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound including a π-electron deficient heteroaromatic ring is preferable as the above organic compound. The organic compound having a π-electron deficient heteroaromatic ring is preferably one or more of an organic compound having a heteroaromatic ring with an azole skeleton, an organic compound having a heteroaromatic ring with a pyridine skeleton, an organic compound having a heteroaromatic ring with a diazine skeleton, and an organic compound having a heteroaromatic ring with a triazine skeleton,

As the organic compound with an electron-transport property that can be used for the electron-transport layer, any of the above organic compounds that can be used as the organic compound having an electron-transport property in the first layer of the intermediate layer 160 can be used similarly. Among the above materials, the organic compound that includes a heteroaromatic ring having a diazine skeleton, the organic compound that includes a heteroaromatic ring having a pyridine skeleton, and the organic compound that includes a heteroaromatic ring having a triazine skeleton are preferable because of having high reliability. In particular, the organic compound that includes a heteroaromatic ring having a diazine (pyrimidine or pyrazine) skeleton and the organic compound that includes a heteroaromatic ring having a triazine skeleton have a high electron-transport property to contribute to a reduction in driving voltage.

The electron mobility of the electron-transport layer is preferably higher than or equal to 1×10 cm²/Vs and lower than or equal to 5×10⁻⁵ cm²/Vs, when the square root of the electric field strength [V/cm] is 600. The amount of electrons injected into the light-emitting layer can be controlled by reducing the electron-transport property of the electron-transport layer, whereby the light-emitting layer can be prevented from having excess electrons. It is particularly preferable to employ this structure when the hole-injection layer is formed using a composite material that includes a material having a hole-transport property with a relatively low HOMO level higher than or equal to −5.7 eV and lower than or equal to −5.4 eV, in which case a long lifetime can be achieved. In this case, the material with an electron-transport property preferably has a HOMO level higher than or equal to −6.0 eV.

For example, as the electron-transport material that can be used for the electron-transport layer, a heteroaromatic compound can be used. The term heteroaromatic compound refers to a cyclic compound including at least two different kinds of elements in a ring. Examples of cyclic structures include a three-membered ring, a four-membered ring, a five-membered ring, a six-membered ring, and the like, and in particular, a five-membered ring and a six-membered ring are preferable. The elements included in the heteroaromatic compound are preferably one or more of nitrogen, oxygen, and sulfur, in addition to carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and a π-electron deficient heteroaromatic compound including the nitrogen-containing heteroaromatic compound, is preferably used. The compounds in Embodiment 1 have an electron-transport property and thus can be used as an electron-transport material.

Note that the electron-transport material can be different from the materials used in the light-emitting layer. Not all excitons formed by recombination of carriers in the light-emitting layer can contribute to light emission and some excitons are diffused into a layer in contact with the light-emitting layer or a layer in the vicinity of the light-emitting layer. In order to avoid this phenomenon, the energy level (the lowest singlet excitation level or the lowest triplet excitation level) of a material used for the layer in contact with the light-emitting layer or the layer in the vicinity of the light-emitting layer is preferably higher than that of a material used for the light-emitting layer. Therefore, when a material different from the material of the light-emitting layer is used as the electron-transport material, a device with high efficiency can be obtained.

The heteroaromatic compound is an organic compound including at least one heteroaromatic ring.

The heteroaromatic ring includes any one of a pyridine ring, a diazine ring, a triazine ring, an azole ring, and the like. A heteroaromatic ring having a diazine ring includes a heteroaromatic ring having a pyrimidine ring, a pyrazine ring, a pyridazine ring, or the like. A heteroaromatic ring having an azole ring includes a heteroaromatic ring having an imidazole ring, a triazole ring, an oxadiazole ring, an oxazole ring, a thiazole ring, or the like.

The heteroaromatic ring includes a fused heteroaromatic ring having a fused ring structure. Examples of the fused heteroaromatic ring include a quinoline ring, a benzoquinoline ring, a quinoxaline ring, a dibenzoquinoxaline ring, a quinazoline ring, a benzoquinazoline ring, a dibenzoquinazoline ring, a phenanthroline ring, a furodiazine ring, and a benzimidazole ring.

Examples of the heteroaromatic compound having a five-membered ring structure, which is a heteroaromatic compound containing carbon and one or more of nitrogen, oxygen, and sulfur, include a heteroaromatic compound having an imidazole ring, a heteroaromatic compound having a triazole ring, a heteroaromatic compound having an oxazole ring, a heteroaromatic compound having an oxadiazole ring, a heteroaromatic compound having a thiazole ring, and a heteroaromatic compound having a benziridazole ring.

Examples of the heteroaromatic compound having a six-membered ring structure, which is a heteroaromatic compound containing carbon and one or more of nitrogen, oxygen, sulfur, and the like, include a heteroaromatic compound having a heteroaromatic ring, such as a pyridine ring, a diazine ring (a pyrimidine ring, a pyrazine ring, a pyridazine ring, or the like), a triazine ring, or an azole ring. Other examples include a heteroaromatic compound having a bipyridine structure, a heteroaromatic compound having a terpyridine structure, and the like, which are included in examples of a heteroaromatic compound in which pyridine rings are connected.

Examples of the heteroaromatic compound having a fused ring structure partly including the above six-membered ring structure include a heteroaromatic compound having a fused heteroaromatic ring such as a quinoline ring, a benzoquinoline ring, a quinoxaline ring, a dibenzoquinoxaline ring, a phenanthroline ring, a furodiazine ring (including a structure in which an aromatic ring is fused to a furan ring of a furodiazine ring), or a benzimidazole ring.

Specific examples of the above-described heteroaromatic compound having a five-membered ring structure (an azole ring (including an imidazole ring, a triazole ring, or an oxadiazole ring), an oxazole ring, a thiazole ring, or a benzimidazole ring) include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: COIl), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), 2,2′, 2″-(1,3,5-benzenetriyl)tris(1-phenyH-benzinidazole) (abbreviation: TPI31), 2-[3-(dibenzothiophen-4-yl)phenyl]-1-phenyl-1H-benzimidazole (abbreviation: mDBTBIm-11), and 4,4′-bis(5-methylbenzoxazol-2-vl)stilbene (abbreviation: BzOS).

Specific examples of the above-described heteroaromatic compound having a six-membered ring structure (including a heteroaromatic ring having a pyridine ring, a diazine ring, a triazine ring, or the like) include a heteroaromatic compound including a heteroaromatic ring having a pyridine ring, such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB); a heteroaromatic compound including a heteroaromatic ring having a triazine ring, such as 2-{4-[3-(N-phenyl-9H1-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 5-[3-(4,6-diphenyl-1,3,5-triazin-2-yl)phenyl]-7,7-dimethyl-5H,7H-indeno[2,1-b]carbazole (abbreviation: mlNc(II)PTzn), 2-[3′-(triphenylen-2-yl)biphenyl-3-yl]-4,6-diphenyl-1,3,5-triazine (abbreviation: mTpBPTzn), 2-(biphenyl-4-yl)-4-phenyl-6-(9,9′-spirobi[9H-fluoren]-2-yl)-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′: 4′, 1″-terphenyl)-4-yl]-1-dibenzofuranyl}-1,3,5-triazine (abbreviation: mBP-TPDBfTzn), 2-{3-[3-(dibenzothiophen-4-yl)phenyl]phenyl}-4,6-diphenyl-1,3,5-triazine (abbreviation: mDBt3PTzn), or mFBPTzn; and a heteroaromatic compound including a heteroaromatic ring having a diazine (pyrimidine) ring, such as 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-1]), 4,6-bis[3-(9H-carbazol-9-yl)phenyl]pyrimidine (abbreviation: 4,6mCzP2Pm), 4,6mCzBP2Pm, 6-(biphenyl-3-yl)-4-[3,5-bis(91-carbazol-9-yl)phenyl]-2-phenylpyrimidine (abbreviation: 6mBP-4Cz2PPm), 4-[3,5-bis(9H-carbazol-9-yl)phenyl]-2-phenyl-6-(biphenyl-4-yl)pyrimidine (abbreviation: 6BP-4Cz2PPm), 4-[3-(dibenzothiophen-4-yl)phenyl]-8-(naphthalen-2-yl)-[1]benzofuro[3,2-d]pyrimidine (abbreviation: 8PN-4mDBtPBfpm), 8BP-4mDBtPBfpm, 9mDBtBPNfpr, 9μmDBtBPNfpr, 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′: 4,5]furo[3,2-d]pyrimidine (abbreviation: 8mDBtBPNfpm), or 8-[(2,2′-binaphthalen)-6-yl]-4-[3-(dibenzothiophen-4-yl)phenyl]-[1I]benzofuro[3,2-d]pyrimidine (abbreviation: 8(βN2)-4mDBtPBfpm). Note that examples of the above aromatic compounds including a heteroaromatic ring include heteroaromatic compounds having a fused heteroaromatic ring.

Other examples include heteroaromatic compounds including a heteroaromatic ring having a diazine (pyrimidine) ring, such as 2,2′-(pyridine-2,6-diyl)bis(4-phenylbenzo[h]quinazoline) (abbreviation: 2,6(IP-Bqn)2Py), 2,2′-(2,2′-bipyridine-6,6′-diyl)bis(4-phenylbenzo[h]quinazoline) (abbreviation: 6,6′(P-Bqn)2BPy), 2,2′-(pyridine-2,6-diyl)bis{4-[4-(2-naphthyl)phenyl]-6-phenylpyrimidine}(abbreviation: 2,6(NP—PPm)₂Py), or 6-(biphenyl-3-yl)-4-[3,5-bis(9H-carbazol-9-yl)phenyl]-2-phenylpyrimidine (abbreviation: 6mBP-4Cz2PPm), and a heteroaromatic compound including a heteroaromatic ring having a triazine ring, such as 2,4,6-tris[3′-(pyridin-3-yl)biphenyl-3-yl]-1,3,5-triazine (abbreviation: TmPPPyTz), 2,4,6-tris(2-pyridyl)-1,3,5-triazine (abbreviation: 2Py3Tz), or 2-[3-(2,6-dimethyl-3-pyridinyl)-5-(9-phenanthrenyl)phenyl]-4,6-diphenyl-1,3,5-triazine (abbreviation: mPn-mDmePyPTzn).

Specific examples of the above-described heteroaromatic compound having a fused ring structure partly including a six-membered ring structure (the heteroaromatic compound having a fused ring structure) include a heteroaromatic compound having a quinoxaline ring, such as bathophenanthroline (abbreviation: Bphen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), 2,2′-biphenyl-4,4′-diylbis(9-phenyl-1,10-phenanthroline) (abbreviation: PPhen2BP), 2,2′-(pyridine-2,6-diyl)bis(4-phenylbenzo[h]quinazoline) (abbreviation: 2,6(P-Bqn)2Py), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), or 2mpPCBPDBq.

For the electron-transport layer, any of the metal complexes given below as well as the heteroaromatic compounds given above can be used. Examples of the metal complexes include a metal complex having a quinoline ring or a benzoquinoline ring, such as tris(8-quinolinolato)aluminum(III) (abbreviation: Alq₃), Almq₃, 8-quinolinolato-lithium (abbreviation: Liq), BeBq₂, bis(2-methyl-8-quinolinolato)(4-phenylphenolato)aluminum(IIJ) (abbreviation: BAlq), or bis(8-quinolinolato)zinc(II) (abbreviation: Znq), and a metal complex having an oxazole ring or a thiazole ring, such as bis[2-(2-benzoxazolyl)phenolato]zinc(II) (abbreviation: ZnPBO) or bis[2-(2-benzothiazolyl)phenolato]zinc(II) (abbreviation: ZnBTZ).

A high-molecular compound such as poly(2,5-pyridinediyl) (abbreviation: PPy), poly[(9,9-dihexylfluorene-2,7-diyl)-co-(pyridine-3,5-diyl)](abbreviation: PF-Py), or poly[(9,9-dioctylfluorene-2,7-diyl)-co-(2,2′-bipyridine-6,6′-diyl)](abbreviation: PF-BPy) can be used as the electron-transport material.

The electron-transport layer is not limited to a single layer and may have a stacked-layer structure of two or more layers each containing any of the above substances.

### <<Structure of Electron-Injection Layer>>

As the electron-injection layer 115, a layer that includes an alkali metal, an alkaline earth metal, or a rare earth metal or a compound or a complex thereof, such as lithium fluoride (LiF), cesium fluoride (CsF), calcium fluoride (CaF2), 8-quinolinolato-lithium (abbreviation: Liq), or ytterbium (Yb), may be provided. An electride or a layer that is formed using a substance having an electron-transport property and includes an alkali metal, an alkaline earth metal, or a compound thereof can be used as the electron-injection layer 115. Examples of the electride include a substance in which electrons are added at high concentration to calcium oxide-aluminum oxide.

Note that as the electron-injection layer 115, it is possible to use a layer including a substance having an electron-transport property (preferably an organic compound having a bipyridine skeleton) that contains a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device including the layer can have favorable external quantum efficiency.

The organic compound of one embodiment of the present invention described in Embodiment 1 can be used for the electron-injection layer 115. The electron-injection layer 115 may contain a substance having an electron-transport property in addition to the organic compound of one embodiment of the present invention described in Embodiment 1.

### <<Structure of Second Electrode>>

The second electrode 102 is an electrode including a cathode. The second electrode 102 may have a stacked-layer structure, in which case a layer in contact with the organic compound layer 103 functions as a cathode. For the cathode, a metal, an alloy, an electrically conductive compound, or a mixture thereof each having a low work function (specifically, lower than or equal to 3.8 eV) can be used, for example. Specific examples of such a cathode material include elements belonging to Group 1 and Group 2 of the periodic table, such as alkali metals (e.g., lithium (Li) or cesium (Cs)), magnesium (Mg), calcium (Ca), and strontium (Sr), alloys containing any of these elements (e.g., MgAg and AILi), rare earth metals such as europium (Eu) and ytterbium (Yb), and alloys containing any of these rare earth metals. However, when the electron-injection layer is provided between the second electrode 102 and the electron-transport layer, any of a variety of conductive materials such as Al, Ag, ITO, or indium oxide-tin oxide containing silicon or silicon oxide can be used for the cathode regardless of the work function.

When the second electrode 102 is formed using a material that transmits visible light, the light-emitting device can emit light from the second electrode 102 side.

Films of these conductive materials can be formed by a dry process such as a vacuum evaporation method or a sputtering method, an inkjet method, a spin coating method, or the like. Alternatively, a wet process using a sol-gel method or a wet process using a paste of a metal material may be employed.

The organic compound layer 103 can be formed by any of a variety of methods, including a dry process and a wet process. For example, a vacuum evaporation method, a gravure printing method, an offset printing method, a screen printing method, an inkjet method, a spin coating method, or the like may be employed.

Different film formation methods may be used to form the electrodes or the layers described above.

This embodiment can be combined as appropriate with any of the other embodiments or examples. In this specification, in the case where a plurality of structure examples are shown in one embodiment, the structure examples can be combined as appropriate.

### Embodiment 3

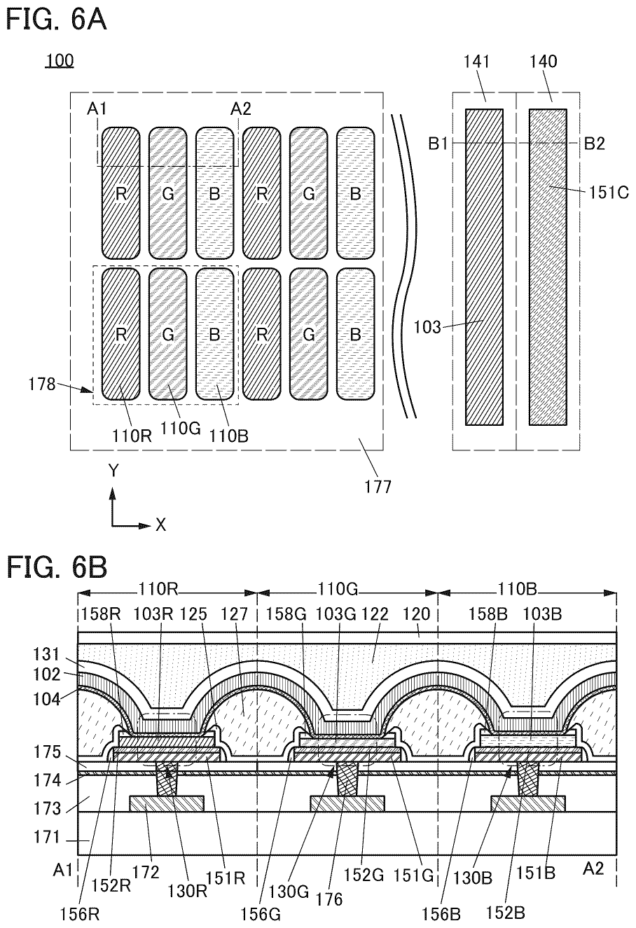

As illustrated in FIGS. 6A and 6B, a plurality of the light-emitting devices 130 are formed over the insulating layer 175 to constitute a display device. In this embodiment, the display device of one embodiment of the present invention will be described in detail.

A display device 100 includes a pixel portion 177 in which a plurality of pixels 178 are arranged in matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 11 OG emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared (IR) light.

In this specification and the like, the row direction and the column direction are sometimes referred to as the X direction and the Y direction, respectively. The X direction and the Y direction intersect with each other and, for example, intersect with each other at right angles.

FIG. 6A illustrates an example in which subpixels of different colors are arranged in the X direction and subpixels of the same color are arranged in the Y direction. Note that subpixels of different colors may be arranged in the Y direction, and subpixels of the same color may be arranged in the X direction.

A connection portion 140 and a region 141 may be provided outside the pixel portion 177, and the region 141 is provided between the pixel portion 177 and the connection portion 140. The organic compound layer 103 is provided in the region 141. A conductive layer 151C is provided in the connection portion 140.

Although FIG. 6A illustrates an example in which the region 141 and the connection portion 140 are located on the right side of the pixel portion 177, there is no particular limitation on the positions of the region 141 and the connection portion 140. The number of regions 141 and the number of connection portions 140 can each be one or more.

FIG. 6B is a cross-sectional view along the dashed-dotted line A1-A2 in FIG. 6A. As illustrated in FIG. 6B, the display device 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is attached to the protective layer 131 with a resin layer 122. An inorganic insulating layer 125 and an insulating layer 127 over the inorganic insulating layer 125 are preferably provided between the adjacent light-emitting devices 130.

Although a plurality of the inorganic insulating layers 125 and the insulating layers 127 are seen in the cross-sectional view in FIG. 6B, each of the inorganic insulating layer 125 and the insulating layer 127 is preferably one continuous layer when the display device 100 is seen from above. In other words, each of the inorganic insulating layer 125 and the insulating layer 127 preferably includes an opening portion over first electrode.

In FIG. 6B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, 130G, or 130B may emit visible light of another color or infrared light.

The display device of one embodiment of the present invention can be, for example, a top-emission display device where light is emitted in the direction opposite to a substrate over which light-emitting devices are formed. Note that the display device of one embodiment of the present invention may be of a bottom-emission type.

Examples of a light-emitting substance included in the light-emitting device 130 include organic compounds or organometallic complexes such as a substance emitting fluorescent light (a fluorescent material), a substance emitting phosphorescent light (a phosphorescent material), and a substance exhibiting thermally activated delayed fluorescence (a thermally activated delayed fluorescent (TADF) material). Other examples include inorganic compounds such as a quantum dot material.

The light-emitting device 130R has a structure as described in Embodiment 1. The light-emitting device 130R includes the first electrode (pixel electrode) including a conductive layer 151R and a conductive layer 152R, an organic compound layer 103R over the first electrode, a common layer 104 over the organic compound layer 103R, and a second electrode (common electrode) 102 over the common layer 104. Although the common layer 104 is not necessarily provided, it is preferable to provide the common layer 104 to reduce damage to the organic compound layer 103R during processing. In the case where the common layer 104 is provided, the common layer 104 is preferably an electron-injection layer. Furthermore, in the case where the common layer 104 is provided, the stacked-layer structure of the organic compound layer 103R and the common layer 104 corresponds to the organic compound layer 103 described in Embodiment 2.

The light-emitting device 130G has a structure as described in Embodiment 1. The light-emitting device 130G includes the first electrode (pixel electrode) including a conductive layer 151G and a conductive layer 152G, an organic compound layer 103G over the first electrode, the common layer 104 over the organic compound layer 103G, and the second electrode (common electrode) 102 over the common layer 104. Although the common layer 104 is not necessarily provided, it is preferable to provide the common layer 104 to reduce damage to the organic compound layer 1030 during processing. In the case where the common layer 104 is provided, the common layer 104 is preferably an electron-injection layer. Furthermore, in the case where the common layer 104 is provided, the stacked-layer structure of the organic compound layer 1030 and the common layer 104 corresponds to the organic compound layer 103 described in Embodiment 2.

The light-emitting device 130B has a structure as described in Embodiment 1. The light-emitting device 130B includes the first electrode (pixel electrode) including a conductive layer 151B and a conductive layer 152B, an organic compound layer 103B over the first electrode, the common layer 104 over the organic compound layer 103B, and the second electrode (common electrode) 102 over the common layer 104. Although the common layer 104 is not necessarily provided, it is preferable to provide the common layer 104 to reduce damage to the organic compound layer 103B during processing. In the case where the common layer 104 is provided, the common layer 104 is preferably an electron-injection layer. Furthermore, in the case where the common layer 104 is provided, the stacked-layer structure of the organic compound layer 103B and the common layer 104 corresponds to the organic compound layer 103 described in Embodiment 2.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, the organic compound layers 103G, and the organic compound layers 103B are island-shaped layers that are separate on a subpixel-by-subpixel basis or on an emission color-by-emission color basis. Providing the island-shaped organic compound layer 103 in each of the light-emitting devices 130 can inhibit leakage current between the adjacent light-emitting devices 130 even in a high-resolution display device. This can prevent crosstalk, so that a display device with extremely high contrast can be obtained. Specifically, a display device having high current efficiency at low luminance can be obtained.

The island-shaped organic compound layer 103 is formed by forming an EL film and processing the EL film by a lithography method.

In the display device of one embodiment of the present invention, the first electrode (pixel electrode) of the light-emitting device preferably has a stacked-layer structure. For example, in the example illustrated in FIG. 6B, the first electrode of the light-emitting device 130 has a stacked-layer structure of the conductive layer 151 (the conductive layer 151R, the conductive layer 151G, and the conductive layer 151B) and the conductive layer 152 (the conductive layer 152R, the conductive layer 152G, and the conductive layer 152B). In the case where the display device 100 is of a top-emission type and the pixel electrode of the light-emitting device 130 functions as the anode, for example, the conductive layer 151 preferably has high visible light reflectance, and the conductive layer 152 preferably has a visible-light-transmitting property and a high work function. In the case where the display device 100 is of a top-emission type, the higher the visible light reflectance of the pixel electrode is, the higher the efficiency of extraction of the light emitted by the organic compound layer 103 is. In the case where the pixel electrode functions as the anode, the higher the work function of the pixel electrode is, the easier hole injection into the organic compound layer 103 is. Accordingly, when the pixel electrode of the light-emitting device 130 has a stacked-layer structure of the conductive layer 151 with high visible light reflectance and the conductive layer 152 with a high work function, the light-emitting device 130 can have high light extraction efficiency and a low driving voltage.

In the case where the conductive layer 151 has high visible light reflectance, the visible light reflectance of the conductive layer 151 is higher than or equal to 40% and lower than or equal to 100%, preferably higher than or equal to 70% and lower than or equal to 100%, for example. When used as an electrode having a visible-light-transmitting property, the conductive layer 152 preferably has a visible light transmittance higher than or equal to 40%, for example.

Here, such a pixel electrode being a stack composed of a plurality of layers sometimes changes in quality as a result of, for example, a reaction between the plurality of layers. For example, when a film formed after the formation of the pixel electrode is removed by a wet etching method, contact of a chemical solution with the pixel electrode might cause galvanic corrosion.

Thus, in the display device 100 of this embodiment, the insulating layer 156 is formed on the side surfaces of the conductive layers 151 and 152. This can inhibit a chemical solution from coming into contact with the conductive layer 151 when a film that is formed after formation of the pixel electrode including the conductive layer 151 and the conductive layer 152 is removed by a wet etching method, for example. Accordingly, occurrence of galvanic corrosion in the pixel electrode can be inhibited, for example. This allows the display device 100 to be manufactured by a high-yield method and to be accordingly inexpensive. In addition, generation of a defect in the display device 100 can be inhibited, which makes the display device 100 highly reliable.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV,

The conductive layers 151 and 152 may each have a stacked-layer structure of a plurality of layers that include different materials. In this case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 has a stacked-layer structure of two or more layers, for example, a layer in contact with the conductive layer 152 can be formed using a material that can be used for the conductive layer 152.

Note that the end portion of the insulating layer 156 may have a tapered shape. Specifically, when the end portion of the insulating layer 156 has a tapered shape with a taper angle less than 90°, a component with higher coverage can be provided along the side surface of the insulating layer 156.

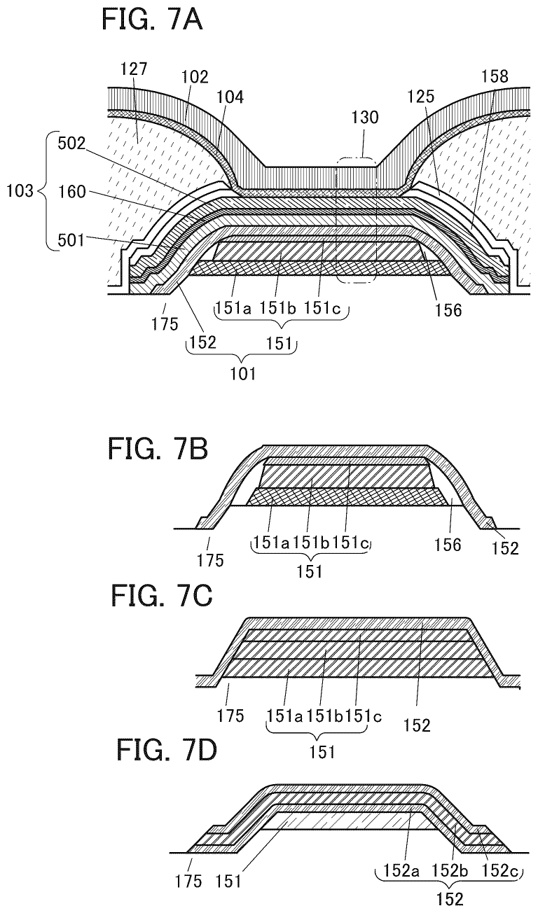

FIG. 7A illustrates the cases where the conductive layer 151 has a stacked-layer structure of a plurality of layers that include different materials. As illustrated in FIG. 7A, the conductive layer 151 includes a conductive layer 151a, a conductive layer 151b over the conductive layer 151a, and a conductive layer 151c over the conductive layer 151b. In other words, the conductive layer 151 illustrated in FIG. 7A has a three-layer-stacked structure. In the case where the conductive layer 151 has a stacked-layer structure of a plurality of layers as described above, the visible light reflectance of at least one of the layers included in the conductive layer 151 is made higher than that of the conductive layer 152.

In the example illustrated in FIG. 7A, the conductive layer 151b is sandwiched between the conductive layers 151a and 151c. A material that is less likely to change in quality than the material for the conductive layer 151b is preferably used for the conductive layers 151a and 151c. The conductive layer 151a can be formed using, for example, a material that is less likely to migrate owing to contact with the insulating layer 175 than the material for the conductive layer 151b. The conductive layer 151c can be formed using a material an oxide of which has lower electrical resistivity than an oxide of the material for the conductive layer 151b and which is less likely to be oxidized than the material for the conductive layer 151b.

In this manner, the structure where the conductive layer 151b is sandwiched between the conductive layers 151a and 151c can expand the range of choices for the material for the conductive layer 151b. The conductive layer 151b, for example, can thus have higher visible light reflectance than at least one of the conductive layers 151a and 151c. For example, aluminum can be used for the conductive layer 151b. The conductive layer 151b may be formed using an alloy containing aluminum. The conductive layer 151a can be formed using titanium; titanium has lower visible light reflectance than aluminum but is less likely to migrate owing to contact with the insulating layer 175 than aluminum. Furthermore, the conductive layer 151c can be formed using titanium; titanium is less likely to be oxidized than aluminum and an oxide of titanium has lower electrical resistivity than aluminum oxide, although titanium has lower visible light reflectance than aluminum.

The conductive layer 151c may be formed using silver or an alloy containing silver. Silver has a feature of higher visible light reflectance than titanium. In addition, silver has a feature of being less likely to be oxidized than aluminum, and silver oxide has a feature of lower electrical resistivity than aluminum oxide. Thus, the conductive layer 151c formed using silver or an alloy containing silver can favorably increase the visible light reflectance of the conductive layer 151 and inhibit an increase in the electrical resistance of the pixel electrode due to oxidation of the conductive layer 151b. Here, as the alloy containing silver, an alloy of silver, palladium, and copper (also referred to as Ag—Pd—Cu or APC) can be used, for example. When the conductive layer 151c is formed using silver or an alloy containing silver and the conductive layer 151b is formed using aluminum, the visible light reflectance of the conductive layer 151c can be higher than that of the conductive layer 151b. Here, the conductive layer 151b may be formed using silver or an alloy containing silver. The conductive layer 151a may be formed using silver or an alloy containing silver.

Meanwhile, a film formed using titanium has better processability in etching than a film formed using silver. Thus, use of titanium for the conductive layer 151c can facilitate formation of the conductive layer 151c. Note that a film formed using aluminum also has better processability in etching than a film formed using silver,

The conductive layer 151 having a stacked-layer structure of a plurality of layers as described above can improve the characteristics of the display device. For example, the display device 100 can have high light extraction efficiency and high reliability.

In the case where the light-emitting device 130 has a microcavity structure, use of silver or an alloy containing silver, i.e., a material with high visible light reflectance, for the conductive layer 151c can favorably increase the light extraction efficiency of the display device 100.

As already described above, the conductive layer 151 preferably has a side surface with a tapered shape. Specifically, the side surface of the conductive layer 151 preferably has a tapered shape with a taper angle less than 90°. For example, in the conductive layer 151 illustrated in FIG. 7A, the side surface of at least one of the conductive layers 151a, 151b, and 151c preferably has a tapered shape.

The conductive layer 151 illustrated in FIG. 7A can be formed by a lithography method. Specifically, first, a conductive film to be the conductive layer 151a, a conductive film to be the conductive layer 151b, and a conductive film to be the conductive layer 151c are sequentially formed. Next, a resist mask is formed over the conductive film to be the conductive layer 151c. Then, the conductive film in the region not overlapping with the resist mask is removed e.g., by etching. Here, the side surface of the conductive layer 151 can have a tapered shape by processing the conductive film under conditions where the resist mask is easily recessed (reduced in size) as compared to the case where the conductive layer 151 is formed such that the side surface does not have a tapered shape, i.e., the conductive layer 151 is formed to have a perpendicular side surface.

Here, when the conductive film is processed under conditions where the resist mask is easily recessed (reduced in size), the conductive film may be easily processed in the horizontal direction, That is, the etching sometimes may become isotropic as compared to the case where the conductive layer 151 is formed to have a perpendicular side surface.

In the case where the conductive layer 151 has a stacked-layer structure of a plurality of layers formed of different materials, the plurality of layers sometimes differ in processability in the horizontal direction. For example, the conductive layers 151a, 151b, and 151c sometimes differ in processability in the horizontal direction.

In that case, after the processing of the conductive film, as illustrated in FIG. 7A, the side surface of the conductive layer 151b may be positioned inward from the side surfaces of the conductive layers 151a and 151c and a protruding portion may be formed. This may impair coverage of the conductive layer 151 with the conductive layer 152 and cause step disconnection of the conductive layer 152.

In view of this, an insulating layer 156 is preferably provided as illustrated in FIG. 7A. FIG. 7A illustrates an example in which the insulating layer 156 is provided over the conductive layer 151a to have a region overlapping with the side surface of the conductive layer 151b. In this structure, occurrence of step disconnection or thinning of the conductive layer 152 due to the protruding portion can be inhibited, so that poor connection or an increase in driving voltage can be inhibited.

Although FIG. 7A illustrates the structure where the side surface of the conductive layer 151b is entirely covered with the insulating layer 156, part of the side surface of the conductive layer 151b is not necessarily covered with the insulating layer 156. Also in a pixel electrode with a later-described structure, part of the side surface of the conductive layer 151b is not necessarily covered with the insulating layer 156.

In the case where the conductive layer 151 has the structure illustrated in FIG. 7A, the conductive layer 152 is provided to cover the conductive layers 151a, 151b, and 151c and the insulating layer 156 and to be electrically connected to the conductive layers 151a, 151b, and 151c. This can prevent a chemical solution from coming into contact with the conductive layers 151a, 151b, and 151c when a film formed after formation of the conductive layer 152 is removed by a wet etching method, for example. It is thus possible to inhibit occurrence of corrosion in all of the conductive layers 151a, 151b, and 151c. Hence, the display device 100 can be fabricated by a high-yield method. Moreover, the display device 100 can have high reliability since generation of defects is inhibited therein.

Here, the insulating layer 156 preferably has a curved surface as illustrated in FIG. 7A. In that case, step disconnection in the conductive layer 152 covering the insulating layer 156 is less likely to occur than in the case where the insulating layer 156 has a perpendicular side surface (a side surface parallel to the Z direction), for example. In addition, step disconnection in the conductive layer 152 covering the insulating layer 156 is less likely to occur also in the case where the side surface of the insulating layer 156 has a tapered shape, or specifically, a tapered shape with a taper angle less than 90°, than in the case where the insulating layer 156 has a perpendicular side surface, for example. As described above, the display device 100 can be fabricated by a high-yield method. Moreover, the display device 100 can have high reliability since generation of defects is inhibited therein.

FIG. 7A illustrates the structure where the side surface of the conductive layer 151b is located inward from those of the conductive layers 151a and 151c; however, one embodiment of the present invention is not limited to this structure. For example, the side surface of the conductive layer 151b may be located outward from that of the conductive layer 151a. The side surface of the conductive layer 151b may be located outward from that of the conductive layer 151c.

FIGS. 7B to 7D illustrate other structures of the first electrode 101. FIG. 7B illustrates another structure example of the first electrode 101 in FIG. 7A, in which the insulating layer 156 covers the side surfaces of the conductive layers 151a, 151b, and 151c instead of covering only the side surface of the conductive layer 151b.

FIG. π illustrates another structure example of the first electrode 101 in FIG. 7A, in which the insulating layer 156 is not provided.

FIG. 7D illustrates another structure example of the first electrode 101 in FIG. 7A, in which the conductive layer 151 does not have a stacked-layer structure but the conductive layer 152 has a stacked-layer structure.

A conductive layer 152a has higher adhesion to a conductive layer 152b than the insulating layer 175 does, for example. For the conductive layer 152a, an oxide containing one or more selected from indium, tin, zinc, gallium, titanium, aluminum, and silicon, for example, can be used. For example, it is preferable to use a conductive oxide containing one or more of indium oxide, indium tin oxide, indium zinc oxide, zinc oxide, zinc oxide containing gallium, titanium oxide, indium titanium oxide, zinc titanate, aluminum zinc oxide, indium zinc oxide containing gallium, indium zinc oxide containing aluminum, indium tin oxide containing silicon, indium zinc oxide containing silicon, and the like. Accordingly, peeling of the conductive layer 152b can be inhibited. The conductive layer 152b is not in contact with the insulating layer 175.

The conductive layer 152b is a layer whose visible light reflectance (e.g., reflectance with respect to light with a predetermined wavelength longer than or equal to 400 nm and shorter than 750 nm) is higher than those of the conductive layers 151, 152a, and 152c. The visible light reflectance of the conductive layer 152b can be, for example, higher than or equal to 70% and lower than or equal to 100%, and is preferably higher than or equal to 80% and lower than or equal to 100%, further preferably higher than or equal to 90% and lower than or equal to 100%. For the conductive layer 152b, a material having higher visible light reflectance than aluminum can be used, for example. Specifically, for the conductive layer 152b, silver or an alloy containing silver can be used, for example. An example of the alloy containing silver is an alloy of silver, palladium, and copper (APC). In the above manner, the display device 100 can have high light extraction efficiency. Note that a metal other than silver may be used for the conductive layer 152b.

When the conductive layers 151 and 152 serve as the anode, a layer having a high work function is preferably used as the conductive layer 152c. The conductive layer 152c has a higher work function than the conductive layer 152b, for example. For the conductive layer 152c, a material similar to the material usable for the conductive layer 152a can be used, for example. For example, the conductive layers 152a and 152c can be formed using the same kind of material. For example, in the case where indium tin oxide is used for the conductive layer 152a, indium tin oxide can also be used for the conductive layer 152c.

When the conductive layers 151 and 152 serve as the cathode, the conductive layers 151 and 152 are preferably layers having a low work function. For example, the conductive layer 152c has a lower work function than the conductive layer 152b.

The conductive layer 152c is preferably a layer having high visible light transmittance (e.g., transmittance with respect to light with a predetermined wavelength longer than or equal to 400 nm and shorter than 750 nm). For example, the visible light transmittance of the conductive layer 152c is preferably higher than those of the conductive layers 151 and 152b. The visible light transmittance of the conductive layer 152c can be, for example, higher than or equal to 60% and lower than or equal to 100%, and is preferably higher than or equal to 70% and lower than or equal to 100%, further preferably higher than or equal to 80% and lower than or equal to 100%. In that case, the amount of light that is absorbed by the conductive layer 152c after being emitted from the organic compound layer 103 can be reduced. As described above, the conductive layer 152b under the conductive layer 152c can be a layer having high visible light reflectance. Thus, the display device 100 can have high light extraction efficiency.

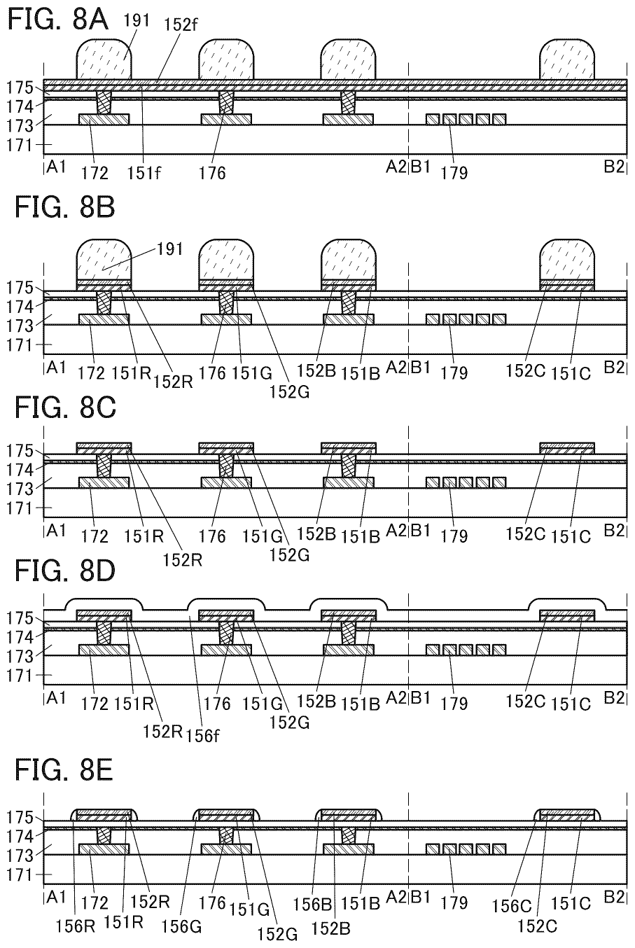

Next, a method for manufacturing the display device 100 having the structure illustrated in FIG. 6A is described with reference to FIGS. 8A to 8E, FIGS. 9A and 9B, FIGS. 10A to 10D, FIGS. 11A to 11C, FIGS. 12A to 12C, and FIGS. 13A to 13C. The organic compound layer of the light-emitting device included in the display device 100 is formed by a manufacturing process including treatment using water. The use of the organic compound of one embodiment of the present invention for the organic compound layer of the light-emitting device included in the display device of one embodiment of the present invention prevents problems such as dissolution of a layer including the organic compound layer and permeation of a chemical solution into a layer including the organic compound layer even in the process by a manufacturing method including treatment using water; consequently, the light-emitting device can have favorable characteristics.

### [Example of Fabrication Method]

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a plasma-enhanced CVD (PECVD) method and a thermal CVD method. An example of a thermal CVD method is a metal organic CVD (MOCVD) method.

Thin films included in the display device (e.g., insulating films, semiconductor films, and conductive films) can also be formed by a wet film-formation method such as spin coating, dipping, spray coating, ink-jetting, dispensing, screen printing, offset printing, doctor blade coating, slit coating, roll coating, curtain coating, or knife coating.

Specifically, for fabrication of the light-emitting device, a vacuum process such as an evaporation method and a solution process such as a spin coating method or an ink-jet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the hole-blocking layer, the light-emitting layer, the electron-blocking layer, the electron-transport layer, and the electron-injection layer) included in the organic compound layer can be formed by an evaporation method (e.g., a vacuum evaporation method), a coating method (e.g., a dip coating method, a die coating method, a bar coating method, a spin coating method, or a spray coating method), a printing method (e.g., ink-jetting, screen printing (stencil), offset printing (planography), flexography (relief printing), gravure printing, or micro-contact printing), or the like.

Thin films included in the display device can be processed by a lithography method, for example, Alternatively, a nanoimprinting method, a sandblasting method, a lift-off method, or the like maybe used to process thin films. Alternatively, island-shaped thin films maybe directly formed by a film formation method using a shielding mask such as a metal mask.

As a lithography method, for example, a photolithography method can be used. Two typical examples of photolithography methods are given. In one of the methods, a resist mask is formed over a thin film that is to be processed, the thin film is processed by etching, for example, and then the resist mask is removed. In the other method, a photosensitive thin film is formed and then processed into a desired shape by light exposure and development.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. It is preferable to use EUV light, X-rays, or an electron beam for extremely minute processing. Note that when exposure is performed by scanning of a beam such as an electron beam, a photomask is not needed.

For etching of thin films, a dry etching method, a wet etching method, a sandblasting method, or the like can be used.

First, as illustrated in FIG. 8A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate having heat resistance high enough to withstand at least heat treatment performed later can be used. When an insulating substrate is used, it is possible to use a glass substrate, a quartz substrate, a sapphire substrate, a ceramic substrate, an organic resin substrate, or the like. Alternatively, it is possible to use a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 8A, openings reaching the conductive layer 172 are formed in the insulating layers 175, 174, and 173. Then, the plugs 176 are formed to fill the openings.

Next, as illustrated in FIG. 8A, a conductive film 151f to be the conductive layers 151R, 151G, 151B, and 151C is formed over the plugs 176 and the insulating layer 175. The conductive film 151f can be formed by a sputtering method or a vacuum evaporation method, for example. A metal material can be used for the conductive film 151f, for example.

Next, as illustrated in FIG. 8A, a conductive film 152f to be the conductive layers 152R, 152G, 152B, and 152C is formed over the conductive film 151f. The conductive film 152f can be formed by a sputtering method or a vacuum evaporation method, for example. A conductive oxide can be used for the conductive film 152f, for example. The conductive film 152f can have a stacked-layer structure of a film formed using a metal material and a film formed thereover using a conductive oxide. For example, the conductive film 152f can have a stacked-layer structure of a film formed using titanium, silver, or an alloy containing silver and a film formed thereover using a conductive oxide.

The conductive film 152f can be formed by an ALD method. In this case, for the conductive film 152f, an oxide containing one or more selected from indium, tin, zinc, gallium, titanium, aluminum, and silicon can be used. In this case, the conductive film 152f can be formed by repeating a cycle of introduction of a precursor (generally referred to as a metal precursor or the like in some cases), purge of the precursor, introduction of an oxidizer (generally referred to as a reactant, a non-metal precursor, or the like in some cases), and purge of the oxidizer. Here, in the case where an oxide film including a plurality of kinds of metals (e.g., an indium tin oxide film) is formed as the conductive film 152f, the composition of the metals can be controlled by varying the number of cycles for different kinds of precursors.

For example, in the case where an indium tin oxide film is formed as the conductive film 152f, after a precursor containing indium is introduced, the precursor is purged, and an oxidizer is introduced to form an In—C film, and then a precursor containing tin is introduced, the precursor is purged, and an oxidizer is introduced to form a Sn—O film. Here, when the number of cycles of forming an In—C film is larger than the number of cycles of forming a Sn—O film, the number of In atoms included in the conductive film 152f can be larger than the number of Sn atoms included therein.

For example, to form a zinc oxide film as the conductive film 152f, a Zn—C film is formed in the above procedure. For another example, to form an aluminum zinc oxide film as the conductive film 152f, a Zn—O film and an Al—C film are formed in the above procedure. For another example, to form a titanium oxide film as the conductive film 152f, a Ti—O film is formed in the above procedure. For another example, to form an indium tin oxide film including silicon as the conductive film 152f, an In—C film, a Sn—O film, and a Si—O film are formed in the above procedure. For another example, to form a zinc oxide film including gallium, a Ga—C film and a Zn—O film are formed in the above procedure.

As a precursor containing indium, it is possible to use, for example, triethylindium, trimethylindium, or [1,1,1-trimethyl-N-(trimethylsilyl)amide]-indium. As a precursor containing tin, it is possible to use, for example, tin chloride or tetrakis(dimethylamido)tin. As a precursor containing zinc, it is possible to use, for example, diethylzinc or dimethylzinc. As a precursor containing gallium, it is possible to use, for example, triethylgallium. As a precursor containing titanium, it is possible to use, for example, titanium chloride, tetrakis(dimethylamido)titanium, or tetraisopropyl titanate. As a precursor containing aluminum, it is possible to use, for example, aluminum chloride or trimethylaluminum. As a precursor containing silicon, it is possible to use, for example, trisilylamine, bis(diethylamino)silane, tris(dimethylamino)silane, bis(tert-butylamino)silane, or bis(ethylmethylamino)silane. As the oxidizer, water vapor, oxygen plasma, or an ozone gas can be used.

Subsequently, a resist mask 191 is formed over the conductive films 151f and 152f as illustrated in FIG. 8A. The resist mask 191 can be formed by application of a photosensitive material (photoresist), light exposure, and development.

Subsequently, as illustrated in FIG. 8B, the conductive films 151f and 152f in a region not overlapping with the resist mask 191, for example, are removed by an etching method, specifically, a dry etching method, for instance, so that a pixel electrode including the conductive layers 151 and 152 is formed. Note that in the case where the conductive film 151f includes a layer formed using a conductive oxide such as indium tin oxide, for example, the layer may be removed by a wet etching method. In this manner, the conductive layers 151 and 152 are formed. In the case where part of the conductive film 151f is removed by a dry etching method, for example, a recessed portion may be formed in a region of the insulating layer 175 not overlapping with the conductive layer 151.

Note that the conductive film 152f may be processed by a lithography method to form the conductive layers 152R, 152G, 152B, and 152C, and then the conductive film 151f may be processed using the conductive layers 152R, 152G, 152B, and 152C as masks. Specifically, after a resist mask is formed, part of the conductive film 152f is removed by an etching method, for example. The conductive film 152f can be removed by a wet etching method, for example. The conductive film 152f may be removed by a dry etching method, After that, the conductive film 151f is preferably removed by a wet etching method.

Here, hydrophobization treatment is preferably performed on the conductive layer 152. The hydrophobization treatment can change the hydrophilic properties of the subject surface to hydrophobic properties or increase the hydrophobic properties of the subject surface. The hydrophobization treatment for the conductive layer 152 can increase the adhesion between the conductive layer 152 and the organic compound layer 103 formed in a later step and inhibit film peeling. Note that the hydrophobization treatment is not necessarily performed.

Next, the resist mask 191 is removed as illustrated in FIG. 8C. The resist mask 191 can be removed by ashing using oxygen plasma, for example. Alternatively, an oxygen gas and any of CF₄, C₄F₈, SF₆, CHF₃, Cl₂, H₂O, BCl₃, and a Group 18 element such as He may be used. Alternatively, the resist mask 191 may be removed by wet etching.

Then, as illustrated in FIG. 8D, an insulating film 156f to be insulating layers 156R, 156G, 156B, and 156C is formed over the conductive layers 151R and 152R, the conductive layers 151G and 152G, the conductive layers 151B and 152B, the conductive layers 151C and 152C, and the insulating layer 175. The insulating film 156f can be formed by a CVD method, an ALD method, a sputtering method, or a vacuum evaporation method, for example.

For the insulating film 156f, an inorganic material can be used. As the insulating film 156f, an inorganic insulating film such as an oxide insulating film, a nitride insulating film, an oxynitride insulating film, or a nitride oxide insulating film can be used, for example. For example, an oxide insulating film including silicon, a nitride insulating film including silicon, an oxynitride insulating film including silicon, a nitride oxide insulating film including silicon, or the like can be used as the insulating film 156f. For the insulating film 156f, silicon oxynitride can be used, for example.

Subsequently, as illustrated in FIG. 8E, the insulating film 156f is processed to form the insulating layers 156R, 156G, 156B, and 156C. The insulating layer 156 can be formed by performing etching substantially uniformly on the top surface of the insulating film 156f, for example. Such uniform etching for planarization is also referred to as etch back treatment. Note that the insulating layer 156 may be formed by a lithography method,

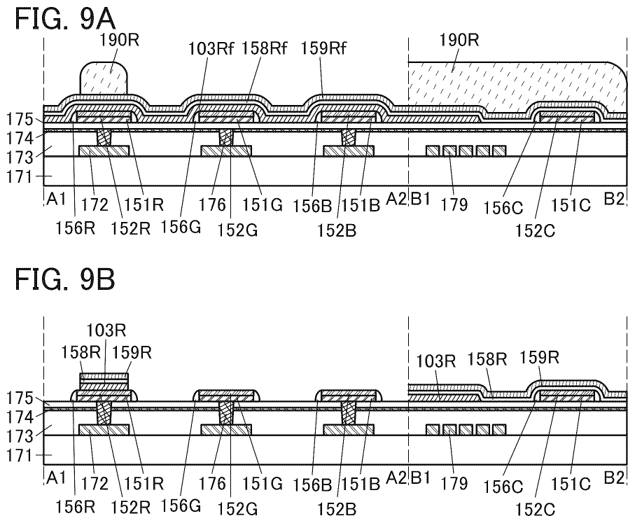

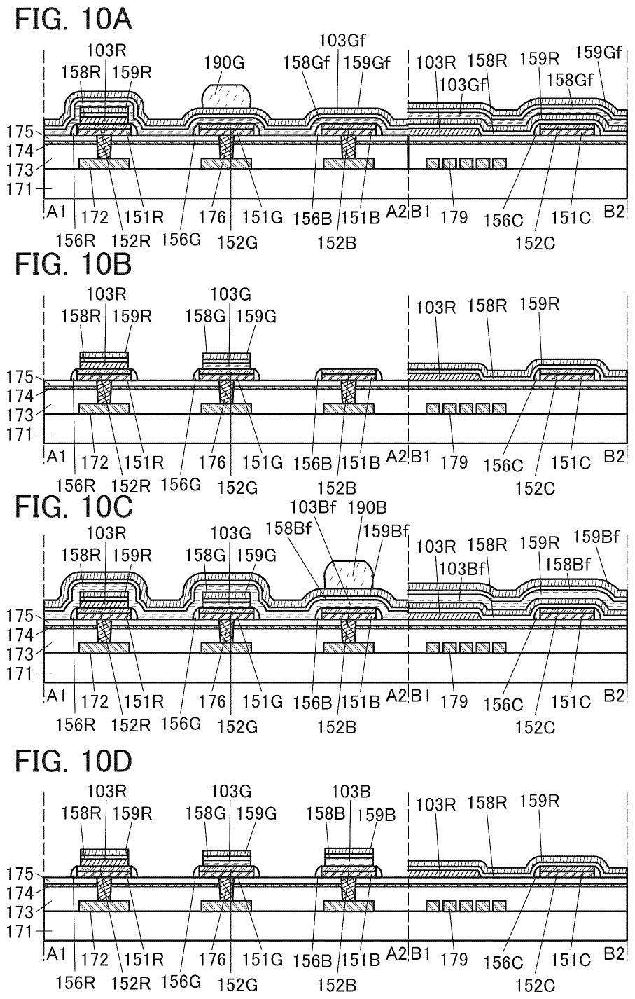

Next, as illustrated in FIG. 9A, an organic compound film 103Rf to be the organic compound layer 103R is formed over the conductive layers 152R, 152G, and 152B, the insulating layers 156R, 156G, and 156B, and the insulating layer 175.

As illustrated in FIG. 9A, the organic compound film 103Rf is not formed over the conductive layer 152C. For example, a mask for defining a film formation area (also referred to as an area mask, a rough metal mask, or the like to be distinguished from a fine metal mask) is used, so that the organic compound film 103Rf can be formed only in a desired region, Employing a film formation step using an area mask and a processing step using a resist mask enables a light-emitting device to be fabricated by a relatively easy process.

The organic compound film 103Rf can be formed by an evaporation method, specifically a vacuum evaporation method, for example. The organic compound film 103Rf may be formed by a transfer method, a printing method, an ink-jet method, a coating method, or the like.

Next, as illustrated in FIG. 9A, a sacrificial film 158Rf to be a sacrificial layer 158R and a mask film 159Rf to be a mask layer 159R are sequentially formed over the organic compound film 103Rf, the conductive layer 152C, and the insulating layer 175.

Although this embodiment shows an example in which a mask film having a two-layer structure of the sacrificial film 158Rf and the mask film 159Rf is formed, the mask film may have a single-layer structure or a stacked-layer structure of three or more layers.

Providing the sacrificial layer over the organic compound film 103Rf can reduce damage to the organic compound film 103Rf in the manufacturing process of the display device, resulting in an increase in reliability of the light-emitting device.

As the sacrificial film 158Rf, a film that is highly resistant to the process conditions for the organic compound film 103Rf, specifically, a film having high etching selectivity with respect to the organic compound film 103Rf is used. For the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each lower than or equal to 200° C., preferably lower than or equal to 150° C., further preferably lower than or equal to 120° C., still further preferably lower than or equal to 100° C., yet still further preferably lower than or equal to 80° C.

The sacrificial film 158Rf and the mask film 159Rf are preferably films that can be removed b_{y} a wet etching method. The use of a wet etching method can reduce damage to the organic compound film 103Rf in processing of the sacrificial film 158Rf and the mask film 159Rf, as compared to the case of using a dry etching method.

The sacrificial film 158Rf and the mask film 159Rf can be formed by a sputtering method, an ALD method (including a thermal ALD method and a PEZALD method), a CVD method, or a vacuum evaporation method, for example. Alternatively, the sacrificial film 158Rf and the mask film 159Rf may be formed by the above-described wet film-formation method.

Note that the sacrificial film 158Rf that is formed over and in contact with the organic compound film 103Rf is preferably formed by a formation method that is less likely to damage the organic compound film 103Rf than a formation method of the mask film 159R_f. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film, for example, can be used.

For each of the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. A metal material that can block ultraviolet rays is preferably used for one or both of the sacrificial film 158Rf and the mask film 159Rf, in which case the organic compound film 103Rf can be inhibited from being irradiated with ultraviolet rays and deteriorating.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon,

In place of gallium described above, an element M (M is one or more of aluminum, silicon, boron, yttrium, copper, vanadium, beryl]ium, titanium, iron, nickel, germanium, zirconium, molybdenum, lanthanum, cerium, neodymium, hafnium, tantalum, tungsten, and magnesium) may be used.

As each of the sacrificial film and the mask film, a film including a material having a light-blocking property, particularly with respect to ultraviolet rays, is preferably used. Although a variety of materials such as a metal, an insulator, a semiconductor, and a metalloid that have a property of blocking ultraviolet rays can be used as a light-blocking material, each of the sacrificial film and the mask film is preferably a film capable of being processed by etching and is particularly preferably a film having good processability because part or the whole of each of the sacrificial film and the mask film is removed in a later step.

The sacrificial film and the mask film are preferably formed using a semiconductor material such as silicon or germanium, for example, for excellent compatibility with a semiconductor manufacturing process. Alternatively, an oxide or a nitride of the semiconductor material can be used. A non-metallic material such as carbon or a compound thereof can be used. A metal such as titanium, tantalum, tungsten, chromium, or aluminum or an alloy containing at least one of these metals can be used. Alternatively, an oxide containing the above-described metal, such as titanium oxide or chromium oxide, or a nitride such as titanium nitride, chromium nitride, or tantalum nitride can be used.

When a film including a material having a property of blocking ultraviolet rays is used as each of the sacrificial film and the mask film, the organic compound layer can be inhibited from being irradiated with ultraviolet rays in a light exposure step, for example. The organic compound layer is inhibited from being damaged by ultraviolet rays, so that the reliability of the light-emitting device can be improved.

Note that the same effect is obtained when a film including a material having a property of blocking ultraviolet rays is used for an after-mentioned inorganic insulating film 125f.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film. For example, an inorganic insulating material such as aluminum oxide, hafnium oxide, or silicon oxide can be used for the sacrificial film 158Rf and the mask film 159Rf, As the sacrificial film 158Rf and the mask film 159Rf, aluminum oxide films can be formed by an ALD method, for example. An ALD method is preferably used, in which case damage to a base (in particular, the organic compound layer) can be reduced.

For example, an inorganic insulating film (e.g., an aluminum oxide film) formed by an ALD method can be used as the sacrificial film 158Rf, and an inorganic film (e.g., an In—Ga—Zn oxide film, an aluminum film, or a tungsten film) formed by a sputtering method can be used as the mask film 159Rf.

Note that the same inorganic insulating film can be used for both the sacrificial film 158Rf and the inorganic insulating layer 125 that is to be formed later. For example, an aluminum oxide film formed by an ALD method can be used for both the sacrificial film 158Rf and the inorganic insulating layer 125. For the sacrificial film 158Rf and the inorganic insulating layer 125, the same film formation conditions may be used or different film formation conditions may be used. For example, when the sacrificial film 158Rf is formed under conditions similar to those of the inorganic insulating layer 125, the sacrificial film 158Rf can be an insulating layer having a high barrier property against at least one of water and oxygen. Meanwhile, since the sacrificial film 158Rf is a layer a large part or the whole of which is to be removed in a later step, it is preferable that the processing of the sacrificial film 158Rf be easy. Therefore, the sacrificial film 158Rf is preferably formed with a substrate temperature lower than that for formation of the inorganic insulating layer 125.

One or both of the sacrificial film 158Rf and the mask film 159Rf may be formed using an organic material. For example, as the organic material, a material that can be dissolved in a solvent chemically stable with respect to at least the uppermost film of the organic compound film 103Rf may be used. Specifically, a material that will be dissolved in water or an alcohol can be suitably used. In fonning a film of such a material, it is preferable to apply the material dissolved in a solvent such as water or an alcohol by a wet film-fornation method and then perform heat treatment for evaporating the solvent. At this time, the heat treatment is preferably performed in a reduced-pressure atmosphere, in which case the solvent can be removed at a low temperature in a short time and thermal damage to the organic compound film 103Rf can be reduced accordingly.

The sacrificial film 158Rf and the mask film 159Rf may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluorine resin like perfluoropolymer.

For example, an organic film (e.g., a PVA film) formed by an evaporation method or any of the above wet film-formation methods can be used as the sacrificial film 158Rf, and an inorganic film (e.g., a silicon nitride film) formed by a sputtering method can be used as the mask film 159Rf.

Subsequently, a resist mask 190R is formed over the mask film 159Rf as illustrated in FIG. 9A. The resist mask 190R can be formed by application of a photosensitive material (photoresist), light exposure, and development.

The resist mask 190R may be formed using either a positive resist material or a negative resist material,

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display device. Note that the resist mask 190R is not necessarily provided over the conductive layer 152C. The resist mask 190R is preferably provided to cover the area from an end portion of the organic compound film 103Rf to an end portion of the conductive layer 152C (the end portion closer to the organic compound film 103Rf), as illustrated in the cross-sectional view along the line B1-B2 in FIG. 9A.

Next, as illustrated in FIG. 9B, part of the mask film 159Rf is removed using the resist mask 190R, so that the mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), so that the sacrificial layer 158R is formed.

Each of the sacrificial film 158Rf and the mask film 159Rf can be processed by a wet etching method or a dry etching method. The sacrificial film 158Rf and the mask film 159Rf are preferably processed by isotropic etching.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a chemical solution containing a mixed solution of any of these acids, for example.

Since the organic compound film 103Rf is not exposed in the processing of the mask film 159Rf, the range of choice for a processing method for the mask film 159Rf is wider than that for the sacrificial film 158Rf. Specifically, even in the case where a gas containing oxygen is used as the etching gas in the processing of the mask film 159Rf, deterioration of the organic compound film 103Rf can be inhibited.

In the case of using a dry etching method to process the sacrificial film 158Rf, deterioration of the organic compound film 103Rf can be inhibited by not using a gas containing oxygen as the etching gas. In the case of using a dry etching method, it is preferable to use a gas containing CF₄, C₄F₈, SF₆, CHF₃, Cl₂, H₂O, BCl₃, or a Group 18 element such as He, for example, as the etching gas.

For example, in the case where an aluminum oxide film formed by an ALD method is used as the sacrificial film 158Rf, part of the sacrificial film 158Rf can be removed by a dry etching method using CH₃ and He or using CHF₃, He, and ClH₄. In the case where an In—Ga—Zn oxide film formed by a sputtering method is used as the mask film 159Rf, part of the mask film 159Rf can be removed by a wet etching method using diluted phosphoric acid. Alternatively, part of the mask film 159Rf may be removed by a dry etching method using CH₄ and Ar. Alternatively, part of the mask film 159Rf can be removed by a wet etching method using diluted phosphoric acid. In the case where a tungsten film formed by a sputtering method is used as the mask film 159Rf, part of the mask film 159Rf can be removed by a dry etching method using SF₆, CF₄, and O₂ or using CF₄, Cl₂, and O₂.

The resist mask 190R can be removed by a method similar to that for the resist mask 191. For example, the resist mask 190R can be removed by ashing using oxygen plasma. Alternatively, an oxygen gas and any of CF₄, C₄F₈, SF₆, CHF₃, Cl₂, H₂O, BCl₃, and a Group 18 element such as He may be used. Alternatively, the resist mask 190R may be removed by wet etching. At this time, the sacrificial film 158Rf is located on the outermost surface, and the organic compound film 103Rf is not exposed; thus, the organic compound film 103Rf can be inhibited from being damaged in the step of removing the resist mask 190R. In addition, the range of choice for the method for removing the resist mask 190R can be widened.

Next, as illustrated in FIG. 9B, the organic compound film 103Rf is processed, so that the organic compound layer 103R is formed. For example, part of the organic compound film 103Rf is removed using the mask layer 159R and the sacrificial layer 158R as a hard mask to form the organic compound layer 103R.

Accordingly, as illustrated in FIG. 9B, the stacked-layer structure of the organic compound layer 103R, the sacrificial layer 158R, and the mask layer 159R remains over the conductive layer 152R. The conductive layers 152G and 152B are exposed.

In the example illustrated in FIG. 9B, an end portion of the organic compound layer 103R is located inward from an end portion of the conductive layer 152R. With this structure, a pixel can be miniaturized, so that a high-resolution display can be formed. Although not illustrated in FIG. 9B, by the above etching treatment, a recessed portion may be formed in the insulating layer 175 in a region not overlapping with the organic compound layer 103R.

As described above, the resist mask 190R is preferably provided to cover the area from the end portion of the organic compound layer 103R to the end portion of the conductive layer 152C (the end portion closer to the organic compound layer 103R) in the cross section along the dashed-dotted line B1-32. In that case, as illustrated in FIG. 9B, the sacrificial layer 158R and the mask layer 159R are provided to cover the area from the end portion of the organic compound layer 103R to the end portion of the conductive layer 152C (the end portion closer to the organic compound layer 103R) in the cross section along the dashed-dotted line B1-B2. Hence, the insulating layer 175 can be inhibited from being exposed in the cross section along the dashed-dotted line B1-B2, for example. This can prevent the insulating layers 175, 174, and 173 from being partly removed by etching and thus prevent the conductive layer 179 from being exposed. Accordingly, the conductive layer 179 can be inhibited from being unintentionally electrically connected to another conductive layer. For example, a short circuit between the conductive layer 179 and a common electrode 155 formed in a later step can be inhibited.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

A gas containing oxygen maybe used as the etching gas. When the etching gas contains oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated in the etching can be inhibited.

In the case of using a dry etching method, it is preferable to use a gas containing at least one of H₂, CF₄, C₄F₈, SF₆, ClH₃, Cl₂, H₂O, BCl₃, and Group 18 elements such as He and Ar as the etching gas, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. For another example, a gas containing CF₄, He, and oxygen can be used as the etching gas. For another example, a gas containing H₂ and Ar and a gas containing oxygen can be used as the etching gas.

As described above, in one embodiment of the present invention, the mask layer 159R is formed in the following manner: the resist mask 190R is formed over the mask film 159Rf and part of the mask film 159Rf is removed using the resist mask 190R. After that, pail of the organic compound film 103Rf is removed using the mask layer 159R as a hard mask, so that the organic compound layer 103R is formed. In other words, the organic compound layer 103R is formed by processing the organic compound film 103Rf by a lithography method. In addition, part of the organic compound film 103Rf may be removed using the resist mask 190R. Then, the resist mask 190R may be removed.

Next, hydrophobization treatment for the conductive layer 152G, for example, is preferably performed. At the time of processing the organic compound film 103Rf, the properties of a surface of the conductive layer 152G change to hydrophilic properties in some cases, for example. The hydrophobization treatment for the conductive layer 152G, for example, can increase the adhesion between the conductive layer 152G and a layer to be formed in a later step (which is the organic compound layer 103G here) and inhibit film peeling. Note that the hydrophobization treatment is not necessarily performed.

Next, as illustrated in FIG. 10A, an organic compound film 103Gf to be the organic compound layer 103G is formed over the conductive layers 152G and 152B, the insulating layers 156R, 156G, and 156B, the mask layer 159R, and the insulating layer 175.

The organic compound film 103Gf can be formed by a method similar to that for forming the organic compound film 103Rf. The organic compound film 103Gf can have a structure similar to that of the organic compound film 103Rf.

Then, as illustrated in FIG. 10A, a sacrificial film 158Gf to be a sacrificial layer 158G and a mask film 159Gf to be a mask layer 159G are sequentially formed over the organic compound film 103Gf and the mask layer 159R. After that, a resist mask 190G is formed. The materials and the formation methods of the sacrificial film 158Gf and the mask film 159Gf are similar to those of the sacrificial film 158Rf and the mask film 159Rf. The material and the formation method of the resist mask 190G are similar to those of the resist mask 190R.

The resist mask 190G is provided at a position overlapping with the conductive layer 152G.

Subsequently, as illustrated in FIG. 10B, part of the mask film 159Gf is removed using the resist mask 190G, so that the mask layer 159G is formed. The mask layer 159G remains over the conductive layer 152G. After that, the resist mask 190G is removed. Then, part of the sacrificial film 158Gf is removed using the mask layer 159G as a mask, so that the sacrificial layer 158G is formed. Next, the organic compound film 103Gf is processed, so that the organic compound layer 103G is formed. For example, part of the organic compound film 103Gf is removed using the mask layer 159G and the sacrificial layer 158G as a hard mask to form the organic compound layer 103G.

Accordingly, as illustrated in FIG. 10B, the stacked-layer structure of the organic compound layer 103G, the sacrificial layer 158G, and the mask layer 159G remains over the conductive layer 152G. The mask layer 159R and the conductive layer 152B are exposed.

Next, hydrophobization treatment for the conductive layer 152B, for example, is preferably performed. At the time of processing the organic compound film 103Gf, the properties of a surface of the conductive layer 152B change to hydrophilic properties in some cases, for example. The hydrophobization treatment for the conductive layer 152B, for example, can increase the adhesion between the conductive layer 152B and a layer to be formed in a later step (which is the organic compound layer 103B here) and inhibit film peeling. Note that the hydrophobization treatment is not necessarily performed.

Next, as illustrated in FIG. 10C, an organic compound film 103Bf to be the organic compound layer 103B is formed over the conductive layer 152B, the mask layer 159R, the insulating layers 156R, 156G, and 156B, the mask layer 159G, and the insulating layer 175.

The organic compound film 103Bf can be formed by a method similar to that for forming the organic compound film 103Rf. The organic compound film 103Bf can have a structure similar to that of the organic compound film 103Rf.

Then, as illustrated in FIG. 10C, a sacrificial film 158Bf to be a sacrificial layer 158B and a mask film 159Bf to be a mask layer 159B are sequentially formed over the organic compound film 103Bf and the mask layer 159R. After that, a resist mask 190B is formed. The materials and the formation methods of the sacrificial film 158Bf and the mask film 159Bf are similar to those of the sacrificial film 158Rf and the mask film 159Rf. The material and the formation method of the resist mask 190B are similar to those of the resist mask 190R.

The resist mask 190B is provided at a position overlapping with the conductive layer 152B.

Subsequently, as illustrated in FIG. 10D, part of the mask film 159Bf is removed using the resist mask 190B, so that the mask layer 159B is formed. The mask layer 159B remains over the conductive layer 152B. After that, the resist mask 190B is removed. Then, part of the sacrificial film 158Bf is removed using the mask layer 159B as a mask, so that the sacrificial layer 158B is formed. Next, the organic compound film 103Bf is processed, so that the organic compound layer 103B is formed. For example, part of the organic compound film 103Bf is removed using the mask layer 159B and the sacrificial layer 158B as a hard mask to form the organic compound layer 103B.

Accordingly, as illustrated in FIG. 10D, the stacked-layer structure of the organic compound layer 103B, the sacrificial layer 158B, and the mask layer 159B remains over the conductive layer 152B. The mask layers 159R and 159G are exposed.

Note that the side surfaces of the organic compound layers 103R, 103G, and 103B are preferably perpendicular or substantially perpendicular to their formation surfaces. For example, the angles between the formation surfaces and these side surfaces are each preferably greater than or equal to 60° and less than or equal to 90°.

The distance between two adjacent layers among the organic compound layers 103R, 103G, and 103B, which are formed by a lithography method as described above, can be shortened to less than or equal to 8 μm, less than or equal to 5 μm, less than or equal to 3 μm, less than or equal to 2 μm, or less than or equal to 1 μm. Here, the distance can be defined, for example, as the distance between opposite end portions of two adjacent layers among the organic compound layers 103R, 103G, and 103B. Shortening the distance between the island-shaped organic compound layers can provide a display device having high resolution and a high aperture ratio. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

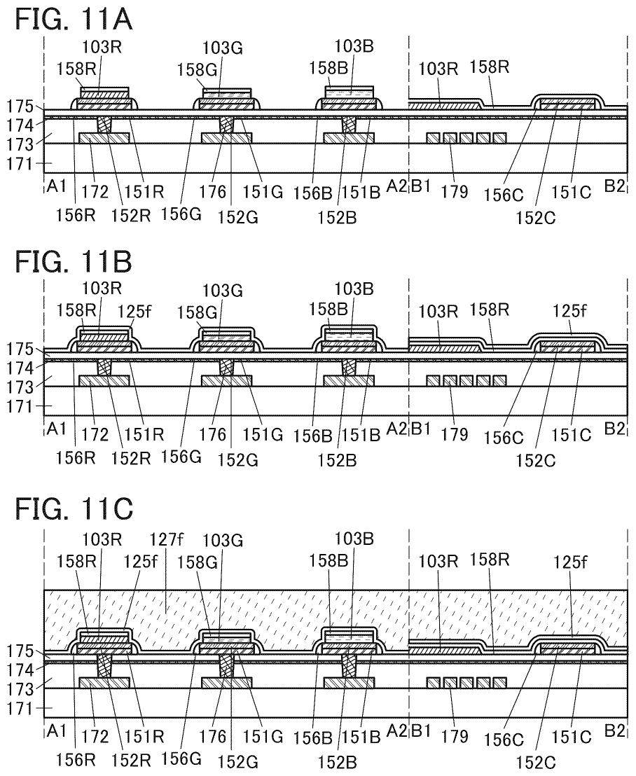

Next, as illustrated in FIG. 11A, the mask layers 159R, 159G, and 159B are preferably removed. The sacrificial layers 158R, 158G, and 158B and the mask layers 159R, 159G, and 159B remain in the display device in some cases depending on the subsequent steps. Removing the mask layers 159R, 159G, and 159B at this stage can inhibit the mask layers 159R, 159G, and 159B from being left in the display device. For example, in the case where a conductive material is used for the mask layers 159R, 159G, and 159B, removing the mask layers 159R, 159G, and 159B in advance can inhibit generation of a leakage current, formation of a capacitor, and the like due to the remaining mask layers 159R, 159G, and 159B.

This embodiment describes an example in which the mask layers 159R, 159G, and 159B are removed; however, the mask layers 159R, 159G, and 159B are not necessarily removed. For example, in the case where the mask layers 159R, 159G, and 159B include the above-described material having a property of blocking ultraviolet rays, the procedure preferably proceeds to the next step without removing the mask layers 159R, 159G, and 159B, in which case the organic compound layers can be protected from ultraviolet rays.

The step of removing the mask layers can be performed by a method similar to that for the step of processing the mask films. Specifically, by using a wet etching method, damage applied to the organic compound layers 103R, 103G, and 103B at the time of removing the mask layers can be reduced as compared to the case of using a dry etching method.

The mask layers may be removed by being dissolved in a solvent such as water or an alcohol. Examples of an alcohol include ethyl alcohol, methyl alcohol, isopropyl alcohol (IPA), and glycerin.

After the mask layers are removed, drying treatment may be performed in order to remove water included in the organic compound layers 103R, 103G, and 103B and water adsorbed onto the surfaces of the organic compound layers 103R, 103G, and 103B. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, as illustrated in FIG. 11B, the inorganic insulating film 125f to be the inorganic insulating layer 125 is formed to cover the organic compound layers 103R, 103G, and 103B and the sacrificial layers 158R, 158G, and 158B.

As described later, an insulating film to be the insulating layer 127 is formed in contact with the top surface of the inorganic insulating film 125f. Therefore, the top surface of the inorganic insulating film 125f preferably has a high affinity for the material used for the insulating film (e.g., a photosensitive resin composition containing an acrylic resin). To improve the affinity, surface treatment is preferably performed so that the top surface of the inorganic insulating film 125f is made hydrophobic (or its hydrophobic property is improved). For example, it is preferable to perform the treatment using a silylation agent such as hexamethyldisilazane (HMDS). By making the top surface of the inorganic insulating film 125f hydrophobic in such a manner, an insulating film 127f can be formed with favorable adhesion. Note that the above-described hydrophobization treatment may be performed as the surface treatment.

Then, as illustrated in FIG. 11C, the insulating film 127f to be the insulating layer 127 is formed over the inorganic insulating film 125f.

The inorganic insulating film 125f and the insulating film 127f are preferably formed by a formation method by which the organic compound layers 103R, 103G, and 103B are less damaged. The inorganic insulating film 125f, which is formed in contact with the side surfaces of the organic compound layers 103R, 103G, and 103B, is particularly preferably formed by a formation method that causes less damage to the organic compound layers 103R, 103G, and 103B than the formation method of the insulating film 127f.

Each of the inorganic insulating film 125f and the insulating film 127f is formed at a temperature lower than the upper temperature limits of the organic compound layers 103R, 103G, and 103B. When the inorganic insulating film 125f is formed at a high substrate temperature, the formed inorganic insulating film 125f, even with a small thickness, can have a low impurity concentration and a high barrier property against at least one of water and oxygen.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.,

As the inorganic insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case damage due to film formation is reduced and a film with good coverage can be formed. As the inorganic insulating film 125f, an aluminum oxide film is preferably formed by an ALD method, for example.

Alternatively, the inorganic insulating film 125f may be formed by a sputtering method, a CVD method, or a PECVD method, each of which has a higher deposition rate than an ALD method. In that case, a highly reliable display device can be manufactured with high productivity.

The insulating film 127f is preferably formed by the aforementioned wet film-formation method. For example, the insulating film 127f is preferably formed by spin coating using a photosensitive material, and specifically, preferably formed using a photosensitive resin composition containing an acrylic resin.

The insulating film 127f is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 127f is formed. The heat treatment is performed at a temperature lower than the upper temperature limits of the organic compound layers 103R, 103G, and 103B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, the solvent included in the insulating film 127f can be removed.

Then, part of the insulating film 127f is exposed to visible light or ultraviolet rays. Here, when a positive photosensitive resin composition containing an acrylic resin is used for the insulating film 127f, a region where the insulating layer 127 is not formed in a later step is irradiated with visible light or ultraviolet rays. The insulating layer 127 is formed in regions that are sandwiched between any two of the conductive layers 152R, 152G, and 152B and around the conductive layer 152C. Thus, the top surfaces of the conductive layers 152R, 152G, 152B, and 152C are irradiated with visible light or ultraviolet rays. Note that when a negative photosensitive material is used for the insulating film 127f, the region where the insulating layer 127 is to be formed is irradiated with visible light or ultraviolet rays.

The width of the insulating layer 127 that is to be formed later can be controlled with the exposed region of the insulating film 127f. In this embodiment, processing is performed such that the insulating layer 127 includes a portion overlapping with the top surface of the conductive layer 151.

The light used for the exposure preferably includes the i-line (wavelength: 365 nm). Furthermore, the light used for the exposure may include at least one of the g-line (wavelength: 436 nm) and the h-line (wavelength: 405 nm).

Here, when a barrier insulating layer against oxygen (e.g., an aluminum oxide film) is provided as one or both of the sacrificial layer 158 (the sacrificial layers 158R, 158G, and 158B) and the inorganic insulating film 125f, diffusion of oxygen into the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen may be bonded to the organic compound included in the organic compound layer. By providing the sacrificial layer 158 and the inorganic insulating film 125f over the island-shaped organic compound layer, bonding of oxygen in the atmosphere to the organic compound included in the organic compound layer can be inhibited,

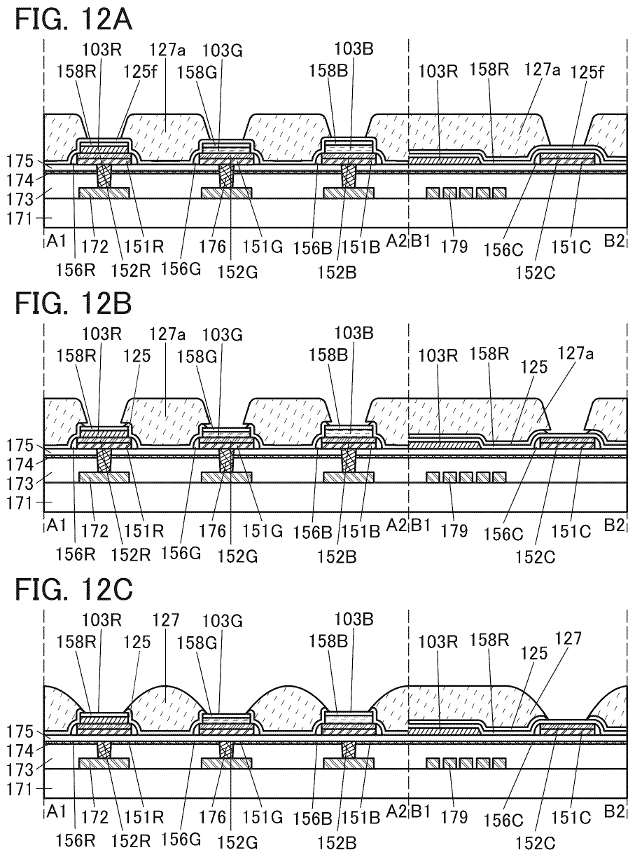

Next, as illustrated in FIG. 12A, development is performed to remove the exposed region of the insulating film 127f, so that an insulating layer 127a is formed. The insulating layer 127a is formed in regions that are sandwiched between any two of the conductive layers 152R, 152G, and 152B and a region surrounding the conductive layer 152C, Here, when an acrylic resin is used for the insulating film 127f, an alkaline solution, such as TMAH, can be used as a developer.

Then, a residue (scum) due to the development may be removed. For example, the residue can be removed by ashing using oxygen plasma.

Etching may be performed to adjust the surface level of the insulating layer 127a. The insulating layer 127a may be processed by ashing using oxygen plasma, for example. In the case where a non-photosensitive material is used for the insulating film 127f, the surface level of the insulating film 127f can be adjusted by the ashing, for example.

Next, as illustrated in FIG. 12B, etching treatment is performed using the insulating layer 127a as a mask to remove part of the inorganic insulating film 125f and reduce the thickness of parts of the sacrificial layers 158R, 158G, and 158B. Thus, the inorganic insulating layer 125 is formed under the insulating layer 127a. Moreover, the surfaces of the thin portions in the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that of the sacrificial layers 158R, 158G, and 158B, in which case the first etching treatment can be performed collectively.

By etching using the insulating layer 127a with a tapered side surface as a mask, the side surface of the inorganic insulating layer 125 and upper end portions of the side surfaces of the sacrificial layers 158R, 158G, and 158B can each be made to have a tapered shape relatively easily.

In the case of performing dry etching, a chlorine-based gas is preferably used. As the chlorine-based gas, one of Cl₂, BC₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCIP) etching apparatus including parallel plate electrodes can be used. The capacitively coupled plasma etching apparatus including parallel plate electrodes may have a structure where a high-frequency voltage is applied to one of the parallel plate electrodes. Alternatively, the capacitively coupled plasma etching apparatus may have a structure where different high-frequency voltages are applied to one of the parallel-plate electrodes. Alternatively, the capacitively coupled plasma etching apparatus may have a structure where high-frequency voltages with the same frequency are applied to the parallel-plate electrodes, Alternatively, the capacitively coupled plasma etching apparatus may have a structure where high-frequency voltages with different frequencies are applied to the parallel-plate electrodes.

In the case of performing dry etching, a by-product or the like generated by the dry etching is sometimes deposited on the top surface and the side surface of the insulating layer 127a, for example. Accordingly, a component of the etching gas, a component of the inorganic insulating film 125f, a component of the sacrificial layers 158R, 158G, and 158B, and the like are included in the insulating layer 127 in the completed display device in some cases.

The first etching treatment is preferably performed by wet etching. The use of a wet etching method can reduce damage to the organic compound layers 103R, 103G, and 103B, as compared to the case of using a dry etching method. For example, the wet etching can be performed using an alkaline solution. For instance, TMAH, which is an alkaline solution, can be used for the wet etching of an aluminum oxide film. In this case, puddle wet etching can be performed. Note that the inorganic insulating film 125f is preferably formed using a material similar to that of the sacrificial layers 158R, 158G, and 158B, in which case the above etching treatment can be performed collectively.

The sacrificial layers 158R, 158G, and 158B are not removed completely by the first etching treatment, and the etching treatment is stopped when the thicknesses of the sacrificial layers 158R, 158G, and 158B are reduced. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, the insulating layer 127a is preferably irradiated with visible light or ultraviolet rays by performing light exposure on the entire substrate. The energy density for the light exposure is preferably greater than 0 mJ/cm² and less than or equal to 800 mJ/cm², further preferably greater than 0 m/cm² and less than or equal to 500 mi/cm². Performing such light exposure after the development can sometimes increase the degree of transparency of the insulating layer 127a. In addition, it is sometimes possible to lower the substrate temperature required for subsequent heat treatment for changing the shape of the insulating layer 127a to a tapered shape.

Here, when a barrier insulating layer against oxygen (e.g., an aluminum oxide film) is provided as each of the sacrificial layers 158R, 158G, and 158B, diffusion of oxygen into the organic compound layers 103R, 103G, and 103B can be inhibited. When the organic compound layer is irradiated with light (visible light or ultraviolet rays), the organic compound included in the organic compound layer is brought into an excited state and a reaction between the organic compound and oxygen in the atmosphere is promoted in some cases. Specifically, when the organic compound layer is irradiated with light (visible light or ultraviolet rays) in an atmosphere containing oxygen, oxygen may be bonded to the organic compound included in the organic compound layer. By providing the sacrificial layers 158R, 158G, and 158B over the island-shaped organic compound layers, bonding of oxygen in the atmosphere to the organic compounds included in the organic compound layers can be inhibited.

Then, heat treatment (also referred to as post-baking) is performed. The heat treatment can change the insulating layer 127a into the insulating layer 127 having a tapered side surface (FIG. 12C). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. The substrate temperature in the heat treatment of this step is preferably higher than that in the heat treatment (prebaking) after the formation of the insulating film 127f. In that case, the adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 1581R, 158G, and 158B are left, the organic compound layers 103R, 103G, and 103B can be prevented from being damaged and deteriorating in the heat treatment. This increases the reliability of the light-emitting devices.

Note that the side surface of the insulating layer 127 may have a concave shape depending on the material of the insulating layer 127 and the temperature, time, and atmosphere of the post-baking. For example, when the temperature of the post-baking is higher or the duration of the post-baking is longer, the insulating layer 127 is more likely to change in shape and thus a concave shape may be more likely to be formed.

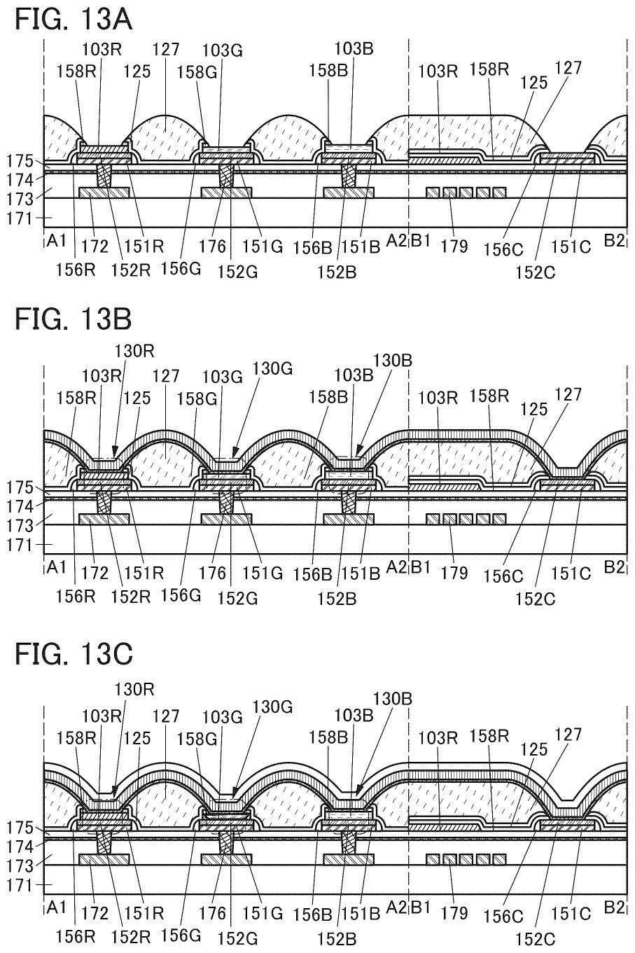

Next, as illustrated in FIG. 13A, etching treatment is performed using the insulating layer 127 as a mask to remove part of the sacrificial layers 158R, 158G, and 158B. Note that part of the inorganic insulating layer 125 is also removed in some cases. Thus, openings are formed in the sacrificial layers 158R, 158G, and 158B, and the top surfaces of the organic compound layers 103R, 103G, and 103B and the conductive layer 152C are exposed. Note that the etching treatment using the insulating layer 127 as a mask may be hereinafter referred to as second etching treatment.

An end portion of the inorganic insulating layer 125 is covered with the insulating layer 127. FIG. 13A illustrates an example in which part of an end portion of the sacrificial layer 158G (specifically a tapered portion formed by the first etching treatment) is covered with the insulating layer 127 and a tapered portion formed by the second etching treatment is exposed.

If the first etching treatment is not performed and the inorganic insulating layer 125 and the mask layer are collectively etched after the post-baking, the inorganic insulating layer 125 and the mask layer under an end portion of the insulating layer 127 may disappear because of side etching and a void may be formed. The void causes unevenness on the formation surface of the common electrode 155, so that step disconnection is more likely to be caused in the common electrode 155. Even when a void is formed owing to side etching of the inorganic insulating layer 125 and the mask layer by the first etching treatment, the post-baking performed subsequently can make the insulating layer 127 fill the void. After that, the thinned mask layer is etched by the second etching treatment; thus, the amount of side etching decreases, a void is less likely to be formed, and even if a void is formed, it can be extremely small. Consequently, the formation surface of the common electrode 155 can be made flatter.

Note that the insulating layer 127 may cover the entire end portion of the sacrificial layer 158G. For example, the end portion of the insulating layer 127 may droop to cover the end portion of the sacrificial layer 158G. For another example, the end portion of the insulating layer 127 may be in contact with the top surface of at least one of the organic compound layers 103R, 103G, and 103B. As described above, when light exposure is not performed on the insulating layer 127a after the development, the shape of the insulating layer 127 may be likely to change.

The second etching treatment is performed by wet etching. The use of a wet etching method can reduce damage to the organic compound layers 103R, 103G, and 103B, as compared to the case of using a dry etching method. The wet etching can be performed using an alkaline solution such as TMAH, for example.

Meanwhile, in the case where the second etching treatment is performed by a wet etching method and there are gaps due to, for example, poor adhesion between the organic compound layer 103 and another layer at the interface between the organic compound layer 103 and the sacrificial layer 158, the interface between the organic compound layer 103 and the inorganic insulating layer 125, and the interface between the organic compound layer 103 and the insulating layer 175, the chemical solution used in the second etching treatment sometimes enters the gaps to come into contact with the pixel electrode. Here, when the chemical solution comes into contact with both the conductive layer 151 and the conductive layer 152, one of the conductive layers 151 and 152 that has a lower spontaneous potential than the other suffers from galvanic corrosion in some cases. For example, when the conductive layer 151 is formed using aluminum and the conductive layer 152 is formed using indium tin oxide, the conductive layer 152 sometimes corrodes. As a result, the yield of the display device decreases in some cases. Moreover, the reliability of the display device decreases in some cases.

When the insulating layer 156 (the insulating layers 156R, 156G, and 156B) is formed to have a region overlapping with the side surface of the conductive layer 151 and the insulating layer 156 is formed to cover the conductive layers 151 and 152 as described above, step disconnection in the inorganic insulating layer 125 can be prevented, whereby the chemical solution can be prevented from coming into contact with a lower-layer structure such as the conductive layer 151 in the second etching treatment, for example. Thus, corrosion of the pixel electrode can be prevented.

As described above, by providing the insulating layer 127, the inorganic insulating layer 125, and the sacrificial layers 158R, 158G, and 158B, poor connection due to a disconnected portion and an increase in electrical resistance due to a locally thinned portion can be inhibited from occurring in the common electrode 155 between the light-emitting devices. Thus, the display device of one embodiment of the present invention can have improved display quality.

Heat treatment is performed after the organic compound layers 103R, 103G, and 103B are partly exposed. By the heat treatment, water included in the organic compound layers and water adsorbed onto the surfaces of the organic compound layers, for example, can be removed. The shape of the insulating layer 127 may be changed by the heat treatment. Specifically, the insulating layer 127 may be widened to cover at least one of the end portion of the inorganic insulating layer 125, the end portions of the sacrificial layers 158R, 158G, and 158B, and the top surfaces of the organic compound layers 103R, 103G, and 103B.

If the temperature of the heat treatment is too low, water included in the organic compound layers and water adsorbed onto the surfaces of the organic compound layers, for example, cannot be sufficiently removed. If the temperature of the heat treatment is too high, the organic compound layer 103 may deteriorate and the insulating layer 127 may change in shape excessively. Therefore, the temperature of the heat treatment is preferably higher than the temperature at which water is released from the organic compound layer 103 and lower than the glass transition temperature of the organic compound included in the organic compound layer 103, further preferably lower than the glass transition temperature of the organic compound included in the upper surface of the organic compound layer 103. Specifically, the substrate temperature is preferably higher than or equal to 80° C. and lower than or equal to 130° C., further preferably higher than or equal to 90° C. and lower than or equal to 120° C., still further preferably higher than or equal to 100° C. and lower than or equal to 120° C., yet still further preferably higher than or equal to 100° C. and lower than or equal to 110° C. The heating atmosphere may be an air atmosphere or an inert gas atmosphere. Although the heating atmosphere may be an atmospheric-pressure atmosphere or a reduced-pressure atmosphere, a reduced-pressure atmosphere is preferably employed to prevent re-adsorption of water released from the organic compound layer 103.

By the heat treatment, water included in the organic compound layers and water adsorbed onto the surfaces of the organic compound layers, for example, can be sufficiently removed without deterioration of the organic compound layers 103R, 103G, and 103B and an excessive change in the shape of the insulating layer 127. Thus, degradation of the characteristics of the light-emitting device can be prevented.

Next, as illustrated in FIG. 13B, the common layer 104 and the common electrode 155 are formed over the organic compound layers 103R, 103G, and 103B, the conductive layer 152C, and the insulating layer 127. The common layer 104 and common electrode 155 can be formed by a sputtering method, a vacuum evaporation method, or the like. The common layer 104 may be formed by an evaporation method while the common electrode 155 may be formed by a sputtering method.

Next, as illustrated in FIG. 13C, the protective layer 131 is formed over the common electrode 155. The protective layer 131 can be formed by a vacuum evaporation method, a sputtering method, a CVD method, an ALD method, or the like.

Then, the substrate 120 is attached to the protective layer 131 using the resin layer 122, so that the display device can be manufactured. As described above, in the method for manufacturing the display device of one embodiment of the present invention, the insulating layer 156 is provided on the side surfaces of the conductive layers 151 and 152. This can increase the yield of the display device and inhibit generation of defects.

As described above, in the method for manufacturing the display device of one embodiment of the present invention, the island-shaped organic compound layers 103R, 103G, and 103B are each formed not by using a fine metal mask but by processing a film formed on the entire surface; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of a leakage current between the subpixels can be inhibited. This can prevent crosstalk, so that a display device with extremely high contrast can be obtained. Moreover, even a display device that includes tandem light-emitting devices formed by a lithography method can have favorable characteristics.

The structure described in this embodiment can be used in combination with any of the structures described in other embodiments as appropriate.

### Embodiment 4

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

### [Display Module]

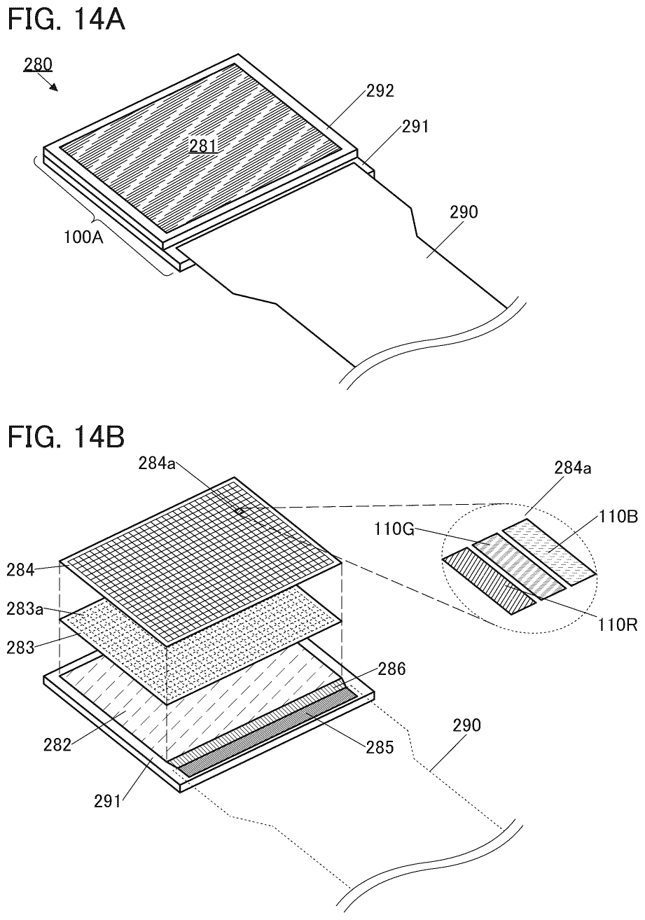

FIG. 14A is a perspective view of a display module 280. The display module 280 includes a display device 100A and an FPC 290.

The display module 280 includes a substrate 291 and a substrate 292. The display module 280 includes a display portion 281. The display portion 281 is an image-displaying region of the display module 280 where light emitted from pixels provided in a pixel portion 284 described later can be seen.

FIG. 14B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is provided in a portion not overlapping with the pixel portion 284 over the substrate 291. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 14B. The pixels 284a can employ any of the structures described in the above embodiments. FIG. 14B illustrates an example in which the pixel 284a has a structure similar to that of the pixel 178 illustrated in FIGS. 6A and 6B.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each of which controls light emission of one light-emitting device. For example, the pixel circuit 283a can include at least one selection transistor, one current control transistor (driving transistor), and a capacitor for one light-emitting device. A gate signal is input to a gate of the selection transistor, and a video signal is input to a source or a drain of the selection transistor. With such a structure, an active-matrix display device is obtained.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An 1C may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have significantly high resolution. For example, the pixels 284a are preferably arranged in the display portion 281 with a resolution higher than or equal to 2000 ppi, further preferably higher than or equal to 3000 ppi, still further preferably higher than or equal to 5000 ppi, yet still further preferably higher than or equal to 6000 ppi, and lower than or equal to 20000 ppi or lower than or equal to 30000 ppi.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display with a high sense of immersion can be provided. Without being limited to such devices, the display module 280 can be suitably used for electronic appliances including a relatively small display portion. For example, the display module 280 can be favorably used in a display portion of a wearable electronic appliance, such as a wrist watch.

### [Display Device 100A]

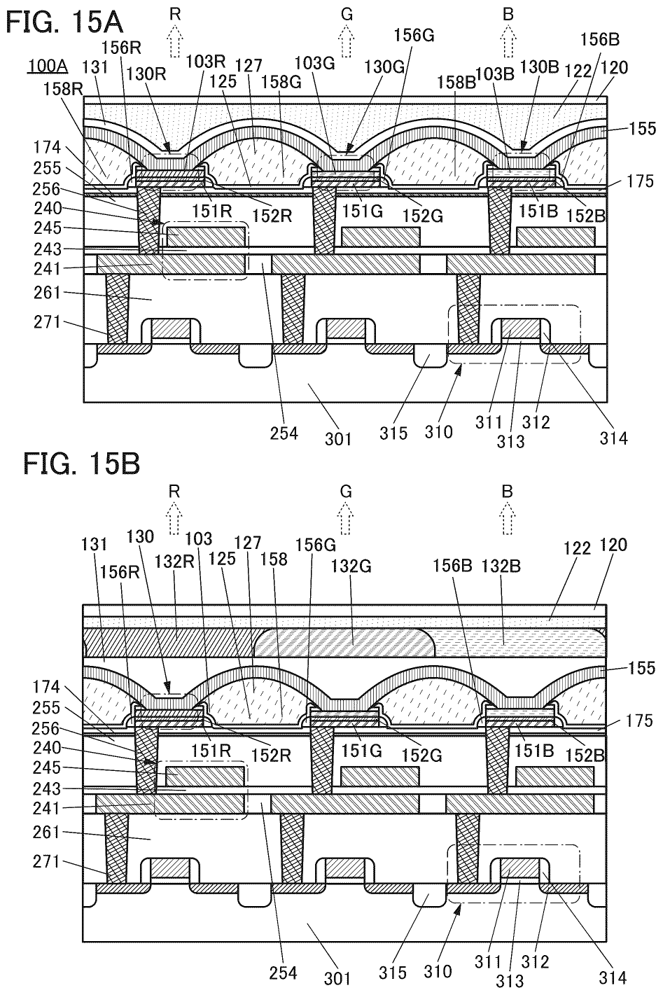

The display device 100A illustrated in FIG. 15A includes a substrate 301, the light-emitting devices 130R, 130G, and 130B, a capacitor 240, and a transistor 310.

The substrate 301 corresponds to the substrate 291 in FIGS. 14A and 14B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is located between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 sandwiched therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. FIG. 15A illustrates an example in which the light-emitting devices 130R, 130G, and 130B each have the stacked-layer structure illustrated in FIG. 9A. An insulator is provided in regions between adjacent light-emitting devices. For example, in FIG. 15A, the inorganic insulating layer 125 and the insulating layer 127 over the inorganic insulating layer 125 are provided in the regions.

The insulating layer 156 is provided on the side surfaces of the conductive layers 151 and 152 included in the light-emitting device 130. The sacrificial layer 158R is located over the organic compound layer 103R of the light-emitting device 130R. The sacrificial layer 158G is located over the organic compound layer 103G of the light-emitting device 130G. The sacrificial layer 158B is located over the organic compound layer 103B of the light-emitting device 130B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. The top surface of the insulating layer 175 and the top surface of the plug 256 are level with or substantially level with each other. Any of a variety of conductive materials can be used for the plugs.

The protective layer 131 is provided over the light-emitting devices 130R, 130G, and 130B. A substrate 120 is attached to the protective layer 131 with a resin layer 122. Embodiment 3 can be referred to for the details of the light-emitting device 130 and the components thereover up to the substrate 120. The substrate 120 corresponds to the substrate 292 in FIG. 14A.

FIG. 15B illustrates a variation example of the display device 100A illustrated in FIG. 15A. The display device illustrated in FIG. 15B includes the coloring layers 132R, 132G, and 132B, and each of the light-emitting devices 130 includes a region overlapping with one of the coloring layers 132R, 132G, and 132B. In the display device illustrated in FIG. 15B, the light-emitting device 130 can emit white light, for example. For example, the coloring layer 132R, the coloring layer 132G, and the coloring layer 132B can transmit red light, green light, and blue light, respectively.

This embodiment can be combined as appropriate with any of the other embodiments or examples. In this specification, in the case where a plurality of structure examples are shown in one embodiment, the structure examples can be combined as appropriate.

### Embodiment 5

In this embodiment, electronic appliances of embodiments of the present invention will be described.

Electronic appliances of this embodiment include the display device of one embodiment of the present invention in their display portions. The display device of one embodiment of the present invention is highly reliable and can be easily increased in resolution and definition. Thus, the display device of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display device of one embodiment of the present invention can have high resolution, and thus can be favorably used for an electronic appliance having a relatively small display portion. Examples of such an electronic appliance include watch-type and bracelet-type information terminal devices (wearable devices) and wearable devices capable of being worn on a head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, definition of 4K, 8K, or higher is preferable. The pixel density (resolution) of the display device of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, yet still further preferably higher than or equal to 3000 ppi, yet still further preferably higher than or equal to 5000 ppi, yet still further preferably higher than or equal to 7000 ppi. With such a display device having high definition and/or high resolution, the electronic appliance can provide higher realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10,

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic appliance in this embodiment can have a variety of functions. For example, the electronic appliance in this embodiment can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

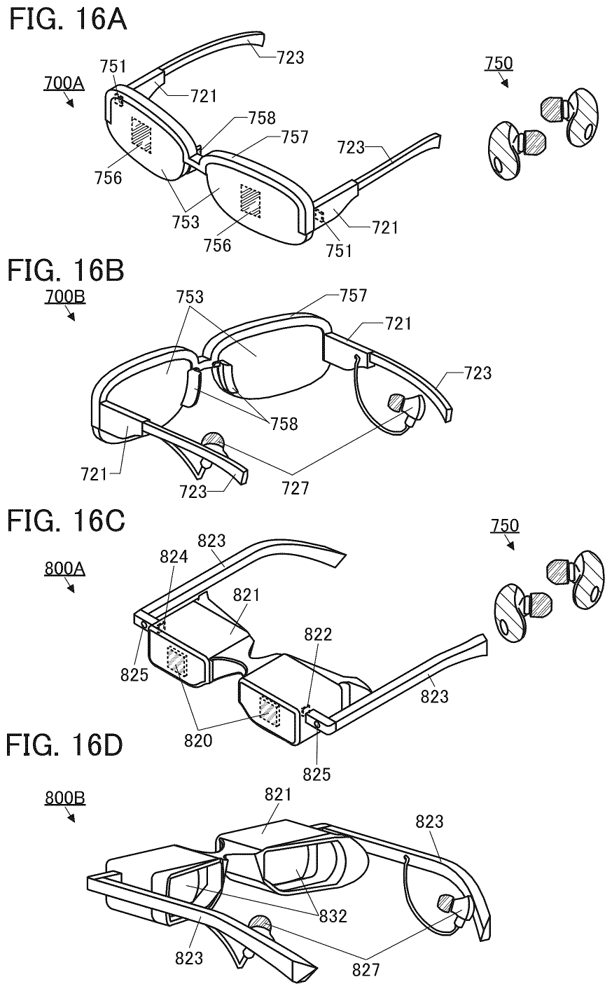

Examples of head-mounted wearable devices are described with reference to FIGS. 16A to 16D. These wearable devices have at least one of a function of displaying AR contents, a function of displaying VR contents, a function of displaying SR contents, and a function of displaying MR contents. The electronic appliance having a function of displaying contents of at least one of AR, VR, SR, MR, and the like enables the user to feel a higher level of immersion.

An electronic appliance 700A illustrated in FIG. 16A and an electronic appliance 700B illustrated in FIG. 16B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for each of the display panels 751. Thus, the electronic appliances can be highly reliable.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliances 700A and 700B are electronic appliances capable of performing AR display.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a moving image can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving element. One or both of an inorganic semiconductor and an organic semiconductor can be used for an active layer of the photoelectric conversion device.

An electronic appliance 800A illustrated in FIG. 16C and an electronic appliance 800B illustrated in FIG. 16D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, the electronic appliances can be highly reliable,

The display portions 820 are located inside the housing 821 so as to be seen through the lenses 832. When the pair of display portions 820 display different images, three-dimensional display using parallax can be performed.

The electronic appliances 800A and 800B can be regarded as electronic appliances for VR. The user who wears the electronic appliance 800A or 800B can see images displayed on the display portions 820 through the lenses 832.

The electronic appliances 800A and 800B preferably include a mechanism for horizontally adjusting the positions of the lenses 832 and the display portions 820 so that the lenses 832 and the display portions 820 are located at positions optimal for the positions of the user's eyes. Moreover, the electronic appliances 800A and 800B preferably include a mechanism for adjusting focus by changing the distance between the lenses 832 and the display portions 820.

The electronic appliance 800A or 800B can be mounted on the user's head with the wearing portions 823. FIG. 16C shows a non-limiting example in which the wearing portion 823 has a shape like a temple of glasses, for instance. The wearing portion 823 may have any shape with which the user can wear the electronic appliance, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example in which the image capturing portions 825 are provided is described here, a range sensor (hereinafter also referred to as a sensing portion) capable of measuring the distance between the user and an object may be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy video and sound only by wearing the electronic appliance 800A.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A in FIG. 16A has a function of transmitting information to the earphones 750 with the wireless communication function. For another example, the electronic appliance 800A in FIG. 16C has a function of transmitting information to the earphones 750 with the wireless communication function.

The electronic appliance may include an earphone portion. The electronic appliance 700B in FIG. 16B includes earphone portions 727. For example, the earphone portion 727 can be connected to the control portion by wire. Part of a wiring that connects the earphone portion 727 and the control portion may be located inside the housing 721 or the wearing portion 723.

Similarly, the electronic appliance 800B in FIG. 16D includes earphone portions 827. For example, the earphone portion 827 can be connected to the control portion 824 by wire. Part of a wiring that connects the earphone portion 827 and the control portion 824 may be located inside the housing 821 or the wearing portion 823. Alternatively, the earphone portions 827 and the wearing portions 823 may include magnets. This structure is preferably employed, in which case the earphone portions 827 can be fixed to the wearing portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

As described above, both the glasses-type device (e.g., the electronic appliances 700A and 700B) and the goggles-type device (e.g., the electronic appliances 800A and 800B) are preferable as the electronic appliance of one embodiment of the present invention.

The electronic appliance of one embodiment of the present invention can transmit information to earphones by wire or wirelessly.

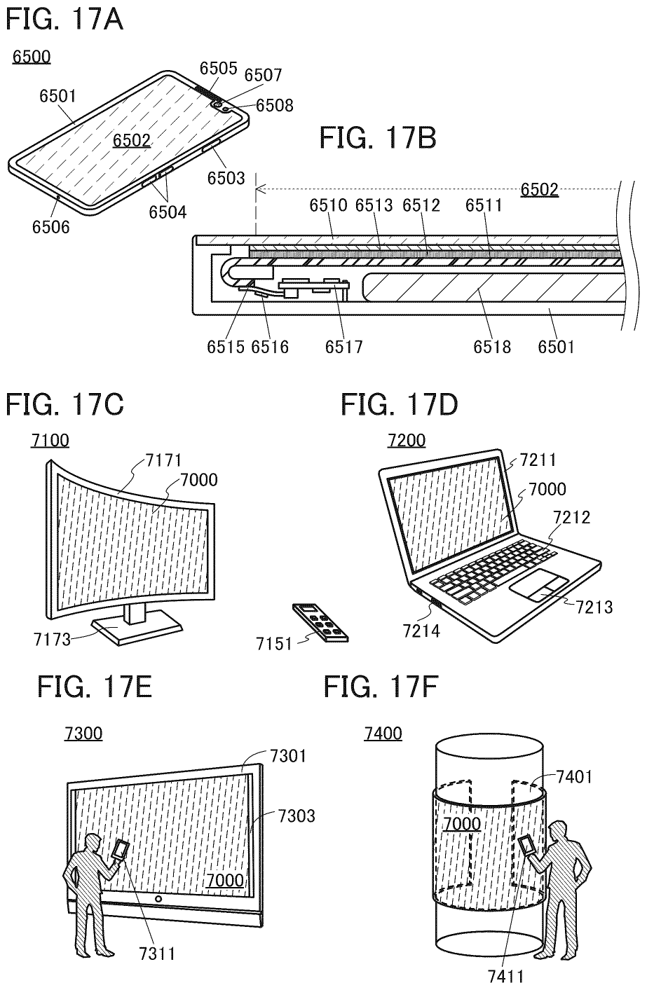

An electronic appliance 6500 illustrated in FIG. 17A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, the electronic appliances can be highly reliable.

FIG. 17B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An 1C 6516 is mounted on the FPC 6515. The FPC 6515 is connected to a terminal provided on the printed circuit board 6517.

A flexible display using the light-emitting device of one embodiment of the present invention can be used as the display panel 6511. Thus, the electronic appliance can be extremely lightweight. Since the display panel 6511 is extremely thin, the battery 6518 with high capacity can be mounted without an increase in the thickness of the electronic appliance. The electronic appliance can have a narrow bezel when part of the display panel 6511 is folded back so that the portion connected to the FPC 6515 is provided on the back side of a pixel portion.

FIG. 1π illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, the electronic appliances can be highly reliable.

Operation of the television device 7100 illustrated in FIG. 1π can be performed with an operation switch provided in the housing 7171 and a separate remote control 7151. Alternatively, the display portion 7000 may include a touch sensor, and the television device 7100 may be operated by touch on the display portion 7000 with a finger or the like. The remote control 7151 may be provided with a display portion for displaying information output from the remote control 7151. With operation keys or a touch panel of the remote control 7151, channels and volume can be controlled and video displayed on the display portion 7000 can be controlled.

Note that the television device 7100 includes a receiver, a modem, and the like. A general television broadcast can be received with the receiver. When the television device is connected to a communication network with or without wires via the modem, one-way (from a transmitter to a receiver) or two-way (e.g., between a transmitter and a receiver or between receivers) information communication can be performed.

FIG. 17D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, the electronic appliances can be highly reliable.

FIGS. 17E and 17F illustrate examples of digital signage.

Digital signage 7300 illustrated in FIG. 17E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 17F shows digital signage 7400 attached to a cylindrical pillar 7401. The digital signage 7400 includes the display portion 7000 provided along a curved surface of the pillar 7401.

In FIGS. 17E and 17F, the display device of one embodiment of the present invention can be used in the display portion 7000. Thus, the electronic appliances can be highly reliable.

A larger area of the display portion 7000 can increase the amount of information that can be provided at a time. The display portion 7000 having a larger area attracts more attention, so that the effectiveness of the advertisement can be increased, for example.

The touch panel is preferably used in the display portion 7000, in which case in addition to display of still or moving images on the display portion 7000, intuitive operation by a user is possible. Moreover, in the case of an application for providing information such as route information or traffic information, usability can be enhanced by intuitive operation.

As illustrated in FIGS. 17E and 17F, the digital signage 7300 or the digital signage 7400 preferably can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, a displayed image on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

This embodiment can be combined as appropriate with any of the other embodiments or examples. In this specification, in the case where a plurality of structure examples are shown in one embodiment, the structure examples can be combined as appropriate.

### Example 1

In this example, a light-emitting device 1A of one embodiment of the present invention and a light-emitting device 1B for comparison (hereinafter, a light-emitting device for comparison is referred to as a comparative light-emitting device) were fabricated by a continuous vacuum process, and the evaluation results of their characteristics are described below.

Structural Formulas of organic compounds used in common for the light-emitting device 1A and the comparative light-emitting device 1B are shown below.

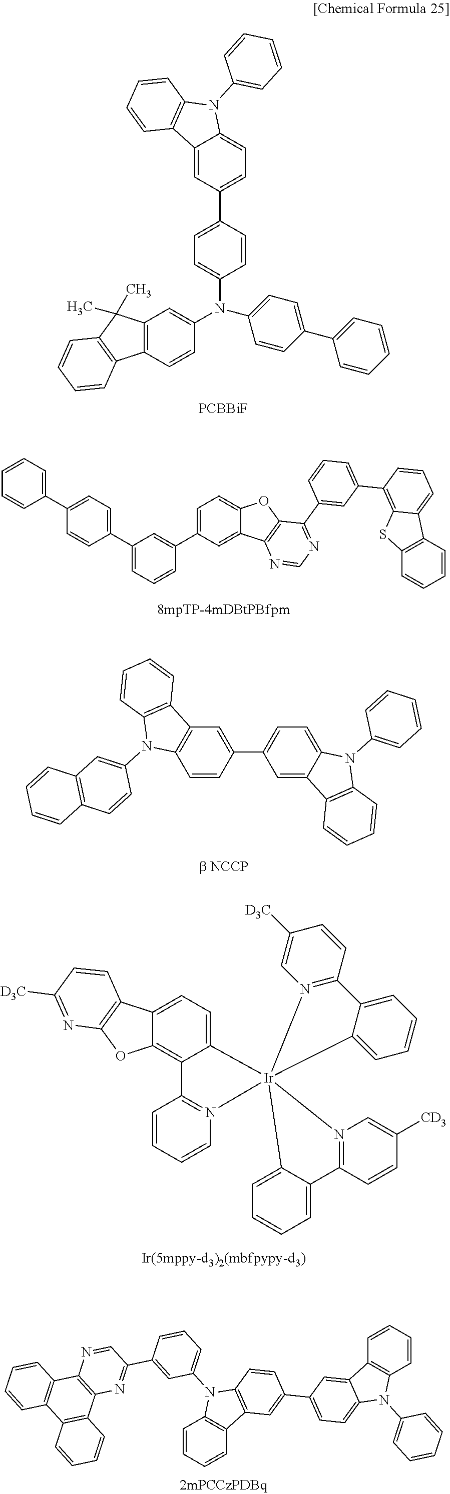

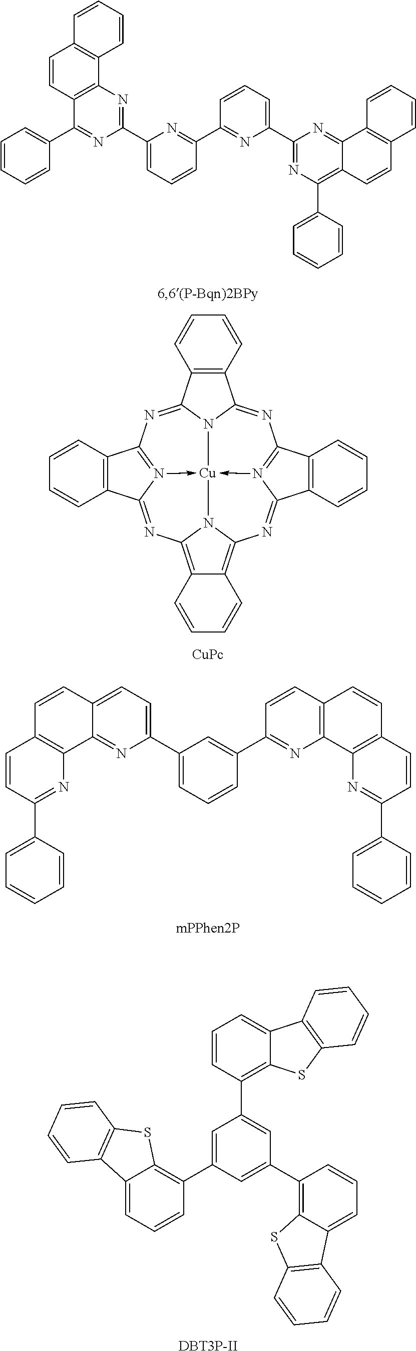

Structural Formula of an organic compound used for an electron-transport layer in the light-emitting device 1A is shown below.

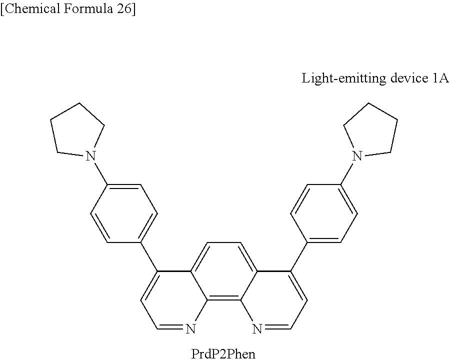 [SMILES: c1cc(-c2ccc(N3CCCC3)cc2)c2ccc3c(-c4ccc(N5CCCC5)cc4)ccnc3c2n1]

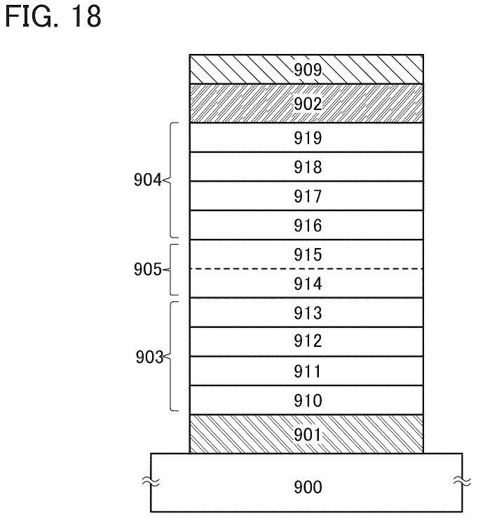

As illustrated in FIG. 18, the light-emitting device 1A and the comparative light-emitting device 1B each have a tandem structure in which a first EL layer 903, an intermediate layer 905, a second EL layer 904, and a second electrode 902 are stacked over a first electrode 901 formed over a substrate 900 that is a glass substrate. Furthermore, a cap layer 909 is provided over the second electrode.

The first EL layer 903 has a structure in which a hole-injection layer 910, a first hole-transport. layer 911, a first light-emitting layer 912, and a first electron-transport layer 913 are stacked in this order. The intermediate layer 905 includes an electron-injection buffer region 914 and a layer 915 including an electron-relay region and a charge-generation region. The second EL layer 904 has a structure in which a second hole-transport layer 916, a second light-emitting layer 917, a second electron-transport layer 918, and an electron-injection layer 919 are stacked in this order.

### <Fabrication Method of Light-Emitting Device 1A>

First, an alloy containing silver (Ag), palladium (Pd), and copper (Cu) (abbreviation: APC) was deposited to a thickness of 100 nmn as a reflective electrode over the substrate 900 that was a glass substrate by a sputtering method, and then, indium tin oxide containing silicon oxide (ITSO) was deposited to a thickness of 85 nmn as a transparent electrode by a sputtering method, whereby the first electrode 901 was formed. The electrode area was set to 4 mm² (2 mm×2 mm). Note that the first electrode is a transparent electrode, and the transparent electrode and the reflective electrode can be collectively regarded as the first electrode 901.

Next, the first EL, layer 903 was provided. First, in pretreatment for forming the light-emitting device 1A over the substrate, a surface of the substrate was washed with water and baking was performed at 200° C. for 1 hour. Then, the substrate was transferred into a vacuum evaporation apparatus where the internal pressure was reduced to approximately 1×10⁻⁴ Pa, and vacuum baking was performed at 170° C. for 30 minutes in a heating chamber of the vacuum evaporation apparatus. After that, natural cooling was performed for approximately 30 minutes.

Then, the substrate provided with the first electrode 901 was fixed to a substrate holder provided in the vacuum evaporation apparatus such that the surface on which the first electrode 901 was formed faced downward. The hole-injection layer 910 was deposited to a thickness of nm over the first electrode 901 by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) by a resistance heating evaporation method so as to have a PCBBiF:OCHD-003 weight ratio of 1:0.03.

Next, the first hole-transport layer 911 was deposited to a thickness of 85 nm over the hole-injection layer 910 by evaporation of PCBBiF.

Next, the first light-emitting layer 912 was formed over the first hole-transport layer 911. The first light-emitting layer 912 was deposited to a thickness of 40 nm by co-evaporation of 8-(1,1′: 4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), 9-(2-naphthyl)-9′-phenyl-9H,9′H-3,3′-bicarbazole (abbreviation: βNCCP), and [2-d3-methyl-8-(2-pyridinyl-κN)benzofuro[2,3-b]pyridine-κC]bis[2-(5-d3-methyl-2-pyridinyl-κN²)phenyl-KC]iridium(III) (abbreviation: Ir(5mppy-d₃)₂(mbfpypy-d₃)) by a resistance heating evaporation method so as to have an 8mpTP-4mDBtPBfpm:βNCCP:lr(5mppy-d₃)₂(mbfpypy-d₃) weight ratio of 0.5:0.5:0.1.

Then, the first electron-transport layer 913 was deposited to a thickness of 10 nm over the first light-emitting layer 912 by evaporation of 2-{3-[3-(N-phenyl-9H-carbazol-3-yl)-9H-carbazol-9-yl]phenyl}dibenzo[f,h]quinoxaline (abbreviation: 2mPCCzPDBq).

Next, the intermediate layer 905 was provided. First, a layer to be the electron-injection buffer region 914 was deposited to a thickness of 5 nm over the first electron-transport layer 913 by co-evaporation of 2,2′-(2,2′-bipyridine-6,6′-diyl)bis(4-phenylbenzo[h]quinazoline) (abbreviation: 6,6′(P-Bqn)2BPy), 4,7-bis[4-(I-pyrrolidinyl)phenyl]-1,10-phenanthroline (abbreviation: PrdP2Phen), and Li₂O by a resistance heating evaporation method so as to have a 6,6′(P-Bqn)2Bpy:PrdP2Phen:Li₂O weight ratio of 0.5:0.5:0.02.

Then, as the electron-relay region, copper phthalocyanine (abbreviation: CuPc) was deposited to a thickness of 2 nm. Next, as the charge-generation region, the layer 915 including the charge-generation region was deposited to a thickness of 10 nm by co-evaporation of PCBBiF and a fluorine-containing electron acceptor material with a molecular weight of 672 (OCHD-003) by a resistance heating evaporation method so as to have a PCBBiF:OCI-LD-003 weight ratio of 1:0.15.

Next, the second EL layer 904 was provided. First, the second hole-transport layer 916 was deposited to a thickness of 50 nm by evaporation of PCBBiF.

Then, the second light-emitting layer 917 was deposited to a thickness of 40 nm by co-evaporation of 8mpTP-4mDBtPBfpm, βNCCP, and Jr(5mppy-d₃)₂(mbfpypy-d₃) by a resistance heating evaporation method so as to have a 8mpTP-4mDBtPBfpm::βNCCP:lr(5mppy-d₃)₂(mbfpypy-d₃) weight ratio of 0.5:0.5:0.1.

Next, the second electron-transport layer 918 was deposited over the second light-emitting layer 917 by evaporation of 2mPCCzPDBq to a thickness of 20 nm, followed by evaporation of 2,2′-(1,3-phenylene)bis(9-phenyl-1,10-phenanthroline) (abbreviation: mPPhen2P) to a thickness of 20 nm.

Next, the electron-injection layer 919 was deposited to a thickness of 1.5 nm over the second electron-transport layer 918 by co-evaporation of lithium fluoride (LiF) and ytterbium (Yb) so as to have a LiF:Yb volume ratio of 2:1.

Next, the second electrode 902 was deposited to a thickness of 15 nm over the electron-injection layer 919 by co-evaporation of Ag and Mg so as to have an Ag:Mg volume ratio of 1:0.1. Note that the second electrode 902 is a transflective electrode having functions of transmitting light and reflecting light.

Then, as the cap layer, 4,4′,4″-(benzene-1,3,5-triyl)tri(dibenzothiophene) (abbreviation: DBT3P-JJ) was deposited to a thickness of 70 nm by evaporation.

Through the above process, the light-emitting device 1A was fabricated.

### <Fabrication Method of Comparative Light-Emitting Device 1B>

Next, a method for fabricating the light-emitting device 1B is described.

The comparative light-emitting device 1B is different from the light-emitting device 1A in the structure of the electron-injection buffer region 914. That is, in the light-emitting device 1B, the layer to be the electron-injection buffer region 914 was deposited to a thickness of 5 nm over the first electron-transport layer 913 by co-evaporation of 2,2′-(2,2′-bipyridine-6,6′-diyl)bis(4-phenylbenzo[h]quinazoline) (abbreviation: 6,6′(P-Bqn)2BPy) and Li₂O by a resistance heating evaporation method so as to have a 6,6′(P-Bqn)2Bpy:Li₂O weight ratio of 1:0.02.

Other components were fabricated in a manner similar to that for the light-emitting device 1A.

The structures of the light-emitting devices 1A and 1B are listed in the table below.

TABLE 6

| | Thickness | | Light-emitting device 1B |
|---|---|---|---|
| | [nm] | Light-emitting device 1A | (for comparison) |
| Cap layer | 70 | DBT3P-II | |
| Second electrode | 15 | Ag:Mg (1:0.1) | |
| Electron-injection | 1.5 | LiF:Yb (2:1) | |
| layer | | | |
| Second electron- | 20 | mPPhen2P | |
| transport layer | 20 | 2mPCCzPDBq | |
| Second light- | 40 | 8mpTP-4mDBtPBfpm:βNCCP:Ir(5mppy-d₃)₂(mbfpypy-d₃) | |
| emitting layer | | (0.5:0.5:0.1) | |
| Second hole- | 50 | PCBBiF | |
| transport layer | | | |
| Charge-generation | 10 | PCBBiF:OCHD-003 (1:0.15) | |
| region | | | |
| Electron-relay | 2 | CuPc | |
| region | | | |
| Electron-injection | 5 | 6,6′(P-Bqn)2BPy:PrdP2Phen:Li2O | 6,6′(P-Bqn)2BPy:Li₂O |
| buffer region | | (0.5:0.5:0.02) | (1:0.02) |

| | | |
|---|---|---|
| First electron- | 10 | 2mPCCzPDBq |
| transport layer | | |
| First light-emitting | 40 | 8mpTP-4mDBtPBfpm:βNCCP:Ir(5mppy-d₃)₂(mbfpypy-d₃) |
| layer | | (0.5:0.5:0.1) |
| First hole-transport | 85 | PCBBiF |
| layer | | |
| Hole-injection layer | 10 | PCBBiF:OCHD-003 (1:0.03) |
| First electrode | 85 | ITSO |
| | 100 | APC |

Here, the HOMO and LUMO levels of 6,6′(P-Bqn)2BPy and PrdP2Phen were calculated with the use of cyclic voltammretry (CV) measurement. An electrochemnical analyzer (ALS model 600A or 600C, BAS Inc.) was used for the measurement. A solvent of the solution used in the measurement was dehydrated dimnethylformamide (DMF). In the measurement, the potential of a. working electrode with respect to a reference electrode was changed within an appropriate range, so that the oxidation peak potential and the reduction peak potential were obtained. A platinum electrode (PTE platinum electrode. BAS Inc.) was used as a. working electrode, a platinum electrode (Pt counter electrode for VC-3 (5 cm), BAS Inc.) was used as an auxiliary electrode, and an Ag/Ag-±electrode (RE-7 nonaqueous reference electrode. BAS Inc.) was used as a reference electrode. The HOMO and LUMO levels of the compounds were calculated from the estimated redox potential of the reference electrode of −4.94 eV and the obtained peak potentials. As a result, the LUMO level of 6,6′(P-Bqn)2BPy was −2.92 eV and the LUMO level of PrdP2Phen was −2.61 eV. This indicates that 6,6′(P-Bqn)2BPy has a lower LUMO level than PrdP2Phen.

### <Device Characteristics>

The light-emitting device 1A and the comparative light-emitting device 1B were each sealed with a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting device 1A and the comparative light-emitting device 1B were measured.

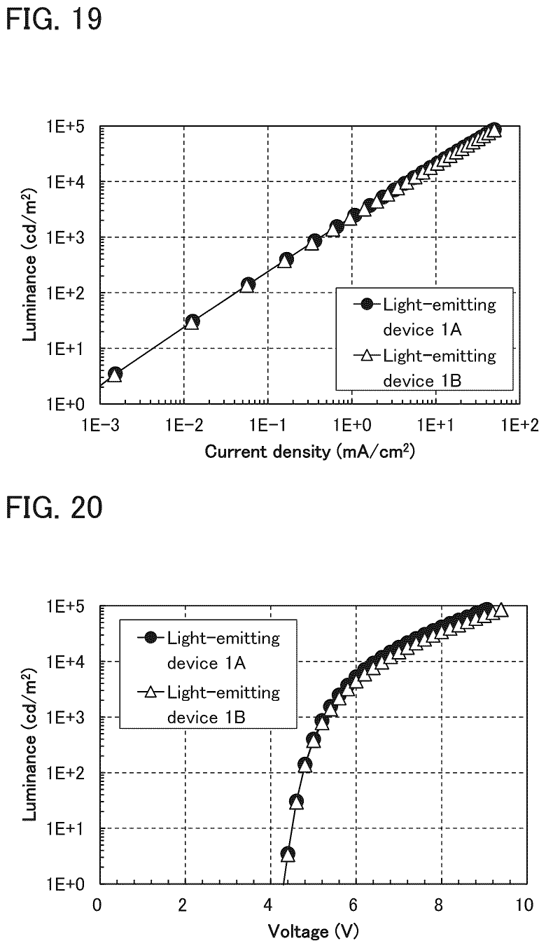

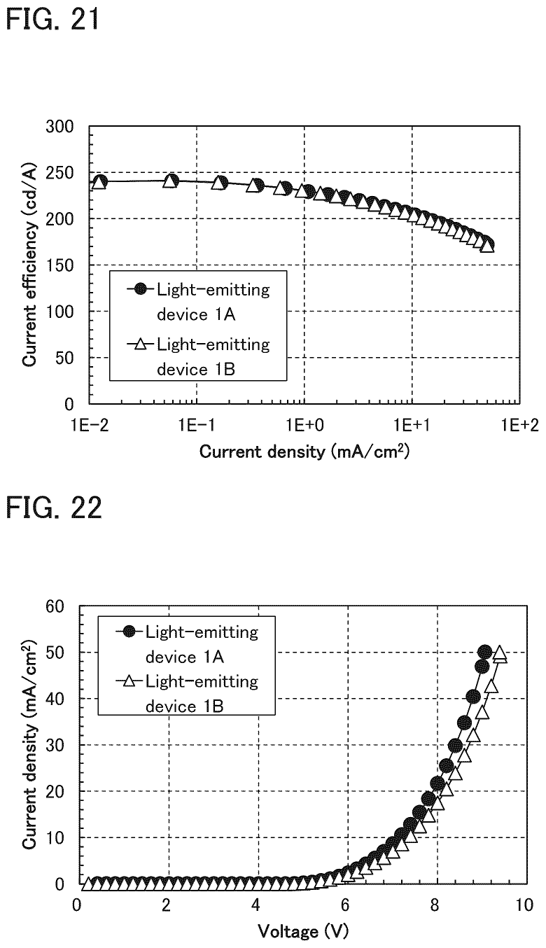

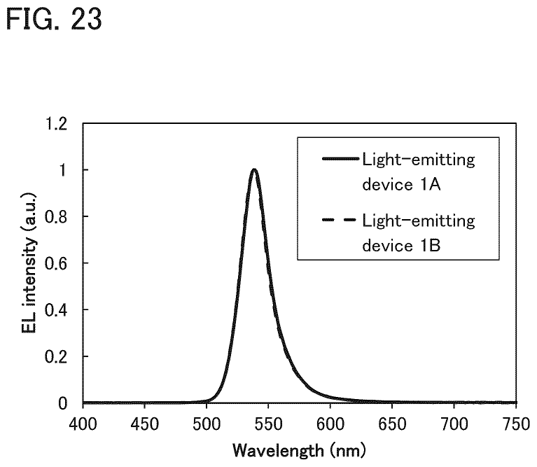

FIG. 19 shows the luminance-current density characteristics of the light-emitting device 1A and the comparative light-emitting device 1B. FIG. 20 shows the luminance-voltage characteristics of the light-emitting device 1A and the comparative light-emitting device 1B. FIG. 21 shows the current efficiency-current density characteristics of the light-emitting device 1A and the comparative light-emitting device 1B. FIG. 22 shows the current density-voltage characteristics of the light-emitting device 1A and the comparative light-emitting device 1B. FIG. 23 shows the electroluminescence spectra of the light-emitting device 1A and the comparative light-emitting device 1B. The table below shows the main characteristics of the light-emitting device 1A and the comparative light-emitting device 1B at a current density of 50 mA/cm². Note that the luminance, CIE chromaticity, and electroluminescence spectra were measured with a spectroradiometer (SR-ULIR, TOPCON TECHNOHOUSE CORPORATION).

TABLE 7

| | | | Current | | | | Current |
|---|---|---|---|---|---|---|---|
| | Voltage | Current | density | Luminance | Chromaticity | Chromaticity | efficiency |
| | (V) | (mA) | (mA/cm²) | (cd/m²) | x | y | (cd/A) |
| Light-emitting | 9.1 | 2.0 | 50 | 85980 | 0.28 | 0.70 | 172 |
| device 1A | | | | | | | |
| Light-emitting | 9.4 | 2.0 | 50 | 85760 | 0.27 | 0.70 | 171 |
| device 1B | | | | | | | |

As shown in FIG. 23, the light-emitting device 1A and the comparative light-emitting device 1B each emitted green light with peak wavelengths of 538 nm in their electroluminescence spectra.

FIG. 19 to FIG. 22 and the above table demonstrate that the light-emitting device 1A and the comparative light-emitting device 1B are each a tandem light-emitting device with high current efficiency.

In addition, the light-emitting device 1A is proven to be driven at a lower voltage than the comparative light-emitting device 1B.

The above reveals that a light-emitting device with a low driving voltage and a high emission efficiency can be provided according to one embodiment of the present invention.

### Example 2

In this example, light-emitting devices 2A and 2B of one embodiment of the present invention and a comparative light-emitting device 2C were fabricated through a process (MML process) including processing such as exposure to the air and etching. The evaluation results of their characteristics are described below.

Structural formulas of organic compounds used in common for the light-emitting devices 2A to 2C are shown below.

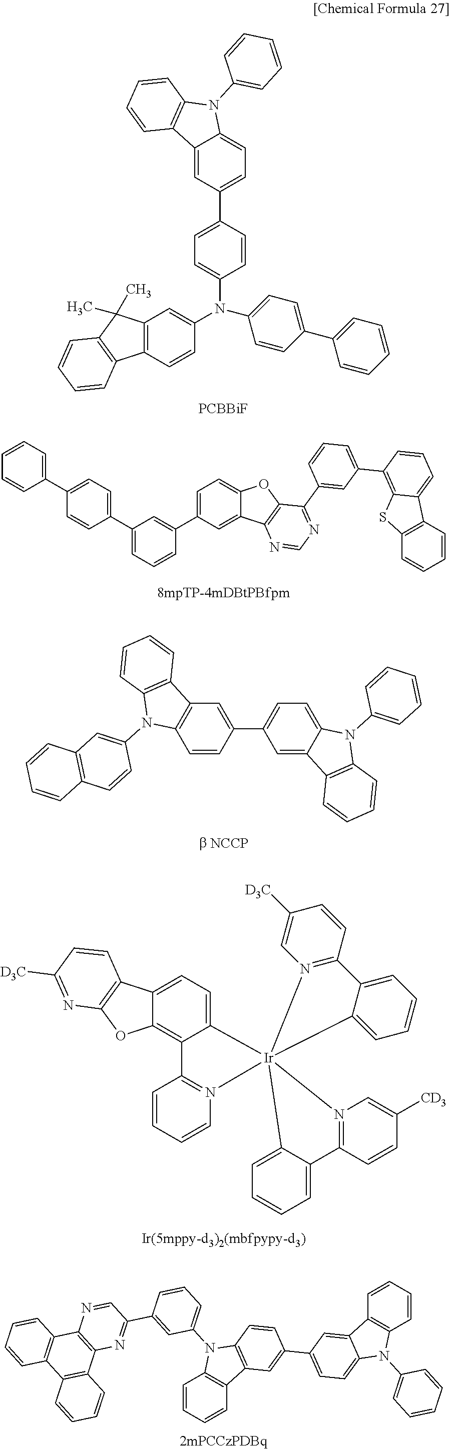

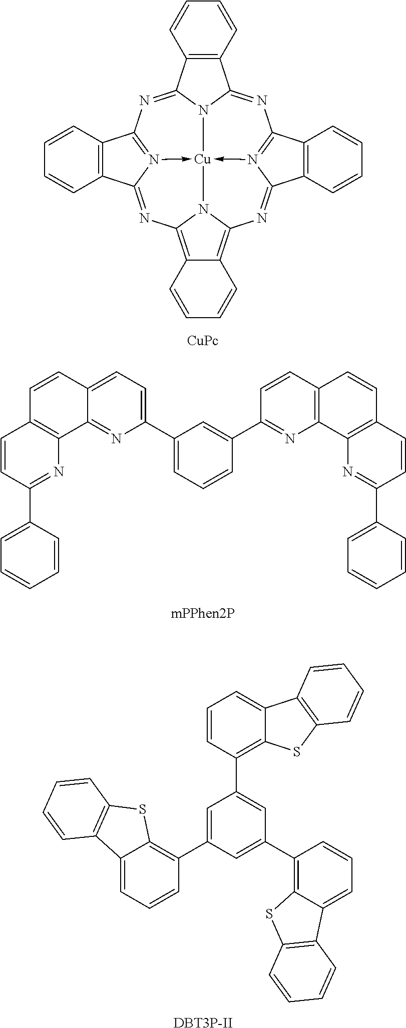

Structural Formulas of organic compounds used for electron-transport layers in the light-emitting devices 2A to 2C are shown below.

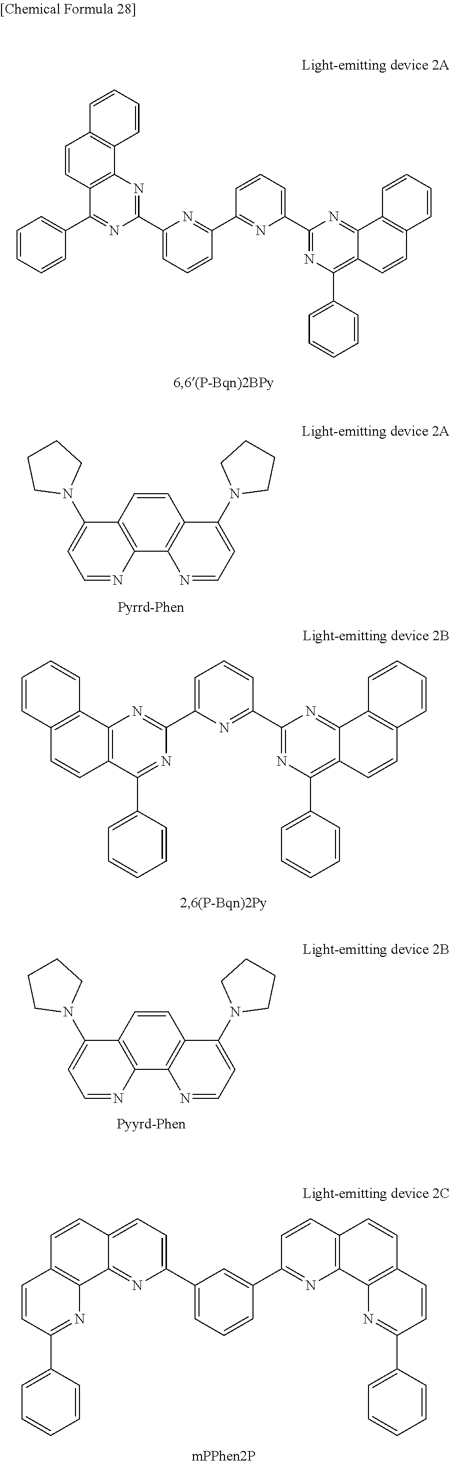 [SMILES: c1ccc(-c2nc(-c3cccc(-c4cccc(-c5nc(-c6ccccc6)c6ccc7ccccc7c6n5)n4)n3)nc3c2ccc2ccccc23)cc1 ; c1cc(N2CCCC2)c2ccc3c(N4CCCC4)ccnc3c2n1 ; c1ccc(-c2nc(-c3cccc(-c4nc(-c5ccccc5)c5ccc6ccccc6c5n4)n3)nc3c2ccc2ccccc23)cc1 ; c1cc(N2CCCC2)c2ccc3c(N4CCCC4)ccnc3c2n1 ; c1ccc(-c2ccc3ccc4ccc(-c5cccc(-c6ccc7ccc8ccc(-c9ccccc9)nc8c7n6)c5)nc4c3n2)cc1]

As illustrated in FIG. 18, the light-emitting devices 2A to 2C have a tandem structure in which the first EL layer 903, the intermediate layer 905, the second EL layer 904, and the second electrode 902 are stacked over the first electrode 901 formed over the substrate 900 that is a glass substrate. Furthermore, the cap layer 909 is provided over the second electrode.

The first EL layer 903 has a structure in which the hole-injection layer 910, the first hole-transport layer 911, the first light-emitting layer 912, and the first electron-transport layer 913 are stacked in this order. The intermediate layer 905 includes the electron-injection buffer region 914 and the layer 915 including an electron-relay region and a charge-generation region. The second EL layer 904 has a structure in which the second hole-transport layer 916, the second light-emitting layer 917, the second electron-transport layer 918, and the electron-injection layer 919 are stacked in this order.

### <Fabrication Method of Light-Emitting Device 2A>

First, an alloy containing silver (Ag), palladium (Pd), and copper (Cu) (abbreviation: APC) was deposited to a thickness of 100 nm as a reflective electrode over the substrate 900 that was a glass substrate by a sputtering method, and then, indium tin oxide containing silicon oxide (ITSO) was deposited to a thickness of 85 nm as a transparent electrode by a sputtering method, whereby the first electrode 901 was formed. The electrode area was set to 4 mm² (2 mm×2 mm). Note that the first electrode 901 is a transparent electrode, and the transparent electrode and the reflective electrode can be collectively regarded as the first electrode 901.

Next, the first EL. layer 903 was provided. First, in pretreatment for forming the light-emitting device 2A over the substrate, a surface of the substrate was washed with water and baking was performed at 200° C. for 1 hour. Then, the substrate was transferred into a vacuum evaporation apparatus where the internal pressure was reduced to approximately 1×10′ Pa, and vacuum baking was performed at 170° C. for 30 minutes in a heating chamber of the vacuum evaporation apparatus. After that, natural cooling was performed for approximately 30 minutes.

Then, the substrate provided with the first electrode 901 was fixed to a substrate holder provided in the vacuum evaporation apparatus such that the surface on which the first electrode 901 was formed faced downward. The hole-injection layer 910 was formed to a thickness of 10 nm over the first electrode 901 by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) by a resistance heating evaporation method so as to have a PCBBiF:OCHD-003 weight ratio of 1:0.03.

Next, the first hole-transport layer 911 was deposited to a thickness of 85 nm over the hole-injection layer 910 by evaporation of PCBBiF.

Next, the first light-emitting layer 912 was formed over the first hole-transport layer 911. The first light-emitting layer 912 was deposited to a thickness of 40 nm by co-evaporation of 8-(1,1′: 4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), 9-(2-naphthyl)-9′-phenyl-91H,9′-3,3′-bicarbazole (abbreviation: βNCCP), and [2-d3-methyl-8-(2-pyridinyl-icN)benzofuro[2,3-b]pyridine-κC]bis[2-(5-d3-methyl-2-pyridinyHcN2)phenyl-κC]iridium(III) (abbreviation: Ir(5mppy-d₃)₂(mbfpypy-d₃)) by a resistance heating evaporation method so as to have a 8mpTP-4mDBtPBfpm:[INCCP:Ir(5mppy-d₃)₂(mbfpypy-d₃) weight ratio of 0.5:0.5:0.1.

Then, the first electron-transport layer 913 was deposited to a thickness of 10 nm over the first light-emitting layer 912 by evaporation of 2-{3-[3-(N-phenyl-9H-carbazol-3-yl)-9H-carbazol-9-yl]phenyl}dibenzo[f,h]quinoxaline (abbreviation: 2mPCCzPDBq).

Next, the intermediate layer 905 was provided. First, under Condition 2 shown in the table below, the layer to be the electron-injection buffer region 914 was deposited to a thickness of 5 nm over the first electron-transport layer 913 by co-evaporation of 2,2′-(2,2′-bipyridine-6,6′-diyl)bis(4-phenylbenzo[h]quinazoline) (abbreviation: 6,6′(P-Bqn)2BPy), 4,7-di-1-pyrrolidinyl-1,10-phenanthroline (abbreviation: Pyrrd-Phen), and Li₂O by a resistance heating evaporation method so as to have a 6,6′(P-Bqn)2Bpy:Pyrrd-Phen:Li₂O volume ratio of 0.5:0.5:0.02.

Then, as the electron-relay region, copper phthalocyanine (abbreviation: CuPc) was deposited to a thickness of 2 nm. Next, as the charge-generation region, the layer 915 including the charge-generation region was deposited to a thickness of 10 nm by co-evaporation of PCBBiF and a fluorine-containing electron acceptor material with a molecular weight of 672 (OCHD-003) by a resistance heating evaporation method so as to have a PCBBiF:OCHD-003 weight ratio of 1:0.15.

Next, the second EL layer 904 was provided. First, the second hole-transport layer 916 was deposited to a thickness of 50 nm by evaporation of PCBBiF.

Then, the second light-emitting layer 917 was deposited to a thickness of 40 nm by co-evaporation of 8mpTP-4mDBtPBfpm, βNCCP, and Ir(5mppy-d₃)₂(mbfpypy-d₃) by a resistance heating evaporation method so as to have a 8mpTP-4mDBtPBfpm:βNCCP:Ir(5mppy-d₃)₂(mbfpypy-d₃) of 0.5:0.5:0.1.

Next, 2mPCCzPDBq was deposited to a thickness of 20 nm by evaporation, and then 2,2′-(1,3-phenylene)bis(9-phenyl-1,10-phenanthroline) (abbreviation: mPPhen2P) was deposited to a thickness of 20 nm by evaporation, whereby the second electron-transport layer 918 was formed over the second light-emitting layer 917,

Here, the substrate 900 was exposed to the air, then an aluminum oxide (AlOₓ) film was deposited to a thickness of 30 nm by an ALD method, and molybdenum (Mo) was deposited to a thickness of 50 nm by a sputtering method. After that, a resist was formed using a photoresist, and the molybdenum was processed into a predetermined shape by a lithography method. Specifically, a slit with a width of 3 μm was formed at a position 3.5 μm away from the end portion of the first electrode 901.

Next, using the molybdenum as a mask, the stacked-layer structure formed of the aluminum oxide film, the first EL layer 903, the intermediate layer 905, the second hole-transport layer 916, the second light-emitting layer 917, and the second electron-transport layer 918 was processed into a predetermined shape. After that, molybdenum was removed by a dry etching method, and then the aluminum oxide film was removed. The aluminum oxide film was removed by wet etching using an acidic chemical solution.

Then, heat treatment was performed at 100° C. for 1 hour in a vacuum where the internal pressure was reduced to approximately 1×10⁻⁴ Pa. The heat treatment can remove moisture or the like attached by the above-described processing, the exposure to the air, or the like.

Next, the electron-injection layer 919 was deposited to a thickness of 1.5 nm over the second electron-transport layer 918 by co-evaporation of lithium fluoride (LiF) and ytterbium (Yb) so as to have a LiF:Yb volume ratio of 2:1.

Next, the second electrode 902 was deposited to a thickness of 15 nm over the electron-injection layer 919 by co-evaporation of Ag and Mg so as to have an Ag:Mg volume ratio of 1:0.1. Note that the second electrode 902 is a transflective electrode having functions of transmitting light and reflecting light.

Then, as the cap layer, 4,4′,4″-(benzene-1,3,5-triyl)tri(dibenzothiophene) (abbreviation: DBT3P-II) was deposited to a thickness of 70 nm by evaporation.

Through the above process, the light-emitting device 2A was fabricated.

### <Fabrication Method of Light-Emitting Device 2B>

Next, a method for fabricating the light-emitting device 2B is described.

The light-emitting device 2B is different from the light-emitting device 2A in the structure of the electron-injection buffer region 914. That is, in the light-emitting device 2B, the layer to be the electron-injection buffer region 914 was deposited to a thickness of 5 nm over the first electron-transport layer 913 by co-evaporation of 2,2′-(pyridine-2,6-diyl)bis(4-phenylbenzo[h]quinazoline) (abbreviation: 2,6(P-Bqn)2Py), Pyrrd-Phen, and Li₂O by a resistance heating evaporation method so as to have a 2,6(P-Bqn)2Py:Pyrrd-Phen:Li₂O volume ratio of 0.5:0.5:0.02.

Other components were fabricated in a manner similar to that for the light-emitting device 2A.

### <Fabrication Method of Comparative Light-Emitting Device 2C>

Next, a method for fabricating the comparative light-emitting device 2C is described.

The comparative light-emitting device 2C is different from the light-emitting device 2A in the structure of the electron-injection buffer region 914. First, the layer to be the electron-injection buffer region 914 was deposited to a thickness of 5 nm over the first electron-transport layer 913 by co-evaporation of mPPhen2P and Li₂O by a resistance heating evaporation method so as to have an mPPhen2P:Li₂O volume ratio of 1:0.02.

The structures of the light-emitting devices 2A to 2C are listed in the table below.

TABLE 8

| | | | |
|---|---|---|---|
| Thickness | Light-emitting | Light-emitting | Light-emitting |
| [nm] | device 2A | device 2B | device 2C |

| | | |
|---|---|---|
| Cap layer | 70 | DBT3P-II |
| Second electrode | 15 | Ag:Mg (1:0.1) |
| Electron-injection layer | 1.5 | LiF:Yb (2:1) |

Processing by photolithography was performed

| | | |
|---|---|---|
| Second electron- | 20 | mPPhen2P |
| transport layer | 20 | 2mPCCzPDBq |
| Second light-emitting | 40 | 8mpTP-4mDBtPBfpm:βNCCP:Ir(5mppy-d₃)₂(mbfpypy-d₃) |
| layer | | (0.5:0.5:0.1) |
| Second hole-transport | 40 | PCBBiF |
| layer | | |
| Charge-generation | 10 | PCBBiF:OCHD-003 (1:0.15) |
| region | | |
| Electron-relay region | 2 | CuPc |
| Electron-injection | 5 | Condition 2 |
| buffer region | | |
| First electron-transport | 10 | 2mPCCzPDBq |
| layer | | |
| First light-emitting layer | 40 | 8mpTP-4mDBtPBfpm:βNCCP:Ir(5mppy-d₃)₂(mbfpypy-d₃) |
| | | (0.5:0.5:0.1) |
| First hole-transport | 60 | PCBBiF |
| layer | | |
| Hole-injection layer | 10 | PCBBiF:OCHD-003 (1:0.03) |
| First electrode | 85 | ITSO |
| | 100 | APC |

TABLE 9

| | Condition 2 for electron-injection buffer region |
|---|---|
| Light-emitting | 6,6′(P-Bqn)2BPy:Pyrrd-Phen:Li₂O |
| device 2A | (0.5:0.5:0.02) |
| Light-emitting | 2,6(P-Bqn)2Py:Pyrrd-Phen:Li₂O |
| device 2B | (0.5:0.5:0.02) |
| Light-emitting | mPPhen2P:Li₂O |
| device 2C | (1:0.02) |

Here, the HOMO and LUMO levels of 6,6′(P-˜Bqn)2BPy, 2,6(P-Bqn)2Py, and Pyrrd-Phen were calculated by cyclic volta_mmetry (CV) measurement, An electrochemnical analyzer (ALS model 600A or 600C, BAS Inc.) was used for the measurement. A solvent of the solution used in the measurement was dehydrated dimethylformamide (DMF). In the measurement, the potential of a working electrode with respect to a reference electrode was changed within an appropriate range, so that the oxidation peak potential and the reduction peak potential were obtained. A platinum electrode (PTE platinum electrode, BAS Inc.) was used as a working electrode, a platinum electrode (Pt counter electrode for VC-3 (5 cm), BAS Inc.) was used as an auxiliary electrode, and an Ag/Ag+ electrode (RE-7 nonaqueous reference electrode, BAS Inc.) was used as a reference electrode. The HOMO and LUMO levels of the compounds were calculated from the estimated redox potential of the reference electrode of −4.94 eV and the obtained peak potentials. As a result, the LUMO level of 6,6′(P-Bqn)2BPy was −2.92 eV, the LUNMO level of 2,6(P-Bqn)2Py was −2.92 eV, and the LUMO level of Pyrrd-Phen was −2.55 eV. This result indicates that 6,6′(P-Bqn)2BPy and 2,6(P-Bqn)2Py each have a lower LUMO level than Pyrrd-Phen.

### <Device Characteristics>

The light-emitting devices 2A and 2B and the comparative light-emitting device 2C were each sealed with a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting devices 2A to 2C were measured.

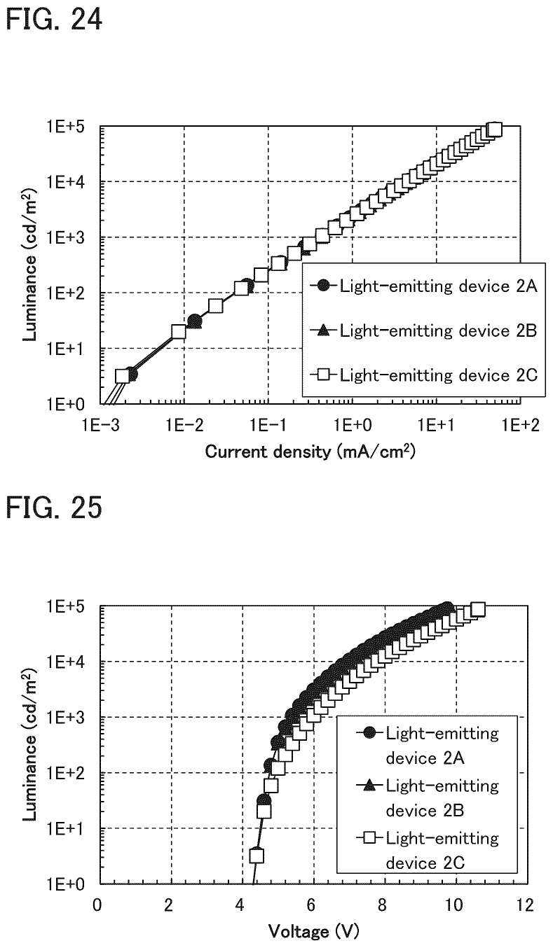

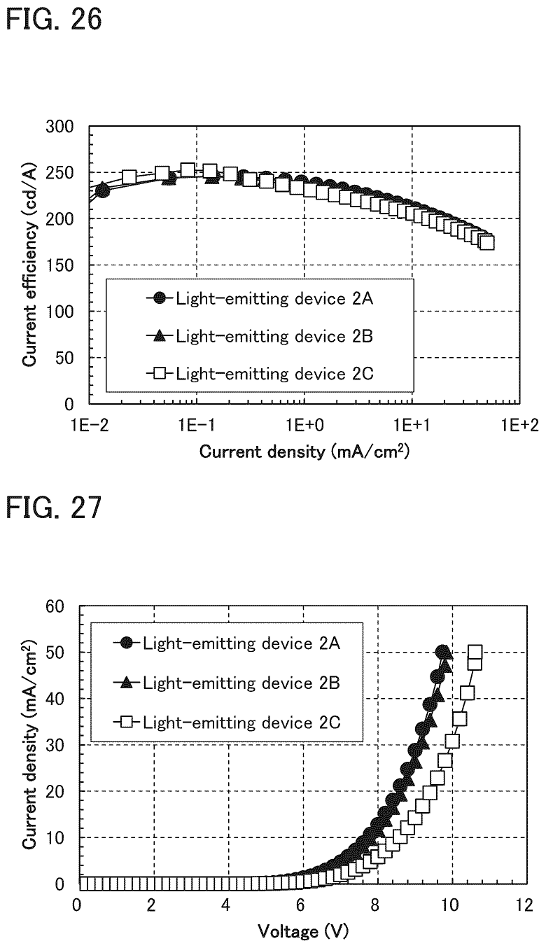

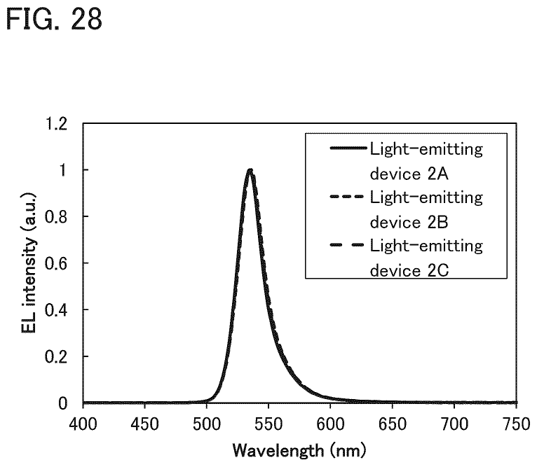

FIG. 24 shows the luminance-current density characteristics of the light-emitting devices 2A to 2C, FIG. 25 shows the luminance-voltage characteristics of the light-emitting devices 2A to 2C, FIG. 26 shows the current efficiency-current density characteristics of the light-emitting devices 2A to 2C, FIG. 27 shows the current density-voltage characteristics of the light-emitting devices 2A to 2C, and FIG. 28 shows the electroluminescence spectra of the light-emitting devices 2A to 2C. The following table shows the main characteristics of the light-emitting devices 2A to 2C at a current density of 50 mA/cm². Note that the luminance, CIE chromaticity, and electroluminescence spectra were measured with a spectroradiometer (SR-ULlR, TOPCON TECHNOHOUSE CORPORATION).

TABLE 10

| | | | Current | | | | Current |
|---|---|---|---|---|---|---|---|
| | Voltage | Current | density | Luminance | Chromaticity | Chromaticity | efficiency |
| | (V) | (mA) | (mA/cm²) | (cd/m²) | x | y | (cd/A) |
| Light-emitting device 2A | 9.7 | 2.0 | 50 | 88260 | 0.25 | 0.72 | 176 |
| Light-emitting device 2B | 9.8 | 2.0 | 50 | 88020 | 0.26 | 0.72 | 176 |
| Light-emitting device 2C | 10.6 | 2.0 | 50 | 86940 | 0.26 | 0.72 | 174 |

Furthermore, as shown in FIG. 28, the light-emitting devices 2A to 2C each emitted green light with peak wavelengths of 535 nm in their electroluminescence spectra.

FIG. 24 to FIG. 27 and the above table demonstrate that the light-emitting devices 2A to 2C are each a tandem light-emitting device with high current efficiency.

FIG. 27 shows that the light-emitting devices 2A and 2B were driven at a lower voltage than the comparative light-emitting device 2C. It is also shown that the light-emitting devices 2A and 2B are less likely to be degraded in characteristics and are driven at low voltage even after undergoing the process including processing such as exposure to the air and etching. On the other hand, the comparative light-emitting device 2C is found to need a higher voltage for driving, due to the process including processing such as exposure to the air and etching.

Here, thin films containing organic compounds used for the intermediate layer 905 were evaluated by electron spin resonance (ESR) method.

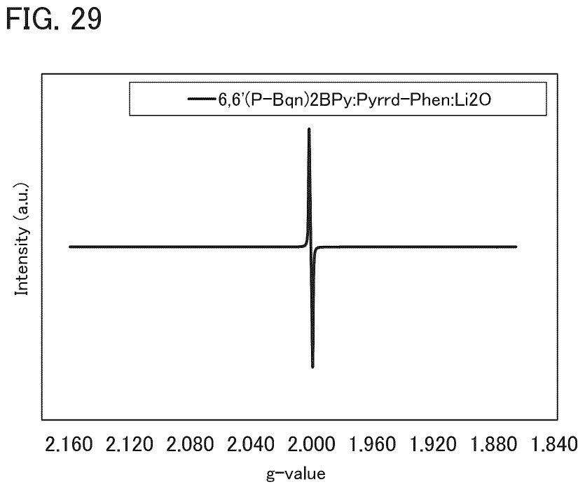

Specifically, a thin film was deposited to a thickness of 100 nr over a quartz substrate by co-evaporation of 6,6′(P-Bqn)2BPy, Pyrrd-Phen, and Li₂O so as to have a 6,6′(P-Bqn)2Bpy:Pyrrd-Phen:Li₂O volume ratio of 0.5:0.5:0.02, and an electron spin resonance spectrum of a thin film was measured at room temperature. Note that the measurement of the electron spin resonance spectrum using an ESR method was performed with an electron spin resonance spectrometer E500 (Bruker Corporation). The measurement was performed at room temperature under the conditions where the resonance frequency was 9.56 G1-z, the output power was 1 mW, the modulated magnetic field was 50 mT, the modulation width was 0.5 mT, the time constant was 0.04 s, and the sweep time was 1 min. The results are shown in FIG. 29. FIG. 29 shows that a signal was observed at a g-factor of approximately 2.00 and the spin density was 1 ×10²O spins/cm³. The spin density of 1×10¹⁷ spins/cm³ or higher indicates that efficient interaction is caused between the metal and the organic compound.

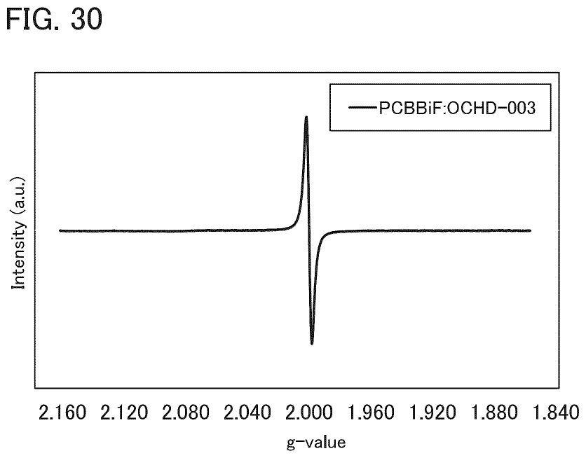

Furthermore, a thin film was deposited to a thickness of 100 nm over a quartz substrate by co-evaporation of PCBBiF and OCHD-003 so as to have a PCBBiF:OCHD-003 weight ratio of 1:0.1, and an electron spin resonance spectrum of the thin film was measured at room temperature. Note that the measurement of electron spin resonance spectrum using ESR spectroscopy was performed with an electron spin resonance spectrometer JES FA300 (JEOL Ltd.). The measurement was performed at room temperature under the conditions where the resonance frequency was 9.18 GHz, the output power was 1 mW, the modulated magnetic field was 50 mT, the modulation width was 0.5 mT, the time constant was 0.03 s, and the sweep time was 1 min. The results are shown in FIG. 30. FIG. 30 shows that a signal was observed at a g-factor of approximately 2.00 and the spin density was 5×10¹⁹ spins/cm³. This shows that OCHD-003 has an electron-acceptor property with respect to PCBBiF and the layer including PCBBiF and OCHD-003 functions as a charge-generation layer.

### <Reliability Test Result>

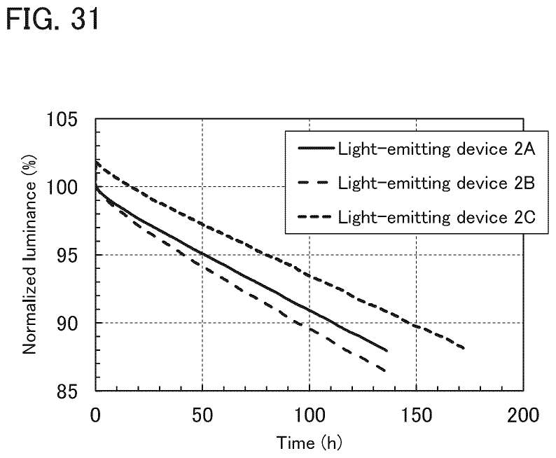

Furthermore, a reliability test was performed on the light-emitting devices 2A to 2C. FIG. 31 shows a time-dependent change in normalized luminance at the time of constant current density driving (50 [mA/cm²]). In FIG. 31, the vertical axis represents the luminance (%) normalized with the luminance at the time of the start of emission as 100%, and the horizontal axis represents time (h).

FIG. 31 confirms that an increase in luminance of the comparative light-emitting device 2C was observed at the initial stage. On the contrary, the luminance of each of the light-emitting devices 2A and 2B was not increased, and the light-emitting devices 2A and 2B exhibited favorable luminance degradation curves. As shown in FIG. 31, LT90 (h), which is the time that has elapsed until the measured luminance decreases to 90% of the initial luminance, of the light-emitting device 2A was 112 hours. In addition, LT90 of the light-emitting device 2B was 94 hours.

The above results shows that a light-emitting device that can be driven at low voltage and has high emission efficiency and high reliability can be provided according to one embodiment of the present invention.

### Example 3

In this example, a light-emitting device 3A of one embodiment of the present invention and a comparative light-emitting device 3B were fabricated by a continuous vacuum process, and the evaluation results of their characteristics are described below.

Structural Formulas of organic compounds used in common for the light-emitting device 3A and the comparative light-emitting device 3B are shown below.

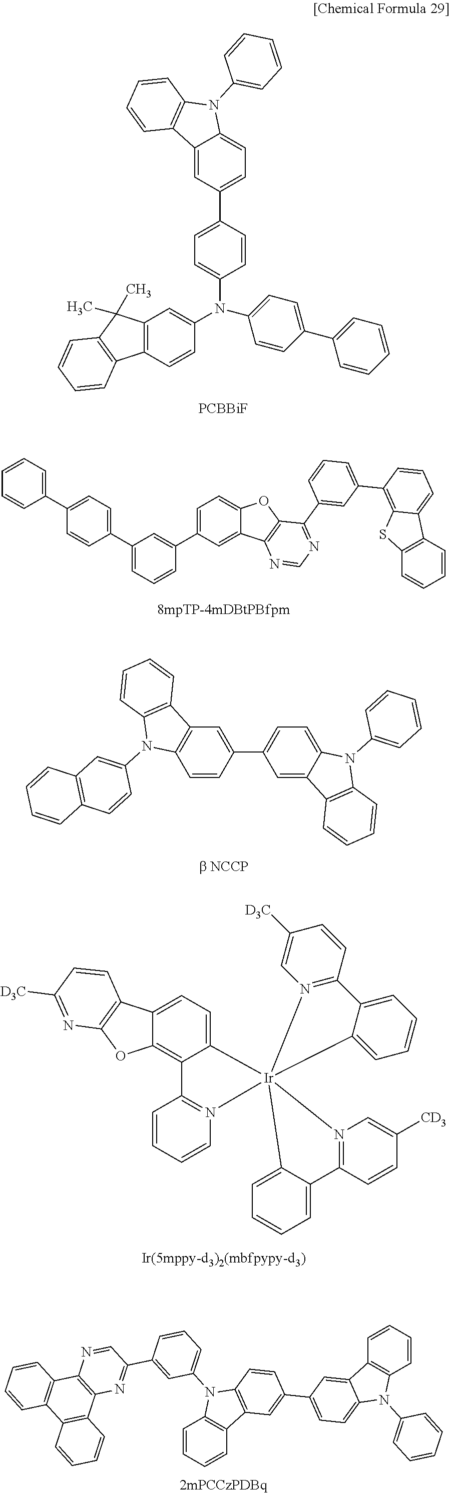

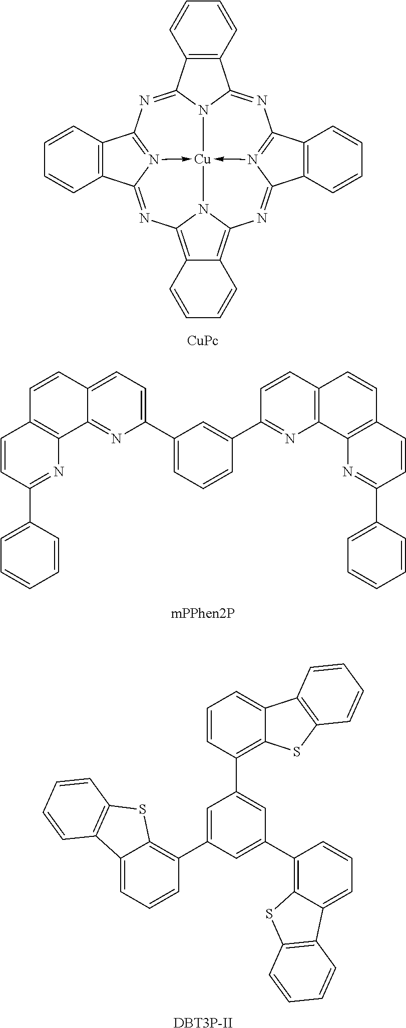

Structural Formulas of organic compounds used for the light-emitting device 3A and the light-emitting device 3B are shown below.

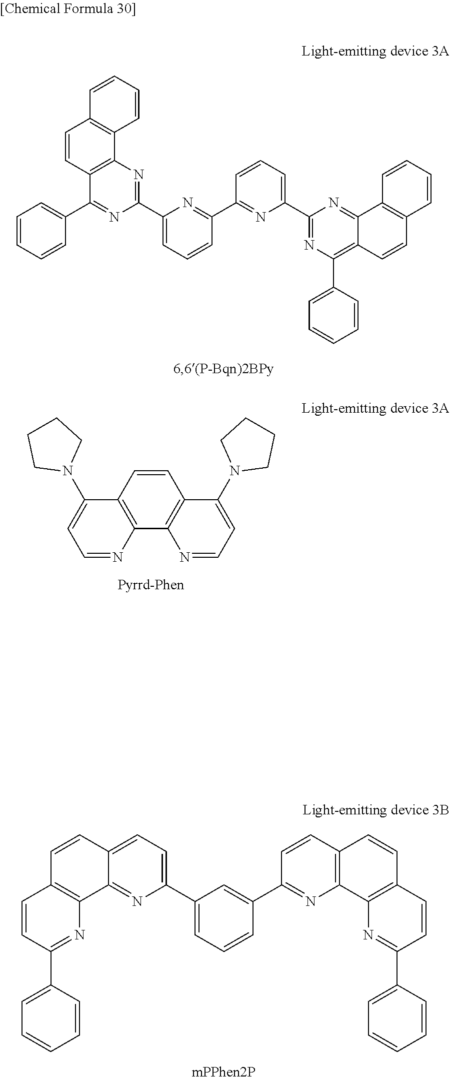 [SMILES: c1ccc(-c2nc(-c3cccc(-c4cccc(-c5nc(-c6ccccc6)c6ccc7ccccc7c6n5)n4)n3)nc3c2ccc2ccccc23)cc1 ; c1cc(N2CCCC2)c2ccc3c(N4CCCC4)ccnc3c2n1 ; c1ccc(-c2ccc3ccc4ccc(-c5cccc(-c6ccc7ccc8ccc(-c9ccccc9)nc8c7n6)c5)nc4c3n2)cc1]

The light-emitting device 3A and the light-emitting device 3B each have a tandem structure in which the first EL layer 903, the intermediate layer 905, the second EL layer 904, and the second electrode 902 are stacked over the first electrode 901 formed over the substrate 900 that is a glass substrate, as illustrated in FIG. 18. Furthermore, the cap layer 909 is provided over the second electrode.

The first EL layer 903 has a structure in which the hole-injection layer 910, the first hole-transport layer 911, the first light-emitting layer 912, and the first electron-transport layer 913 are stacked in this order. The intermediate layer 905 includes the electron-injection buffer region 914 and the layer 915 including an electron-relay region and a charge-generation region. The second EL layer 904 has a structure in which the second hole-transport layer 916, the second light-emitting layer 917, the second electron-transport layer 918, and the electron-injection layer 919 are stacked in this order.

### <Fabrication Method of Light-Emitting Device 3A>

First, an alloy containing silver (Ag), palladium (Pd), and copper (Cu) (abbreviation: APC) was deposited to a thickness of 100 nm as a reflective electrode over the substrate 900 that was a glass substrate by a sputtering method, and then, indium tin oxide containing silicon oxide (ITSO) was deposited to a thickness of 85 nm as a transparent electrode by a sputtering method, whereby the first electrode 901 was formed. The electrode area was set to 4 mm² (2 mm x, 2 mm). Note that the first electrode is a transparent electrode, and the transparent electrode and the reflective electrode can be collectively regarded as the first electrode 901.

Next, the first EL layer 903 was provided. First, in pretreatment for forming the light-emitting device 3A over the substrate, a surface of the substrate was washed with water and baking was performed at 200° C. for 1 hour. Then, the substrate was transferred into a vacuum evaporation apparatus where the internal pressure was reduced to approximately 1×10″ Pa, and vacuum baking was performed at 170° C. for 30 minutes in a heating chamber of the vacuum evaporation apparatus. After that, natural cooling was performed for approximately 30 minutes.

Then, the substrate provided with the first electrode 901 was fixed to a substrate holder provided in the vacuum evaporation apparatus such that the surface on which the first electrode 901 was formed faced downward. The hole-injection layer 910 was formed to a thickness of 10 nm over the first electrode 901 by co-evaporation of N-(biphenyl-4-yl)-N-[4-(9-phenyl-9H-carbazol-3-yl)phenyl]-9,9-dimethyl-911-fluoren-2-amine (abbreviation: PCBBiF) and a fluorine-containing electron acceptor material with a molecular weight of 672 (OCHD-003) by a resistance heating evaporation method so as to have a PCBBiF:OCHD-003 weight ratio of 1:0.03.

Next, the first hole-transport layer 911 was deposited to a thickness of 85 nm over the hole-injection layer 910 by evaporation of PCBBiF.

Next, the first light-emitting layer 912 was formed over the first hole-transport layer 911. The first light-emitting layer 912 was deposited to a thickness of 40 nm by co-evaporation of 8-(1,1′: 4′, 1″-terphenyl-3-yl)-4-[3-(dibenzothiophen-4-yl)phenyl]-[1]benzofuro[3,2-d]pyrimidine (abbreviation: 8mpTP-4mDBtPBfpm), 9-(2-naphthyl)-9′-phenyl-9H,9′H-3,3′-bicarbazole (abbreviation: βNCCP), and [2-d3-methyl-8-(2-pyridinyl-κN)benzofuro[2,3-b]pyridine-κC]bis[2-(5-d3-methyl-2-pyridinyl-irN2)phenyl-C]iridium(III) (abbreviation: Ir(5mppy-d₃)₂(mbfpypy-d₃)) by a resistance heating evaporation method so as to have a 8mpTP-4mDBtPBfpm::βNCCP:Ir(5mppy-d₃)₂(mbfpypy-d₃) weight ratio of 0.5:0.5:0.1.

Then, over the first light-emitting layer 912, 2-{3-[3-(N-phenyl-9H-carbazol-3-yl)-9H-carbazol-9-yl]phenyl}dibenzo[f,h]quinoxaline (abbreviation: 2mPCCzPDBq) was deposited by evaporation to a thickness of 10 nm, so that the first electron-transport layer 913 was formed.

Next, the intermediate layer 905 was provided. First, under Condition 3 shown in the table below, the layer to be the electron-injection buffer region 914 was deposited to a thickness of 5 nm over the first electron-transport layer 913 by co-evaporation of 2,2′-(2,2′-bipyridine-6,6′-diyl)bis(4-phenylbenzo[h]quinazoline) (abbreviation: 6,6′(P-Bqn)2BPy), 4,7-di-1-pyrrolidinyl-1,10-phenanthroline (abbreviation: Pyrrd-Phen), and Li₂O by a resistance heating evaporation method so as to have a 6,6′(P-Bqn)2Bpy:Pyrrd-Phen:Li₂O volume ratio of 0.5:0.5:0.02.

Then, as the electron-relay region, copper phthalocyanine (abbreviation: CuPc) was deposited to a thickness of 2 nm. Next, as the charge-generation region, the layer 915 including the charge-generation region was deposited to a thickness of 10 nm by co-evaporation of PCBBiF and a fluorine-containing electron acceptor material with a molecular weight of 672 (OCHD-003) by a resistance heating evaporation method so as to have a PC3BiF:OC-ID-003 weight ratio of 1:0.15.

Next, the second EL layer 904 was provided. First, the second hole-transport layer 916 was deposited to a thickness of 50 nm by evaporation of PCBBiF.

Then, the second light-emitting layer 917 was deposited to a thickness of 40 nm by co-evaporation of 8mpTP-4mDBtPBfpm, βNCCP, and Ir(5mppy-d₃)₂(mbfpypy-d₃) by a resistance heating evaporation method so as to have a 8mpTP-4mDBtPBfpm:βNCCP:Ir(5mppy-d₃)₂(mbfpypy-d₃) weight ratio of 0.5:0.5:0.1.

Next, 2mPCCzPDBq was deposited to a thickness of 20 nm by evaporation, and then 2,2′-(1,3-phenylene)bis(9-phenyl-1,10-phenanthroline) (abbreviation: mPPhen2P) was deposited to a thickness of 20 nm by evaporation, whereby the second electron-transport layer 918 was formed over the second light-emitting layer 917.

Next, the electron-injection layer 919 was deposited to a thickness of 1.5 nm over the second electron-transport layer 918 by co-evaporation of lithium fluoride (LiF) and ytterbium (Yb) so as to have a LiF:Yb volume ratio of 2:1.

Next, the second electrode 902 was deposited to a thickness of 15 nm over the electron-injection layer 919 by co-evaporation of Ag and Mg so as to have an Ag:Mg volume ratio of 1:0.1. Note that the second electrode 902 is a transflective electrode having functions of transmitting light and reflecting light.

Then, as the cap layer, 4,4′,4″-(benzene-1,3,5-triyl)tri(dibenzothiophene) (abbreviation: DBT3P-II) was deposited to a thickness of 70 nm by evaporation.

Through the above process, the light-emitting device 3A was fabricated.

### <Fabrication Method of Light-Emitting Device 3B>

Next, a method for fabricating the comparative light-emitting device 3B is described.

The light-emitting device 3B is different from the light-emitting device 3A in the structure of the electron-injection buffer region 914. Specifically, in the light-emitting device 3B, the layer to be the electron-injection buffer region 914 was deposited to a thickness of 5 nm over the first electron-transport layer 913 by co-evaporation of mPPhen2P and Li₂O using a resistance-heating method so as to have an mPPhen2P:Li₂O volume ratio of 1:0.02.

Other components were fabricated in a manner similar to that for the light-emitting device 3A.

The structures of the light-emitting devices 3A and 3B are listed in the table below,

TABLE 11

| | | |
|---|---|---|
| Thickness | Light-emitting | Light-emitting |
| [nm] | device 3A | device 3B |

| | | |
|---|---|---|
| Cap layer | 70 | DBT3P-II |
| Second electrode | 15 | Ag:Mg (1:0.1) |
| Electron-injection | 1.5 | LiF:Yb (2:1) |
| layer | | |
| Second electron- | 20 | mPPhen2P |
| transport layer | 20 | 2mPCCzPDBq |
| Second light-emitting | 40 | 8mp TP-4mDBtPBfpm:βNCCP:Ir(5mppy-d₃)₂(mbfpypy-d₃) |
| layer | | (0.5:0.5:0.1) |
| Second hole-transport | 40 | PCBBiF |
| layer | | |
| Charge-generation | 10 | PCBBiF:OCHD-003 (1:0.15) |
| region | | |
| Electron-relay region | 2 | CuPc |
| Electron-injection | 5 | Condition 3 |
| buffer region | | |
| First electron- | 10 | 2mPCCzPDBq |
| transport layer | | |
| First light-emitting | 40 | 8mp TP-4mDBtPBfpm:βNCCP:Ir(5mppy-d₃)₂(mbfpypy-d₃) |
| layer | | (0.5:0.5:0.1) |
| First hole-transport | 60 | PCBBiF |
| layer | | |
| Hole-injection layer | 10 | PCBBiF:OCHD-003 (1:0.03) |
| First electrode | 85 | ITSO |
| | 100 | APC |

TABLE 12

| | Condition 3 for electron-injection buffer region |
|---|---|
| Light-emitting | 6,6′(P-Bqn)2BPy:Pyrrd-Phen:Li₂O |
| device 3A | (0.5:0.5:0.02) |
| Light-emitting | mPPhen2P:Li₂O |
| device 3B | (1:0.02) |

### <Device Characteristics>

The light-emitting device 3A and the comparative light-emitting device 3B were each scaled with a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting device 3A and the comparative light-emitting device 3B were measured.

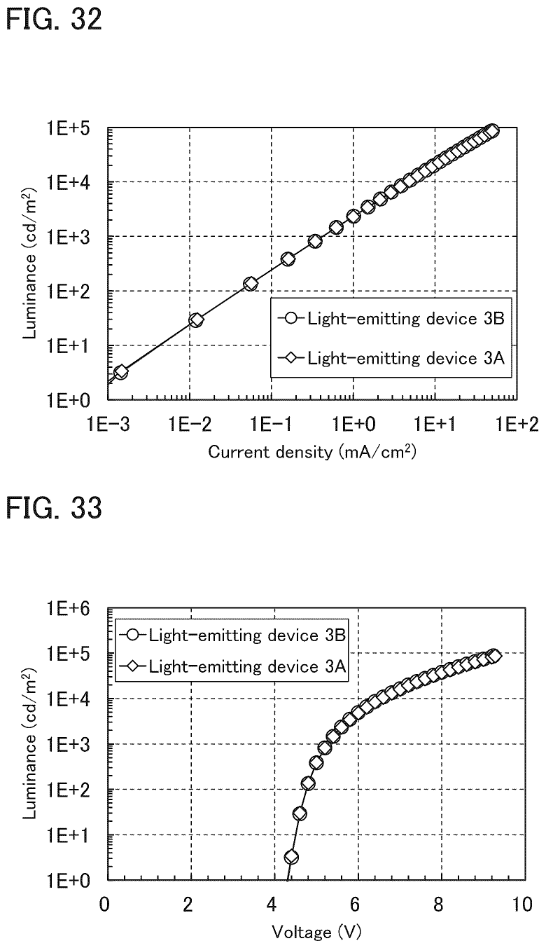

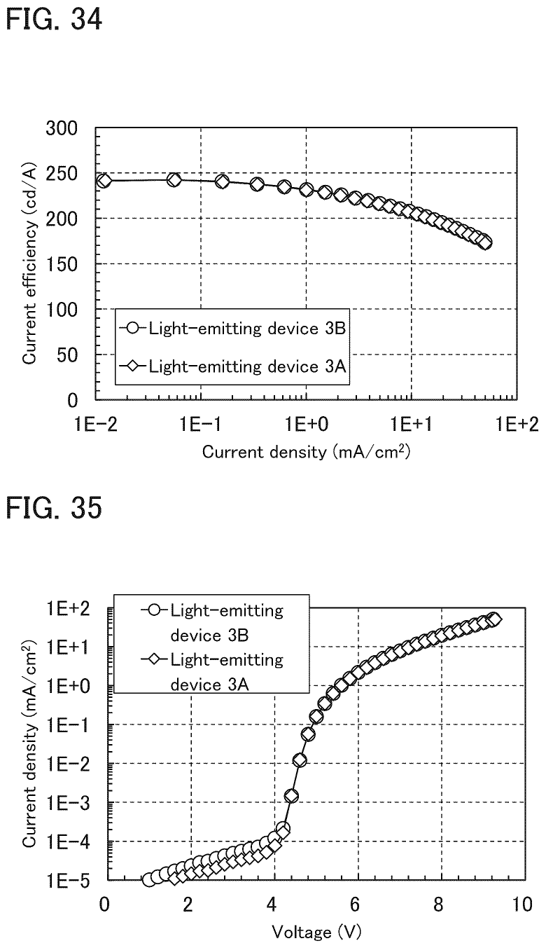

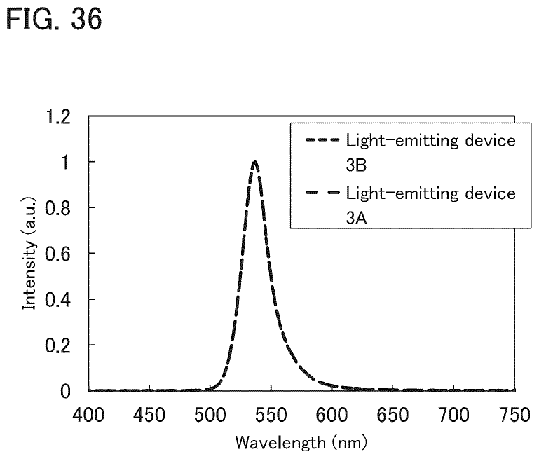

FIG. 32 shows the luminance-current density characteristics of the light-emitting devices 3A and 3B, FIG. 33 shows the luminance-voltage characteristics of the light-emitting devices 3A and 3B, FIG. 34 shows the current efficiency-current density characteristics of the light-emitting devices 3A and 3B, FIG. 35 shows the current density-voltage characteristics of the light-emitting devices 3A and 3B, and FIG. 36 shows the electroluminescence spectra of the light-emitting devices 3A and 3B. The table below shows the main characteristics of the light-emitting devices 3A and 3B at a current density of 50 mA/cm². Note that the luminance, CIE chromaticity, and electroluminescence spectra were measured with a spectroradiometer (SR-ULIR, TOPCON TECHNOHOUSE CORPORATION),

TABLE 13

| | | | Current | | | | Current |
|---|---|---|---|---|---|---|---|
| | Voltage | Current | density | Luminance | Chromaticity | Chromaticity | efficiency |
| | (V) | (mA) | (mA/cm²) | (cd/m²) | x | y | (cd/A) |
| Light-emitting | 9.3 | 2.0 | 50 | 86330 | 0.27 | 0.71 | 173 |
| device 3A | | | | | | | |
| Light-emitting | 9.2 | 2.0 | 50 | 86650 | 0.27 | 0.71 | 173 |
| device 3B | | | | | | | |

Furthermore, as shown in FIG. 36, the light-emitting devices 3A and 3B each emitted green light with peak wavelengths of 535 nm in their electroluminescence spectra.

FIG. 32 to FIG. 34 and the above table demonstrate that the light-emitting devices 3A and 3B are each a tandem light-emitting device with high current efficiency.

The above reveals that the light-emitting devices in this example are light-emitting devices that can be driven with a low driving voltage and have a high emission efficiency.

### Example 4

In this example, a device including only holes as carriers and a device including only electrons as carriers were fabricated as the structures of the light-emitting device of one embodiment of the present invention and a comparative light-emitting device, and the carrier-transport characteristics of the electron-injection buffer layer in each device were measured. The measurement results are described.

A device 4A(H1) and a device 4A(H2) each having a structure of the light-emitting device of one embodiment of the present invention and using only holes as carriers were fabricated, and a device 4B(H1), a device 4B(H2), a device 4C(H11), and a device 4C(H2) each having a structure of the comparative light-emitting device and using only holes as carriers were fabricated.

Similarly, a device 4A(E1) and a device 4A(E2) each having a structure of the light-emitting device of one embodiment of the present invention and using only electrons as carriers were fabricated, and a device 4B(E1), a device 4B(E2), a device 4C(E1), and a device 4C(E2) each having a structure of the comparative light-emitting device and using only electrons as carriers were fabricated.

Structural Formulas of organic compounds used in this example are shown below.

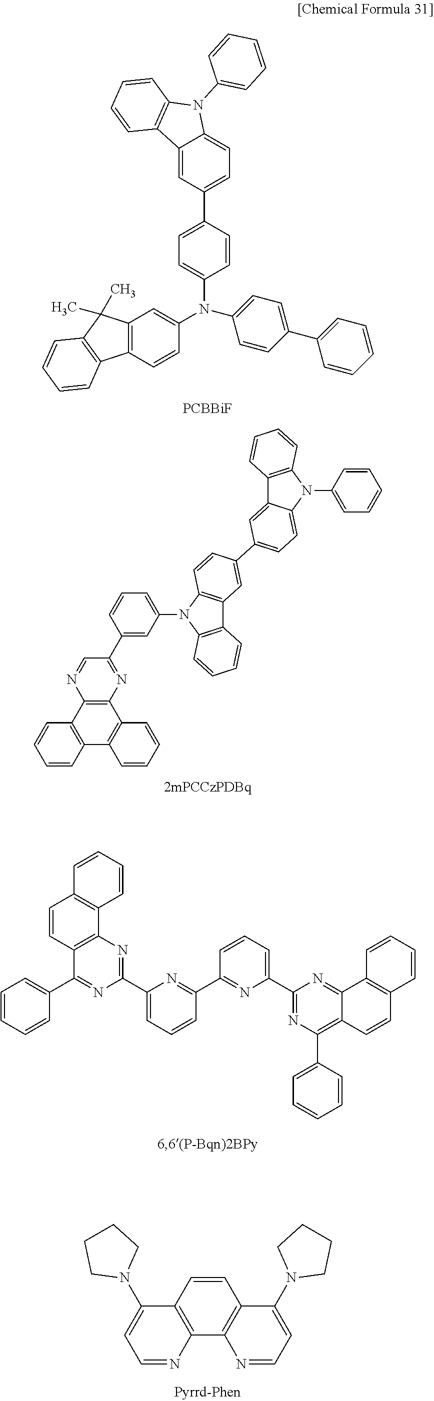

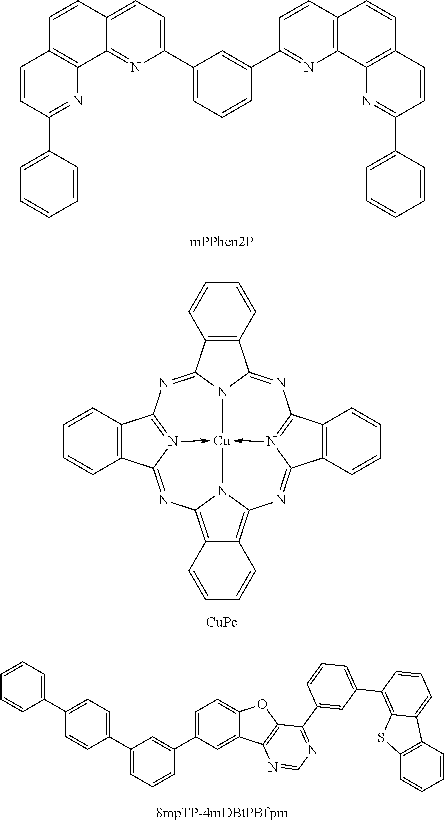

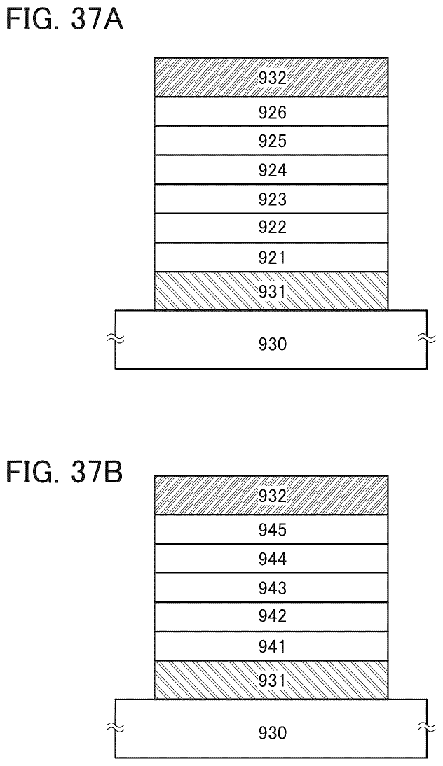

Note that each of the device 4A(H1), the device 4A(H2), the device 4B(H11), the device 4B(H2), the device 4C(H1), and the device 4C(H2) using only holes as carriers has a structure in which a layer h1 921, a layer h2 922, a layer h3 923, a layer h4 924, a layer h5 925, a layer h6 926, and an electrode 2 932 are stacked over an electrode 1 931 formed over a substrate 930 that is a glass substrate, as illustrated in FIG. 37A.

As illustrated in FIG. 37B, each of the device 4A(E1), the device 4A(E2), the device 4B(E1), the device 4B(E2), the device 4C((E1), and the device 4C((E2) using only electrons as carriers has a structure in which a layer e1 941, a layer e2 942, a layer e3 943, a layer e4 944, a layer e5 945, and the electrode 2 932 are stacked over the electrode 1 931 formed over the substrate 930 that is a glass substrate.

### <Fabrication Method of Device 4A(H1)>

First, indium tin oxide containing silicon oxide (ITSO) was deposited to a thickness of 70 nm over the substrate 930 that was a glass substrate by a sputtering method, so that the electrode 1 931 was formed. The electrode area was set to 4 mm² (2 mm×2 mm).

Next, in pretreatment for forming the device over the substrate, a surface of the substrate was washed with water and baking was performed at 200° C. for 1 hour. Then, the substrate was transferred into a vacuum evaporation apparatus where the internal pressure was reduced to approximately 1×10⁻⁴ Pa, and vacuum baking was performed at 170° C. for 30 minutes in a heating chamber of the vacuum evaporation apparatus. After that, natural cooling was performed for approximately 30 minutes.

Then, the substrate provided with the electrode 1 931 was fixed to a substrate holder provided in the vacuum evaporation apparatus such that the surface on which the electrode 1 931 was formed faced downward. The layer h1 921 was deposited to a thickness of 10 nm over the electrode 1 931 by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) by a resistance heating evaporation method so as to have a PCBBiF:OCHD-003 weight ratio of 1:0.03.

Next, the layer h2 922 was deposited to a thickness of 100 nm over the layer h1 921 by evaporation of PCBBiF.

After that, the layer h3 923 was deposited to a thickness of 10 nm over the layer h2 922 by evaporation of 2-{3-[3-(N-phenyl-9H-carbazol-3-yl)-9H-carbazol-9-yl]phenyl}dibenzo[f,hlquinoxaline (abbreviation: 2mPCCzPDBq).

Then, the layer h4 924 was deposited to a thickness of 10 nm over the layer h3 923 by co-evaporation of 2,2′-(2,2′-bipyridine-6,6′-diyl)bis(4-phenylbenzo[h]quinazoline) (abbreviation: 6,6′(P-Bqn)2BPy), 4,7-di-1-pyirolidinyl-1,10-phenanthroline (abbreviation: Pyrrd-Phen), and Li₂O by a resistance heating evaporation method so as to have a 6,6′(P-Bqn)2BPy:Pyrrd-Phen:Li₂O volume ratio of 0.5:0.5:0.02.

Next, the layer h5 925 was deposited to a thickness of 100 nm over the layer h4 924 by evaporation of PCBBiF.

Then, the layer h6 926 was deposited to a thickness of 50 nm over the layer h5 925 by co-evaporation of PCBBiF and OCI-ID-003 so as to have a PCBBiF:OCI-ID-003 ratio of 1:0.15.

After that, exposure to the air was performed for 1 hour. Then, the substrate was transferred into a vacuum evaporation apparatus where the internal pressure was reduced to approximately 1×10⁻⁴ Pa, and heating was performed at 100° C. for 60 minutes in a heating chamber of the vacuum evaporation apparatus.

Then, the electrode 2 932 was deposited to a thickness of 150 nm over the layer h6 926 by evaporation of Al.

Through the above process, the device 4A(H1) was fabricated.

### <Fabrication Method of Device 4A(H2)>

Next, a method for fabricating the device 4A(H2) is described.

In the device 4A(H2), the layer h6 926 was formed without the exposure to the air and heating step after the formation of the layer h6 926 in the fabrication method of the device 4A(H1), and then Al was deposited to a thickness of 150 nm by evaporation to form the electrode 2 932.

Other components were fabricated in a manner similar to that of the device 4A(H1). That is, the device 4A(H2) is different from the device 4A(H1) only in the presence or absence of the exposure to the air and the heating step after the formation of the layer h6 926.

### <Fabrication Method of Device 4B(H1)>

Next, a method for fabricating the device 4B(H1) is described.

The device 4B(H1) was fabricated in a manner similar to that of the device 4A(H1) except that the layer h4 924 was deposited to a thickness of 10 nm by co-evaporation of 2,2′-(1,3-phenylene)bis(9-phenyl-1,10-phenanthroline) (abbreviation: mPPhen2P) and Li₂O so as to have an mPPhen2P:Li₂O volume ratio of 1:0.02.

That is, the device 4B(H1) is different from the device 4A(H1) only in the structure of the layer h4.

### <Fabrication Method of Device 4B(H2)>

Next, a method for fabricating the device 4B(H2) is described,

In the device 4B(H2), the layer h6 926 was formed without the exposure to the air and heating step after the formation of the layer h6 926 in the fabrication method of the device 4B(H1), and then Al was deposited to a thickness of 150 nm by evaporation to form the electrode 2 932.

Other components were fabricated in a manner similar to that of the device 4B(H1). That is, the device 4B(112) is different from the device 4B(H1) only in the presence or absence of the exposure to the air and the heating step after the formation of the layer h6 926.

### <Fabrication Method of Device 4C(H1)>

Next, a method for fabricating the device 4C(H1) is described.

The device 4C(H1) was fabricated in a manner similar to that of the device 4A(H1) except that the layer h4 924 was deposited to a thickness of 10 nm by co-evaporation of mPPhen2P, Pyrrd-Phen, and LiO so as to have an mPPhen2P:Pyrrd-Phen:Li₂O volume ratio of 0.5:0.5:0.02.

That is, the device 4C(H1) is different from the device 4A(H1) only in the structure of the layer h4.

### <Fabrication Method of Device 4C(H2)>

Next, a method for fabricating the device 4C(H2) is described.

In the device 4C(H2), the layer h6 926 was formed without the exposure to the air and heating step after the formation of the layer h6 926 in the fabrication method of the device 4C(H1), and then Al was deposited to a thickness of 150 nm by evaporation to form the electrode 2 932.

Other components were fabricated in a manner similar to that of the device 4C(H1). That is, the device 4C(H2) is different from the device 4C(H1) only in the presence or absence of the air exposure and the heating step after the formation of the layer h6 926.

Note that each of the device 4A(H1), the device 4A(H2), the device 4B(H1), the device 4B(H2), the device 4C(H1), and the device 4C(H2) uses only holes as carriers.

### <Fabrication Method of Device 4A(E1)>

The formation of the electrode 1 and the pretreatment for the device 4A(E1) were performed in a manner similar to those for the device 4A(H1).

Next, the substrate provided with the electrode 1 931 was fixed to a substrate holder provided in the vacuum evaporation apparatus such that the surface on which the electrode 1 931 was formed faced downward, and the layer e1 941 was deposited to a thickness of 50 nm over the electrode 1 931 by evaporation of 8-(1,1′:4′,1″-terphenyl-3-yl)-4-[3-(dibenzothiophen-4-yl)phenyl]-[1]benzofuro-[3,2-d]pyrimidine (abbreviation: 8mpTP-4mDBtPBfpm) by a resistance heating evaporation method.

Next, the layer e2 942 was deposited to a thickness of 10 nm over the layer e1 941 by evaporation of 2mPCCzPDBq.

Next, the layer e3 943 was deposited to a thickness of 10 nm over the layer e2 942 by co-evaporation of 6,6′(P-Bqn)2BPy, Pyrrd-Phen, and Li₂O by a resistance heating evaporation method so as to have a 6,6′(P-Bn)2BPy:Pyrrd-Phen: Li₂O volume ratio of 0.5:0.5:0.02.

Then, the layer e4 944 was deposited to a thickness of 2 nm over the layer e3 943 by evaporation of copper phthalocyanine (abbreviation: CuPc).

Next, the layer e5 945 was deposited to a thickness of 50 nm over the layer e4 944 by co-evaporation of PCBBiF and OCHD-003 so as to have a PCBBiF:OCHD-003 ratio of 1:0.15,

After that, exposure to the air was performed for 1 hour. Then, the substrate was transferred into a vacuum evaporation apparatus where the internal pressure was reduced to approximately 1×10⁻⁴ Pa, and heating was performed at 100° C. for 60 minutes in a heating chamber of the vacuum evaporation apparatus.

Then, the electrode 2 932 was deposited to a thickness of 150 nm over the layer e5 945 by evaporation of Al.

Through the above process, the device 4A(E1) was fabricated.

### <Fabrication Method of Device 4A(E2)>

Next, a method for fabricating the device 4A(E2) is described.

In the device 4A(E2), the layer e5 945 was formed without the exposure to the air and heating step after the formation of the layer e5 945 in the fabrication method of the device 4A(E1), and then Al was deposited to a thickness of 150 nm by evaporation to form the electrode 2 932.

Other components were fabricated in a manner similar to that of the device 4A(E1),

### <Fabrication Method of Device 4B(E1)>

Next, a method for fabricating the device 4B(E1) is described.

The device 4B(E1) was fabricated in a manner similar to that of the device 4A(E1) except that the layer e3 943 was formed to a thickness of 10 nm by co-evaporation of mPPhen2P and Li₂O to have an mPPhen2P:Li₂O volume ratio of 1:0.02.

### <Fabrication Method of Device 4B(E2)>

Next, a method for fabricating the device 4B(E2) is described.

In the device 4B(E2), the layer e5 945 was formed without the exposure to the air and heating step after the formation of the layer e5 945 in the fabrication method of the device 4B(E1), and then Al was deposited to a thickness of 150 nm by evaporation to form the electrode 2 932.

Other components were fabricated in a manner similar to that of the device 4B(E1).

### <Fabrication Method of Device 4C(E1)>

Next, a method for fabricating the device 4C(E1) is described.

The device 4C(E1) was fabricated in a manner similar to that of the device 4A(E1) except that the layer e3 943 was formed to a thickness of 10 nm by co-evaporation of mPPhen2P, Pyrrd-Phen, and Li₂O so as to have an mPPhen2P:Pyrrd-Phen:Li₂O volume ratio of 0.5:0.5:0.02.

### <Fabrication Method of Device 4C(E2)>

Next, a method for fabricating the device 4C(E2) is described.

In the device 4C(E2), the layer e5 945 was formed without the exposure to the air and heating step after the formation of the layer e5 945 in the fabrication method of the device 4C(E1), and then A1 was deposited to a thickness of 150 nrn by evaporation to form the electrode 2 932.

Other components were fabricated in a manner similar to that of the device 4C(E1).

Note that each of the device 4A(E1), the device 4A(E2), the device 4B(E1), the device 4B(E2), the device 4C(E1), and the device 4C(E2) uses only electrons as carriers.

The structures of the device 4A(I-H1), the device 4A(I-12), the device 4B(H1), the device 4B(H2), the device 4C(H1), and the device 4C(H2) are listed in the following table. Note that Condition 4-1 in the table is shown in a separate table.

TABLE 14

| | | | | | | |
|---|---|---|---|---|---|---|
| Thickness | Device | Device | Device | Device | Device | Device |
| (nm) | 4A(H1) | 4A(H2) | 4B(H1) | 4B(H2) | 4C(H1) | 4C(H2) |

| | | |
|---|---|---|
| Electrode 2 | 150 | Al |

| | | | | | | |
|---|---|---|---|---|---|---|
| Exposure to the air and | ◯ | — | ◯ | — | ◯ | — |
| heat treatment | | | | | | |

| | | |
|---|---|---|
| Layer h6 | 50 | PCBBiF:OCHD-003 |
| | | (1:0.15) |
| Layer h5 | 100 | PCBBiF |
| Layer h4 | 10 | Condition 4-1 |
| Layer h3 | 10 | 2mPCCzPDBq |
| Layer h2 | 100 | PCBBiF |
| Layer h1 | 10 | PCBBiF:OCHD-003 |
| | | (1:0.03) |
| Electrode 1 | 70 | ITSO |

TABLE 15

| | Condition 4-1 for Layer h4 |
|---|---|
| Device 4A(H1) | 6,6′(P-Bqn)2BPy:Pyrrd-Phen:Li₂O |
| Device 4A(H2) | (0.5:0.5:0.02) |
| Device 4B(H1) | mPPhen2P:Li₂O |
| Device 4B(H2) | (1:0.02) |
| Device 4C(H1) | mPPhen2P:Pyrrd-Phen:Li₂O |
| Device 4C(H2) | (0.5:0.5:0.02) |

The structures of the device 4A(E1), the device 4A(E2), the device 4B(E1), the device 4B(E2), the device 4C(E1), and the device 4C(E2) are listed in the following table. Note that Condition 4-2 in the table is shown in a separate table.

TABLE 16

| | | | | | | |
|---|---|---|---|---|---|---|
| Thickness | Device | Device | Device | Device | Device | Device |
| (nm) | 4A(E1) | 4A(E2) | 4B(E1) | 4B(E2) | 4C(E1) | 4C(E2) |

| | | |
|---|---|---|
| Electrode 2 | 150 | Al |

| | | | | | | |
|---|---|---|---|---|---|---|
| Exposure to the air and | ◯ | — | ◯ | — | ◯ | — |
| heat treatment | | | | | | |

| | | |
|---|---|---|
| Layer e5 | 50 | PCBBiF:OCHD-003 |
| | | (1:0.15) |
| Layer e4 | 2 | CuPc |
| Layer e3 | 10 | Condition 4-2 |
| Layer e2 | 10 | 2mPCCzPDBq |
| Layer e1 | 50 | 8mpTP-4mDBtPBfpm |
| Electrode 1 | 70 | ITSO |

TABLE 17

| | Condition 4-2 for Layer e3 |
|---|---|
| Device 4A(E1) | 6,6′(P-Bqn)2BPy:Pyrrd-Phen:Li₂O |
| Device 4A(E2) | (0.5:0.5:0.02) |
| Device 4B(E1) | mPPhen2P:Li₂O |
| Device 4B(E2) | (1:0.02) |
| Device 4C(E1) | mPPhen2P:Pyrrd-Phen:Li₂O |
| Device 4C(E2) | (0.5:0.5:0.02) |

### <Device Characteristics>

The device 4A(H1). the device 4A(H2), the device 413(H1). the device 4B(H2), the device 4C(H1), the device 4C(H2), the device 4A(E1), the device 4A(E2), the device 4B(E1), the device 4B(E2), the device 4C(E1), and the device 4C(E2) were each sealed with a glass substrate in a glove box containing a nitrogen atmosphere (a sealing material was applied to surround the devices and UV treatment and heat treatment at 80° C. for 1 hour were performed at the time of sealing), and then the current density-voltage characteristics of the devices were measured.

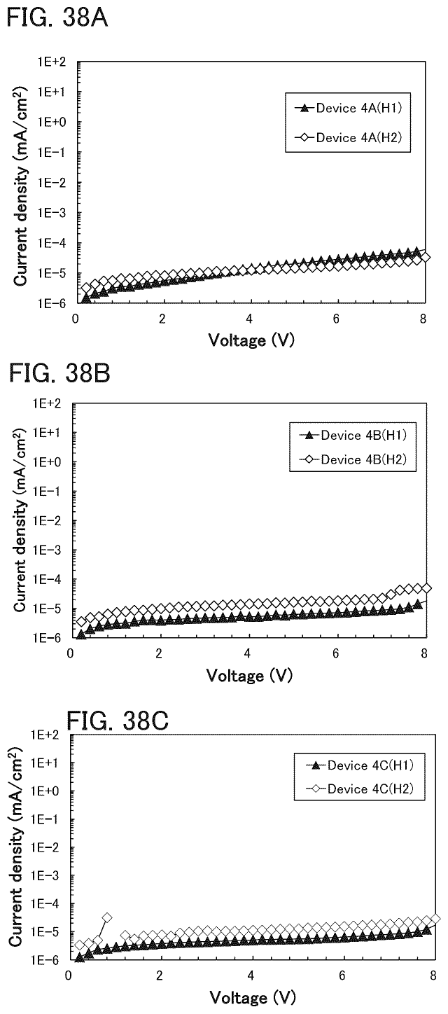

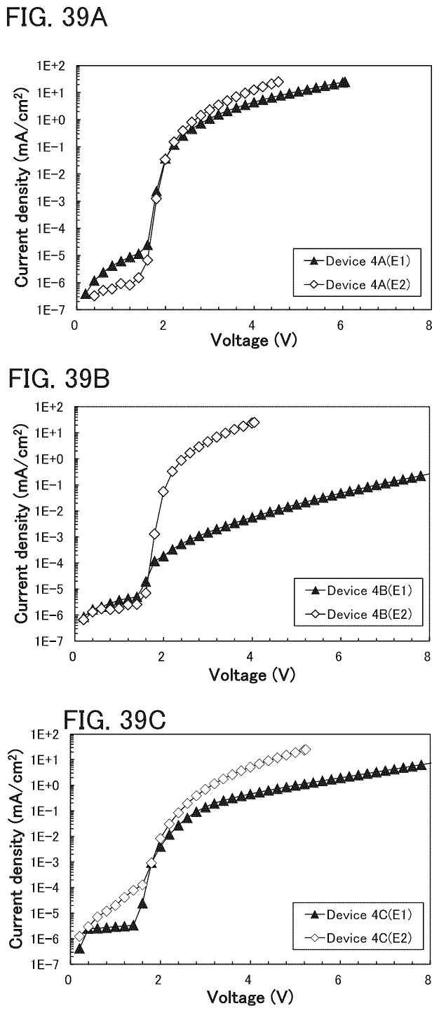

FIG. 38A shows the current density-voltage characteristics of the device 4A(H1) and the device 4A(H2), FIG. 38B shows the current density-voltage characteristics of the device 4B(H1) and the device 4B(H2), FIG. 38C shows the current density-voltage characteristics of the device 4C(H1) and the device 4C(H2), FIG. 39A shows the current density-voltage characteristics of the device 4A(E1) and the device 4A(E2), FIG. 39B shows the current density-voltage characteristics of the device 4B(E1) and the device 4B(E2), and FIG. 39C shows the current density-voltage characteristics of the device 4C(E1) and the device 4C(E2).

FIG. 38A shows that the layer h4 924 having the electron-injection buffer region of one embodiment of the present invention hardly allows holes to flow. Similarly, FIGS. 38B and 38C show that the layer h4 924 having the electron-injection buffer region for comparison also hardly allows holes to flow. In addition, the results shows no significant difference between the presence and absence of exposure to the air and heat treatment.

FIG. 39A shows that the device 4A(E1) and the device 4A(E2) each including the layer e3 having the electron-injection buffer region of one embodiment of the present invention have a favorable electron-transport property. In other words, the layer e3 having the electron-injection buffer region of one embodiment of the present invention is a layer having a favorable electron-transport property even after or without exposure to the air and heat treatment.

Meanwhile, as apparent from FIGS. 39B and 39C, among the device 4B(E1), the device 4B(E2), the device 4C(E1), and the device 4C(E2) each including the layer e3 having the electron-injection buffer region for comparison, the electron-transport properties of the device 4B(E1) and the device 4C(E1) that were subjected to exposure to the air and heat treatment are significantly decreased.

As described above, the electron-transport property of the layer e3 having the electron-injection buffer region for comparison significantly decreases when the layer e3 is exposed to the air and subjected to heat treatment. That is, in the light-emitting device including the electron-injection buffer region for comparison, performing processing by photolithography in fabricating the light-emitting device reduces the electron-transport property and increases the driving voltage. Meanwhile, in the light-emitting device including the electron-injection buffer region of one embodiment of the present invention, the electron-transport property hardly decreases even after exposure to the air and heat treatment; thus, even when processing by a photolithography method is performed, a light-emitting device having favorable characteristics in which an increase in driving voltage is inhibited can be obtained.

Accordingly, a display device using the light-emitting device of one embodiment of the present invention can be a light-emitting apparatus having high resolution and low driving voltage.

### Example 5

In this example, a light-emitting device 5A, which is a light-emitting device of one embodiment of the present invention, and a comparative light-emitting device 5B are described. The light-emitting devices 5A and 5B were fabricated through a process of processing the organic compound layer by a photolithography method. The light-emitting devices 5A and 5B were each fabricated by forming organic compound layers so as to make a resolution of 3207 ppi. Structural Formulas of organic compounds used in the light-emitting devices 5A and 5B are shown below.

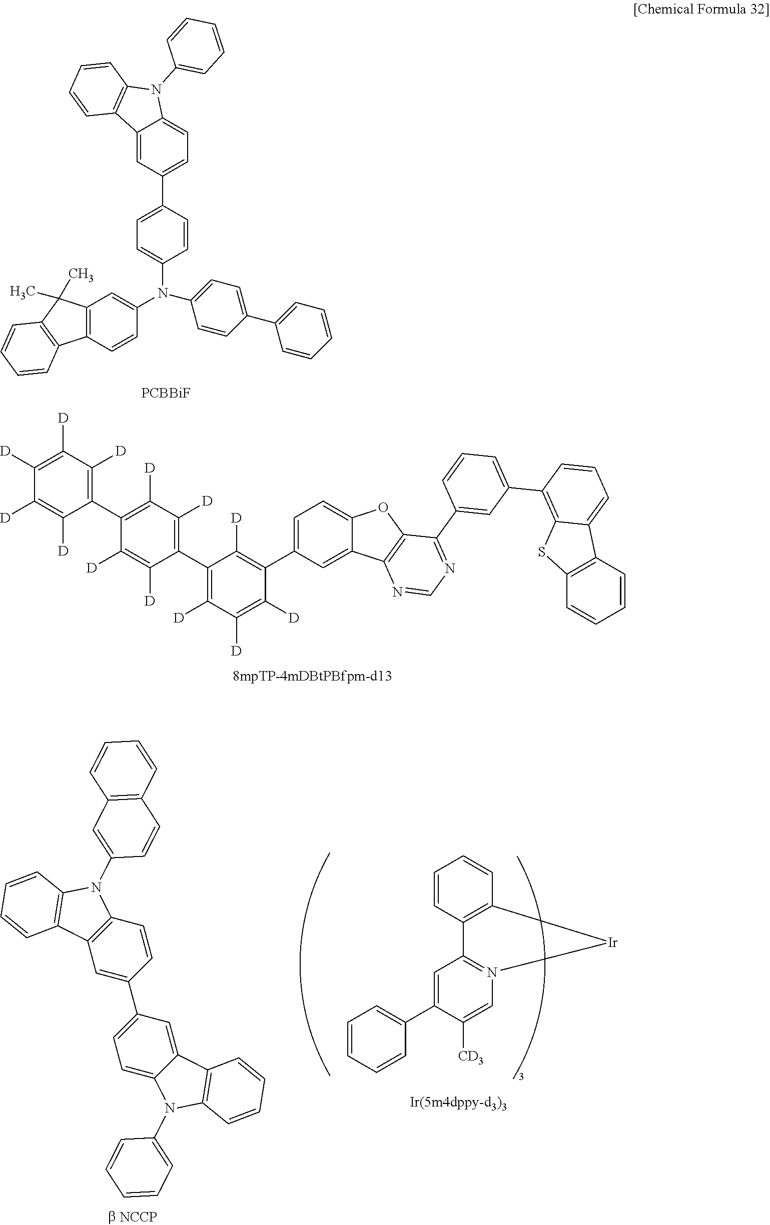

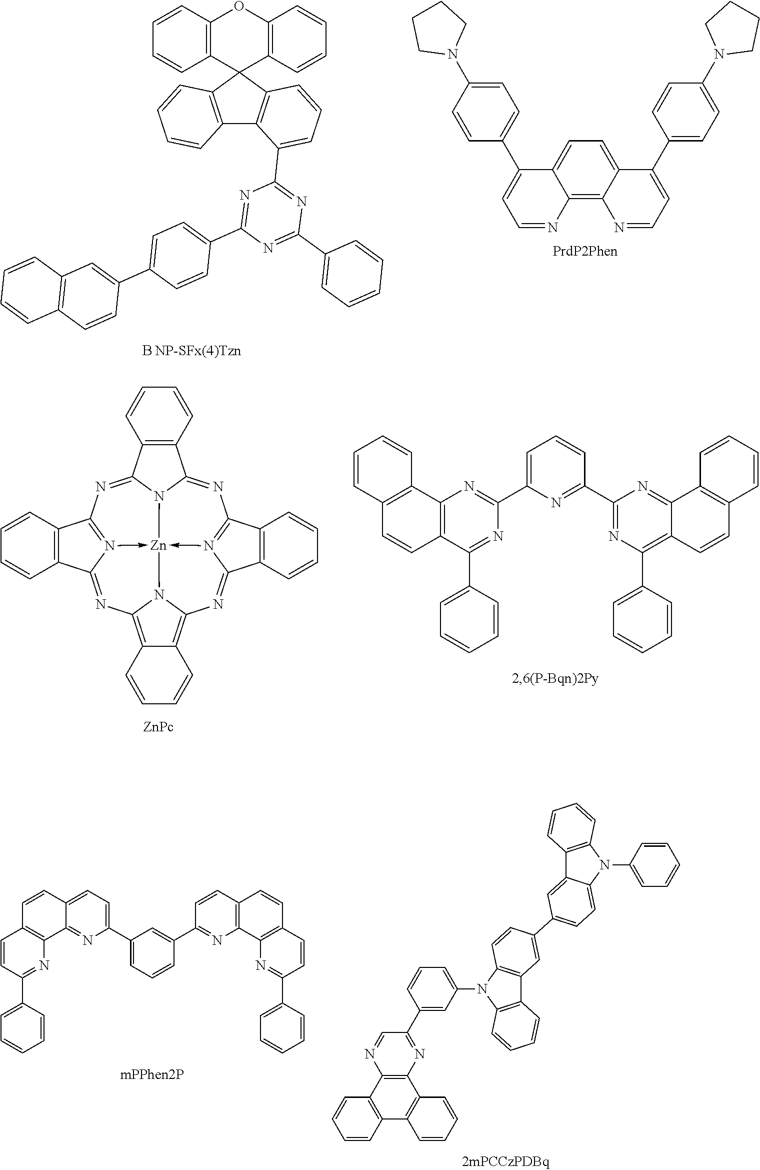

### <Fabrication Method of Light-Emitting Device 5A>

Over a silicon substrate provided with wirings, 1-nm-thick titanium nitride (TiNₓ), 49-nm-thick titanium (Ti), 70-nm-thick aluminum (Al), and 2-nm-thick T₁ were stacked from the substrate side, After that, a 10-nm-thick indium tin oxide containing silicon oxide (ITSO) was stacked thereover by a sputtering method. Then, processing by a lithography method was performed to make a resolution of 3207 ppi, and the first electrodes were formed. Note that 1TSO functions as an anode, and is regarded as the first electrode together with the stacked-layer structure of T₁ and Al described above,

Note that the first electrodes were formed to make matrix arrangement of 251×251 pixels) in an area of 2 mm×2 mm. This shape and arrangement correspond to a resolution of 3207 ppi.

Next, in pretreatment for forming the light-emitting devices over the substrate, the substrate was subjected to heat treatment at 120° C. for 120 seconds, 1,1,1,3,3,3-hexamethyldisilazane (abbreviation: HMDS) was then vaporized and sprayed for 120 seconds to the substrate heated to 60° C. This can make it difficult for the stacked-layer film formed over the first electrode to be separated from the first electrode in the fabrication process.

After that, the substrate was transferred into a vacuum evaporation apparatus where the internal pressure was reduced to approximately 1×10- Pa, and was subjected to vacuum baking at 170° C. for 60 minutes in a heating chamber of the vacuum evaporation apparatus, and then, the substrate was cooled down for approximately 30 minutes.

Then, the substrate provided with the first electrode was fixed to a substrate holder provided in the vacuum evaporation apparatus such that the surface on which the first electrode was formed faced downward. The hole-injection layer was deposited to a thickness of 10 nm over the first electrode by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) by an evaporation method so as to have a PCBBiF:OCHD-003 weight ratio of 1:0.03.

The first hole-transport layer was deposited to a thickness of 42.5 nm over the hole-injection layer by evaporation of PCBBiF.

Next, the first light-emitting layer was deposited to a thickness of 40 nm over the first hole-transport layer by co-evaporation of 8-(1,1′: 4′, 1″-terphenyl-3-yl-2,4,5,6,2′, 3′, 5′, 6′, 2″, 3″, 4″, 5″, 6″-d₁₃)-4-[3-(dibenzothiophen-4-yl)phenyl]-[1]benzofuro[3,2-d]pyrimidine (abbreviation: 8mpTP-4mDBtPBfpm-d₁₃), 9-(2-naphthyl)-9′-phenyl-9H,9′H-3,3′-bicarbazole (abbreviation: [NCCP), and tris{2-[5-(methyl-d₃)-4-phenyl-2-pyridinyl-KiVNphenyl-κC}iridiurn(III) (abbreviation: Ir(5m4dppy-d₃)3) so as to have a 8mpTP-4mDBtPBfpm-d₁₃:βNCCP: Ir(5m4dppy-d₃)₃ weight ratio of 0.5:0.5:0.1.

The first electron-transport layer was deposited to a thickness of 10 nm by evaporation of 2-[4-(2-naphthalenyl)phenyl]-4-phenyl-6-spiro[91-fluorene-9,9′-[9H]xanthen]-4-yH,3,5-triazine (abbreviation: P3NP-SFx(4)Tzn).

After the formation of the first electron-transport layer, the first layer of the intermediate layer was formed to a thickness of 5 nm by co-evaporation of 2,2′-(pyridine-2,6-diyl)bis(4-phenylbenzo[h]quinazoline) (abbreviation: 2,6(P-Bqn)2Py), 4,7-bis[4-(1-pyrrolidinyl)phenyl]-1,10-phenanthroline (abbreviation: PrdP2Phen), and Li₂O so as to have a 2,6(P-Bqn)2Py: PrdP2Phen:Li₂O volume ratio of 2.5:2.5:0.05.

Then, the third layer of the intermediate layer was formed by forming a film of zinc phthalocyanine (abbreviation: ZnPc) to a thickness of 2 nm.

Furthermore, the second layer of the intermediate layer was deposited to a thickness of nm by co-evaporation of PCBBiF and OCHD-003 so as to have a PCBBiF:OCHD-003 weight ratio of 1:0.15.

Next, the second hole-transport layer was deposited to a thickness of 55 nm over the intermediate layer by evaporation of PCBBiF.

The second light-emitting layer was deposited to a thickness of 40 nm formed over the second hole-transport layer by co-evaporation of 8mpTP-4mDBtPBfpm-d₁₃, J3NCCP, and Ir(5m4dppy-d₃)3 so as to have an 8mpTP-4mDBtPBfpm-d₁₃:NCCP:Ir(5m4dppy-d₃)₃ weight ratio of 0.5:0.5:0.1.

Then, 2-{3-[3-(N-phenyl-9H-carbazol-3-yl)-9H-carbazol-9-yl]phenyl}dibenzo[f,h]quinoxaline (abbreviation: 2mPCCzPDBq) was deposited to a thickness of nm by evaporation, and then 2,2′-(1,3-phenylene)bis(9-phenyl-1,10-phenanthroline) (abbreviation: mPPhen2P) was deposited to a thickness of 15 nm by evaporation, whereby the second electron-transport layer was formed.

After the formation of the second electron-transport layer, processing by a photolithography method and heat treatment were performed.

### <<Processing by Photolithography Method and Heat Treatment>

The substrate provided with the second electron-transport layer and the components thereunder was taken out from the vacuum evaporation apparatus and exposed to the air, and then, as a first sacrificial layer, aluminum oxide was deposited to a thickness of 30 nm by an ALD method using trimethylaluminum (abbreviation: TMA) as a precursor and water vapor as an oxidizer.

Next, a film of tungsten (W) serving as a second sacrificial layer was deposited to a thickness of 54 nm over the first sacrificial layer by a sputtering method.

A photoresist was applied onto the second sacrificial layer, light exposure and development were performed, and processing was performed such that an end portion of the second sacrificial layer was located inward from an end surface of the first electrode. This makes it possible that the organic compound layer of the light-emitting device 5A is formed by processing to have a shape such that an end portion of the organic compound layer is located inward from the end surface of the first electrode.

The second sacrificial layer was processed using an etching gas containing SF₆ with the use of the photoresist as a mask and then, the first sacrificial layer was processed using an etching gas containing fluoroform (CHF₃), helium (He), and methane (CH₄) at a CHF₃:He:CH₄ flow rate ratio of 16.5:118.5:15 with the use of the second sacrificial layer as a hard mask. Then, organic compound layers (the hole-injection layer, the first hole-transport layer, the first light-emitting layer, the first electron-transport layer, the intermediate layer, the second hole-transport layer, the second light-emitting layer, and the second electron-transport layer) were processed using an etching gas containing oxygen (O₂).

After the organic compound layer was formed by the processing, the second sacrificial layer was removed using an etching gas containing SF₆, whereas the first sacrificial layer was left. Then, aluminum oxide serving as a protective film was deposited to a thickness of 15 nm by an ALD method.

Next, a layer of a photosensitive high molecular material was formed over the first electrode over the protective film by a photolithography method. After that, heating was performed at 100° C. in an air atmosphere for 10 minutes, and then the first sacrificial layer and the protective film in an unnecessary portion were removed using a mixed acid aqueous solution containing hydrofluoric acid (H), so that the second electron-transport layer was exposed. At this time, the layer of the photosensitive high molecular material functions as a resist.

The substrate, over which the second electron-transport layer was exposed, was transferred into a vacuum evaporation apparatus where the internal pressure was reduced to approximately 1×10⁻⁴ Pa, and was subjected to vacuum baking at 100° C. for 90 minutes in a heating chamber of the vacuum evaporation apparatus.

Next, the electron-injection layer was deposited to a thickness of 1.5 nm by co-evaporation of lithium fluoride and ytterbium so as to have a LiF:Yb volume ratio of 1:0.5. Then, the second electrode was deposited to a thickness of 15 nm by co-evaporation silver (Ag) and magnesium (Mg) so as to have a Ag:Mg volume ratio of 1:0.1. Over the second electrode, PCBBiF was deposited to a thickness of 80 nm by evaporation as a cap layer.

### <Fabrication Method of Light-Emitting Device 5B>

The light-emitting device 5B was fabricated in a manner similar to the light-emitting device 5A, except that the first electrode had a structure of 50-nm-thick titanium (Ti), 70-nm-thick aluminum (Al), and 6-nm-thick titanium in contact with ITSO, from the substrate side; one-hour baking was performed at 300° C. in the atmosphere after the formation of the titanium films; a SiON film was formed after the formation of the first electrode; a sidewall of SiON was formed to cover the end portion of the first electrode; the thickness of the first hole-transport layer in the organic compound layer was 35 nm; 2mPCCzPDBq was deposited as the first electron-transport layer; and mPPhen2P and Li₂O were co-deposited so as to have an mPPhen2P:Li₂O volume ratio of 1:0.01 as the first layer of the intermediate layer. Other components were fabricated in a manner similar to that of the light-emitting device 5A.

Table 18 lists the structures of the light-emitting devices 5A and 5B.

TABLE 18

| | | | Light-emitting | Light-emitting |
|---|---|---|---|---|
| | | Thickness | device 5A | device 5B |
| Cap layer | | 80 nm | PCBBiF | |
| Second electrode | | 15 nm | Ag:Mg (1:0.1) | |
| Electron-injection layer | | 1.5 nm | LiF:Yb (1:0.5) | |
| Processing by photolithography | | | Processing by photolithography was performed. | |
| Second electron- | 2 | 15 nm | mPPhen2P | |
| transport Layer | 1 | 10 nm | 2mPCCzPDBq | |
| Second light-emitting layer | | 40 nm | 8mpTP-4mDBtPBfpm-d₁₃:βNCCP:Ir(5m4dppy-d₃)₃ | |
| | | | (0.5:0.5:0.1) | |
| Second hole-transport layer | | 55 nm | PCBBiF | |
| Intermediate layer | Second layer | 10 nm | PCBBiF:OCHD-003 (1:0.15) | |
| | Third layer | 2 nm | ZnPc | |
| | First layer | 5 nm | 2,6(P-Bqn) | mPPhen2P:Li₂O |
| | | | 2Py:PrdP2Phen:Li₂O | (1:0.01) |
| | | | (2.5:2.5:0.05) | |

| First electron-transport layer | | 10 nm | BNP-SFx(4)Tzn 2mPCCzPDBq |
|---|---|---|---|
| First light-emitting layer | | 40 nm | 8mpTP-4mDBtPBfpm-d₁₃:βNCCP:Ir(5m4dppy-d₃)₃ |
| | | | (0.5:0.5:0.1) |
| First hole-transport layer | | *4 | PCBBiF |
| Hole-injection layer | | 10 nm | PCBBiF:OCHD-003 (1:0.03) |
| First electrode | 5 | 10 nm | ITSO |
| | 4 | *3 | Ti |
| | 3 | 70 nm | Al |
| | 2 | *2 | Ti |
| | 1 | *1 | TiNx |

*1 Light-emitting device 5A: 1 nm, Light-emitting device 5B: 0 nm
*2 Light-emitting device 5A: 49 nm, Light-emitting device 5B: 50 nm
*3 Light-emitting device 5A: 2 nm, Light-emitting device 5B: 6 nm
*4 Light-emitting device 5A: 42.5 nm, Light-emitting device 5B: 35 nm

The light-emitting devices fabricated were sealed using a glass substrate in a glove box containing a nitrogen atmosphere so as not to be exposed to the air, Specifically, a UV curable sealing material was applied to surround the devices, only the sealing material was irradiated with UV while the light-emitting devices were. not irradiated with the UV, and heat treatment was performed at 80′° C. under an atmospheric pressure for 1 hour. Then, the initial characteristics of the light-emitting devices were measured.

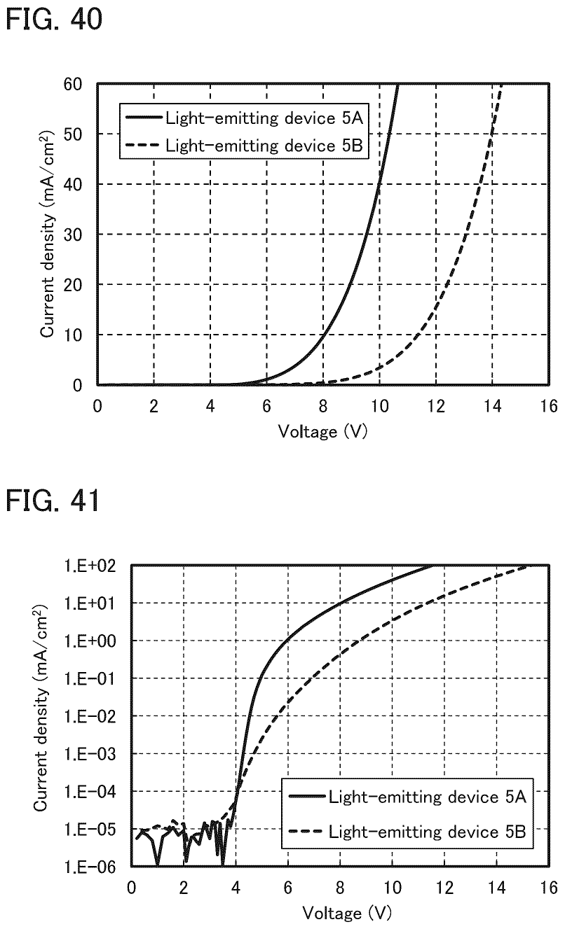

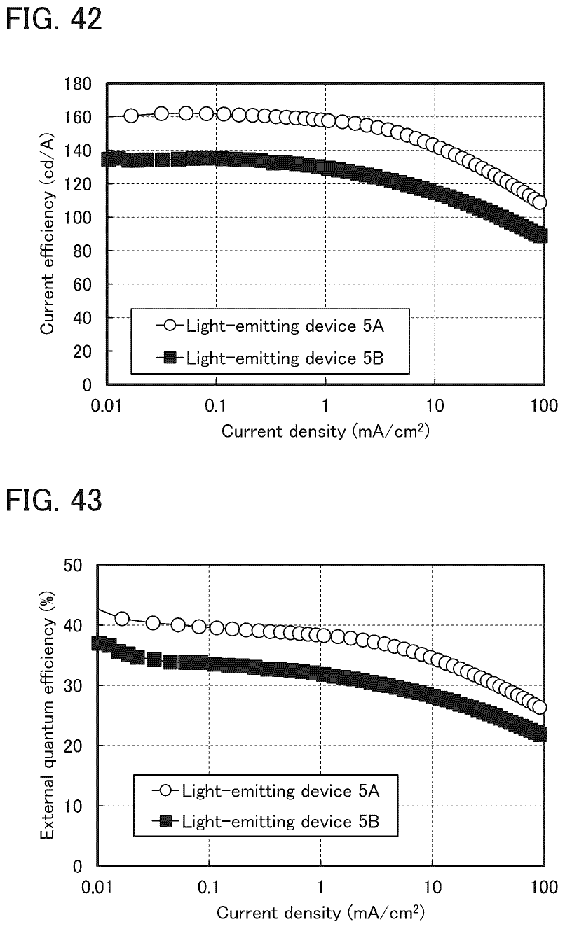

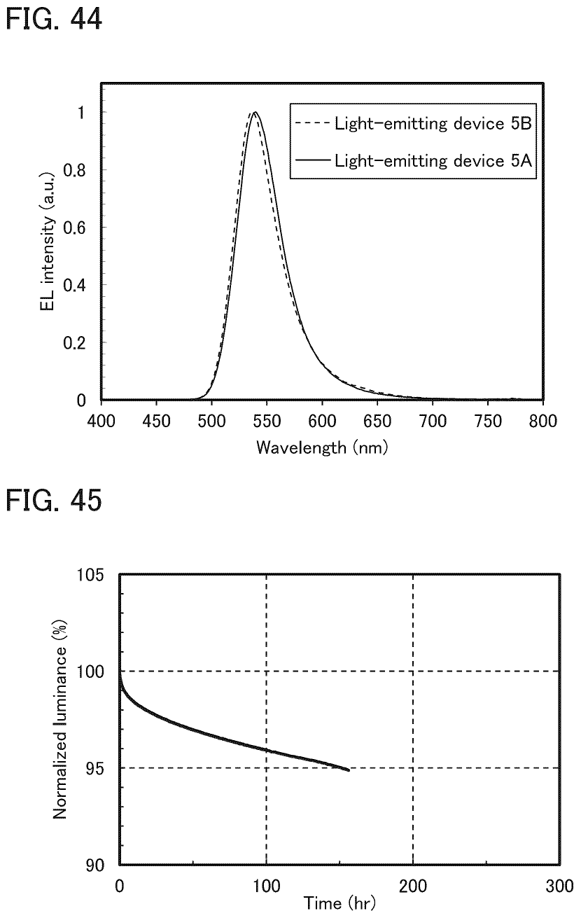

Next, FIGS. 40 and 41 show the current density—voltage characteristics of the light-emitting devices 5A and 5B, FIG. 42 shows the current efficiency-current density characteristics of the light-emitting devices 5A and 5B, FIG. 43 shows the external quantum efficiency-current density characteristics of the light-emitting devices 5A and 5B3, FIG. 44 shows the electroluminescence spectra of the light-emitting devices 5A and 51B, and FIG. 45 shows the time dependence of normalized luminance at a current density of 46.4 mA/cm^{z}(corresponding to 15000 cd/m², white emission (D65)) of the light-emitting device 5A.

Table 19 shows the main characteristics of the light-emitting devices 5A and 5B at a luminance of approximately 1000 cd/m². The luminance, CIE chromaticity, and electroluminescence spectra were measured at normal temperature with a spectroradiometer (SR-ULIR, TOPCON TECHNOHOUSE CORPORATION). The external quantum efficiency was calculated from the luminance and the electroluminescence spectra measured with the spectroradiometer, on the assumption that the devices had Lambertian light-distribution characteristics,

TABLE 19

| | | | Current | | | Current |
|---|---|---|---|---|---|---|
| | Voltage | Current | density | Chromaticity | Chromaticity | efficiency |
| | (V) | (mA) | (mA/cm²) | x | y | (cd/A) |
| Light-emitting | 7.6 | 0.028 | 0.70 | 0.33 | 0.65 | 147 |
| device 5A | | | | | | |
| Light-emitting | 11.4 | 0.035 | 0.87 | 0.32 | 0.65 | 115 |
| device 5B | | | | | | |

As described above, the light-emitting device 5A of one embodiment of the present invention includes, as the first layer of the intermediate layer, the metal or metal compound, the first organic compound having a f-electron deficient heteroaromatic ring, and the second organic compound having two or more heteroaromatic rings that are bonded or condensed to each other and include three or more heteroatoms in total. It is thus demonstrated that the light-emitting device 5A has lower driving voltage and higher characteristics than the light-emitting device 5B having the intermediate layer for comparison.

Note that the light-emitting devices 5A and 5B were both processed by a photolithography method. The driving voltage of the light-emitting device 5B is significantly increased by being affected by the processing, whereas the light-emitting device 5A of one embodiment of the present invention is less likely to be affected by the processing and can have favorable characteristics even after processing by a photolithography method.

FIG. 45 shows the time dependence of normalized luminance of the light-emitting device 5A at a current density of 46.4 mA/cm², which is the current density when the luminance of green light emission to obtain white emission corresponding to D65 at the luminance of 15000 cd/m² in a display device with a green pixel aperture ratio of 10.4% and a resolution of 3207 ppi is 56050 cd/m². The light-emitting device 5A maintained a luminance higher than or equal to 95% of the initial luminance at the time when 150 hours have passed, which indicates that the light-emitting device 5A has high reliability.

### Example 6

In this example, a mixed film including the first organic compound, the second organic compound, and the metal compound that can be used in the light-emitting device of one embodiment of the present invention was formed, and the characteristics thereof were measured.

Specifically, Sample 6A and Sample 6B were fabricated as the above mixed film. As Reference 6a to Reference 6c, single films of organic compounds used for Sample 6A and Sample 6B were formed, The surfaces of the samples and the references were measured by SIMS analysis. For the SIMS analysis, time-of-flight secondary ion mass spectrometry (ToF-SIMS) was used.

Sample 6A-2 was fabricated as the above mixed film. As References 6a-2 and 6b-2, single films of the organic compound used for Sample 6A-2 were formed. The absorption spectra of the sample and the references were measured.

Structural Formulas of the organic compounds used for Samples 6A, 6A-2, 6B and References 6a to 6c, 6a-2, and 6b-2 are shown below.

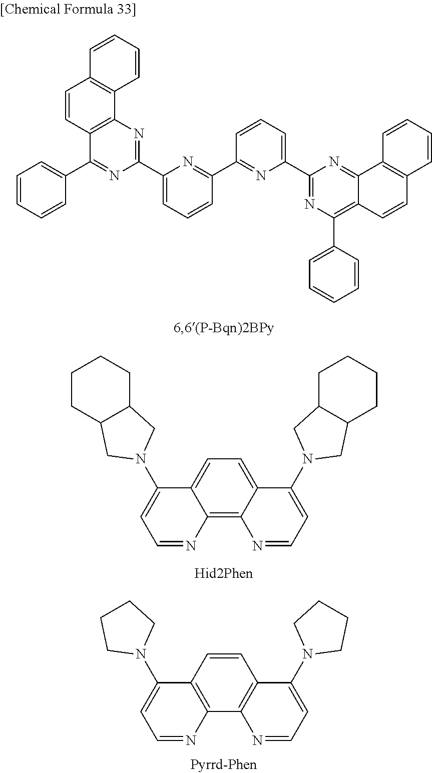 [SMILES: c1ccc(-c2nc(-c3cccc(-c4cccc(-c5nc(-c6ccccc6)c6ccc7ccccc7c6n5)n4)n3)nc3c2ccc2ccccc23)cc1 ; c1cc(N2CC3CCCCC3C2)c2ccc3c(N4CC5CCCCC5C4)ccnc3c2n1 ; c1cc(N2CCCC2)c2ccc3c(N4CCCC4)ccnc3c2n1]

### <Tof-Sims Measurement>

First, Sample 6A and Sample 6B were fabricated as mixed films that can be used in the light-emitting device of one embodiment of the present invention.

First, in pretreatment for forming samples over a quartz substrate, a surface of the substrate was washed with water and baking was performed at 200° C. for 1 hour. After that, the substrate was transferred into a vacuum evaporation apparatus where the internal pressure was reduced to approximately 1×10⁴ Pa.

For Sample 6A, 2,2′-(2,2′-bipyridine-6,6′-diyl)bis(4-phenylbenzo[h]quinazoline) (abbreviation: 6,6′(P-Bqn)2BPy), 4,7-di(2,3,3a,4,5,6,7,7a-octahydro-1H-isoindol-2-yl)-1,10-phenanthroline (abbreviation: Hid2Phen), and Li were deposited by co-evaporation to a thickness of 10 nm over a quartz substrate by a resistance heating evaporation method so as to have a 6,6′(P-Bqn)2BPy:Hid2Phen:Li volume ratio of 0.5:0.5:0.02.

For Sample 6B, 6,6′(P-Bqn)2BPy, 4,7-di-1-pyrrolidinyl-1,10-phenanthroline (abbreviation: Pyrrd-Phen), and Li₂O were deposited by co-evaporation to a thickness of 10 nm over a quartz substrate by a resistance heating evaporation method so as to have a 6,6′(P-Bqn)2BPy:Pyrrd-Phen:Li₂O volume ratio of 0.5:0.5:0.02.

For Reference 6a, 6,6′(P-Bqn)2BPy was deposited to a thickness of 10 nm over a quartz substrate by a resistance heating evaporation method. For Reference 6b, Hid2Phen was deposited to a thickness of 10 nm over a quartz substrate by a resistance heating evaporation method. For Reference 6c, PyrrdPhen was deposited to a thickness of 10 nm over a quartz substrate by a resistance heating evaporation method.

The list of Samples 6A and 6B and References 6a to 6c for ToF-SIMS analysis are shown below.

TABLE 20

| | Film structure |
|---|---|
| Sample 6A | 6,6′(P-Bqn)2BPy:Hid2Phen:Li (0.5:0.5:0.02) |
| Sample 6B | 6,6′(P-Bqn)2BPy:PyrrdPhen:Li₂O (0.5:0.5:0.02) |
| Reference 6a | 6,6′(P-Bqn)2BPy |
| Reference 6b | Hid2Phen |
| Reference 6c | PyrrdPhen |

ToF-SIMS measurement was performed on the fabricated Samples 6A and 6B and References 6a to 6c. In the ToF-SIMS measurement, TOF.SIMS5 (ION-TOF) was used, and the measurement mode had a high mass resolution and a measurement area of 150 μm square. The primary ion source was Bi and the sputtered ion source was fullerene (C₆₀).

### <ToF-SIMS Measurement Result>

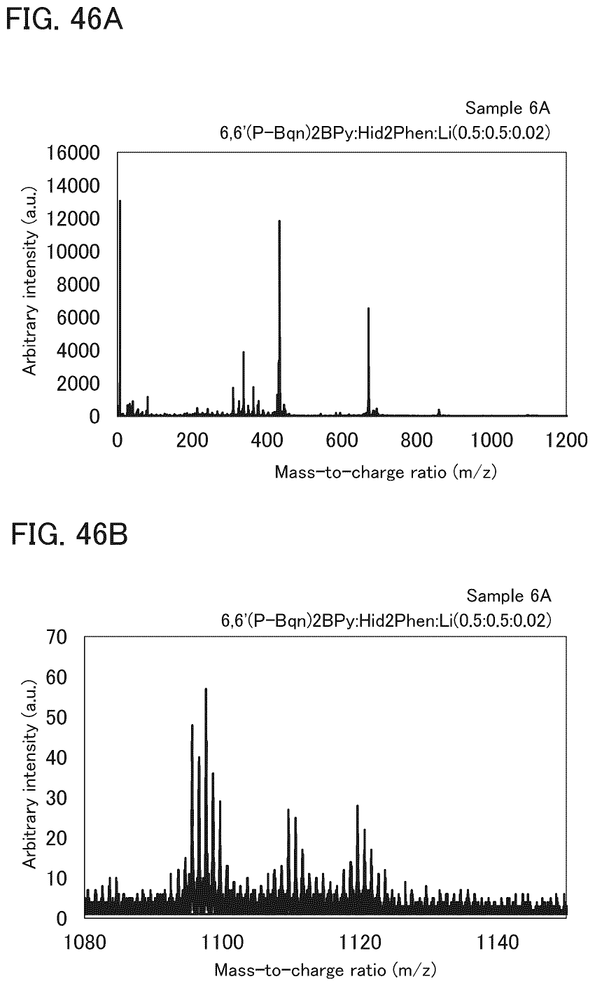

FIG. 46 to FIG. 50 show the results of positive ions in the ToF-SIMS measurement of the fabricated Samples 6A and 6B and References 6a to 6c.

FIG. 46A shows the measurement result of Sample 6A. FIG. 46B is an enlarged graph of the portion in FIG. 46A in which the mass-to-charge ratio (m/z) is approximately 1000. The following table shows the mass numbers of materials used for Sample 6A and the sum of the mass numbers of materials used in combination.

TABLE 21
Sample 6A

| | Mass |
|---|---|
| Structure | number |
| Li | 7 |
| Hid2Phen | 426 |
| 6,6′(P-Bqn)2BPy | 664 |
| 6,6′(P-Bqn)2BPy:HidPhen:Li | 1097 |

As shown in FIGS. 46A and 46B, peaks are detected at the mass-to-charge ratios corresponding to the mass numbers of 6,6′(P-Bqn)2BPy, Hid2Phen, and Li, and isotopes thereof, and at the mass-to-charge ratios corresponding to the sum of the mass numbers of 6,6′(P-Bqn)2BPy, Hid2Phen, and Li, i.e., 1097 and the mass numbers of isotopes thereof. This demonstrates that 6,6′(P-Bqn)2BPy, Hid2Phen, and Li interacted with each other to form a stable structure.

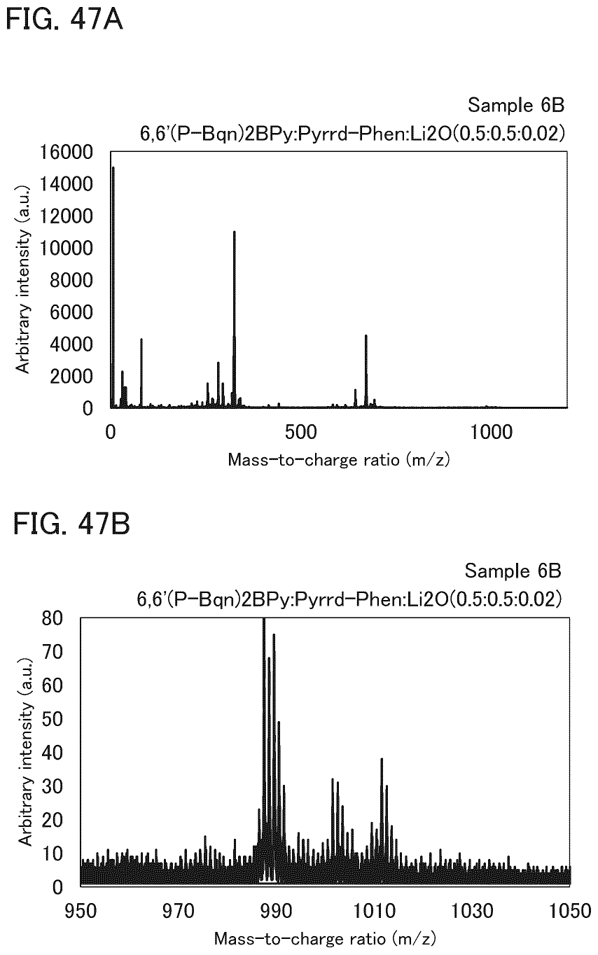

FIG. 47A shows the measurement results of Sample 6B. FIG. 47B is an enlarged graph of the portion in FIG. 47A in which the mass-to-charge ratio (m/z) is approximately 1000. The following table shows the mass numbers of materials used for Sample 6B and the sum of the mass numbers of materials used in combination.

TABLE 22
Sample 6B

| | Mass |
|---|---|
| Structure | number |
| Li | 7 |
| Li₂O | 30 |
| PyrrdPhen | 318 |
| 6,6′(P-Bqn)2BPy | 664 |
| 6,6′(P-Bqn)2BPy:PyrrdPhen:Li | 989 |
| 6,6′(P-Bqn)2BPy:PyrrdPhen:Li₂O | 1012 |

As also shown in FIGS. 47A and 47B, peaks are detected at the mass-to-charge ratios corresponding to the mass numbers of 6,6′(P-Bqn)2BPy, Pyrrd-Phen, and Li extracted from Li₂O and isotopes thereof, and at the mass-to-charge ratio corresponding to the sum of the mass numbers of 6,6′(P-Bqn)2BPy, Pyrrd-Phen, and Li extracted from Li₂O, i.e., 989, the sum of the mass numbers of 6,6′(P-Bqn)2BPy, Pyrrd-Phen, and Li₂O, i.e., 1012, and the mass numbers of isotopes thereof, This demonstrates that 6,6′(P-Bqn)2BPy, Pyrrd-Phen, and Li extracted from Li₂O interacted with each other to form a stable structure, as in Sample A.

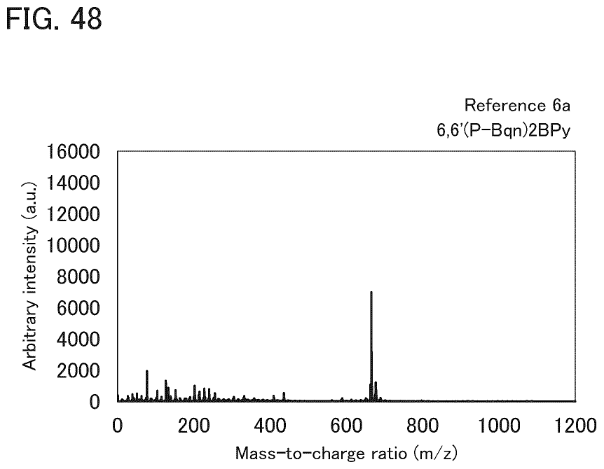

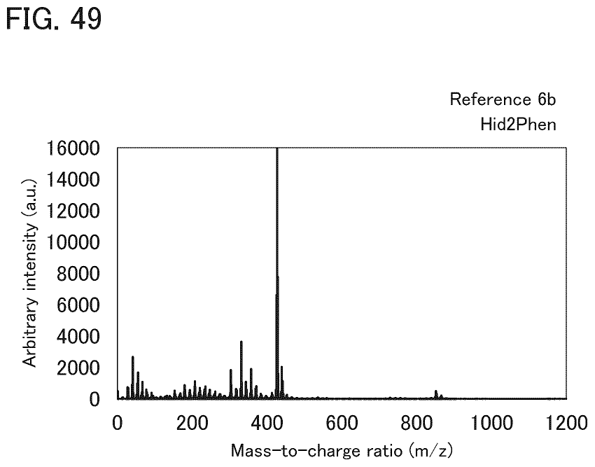

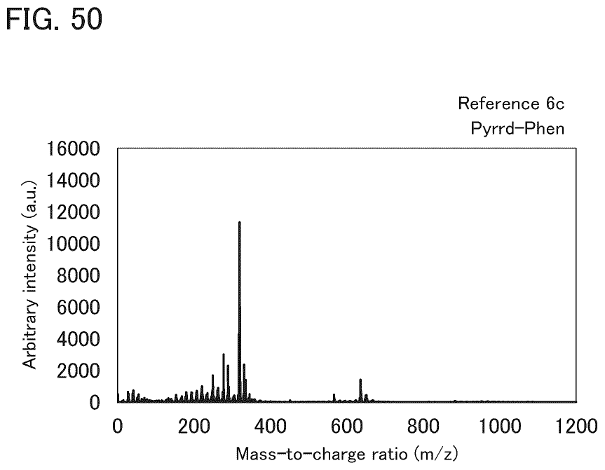

FIG. 48 shows the measurement result of Reference 6a, FIG. 49 shows the measurement result of Reference 6b, and FIG. 50 shows the measurement result of Reference 6c. The mass numbers of materials used for References 6a to 6c are shown in the table below.

TABLE 23

| | | Mass |
|---|---|---|
| | Structure | number |
| Reference 6a | 6,6′(P-Bqn)2BPy | 664 |
| Reference 6b | Hid2Phen | 426 |
| Reference 6c | PyrrdPhen | 318 |

In FIG. 48 to FIG. 50, peaks were detected at mass-to-charge ratios corresponding to the mass numbers of 6,6′(P-Bqn)2BPy, Hid2Phen, and Pyrrd-Phen, and the mass numbers of the isotopes thereof.

### <Absorption Spectrum Measurement>

For Sample 6A-2, a mixed film that can be used for the light-emitting device of one embodiment of the present invention was formed.

For Sample 6A-2, 6,6′(P-Bqn)2BPy, Hid2Phen, and Li were deposited by co-evaporation to a thickness of 50 nm over a quartz substrate by a resistance heating evaporation method to so as have a 6,6′(P-Bqn)2BPy:Hid2Phen:Li volume ratio of 0.5:0.5:0.02.

For References 6a-2 and 6b-2, single films of the organic compounds used for Sample 6A-2 were formed, Specifically, for Reference 6a-2, 6,6′(P-Bqn)2BPy was deposited to a thickness of 50 nm over a quartz substrate by a resistance heating evaporation method. As Reference 6b-2, Hid2Phen was deposited to a thickness of 50 nm over a quartz substrate by a resistance heating evaporation method.

The table below lists Sample 6A-2 and References 6a-2 and 6b-2 for the absorption spectrum measurement.

TABLE 24

| | Film structure |
|---|---|
| Sample 6A-2 | 6,6′(P-Bqn)2BPy:Hid2Phen:Li (0.5:0.5:0.02) |
| Reference 6a-2 | 6,6′(P-Bqn)2BPy |
| Reference 6b-2 | Hid2Phen |

The absorption spectra of Sample 6A-2 and References 6a-2 and 6b-2 were measured. The absorption spectrum of each thin film was measured with a spectrophotometer (U-4100 Spectrophotometer, Hitachi High-Technologies Corporation).

### <Absorption Spectrum Measurement Result>

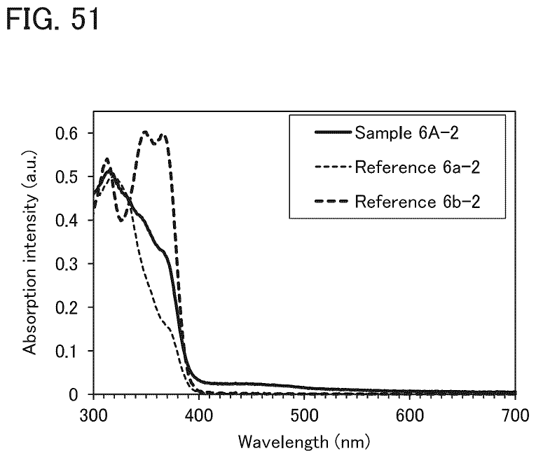

FIG. 51 shows the measurement results of the absorption spectra of Sample 6A-2 and References 6a-2 and 6b-2.

As shown in FIG. 51, an absorption band, which was not observed in the absorption spectra of References 6a-2 and 6b-2, was observed at a wavelength of around 400 nm to 600 nm in the absorption spectrum of Sample 6A-2. This is because interaction is generated in the mixed film in which Li is added to 6,6′(P-Bqn)2BPy and Hid2Phen and absorption derived from charge transfer is generated.

The above shows that in the mixed film of the organic compounds that can be used in the light-emitting device of one embodiment of the present invention, interaction is caused between the first organic compound, the second organic compound, and the metal, which forms a stable structure.

### Example 7

In this example, the characteristics of the intermediate layer that can be used in the light-emitting device of one embodiment of the present invention were evaluated. The light-emitting device 7A for evaluation and the light-emitting device 7B for evaluation were fabricated through a continuous vacuum process, and the light-emitting device π for evaluation and the light-emitting device 7D for evaluation were fabricated through a process involving exposure to the air.

For each of the light-emitting devices 7A and 7C, an intermediate layer that can be used for the light-emitting device of one embodiment of the present invention was used. On the other hand, the light-emitting devices 7B and 7D are evaluation devices for comparison, in each of which a conventional intermediate layer containing Li was used. The evaluation results of the characteristics of the light-emitting devices are described.

Structural Formulas of organic compounds used for the light-emitting devices 7A to 7D are shown below.

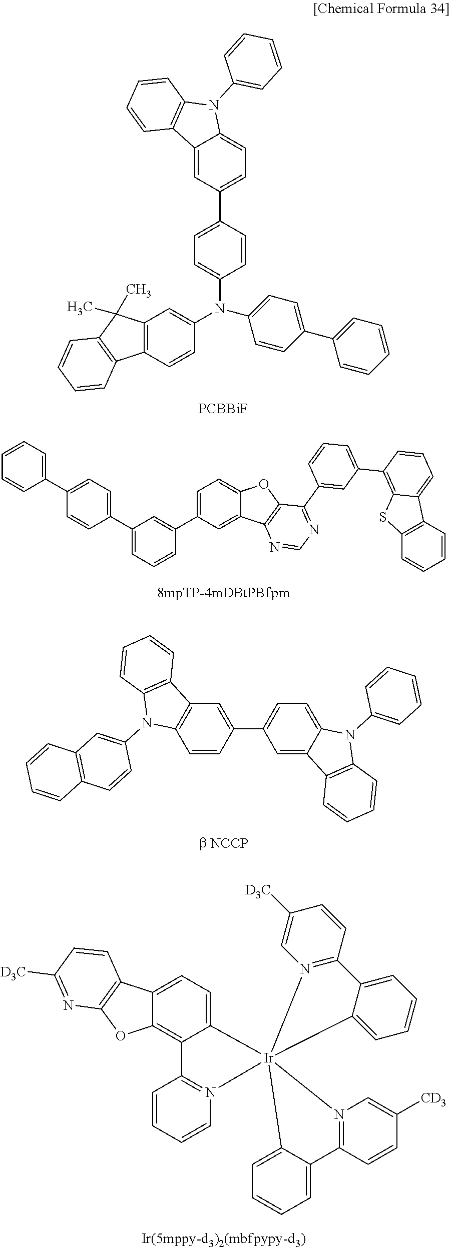

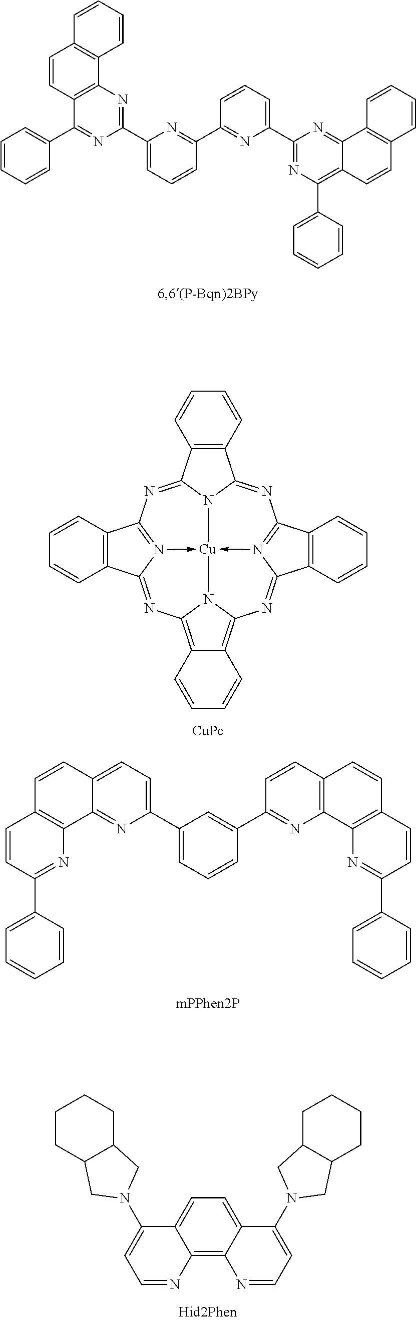

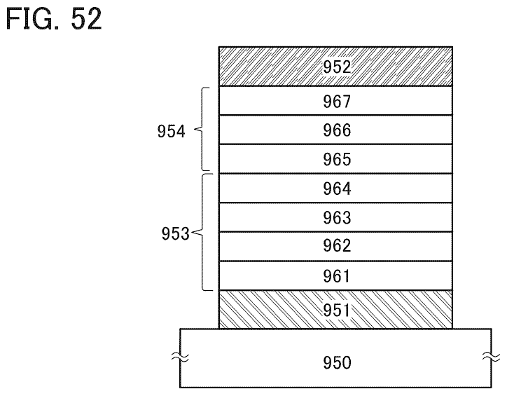

Note that in the light-emitting devices 7A to 7D), as illustrated in FIG. 52, the first EL layer 953) and the intermediate layer 954 were. stacked over a first electrode 951 formed over the substrate 950 that was a glass substrate, and a second electrode 952 was formed over the intermediate layer 954. That is, the light-emitting devices 7A to 7D each have a structure assuming the first EL layer and the intermediate layer for the tandem structure.

The first EL layer 953 has a structure in which the hole-injection layer 961, the first hole-transport layer 962, the first light-emitting layer 963, and the first electron-transport layer 964 are stacked in this order. The intermediate layer 954 includes an electron-injection buffer region 965, an electron-relay region 966, and a charge-generation region 967.

### <Fabrication Method of Light-Emitting Device 7A>

First, as a transparent electrode, indium tin oxide containing silicon oxide (ITSO) was deposited to a thickness of 70 nm over the substrate 950 that was a glass substrate by a sputtering method, whereby the first electrode 951 was formed, The electrode area was set to 4 mm² (2 mm×2 mm).

Next, the first EL layer 953 was provided. First, in pretreatment for forming the light-emitting device 7A over the substrate, a surface of the substrate was washed with water and baking was performed at 200° C. for 1 hour. Then, the substrate was transferred into a vacuum evaporation apparatus where the internal pressure was reduced to approximately 1×10⁻⁴ Pa, and vacuum baking was performed at 170° C. for 30 minutes in a heating chamber of the vacuum evaporation apparatus. After that, natural cooling was performed for approximately 30 minutes.

Then, the substrate provided with the first electrode 951 was fixed to a substrate holder provided in the vacuum evaporation apparatus such that the surface on which the first electrode 951 was formed faced downward. The hole-injection layer 961 was deposited to a thickness of nm over the first electrode 951 by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) by a resistance heating evaporation method so as to have a PCBBiF:OCHD-003 weight ratio of 1:0.03.

Next, the first hole-transport layer 962 was deposited to a thickness of 50 nm over the hole-injection layer 961 by evaporation of PCBBiF.

Next, the first light-emitting layer 963 was formed over the first hole-transport layer 962. The first light-emitting layer 963 was deposited to a thickness of 40 nm by co-evaporation of 8-(1,1′: 4′,″-terphenyl-3-yl)-4-[3-(dibenzothiophen-4-yl)phenyl]-1[ ]benzofuro[3,2-d]pyrimidine (abbreviation: 8mpTP-4mDBtPBfpn), 9-(2-naphthyl)-9′-phenyl-91H,9′-3,3′-bicarbazole (abbreviation: βNCCP), and [2-d3-methyl-8-(2-pyridinyl-κN)benzofuro[2,3-b]pyridine-κC]bis[2-(5-d3-methyl-2-pyridinyl-κN²′)phenyl-κC]iridium(III) (abbreviation: Ir(5mppy-d₃)₂(mbfpypy-d₃)) by a resistance heating evaporation method so as to have an 8mpTP-4mDBtPBfpm:βNCCP:Ir(5mppy-d₃)₂(mbfpypy-d₃) weight ratio of 0.5:0.5:0.1.

Subsequently, as the first electron-transport layer 964, 2,2′-(2,2′-bipyridine-6,6′-diyl)bis(4-phenylbenzo[h]quinazoline) (abbreviation: 6,6′(P-Bqn)2BPy) was deposited to a thickness of 10 nm by evaporation over the first light-emitting layer 963.

Next, the intermediate layer 954 was provided. First, a layer to be the electron-injection buffer region 965 was formed to a thickness of 5 nm over the first electron-transport layer 964 by co-evaporation of 2,2′-(2,2′-bipyridine-6,6′-diyl)bis(4-phenylbenzo[hlquinazoline) (abbreviation: 6,6′(P-Bqn)2BPy), 4,7-di(2,3,3a,4,5,6,7,7a-octahydro-1H-isoindol-2-yl)-1,10-phenanthroline (abbreviation: Hid2Phen), and Li₂O by a resistance heating evaporation method so as to have a 6,6′(P-Bqn)2BPy:Hid2Phen:Li₂O volume ratio of 0.5:0.5:0.02.

Then, as the electron-relay region 966, copper phthalocyanine (abbreviation: CuPc) was deposited to a thickness of 2 nm. Next, as the charge-generation region 967, PCBBiF and a fluorine-containing electron acceptor material with a molecular weight of 672 (OCHD-003) were co-deposited to a thickness of 10 nm by a resistance heating evaporation method so as to have a PCBBiF:OCHD-003 weight ratio of 1:0.15.

Then, aluminum (Al) was formed to a thickness of 150 nm as the second electrode 952.

Through the above process, the light-emitting device 7A was fabricated.

### <Fabrication Method of Light-Emitting Device 7B>

Next, a method for fabricating the light-emitting device 7B is described.

The light-emitting device 7B is different from the light-emitting device 7A in the structure of the electron-injection buffer region 965. That is, in the light-emitting device 7B, 2,2′-(1,3-phenylene)bis(9-phenyl-1,10-phenanthroline) (abbreviation: mPPhen2P) was deposited to a thickness of 5 nm over the first electron-transport layer 964, and then Li₂O was deposited to a thickness of 0.1 nm by a resistance heating evaporation method.

Other components were fabricated in a manner similar to that for the light-emitting device 7A.

### <Fabrication Method of Light-Emitting Device 7C>

Next, a method for fabricating the light-emitting device π is described.

The light-emitting device π is different from the light-emitting device 7A in that exposure to the air and heat treatment were performed after the charge-generation region 967 was formed.

### <<Exposure to Air and Heat Treatment>

The substrate provided with the intermediate layer 954 and the components thereunder was taken out from a vacuum evaporation apparatus and exposed to the air for 1 hour. The substrate exposed to the air was transferred into the vacuum evaporation apparatus where internal the pressure was reduced to approximately 1×10⁴ Pa, and was subjected to vacuum baking at 100° C. for 60 minutes in a heating chamber of the vacuum evaporation apparatus.

### <Fabrication Method of Light-Emitting Device 7D>

Next, a method for fabricating the light-emitting device 7D is described.

The light-emitting device 7D is different from the light-emitting device 7B in the structure of the electron-injection buffer region 965. That is, in the light-emitting device 7D, 2,2′-(1,3-phenylene)bis(9-phenyl-1,10-phenanthroline) (abbreviation: mPPhen2P) was deposited to a thickness of 5 nm over the first electron-transport layer 964, and then Li₂O was deposited to a thickness of 0.1 nm by a resistance heating evaporation method.

Then, like the light-emitting device 7C, the light-emitting device 7D was exposed to the air. Other components were fabricated in a manner similar to that for the light-emitting device 7C.

The structures of the light-emitting devices 7A to 7D are listed in the table below.

TABLE 25

| | | | | |
|---|---|---|---|---|
| Thickness | Light-emitting | Light-emitting | Light-emitting | Light-emitting |
| [nm] | device 7A | device 7B | device 7C | device 7D |

| | | |
|---|---|---|
| Second electrode | 150 | Al |

| | | | | |
|---|---|---|---|---|
| Exposure to the air and heat | — | — | ∘ | ∘ |

| treatment | | |
|---|---|---|
| Charge-generation | 10 | PCBBiF:OCHD-003 (1:0.15) |
| region | | |
| Electron-relay region | 2 | CuPc |
| Electron-injection | | Condition 7 |
| buffer region | | |
| First electron- | 10 | 6,6′(P-Bqn)2BPy |
| transport layer | | |
| First light-emitting | 40 | 8mpTP-4mDBtPBfpm:βNCCP:Ir(5mppy-d₃)₂(mbfpypy-d₃) |
| layer | | (0.5:0.5:0.1) |
| First hole-transport | 50 | PCBBiF |
| layer | | |
| Hole-injection layer | 10 | PCBBiF:OCHD-003 (1:0.03) |
| First electrode | 70 | ITSO |
| | 100 | APC |

Condition 7 in the table is shown in the following table.

TABLE 26

| | Thickness | Light-emitting devices |
|---|---|---|
| | [nm] | 7A and 7C |
| Electron-relay | 2 | CuPc |
| region | | |
| Electron-injection | 5 | 6,6′(P-Bqn)2BPy:Hid2Phen:Li₂O |
| buffer region | | (0.5:0.5:0.02) |
| (Condition 7) | | |
| First electron- | 10 | 6,6′(P-Bqn)2BPy |
| transport layer | | |

TABLE 27

| | Thickness | Light-emitting devices |
|---|---|---|
| | [nm] | 7B and 7D |
| Electron-relay region | 2 | CuPc |
| Electron-injection | 1 | Li₂O |
| buffer region | 5 | mPPhen2P |
| (Condition 7) | | |
| First electron- | 10 | 6,6′(P-Bqn)2BPy |
| transport layer | | |

### <Device Characteristics>

The light-emitting devices 7A to 7D were sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting devices 7A to 7D were measured.

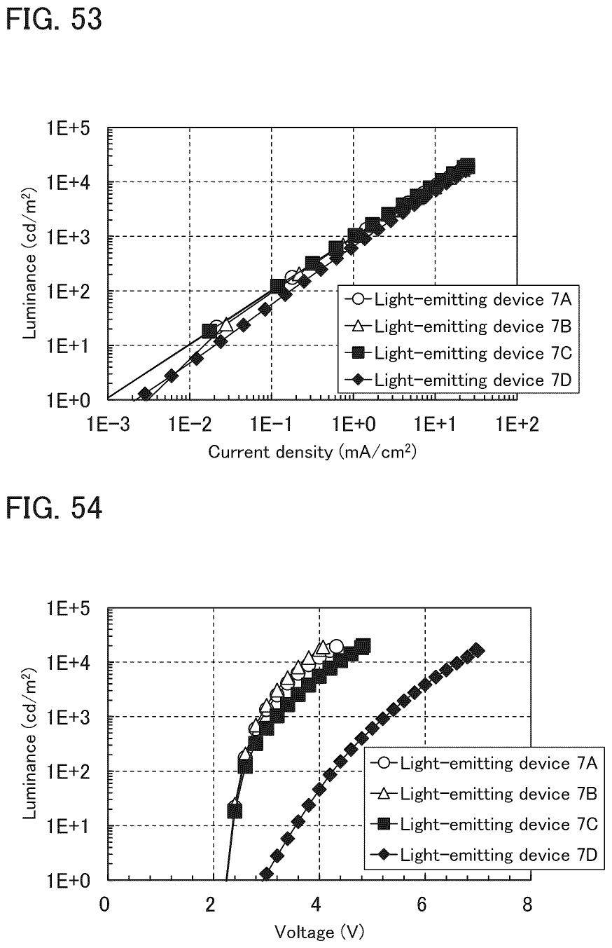

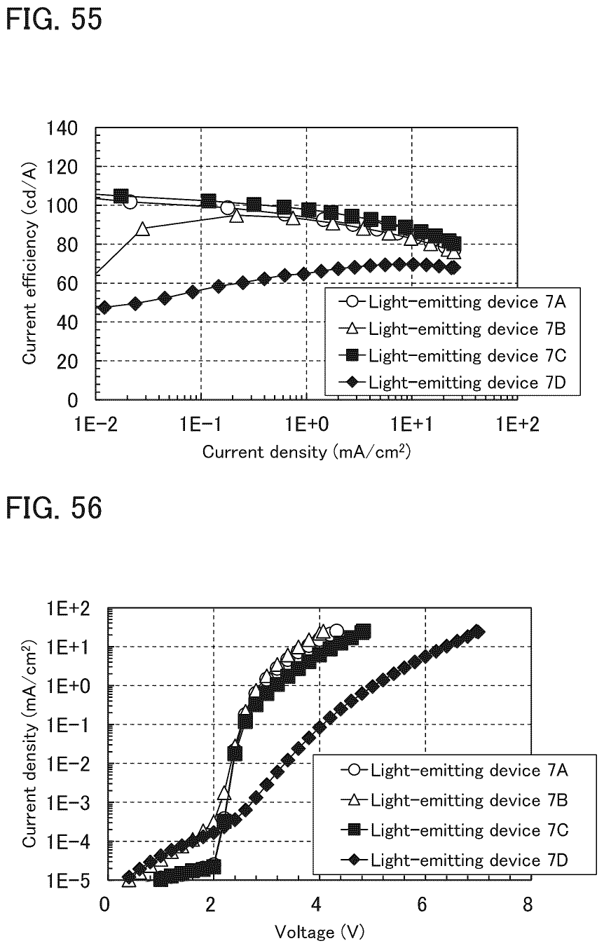

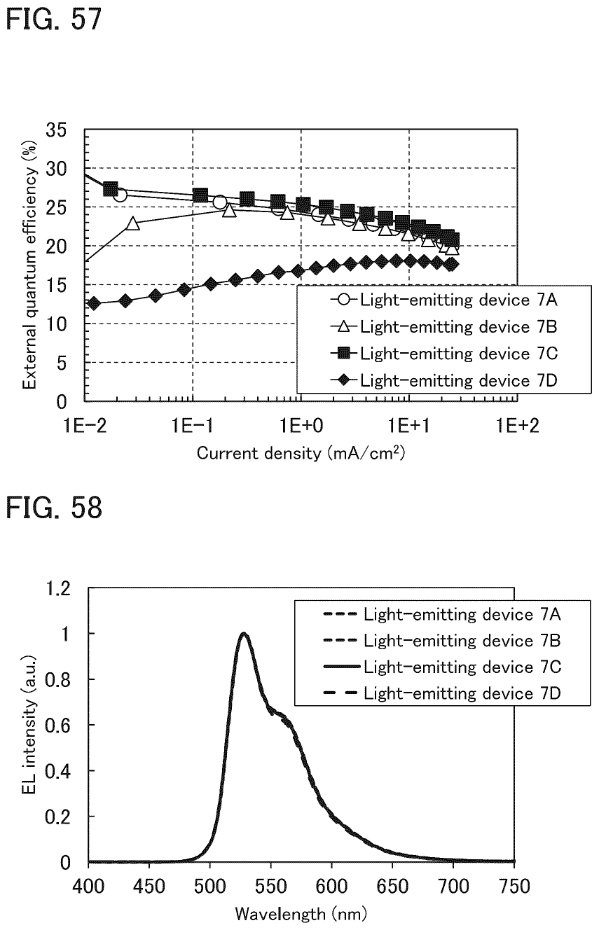

FIG. 53 shows the luminance-current density characteristics of the light-emitting devices 7A to 7D, FIG. 54 shows the luminance-voltage characteristics of the light-emitting devices 7A to 7D, FIG. 55 shows the current efficiency-current density characteristics of the light-emitting devices 7A to 7D, FIG. 56 shows the current density-voltage characteristics of the light-emitting devices 7A to 7D, FIG. 57 shows the external quantum efficiency—current density characteristics of the light-emitting devices 7A to 7D, and FIG. 58 shows the electroluminescence spectra of the light-emitting devices 7A to 7D. The main characteristics of the light-emitting devices 7A to 7D at a luminance of approximately 1000 cd/cm² are shown in the table below. Note that the luminance, CIE chromaticity, and electroluminescence spectra were measured with a spectroradiometer (SR-ULIR, TOPCON TECHNOHOUSE CORPORATION).

TABLE 28

| | | | Current | | | | Current |
|---|---|---|---|---|---|---|---|
| | Voltage | Current | density | Luminance | Chromaticity | Chromaticity | efficiency |
| | (V) | (mA) | (mA/cm²) | (cd/m²) | x | y | (cd/A) |
| Light-emitting | 3.0 | 0.0582 | 1.46 | 1348 | 0.140 | 0.574 | 92.62 |
| device 7A | | | | | | | |
| Light-emitting | 2.8 | 0.0300 | 0.75 | 700 | 0.140 | 0.574 | 93.54 |
| device 7B | | | | | | | |
| Light-emitting | 3.2 | 0.0423 | 1.06 | 1033 | 0.139 | 0.574 | 97.72 |
| device 7C | | | | | | | |
| Light-emitting | 5.2 | 0.0553 | 1.38 | 914 | 0.137 | 0.574 | 66.14 |
| device 7D | | | | | | | |

As shown in FIG. 58, the light-emitting devices 7A to 7D each exhibited green light emission with a peak wavelength of 538 nm in their electroluminescence spectra, originating from Ir(5mppy-d₃)₂(mbfpypy-dA.

FIG. 53 to FIG. 57 confirms that the light-emitting device 7A including the intermediate layer of one embodiment of the present invention has characteristics equivalent to those of the comparative light-emitting device 7B.

It is also confirmed that even after exposure to the air, the light-emitting device 7C including the intermediate layer of one embodiment of the present invention has characteristics equivalent to those of the light-emitting device 7A fabricated in a continuous vacuum process.

Meanwhile, it is found that the light-emitting device 7D using the conventional intermediate layer deteriorated through exposure to the air, and the driving voltage became higher than that of the light-emitting device 7B fabricated in a continuous vacuum process, so that the current efficiency and the external quantum efficiency were lowered.

### <<Impedance Spectroscopic Measurement Result>>

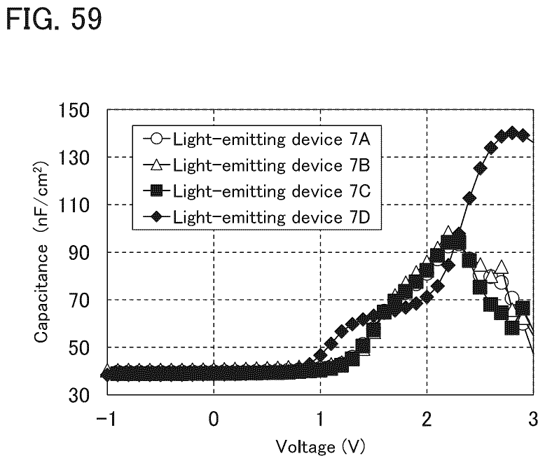

Here, the light-emitting devices 7A to 7D were subjected to analysis by impedance spectroscopy (IS) measurement to obtain capacitance-voltage characteristics, Results thereof are shown in FIG. 59. A frequency response analyzer (FRA) (SP-300, Bio-Logic Science Instruments) was used for the impedance spectroscopy measurement. In the measurement, 50 mV of AC voltage was superimposed on DC voltage and the frequency was 10 Hz.

FIG. 59 shows that the light-emitting device π fabricated through exposure to the air and using the intermediate layer of one embodiment of the present invention has no difference in carrier-injection property from the light-emitting device 7A fabricated in a continuous vacuum and has a carrier-injection property equivalent to that of the light-emitting device 7A. That is, since the carrier-injection property of the intermediate layer of one embodiment of the present invention does not change through exposure to the air, the intermediate layer is proven to have high resistance to the air.

Specifically, in the light-emitting devices 7A and π each fabricated using the intermediate layer of one embodiment of the present invention and the light-emitting device 7B fabricated using the conventional intermediate layer in a continuous vacuum process, holes are injected from the hole-injection layer 961 to the first hole-transport layer 962 at around 1.3 V. After that, electrons were injected from the intermediate layer to the first electron-transport layer 964 at around 1.9 V, and holes and electrons were recombined in the first light-emitting layer 963 at around 2.0 V, leading to light emission.

Meanwhile, it was revealed that the carrier-injection property of the light-emitting device 7D fabricated using the conventional intermediate layer and exposed to the air was largely different from that of the light-emitting device 7B fabricated in a continuous vacuum. That is, the carrier-injection property of the conventional intermediate layer is changed by exposure to the air, which indicates that the conventional intermediate layer has low resistance to the air.

Specifically, it is found that in the light-emitting device 7D fabricated using the conventional intermediate layer and exposed to the air, holes were injected from the hole-injection layer 961 to the first hole-transport layer 962 at around 1.0 V, and then holes passed through from the first hole-transport layer 962 to the first light-emitting layer 963 at around 2.1 V. This is because, in the light-emitting device 7D, Li that is easily oxidized in the air was used for the electron-injection buffer region 965, and the Li deteriorated owing to exposure to the air, which hindered electron injection from the intermediate layer into the first electron-transport layer 964.

The above demonstrates that a light-emitting device with high emission efficiency and low driving voltage even after exposure to the air can be provided according to one embodiment of the present invention.

### Example 8

In this example, light-emitting devices 8 (a light-emitting device 8G, a light-emitting device 8R, a light-emitting device 8B, a comparative light-emitting device 8g, a comparative light-emitting device 8r, and a comparative light-emitting device 8b) were fabricated and the characteristics thereof were evaluated. The light-emitting devices 8G, 8R, and 8B are light-emitting devices each using the intermediate layer of one embodiment of the present invention. The comparative light-emitting devices 8g, 8r, and 8b are light-emitting devices each using a conventional intermediate layer.

The light-emitting devices 8G, 8R, and 8B and the comparative light-emitting devices 8g, 8r, and 8b were fabricated by an MML process in which an organic compound layer was processed by a photolithography method. The light-emitting devices 8 were each fabricated by forming organic compound layers so as to make a resolution of 508 ppi. Structural Formulas of organic compounds used in the light-emitting devices 8 are shown below.

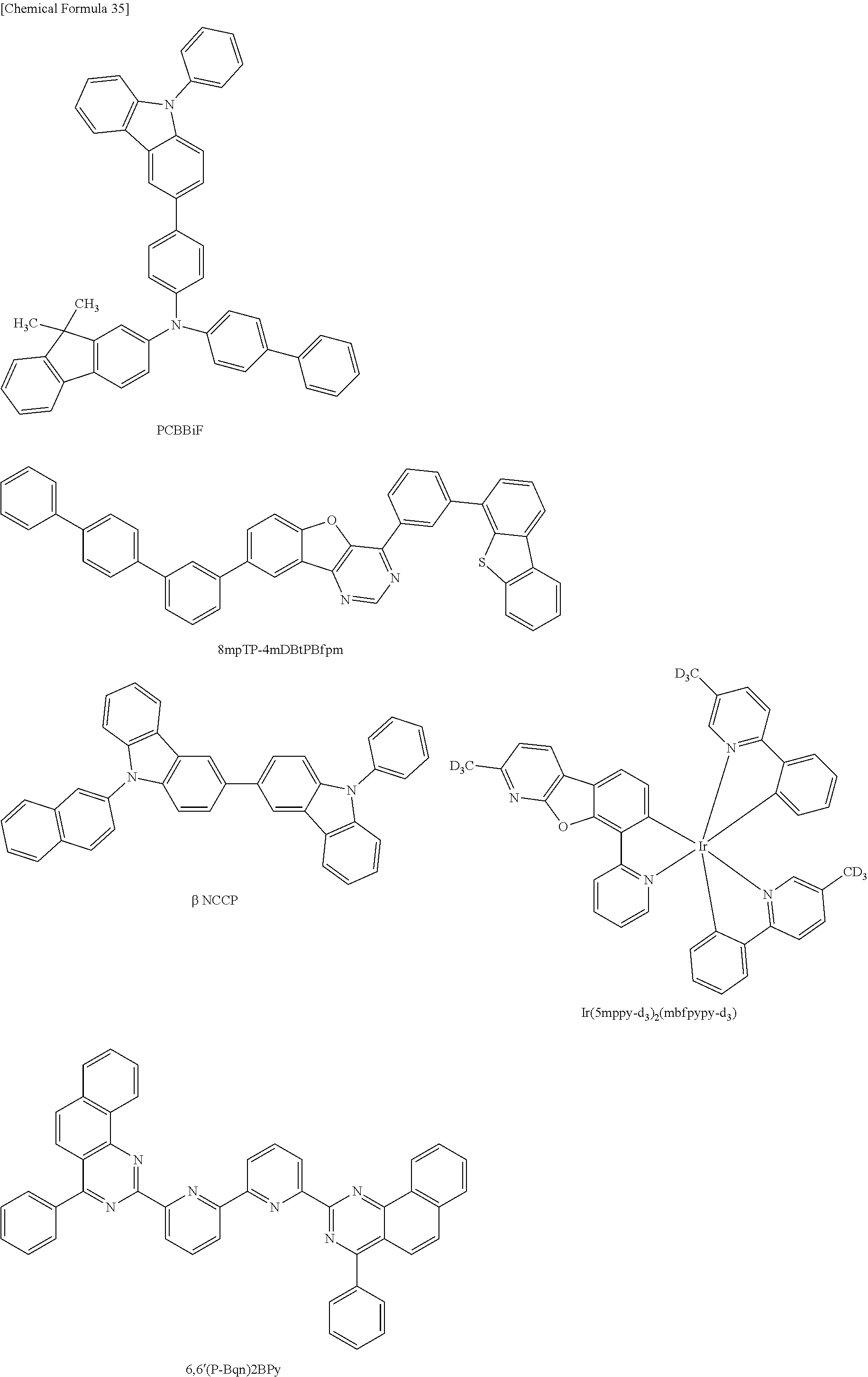

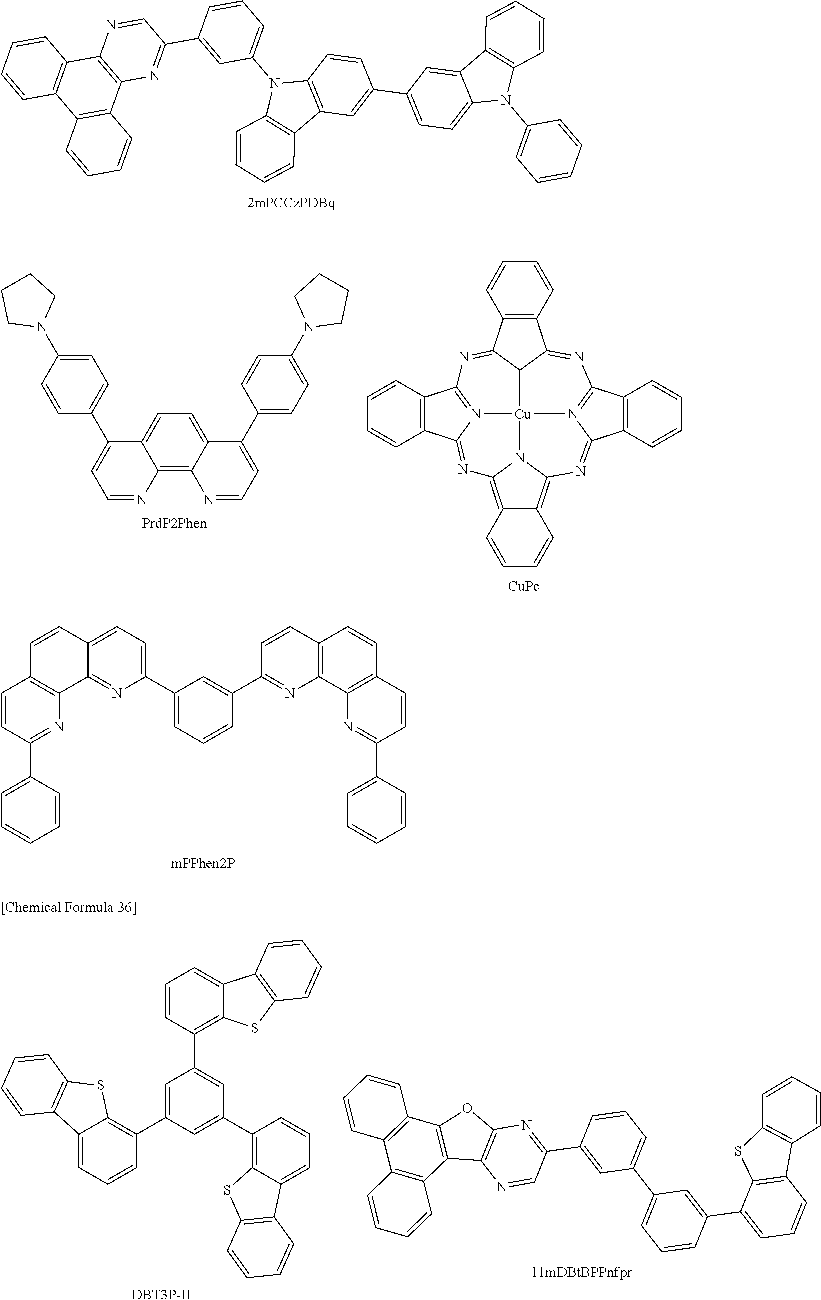

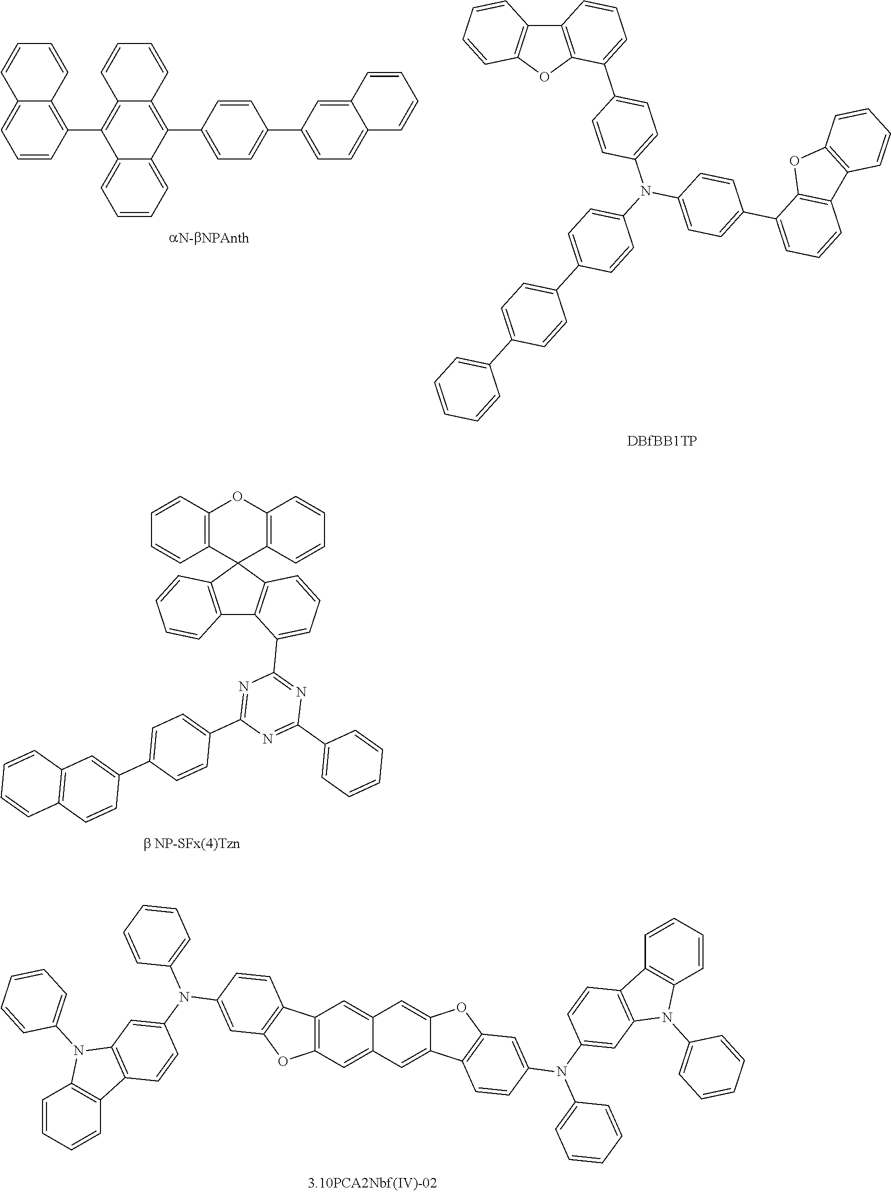

As illustrated in FIG. 18, the light-emitting devices 8 each have the tandem structure in which the first EL layer 903, the intermediate layer 905, the second EL layer 904, and the second electrode 902 are stacked over the first electrode 901 formed over the substrate 900 that is a glass substrate. Furthermore, the cap layer 909 is provided over the second electrode.

The first EL layer 903 has a structure in which the hole-injection layer 910, the first hole-transport layer 911, the first light-emitting layer 912, and the first electron-transport layer 913 are stacked in this order. The intermediate layer 905 includes the electron-injection buffer region 914 and the layer 915 including an electron-relay region and a charge-generation region. The second EL layer 904 has a structure in which the second hole-transport layer 916, the second light-emitting layer 917, the second electron-transport layer 918, and the electron-injection layer 919 are stacked in this order.

### <Fabrication Method of Light-Emitting Device 8G>

First, an alloy containing silver (Ag), palladium (Pd), and copper (Cu) (abbreviation: APC) was deposited to a thickness of 100 nm as a reflective electrode over a glass substrate by a sputtering method, and then, indium tin oxide containing silicon oxide (ITSO) was deposited to a thickness of 50 nm as a transparent electrode by a sputtering method, whereby the first electrode was formed. Note that the transparent electrode serves as an anode, and the transparent electrode and the reflective electrode can be collectively regarded as the first electrode.

Note that the first electrodes were formed to make matrix arrangement of 40×40 (1600 pixels) in an area of 2 mm×2 mm. This shape and arrangement correspond to a resolution of 508 ppi, and each pixel was formed to include three subpixels.

Next, in pretreatment for forming the light-emitting device over the substrate, a surface of the substrate was washed with water, and baking was performed at 200° C. for 1 hour.

After that, the substrate was transferred into a vacuum evaporation apparatus where the internal pressure was reduced to approximately 1×10⁻⁴ Pa, and was subjected to heat treatment at 170° C. for 30 minutes in a heating chamber of the vacuum evaporation apparatus, and then, the substrate was cooled down for approximately 30 minutes.

Then, the substrate provided with the first electrode 901 was fixed to a substrate holder provided in the vacuum evaporation apparatus such that the surface on which the first electrode 901 was formed faced downward. The hole-injection layer 910 was deposited to a thickness of nm over the first electrode 901 by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) by a resistance heating evaporation method so as to have a PCBBiF:OCHD-003 weight ratio of 1:0.03.

Next, the first hole-transport layer 911 was deposited to a thickness of 120 nm over the hole-injection layer 910 by evaporation of PCBBiF.

Next, the first light-emitting layer 912 was formed over the first hole-transport layer 911. The first light-emitting layer 912 was deposited to a thickness of 40 nm by co-evaporation of 8-(1,1′: 4′, 1″-terphenyl-3-yl)-4-[3-(dibenzothiophen-4-yl)phenyl1-[1]benzofuro[3,2-d]pyrimidine (abbreviation: 8mpTP-4mDBtPBfpm), 9-(2-naphthyl)-9′-phenyl-9H,9′H-3,3′-bicarbazole (abbreviation: βNCCP), and [2-d3-methyl-8-(2-pyridinyl-κN)benzofuro[2,3-b]pyridine-κC]bis[2-(5-d3-methyl-2-pyridinyl-N″)phenyl-K(C]iridium(Ill) (abbreviation: lr(5mppy-d₁₂(mbfpypy-d₃)) by a resistance heating evaporation method so as to have a 8mpTP-4mDBtPBfpm:DNCCP:Ir(5mppy-d₃)₂(mbfpypy-d₃) weight ratio of 0.5:0.5:0.1.

Then, the first electron-transport layer 913 was deposited to a thickness of 10 nm over the first light-emitting layer 912 by evaporation of 2-f3-[3-(N-phenyl-9H-carbazol-3-yl)-9H-carbazol-9-yl]phenyl}dibenzo[f,hiquinoxaline (abbreviation: 2mPCCzPDBq).

Next, the intermediate layer 905 was provided. First, a layer to be the electron-injection buffer region 914 was deposited to a thickness of 5 nm over the first electron-transport layer 913 by co-evaporation of 2,2′-(2,2′-bipyridine-6,6′-diyl)bis(4-phenylbenzo[h]quinazoline) (abbreviation: 6,6′(P-Bqn)2BPy), 4,7-bis[4-(1-pyrrolidinyl)phenyl]-1,10-phenanthroline (abbreviation: PrdP2Phen), and Li₂O by a resistance heating evaporation method so as to have a 6,6′(P-Bqn)2Bpy:PrdP2Phen:Li₂O volume ratio of 0.5:0.5:0.02.

Then, as the electron-relay region, copper phthalocyanine (abbreviation: CuPc) was deposited to a thickness of 2 nm. Next, as the charge-generation region, the layer 915 including the charge-generation region was deposited to a thickness of 10 nm by co-evaporation of PCBBiF and a fluorine-containing electron acceptor material with a molecular weight of 672 (OCHD-00³) by a resistance heating evaporation method so as to have a PCBBiF:OCHD-003 weight ratio of 1:0.15.

Next, the second EL layer 904 was provided. First, the second hole-transport layer 916 was deposited to a thickness of 50 nm by evaporation of PCBBiF.

Then, the second light-emitting layer 917 was deposited to a thickness of 40 nm by co-evaporation of 8mpTP-4mDBtPBfpm, βNCCP, and Ir(5mppy-d₃)₂(mbfpypy-d₃) by a resistance heating evaporation method so as to have a 8mpTP-4mDBtPBfpm:βNCCP:Ir(5mppy-d₃)₂(mbfpypy-d₃) weight ratio of 0.5:0.5:0.1.

Next, 2mPCCzPDBq was deposited to a thickness of 20 nm by evaporation, and then 2,2′-(1,3-phenylene)bis(9-phenyl-1,10-phenanthroline) (abbreviation: mPPhen2P) was deposited to a thickness of 20 nm by evaporation, whereby the second electron-transport layer 918 was formed over the second light-emitting layer 917.

After the formation of the second electron-transport layer 918, processing by a photolithography method and heat treatment were performed.

### <<Processing by Photolithography Method and Heat Treatment>>

Tris(8-quinolinolato)aluminum(III) (abbreviation: Alp₃) was deposited to a thickness of nm by evaporation after formation of the second electron-transport layer 918, then the substrate was taken out from the vacuum evaporation apparatus and exposed to the air, and aluminum oxide was deposited to a thickness of 30 nm by an ALD method using trimethylaluminum (abbreviation: TMA) as a precursor and water vapor as an oxidizer to form the first sacrificial layer.

Next, molybdenum was deposited to a thickness of 50 nm over the first sacrificial layer by a sputtering method to form a second sacrificial layer.

Then, a resist was formed using a photoresist over the second sacrificial layer, and processing was performed such that an end portion of the second sacrificial layer was located outward from an end surface of the first electrode. In this manner, the light-emitting devices enabling a resolution of 508 ppi can be formed.

Specifically, the second sacrificial layer was processed using an etching gas containing sulfur hexafluoride (SF₆) and oxygen (O₂) at a SF_{6:2} flow rate ratio of 10:4 and an etching gas containing oxygen (O₂) with the use of the resist as a mask and then, the first sacrificial layer was processed using an etching gas containing fluoroform (CHF₃) and helium (He) at a CHF₃:He flow rate ratio of 1:49 with the use of the second sacrificial layer as a hard mask. After that, the second electron-transport layer, the second light-emitting layer, the second hole-transport layer, the intermediate layer, the first electron-transport layer, the first light-emitting layer, the first hole-transport layer, and the hole-injection layer were processed using an etching gas containing oxygen (O₂).

After the organic compound layer was formed by the processing, the second sacrificial layer was removed using an etching gas containing sulfur hexafluoride (SF₆) and oxygen (O₂) at an SF₆:O₂flow rate ratio of 10:4 and an etching gas containing oxygen (O₂), whereas the first sacrificial layer was left. Then, as a protective film, a film of aluminum oxide was deposited to a thickness of 15 nm by an ALD method.

Next, a layer of a photosensitive high molecular material was formed over the first electrode over the protective film by a photolithography method. After heating was performed at 100° C. in an air atmosphere for 10 minutes, unnecessary portions of the Alq3 layer, the first sacrificial layer, and the protective film were removed using a mixed acid aqueous solution containing hydrofluoric acid (HF), so that the second electron-transport layer was exposed. At this time, the layer of the photosensitive high molecular material functions as a resist.

Then, the substrate was transferred into a vacuum evaporation apparatus where the internal pressure was reduced to approximately 1×10-′Pa, and heat treatment was performed at 100° C. for 1 hour in a heating chamber of the vacuum evaporation apparatus.

The above is the description of the processing by a photolithography method and the heat treatment. As described above, the processing by a photolithography method, the heat treatment, and treatment using water or a chemical solution containing water as a solvent were performed.

After the processing by a photolithography method and the heat treatment, the electron-injection layer 919 was deposited to a thickness of 1.5 nm over the second electron-transport layer 918 by co-evaporation of lithium fluoride (LiF) and ytterbium (Yb) so as to have a LiF:Yb volume ratio of 2:1.

Next, the second electrode 902 was deposited to a thickness of 15 nm over the electron-injection layer 919 by co-evaporation of Ag and Mg so as to have an Ag:Mg volume ratio of 1:0.1. Note that the second electrode 902 is a transflective electrode having functions of transmitting light and reflecting light.

Then, as the cap layer, 4,4′,4″-(benzene-1,3, 5- triyl)tri(dibenzothiophene) (abbreviation: DBT3P-II) was deposited to a thickness of 70 nm by evaporation and the light extraction efficiency is improved.

Through the above process, the light-emitting device 8G was fabricated.

<Fabrication Method of Comparative Light-Emitting Device 8g>

The comparative light-emitting device 8g is different from the light-emitting device 8G in the structure of the electron-injection buffer region 914. Other components are the same as those of the light-emitting device 8G.

Specifically, in the comparative light-emitting device 8g, the layer to be the electron-injection buffer region 914 was deposited to a thickness of 5 nmn over the first electron-transport layer 913 by co-evaporation of mPPhen2P and Li₂O by a resistance heating evaporation method so as to have an mPPhen2P:Li₂O volume ratio of 1:0.02.

The table below lists the structures of the light-emitting device 8G and the comparative light-emitting device 8g.

TABLE 29

| | | |
|---|---|---|
| | | Comparative |
| Thickness | Light-emitting | light-emitting |
| [nm] | device 8G | device 8g |

| | | |
|---|---|---|
| Cap layer | 70 | DBT3P-II |
| Second electrode | 15 | Ag:Mg (1:0.1) |
| Electron-injection | 1.5 | LiF:Yb (2:1) |
| layer | | |

Processing by photolithography was performed

| Second electron- | 20 | mPPhen2P | |
|---|---|---|---|
| transport layer | 20 | 2mPCCzPDBq | |
| Second light-emitting | 40 | 8mpTP-4mDBtPBfpm:βNCCP:Ir(5mppy-d₃)₂(mbfpypy-d₃) | |
| layer | | (0.5:0.5:0.1) | |
| Second hole-transport | 50 | PCBBiF | |
| layer | | | |
| Charge-generation | 10 | PCBBiF:OCHD-003 (1:0.15) | |
| region | | | |
| Electron-relay region | 2 | CuPc | |
| Electron-injection | 5 | 6,6′(P-Bqn) | mPPhen2P:Li₂O |
| buffer region | | 2BPy:PrdP2Phen:Li₂O | (1:0.02) |
| | | (0.5:0.5:0.02) | |

| | | |
|---|---|---|
| First electron- | 10 | 2mPCCzPDBq |
| transport layer | | |
| First light-emitting | 40 | 8mpTP-4mDBtPBfpm:βNCCP:Ir(5mppy-d₃)₂(mbfpypy-d₃) |
| layer | | (0.5:0.5:0.1) |
| First hole-transport | 120 | PCBBiF |
| layer | | |
| Hole-injection layer | 10 | PCBBiF:OCHD-003 (1:0.03) |
| First electrode | 50 | ITSO |
| | 100 | APC |

### <Fabrication Method of Light-Emitting Device 8R>

The light-emitting device 8R is different from the light-emitting device 8G in the structures and thicknesses of the first light-emitting layer 912 and the second light-emitting layer 917 and the thicknesses of the first hole-transport layer 911, the second hole-transport layer 916, and the second electron-transport layer 918. Other components are the same as those of the light-emitting device 8G.

Specifically, in the light-emitting device 8R, each of the first light-emitting layer 912 and the second light-emitting layer 917 was deposited to a thickness of 50 nm by co-evaporation of 11-[3′-(dibenzothiophen-4-yl)biphenyl-3-yl]phenanthro[9′, 10′: 4,5]furo[2,3-b]pyrazine (abbreviation: 11mDBtl3PPnfpr), PCBBiF, and OCPG-006 as a material emitting red phosphorescent light so as to have a 11mDBtBPPnfpr:PCBBiF:OCPG-006 weight ratio of 0.7:0.3:0.05.

In the light-emitting device 8R, the thickness of the first hole-transport layer 911 was 15 nm, the thickness of the second hole-transport layer 916 was 65 nm, the thickness of the 2mPCCzPDBq layer of the second electron-transport layer 918 was 10 nm, and the thickness of the mPPhen2P layer of the second electron-transport layer 918 was 20 nm, which was the same as that in the light-emitting device 8G.

<Fabrication Method of Comparative Light-Emitting Device 8r>

The comparative light-emitting device 8r is different from the light-emitting device SR in the structure of the electron-injection buffer region 914. Other components are the same as those of the light-emitting device 8R.

Specifically, in the comparative light-emitting device 8r, the layer to be the electron-injection buffer region 914 was deposited to a thickness of 5 urn over the first electron-transport layer 913 by co-evaporation of mPPhen2P and Li₂O by a resistance heating evaporation method so as to have an mPPhen2P:Li₂O volume ratio of 1:0.02.

The table below lists the structures of the light-emitting device SR and the comparative light-emitting device 8r.

TABLE 30

| | | |
|---|---|---|
| | | Comparative |
| Thickness | Light-emitting | light-emitting |
| [nm] | device 8R | device 8r |

| | | |
|---|---|---|
| Cap layer | 70 | DBT3P-II |
| Second electrode | 15 | Ag:Mg (1:0.1) |
| Electron-injection | 1.5 | LiF:Yb (2:1) |
| layer | | |

Processing by photolithography was performed

| Second electron- | 20 | mPPhen2P | |
|---|---|---|---|
| transport layer | 10 | 2mPCCzPDBq | |
| Second | 50 | 11mDBtBPPnfpr:PCBBiF:OCPG-006 | |
| light-emitting | | (0.7:0.3:0.05) | |
| layer | | | |
| Second | 65 | PCBBiF | |
| hole-transport | | | |
| layer | | | |
| Charge-generation | 10 | PCBBiF:OCHD-003 (1:0.15) | |
| region | | | |
| Electron-relay | 2 | CuPc | |
| region | | | |
| Electron-injection | 5 | 6,6′(P-Bqn) | mPPhen2P:Li₂O |
| buffer region | | 2BPy:PrdP2Phen:Li₂O | (1:0.02) |
| | | (0.5:0.5:0.02) | |

| | | |
|---|---|---|
| First electron- | 10 | 2mPCCzPDBq |
| transport layer | | |
| First light-emitting | 50 | 11mDBtBPPnfpr:PCBBiF:OCPG-006 |
| layer | | (0.7:0.3:0.05) |
| First hole-transport | 15 | PCBBiF |
| layer | | |
| Hole-injection layer | 10 | PCBBiF:OCHD-003 (1:0.03) |
| First electrode | 50 | ITSO |
| | 100 | APC |

### <Fabrication Method of Light-Emitting Device 8B>

The light-emitting device 8B is different from the light-emitting device 8G in the structures of the first hole-transport layer 911, the first light-emitting layer 912, the first electron-transport layer 913, the second hole-transport layer 916, the second light-emitting layer 917, and the second electron-transport layer 918. Other components are the same as those of the light-emitting device 8G.

Specifically, in the light-emitting device 8B, the first hole-transport layer 911 was deposited by evaporation of PCBBiF to a thickness of 70 nm, followed by evaporation of N,N-bis[4-(dibenzofuran-4-yl)phenyl]-4-amino-p-terphenyl (abbreviation: DBfBB1TP) to a thickness of 10 nm.

In the light-emitting device 8B, each of the first light-emitting layer 912 and the second light-emitting layer 917 was deposited to a thickness of 25 nm by co-evaporation of 9-(1-naphthyl)-10-[4-(2-naphthyl)phenyl]anthracene (abbreviation: αN-βNPAnth) and 3,10-bis[N-(9-phenyl-9H1-carbazol-2-yl)-N-phenylamino]naphtho[2,3-b;6,7-b′]bisbenzofuran (abbreviation: 3,10PCA2Nbf(JV)-02) so as to have an αN-βNPAnth:3,10PCA2Nbf(IV)-02 weight ratio of 1:0.015.

The first electron-transport layer 913 in the light-emitting device 8B was deposited to a thickness of 10 nm by evaporation of 2-[4-(2-naphthalenyl)phenyl]-4-phenyl-6-spiro[9H-fluorene-9,9′-[9H]xanthen]-4-yH,3,5-triazine (abbreviation: βNP-SFx(4)Tzn).

The second hole-transport layer 916 in the light-emitting device 8B was deposited by evaporation of PCBBiF to a thickness of 35 nm, followed by evaporation of DBfBB1TP to a thickness of 10 nm.

The second electron-transport layer 918 in the light-emitting device 8B was deposited by evaporation of βNP-SFx(4)Tzn to a thickness of 15 nm, followed by evaporation of mPPhen2P to a thickness of 20 nn,

<Fabrication Method of Comparative Light-Emitting Device 8b>

The comparative light-emitting device 8b is different from the light-emitting device 8B in the structure of the electron-injection buffer region 914. Other components are the same as those of the light-emitting device 8B.

Specifically, in the comparative light-emitting device 8b, the layer to be the electron-injection buffer region 914 was deposited to a thickness of 5 nm over the first electron-transport layer 913 by co-evaporation of mPPhen2P and Li₂O by a resistance heating evaporation method so as to have an mPPhen2P:Li₂O volume ratio of 1:0.02.

The table below lists the structures of the light-emitting device 8B and the comparative light-emitting device 8b.

TABLE 31

| | | |
|---|---|---|
| | | Comparative |
| Thickness | Light-emitting | light-emitting |
| [nm] | device 8B | device 8b |

| | | |
|---|---|---|
| Cap layer | 70 | DBT3P-II |
| Second electrode | 15 | Ag:Mg (1:0.1) |
| Electron-injection | 1.5 | LiF:Yb (2:1) |
| layer | | |

Processing by photolithography was performed

| Second electron- | 20 | mPPhen2P | |
|---|---|---|---|
| transport layer | 15 | βNP-SFx(4)Tzn | |
| Second | 25 | aN-βNP Anth:3,10PCA2Nbf(IV)-02 | |
| light-emitting | | (1:0.015) | |
| layer | | | |
| Second | 10 | DBfBB1TP | |
| hole-transport | 35 | PCBBiF | |
| layer | | | |
| Charge-generation | 10 | PCBBiF:OCHD-003 (1:0.15) | |
| region | | | |
| Electron-relay | 2 | CuPc | |
| region | | | |
| Electron-injection | 5 | 6,6′(P-Bqn) | mPPhen2P:Li₂O |
| buffer region | | 2BPy:PrdP2Phen:Li₂O | (1:0.02) |
| | | (0.5:0.5:0.02) | |

| | | |
|---|---|---|
| First electron- | 10 | βNP-SFx(4)Tzn |
| transport layer | | |
| First light-emitting | 25 | αN-βNP Anth:3,10PCA2Nbf(IV)-02 |
| layer | | (1:0.015) |
| First hole-transport | 10 | DBfBB1TP |
| layer | 120 | PCBBiF |
| Hole-injection layer | 10 | PCBBiF:OCHD-003 (1:0.03) |
| First electrode | 50 | ITSO |
| | 100 | APC |

### <Device Characteristics>

The light-emitting devices 8 were each sealed using a glass substrate in a glove box containing a nitrogen atmaosphere so as not to be exposed to the air (a sealing material was applied to surround the devices and UV treatment and heat treatment at 80° C. for 1 hour were performed at the time of sealing). Then, the emission characteristics of the light-emitting devices 8 were measured,

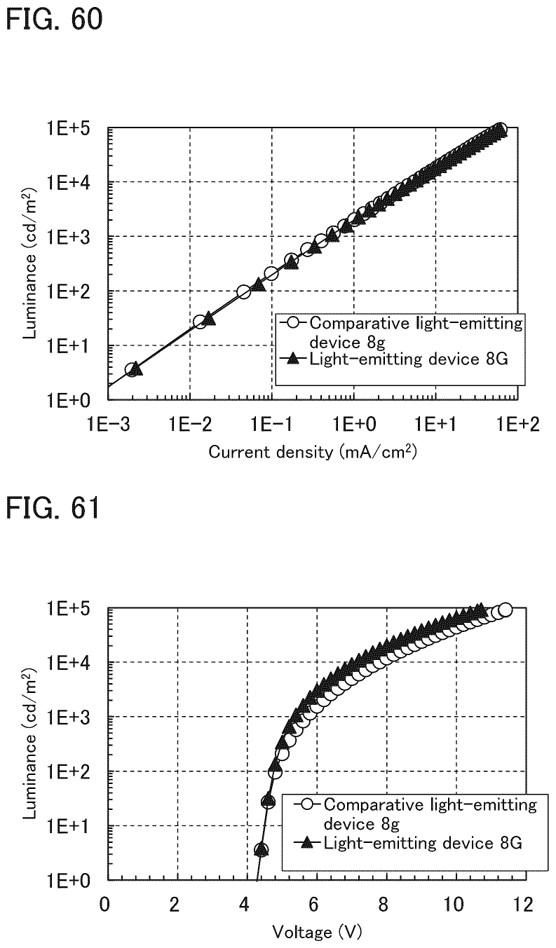

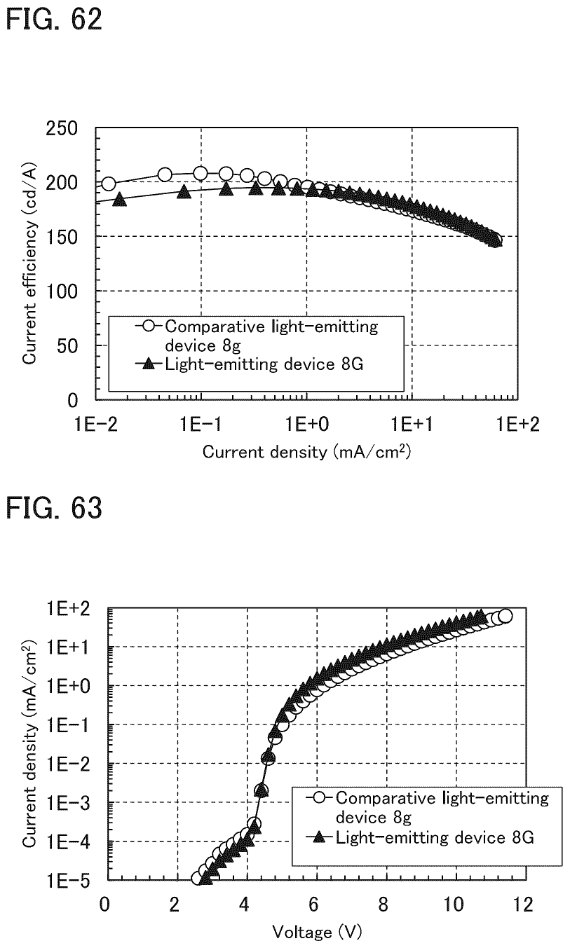

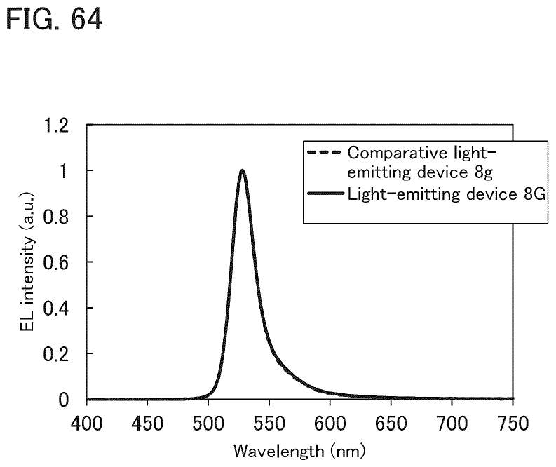

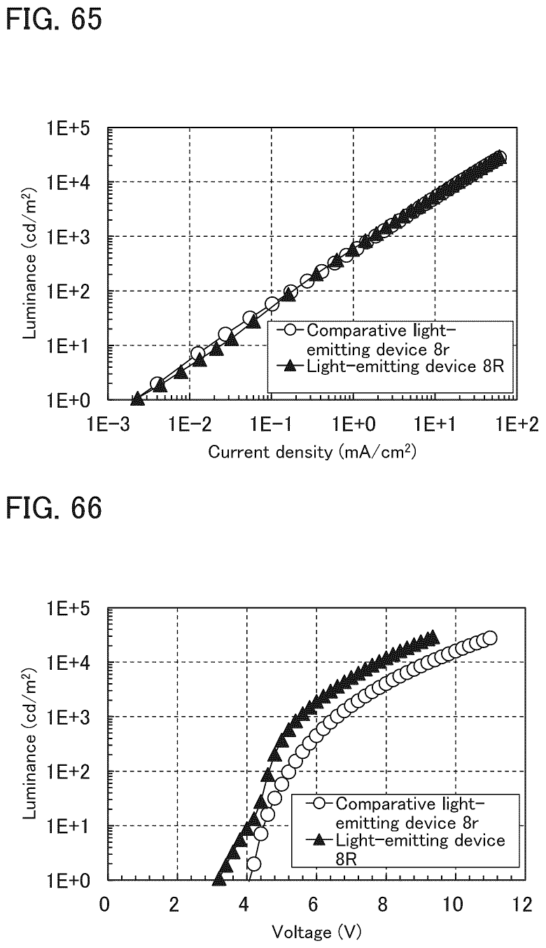

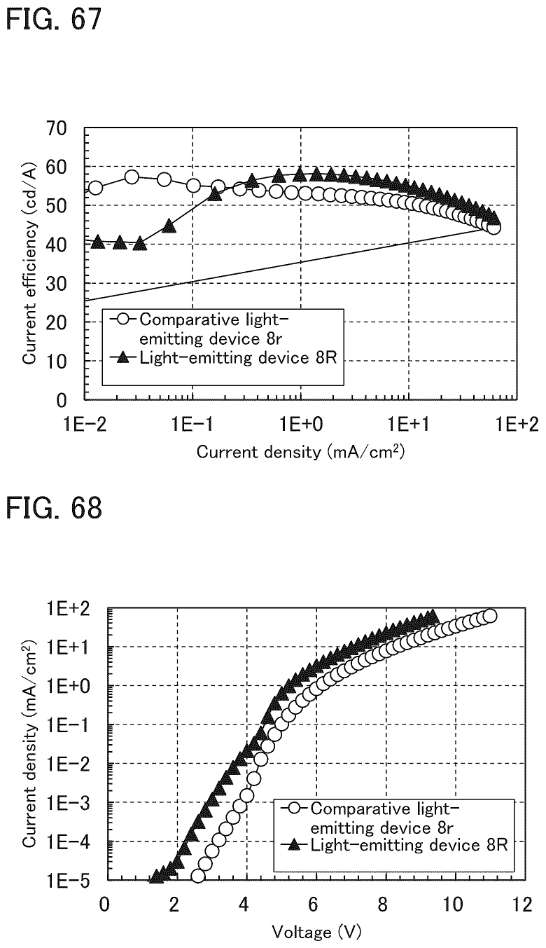

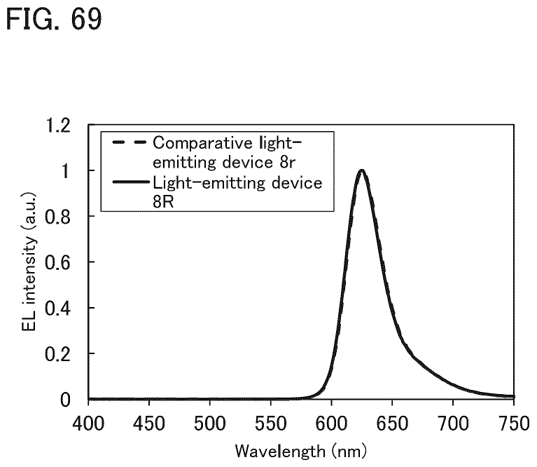

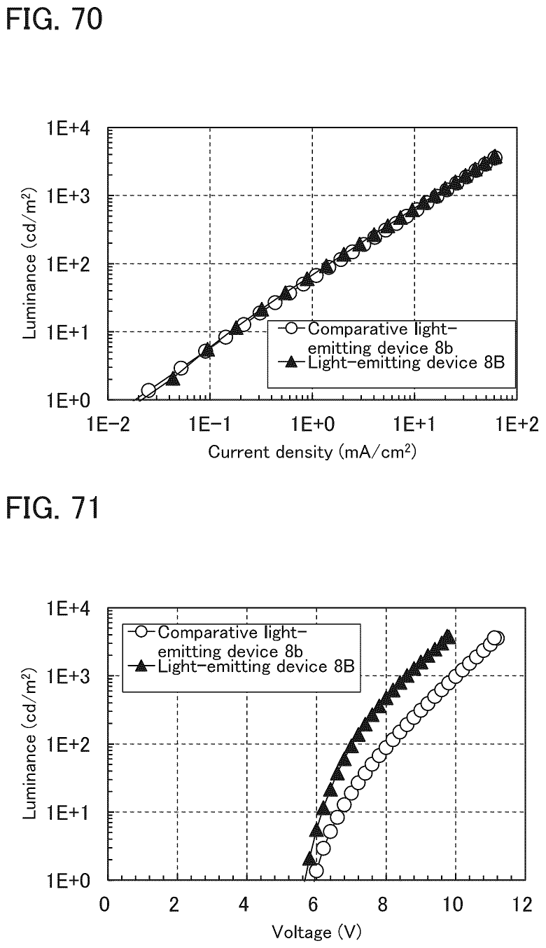

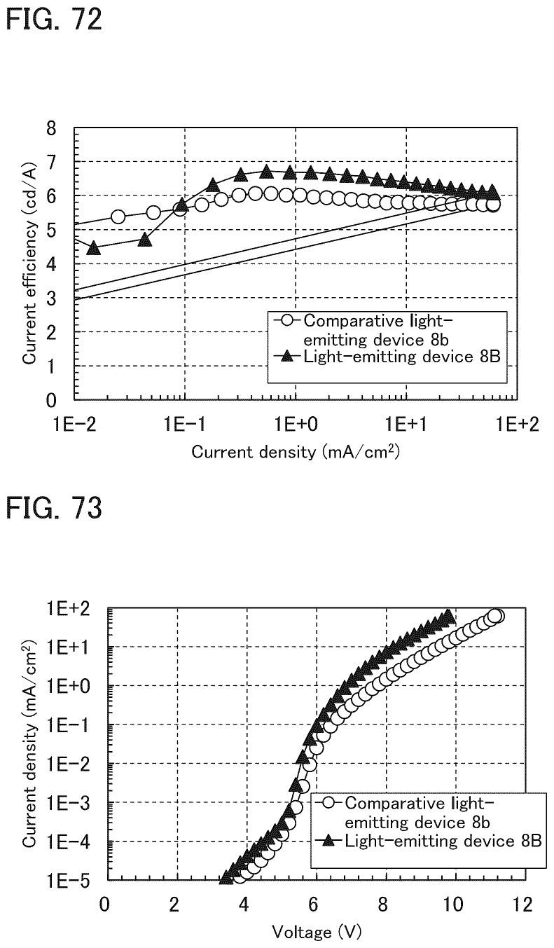

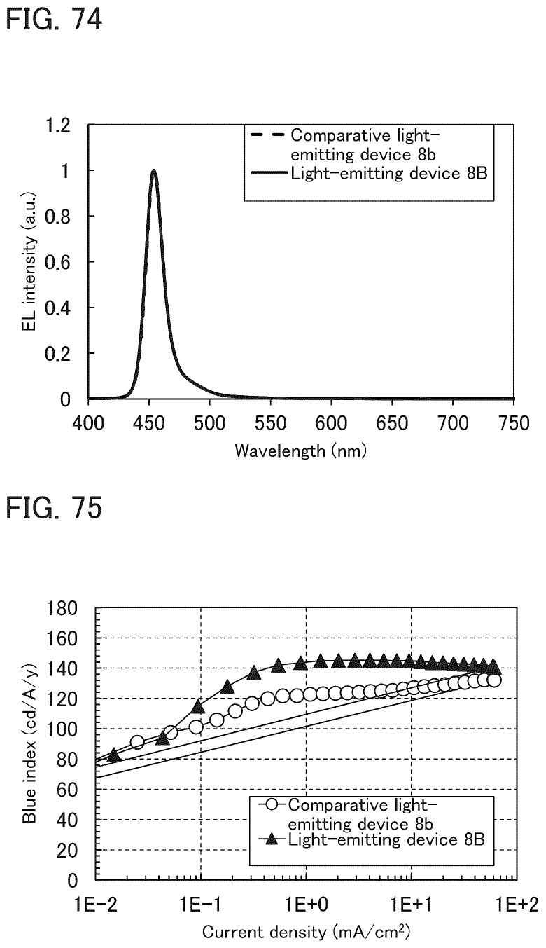

FIG. 60 shows the luminance-current density characteristics of the light-emitting device 8G and the comparative light-emitting device 8g, FIG. 61 shows the luminance-voltage characteristics of the light-emitting device 8G and the comparative light-emitting device 8g, FIG. 62 shows the current efficiency-current density characteristics of the light-emitting device 8G and the comparative light-emitting device 8g, FIG. 63 shows the current density-voltage characteristics of the light-emitting device 8G and the comparative light-emitting device 8g, and FIG. 64 shows the electroluminescence spectra of the light-emitting device 8G and the comparative light-emitting device 8g. FIG. 65 shows luminance-current density characteristics of the light-emitting device 8R and the comparative light-emitting device 8r. FIG. 66 shows luminance-voltage characteristics of the light-emitting device 8R and the comparative light-emitting device 8r. FIG. 67 shows current efficiency-current density characteristics of the light-emitting device 8R and the comparative light-emitting device 8r. FIG. 68 shows current density-voltage characteristics of the light-emitting device 8R and the comparative light-emitting device 8r. FIG. 69 shows electroluminescence spectra of the light-emitting device 8R and the comparative light-emitting device 8r. FIG. 70 shows the luminance-current density characteristics of the light-emitting device 8B and the comparative light-emitting device 8b, FIG. 71 shows the luminance-voltage characteristics of the light-emitting device 8B and the comparative light-emitting device 8b, FIG. 72 shows the current efficiency-current density characteristics of the light-emitting device 8B and the comparative light-emitting device 8b, FIG. 73 shows the current density-voltage characteristics of the light-emitting device 8B and the comparative light-emitting device 8b, FIG. 74 shows the electroluminescence spectra of the light-emitting device 8B and the comparative light-emitting device 8b, and FIG. 75 shows the blue index-current density characteristics of the light-emitting device 8B and the comparative light-emitting device 8b.

Note that the blue index (BI) is a value obtained by dividing current efficiency (cd/A) by the y value of CIE chromaticity (x, y), and is one of the indicators of characteristics of blue light emission. As the y chromaticity value of blue light emission becomes smaller, the color purity thereof tends to be higher. Blue light emission having a small y chromaticity value and high color purity enables expression of blue colors with a wide range of chromaticity in a display. Using blue light emission with high color purity reduces the luminance of light emission necessary for a display to express white, leading to lower power consumption of the display. Thus, BI, which is current efficiency based on a y chromaticity value as one of the indicators of color purity of blue, is suitably used as a means for showing efficiency of blue light emission. The light-emitting device with higher BI can be regarded as a blue-light-emitting device having higher efficiency for a display.

The following table shows the main characteristics of the light-emitting devices 8 at a luminance of approximately 1000 cd/m². The luminance, CIE chromaticity, and electroluminescence spectra were measured at normal temperature with a spectroradiometer (SR-ULIR, TOPCON TECHNOHOUSE CORPORATION).

TABLE 32

| | | | Current | | | | Current | |
|---|---|---|---|---|---|---|---|---|
| | Voltage | Current | density | Chromaticity | Chromaticity | Luminance | efficiency | BI value |
| | (V) | (mA) | (mA/cm²) | x | y | (cd/m²) | (cd/A) | (cd/A/y) |
| Light-emitting | 5.40 | 0.0089 | 0.543 | 0.24 | 0.72 | 1079 | 194.6 | — |
| device 8G | | | | | | | | |
| Comparative light- | 5.80 | 0.0092 | 0.566 | 0.23 | 0.73 | 1156 | 200.3 | — |
| emitting device 8g | | | | | | | | |
| Light-emitting | 5.60 | 0.0313 | 1.915 | 0.69 | 0.31 | 1132 | 58.0 | — |
| device 8R | | | | | | | | |
| Comparative light- | 6.60 | 0.0308 | 1.884 | 0.69 | 0.31 | 1013 | 52.7 | — |
| emitting device 8r | | | | | | | | |
| Light-emitting | 8.60 | 0.2566 | 15.702 | 0.15 | 0.04 | 1011 | 6.3 | 143.8 |
| device 8B | | | | | | | | |
| Comparative light- | 10.00 | 0.2715 | 16.612 | 0.15 | 0.04 | 978 | 5.8 | 128.5 |
| emitting device 8b | | | | | | | | |

FIG. 60 to FIG. 64 and the above table show that the light-emitting device 8G and the comparative light-emitting device 8g exhibited green light emission originating from Ir(5rppy-d₃)₂(mbfpypy-d₃). The light-emitting device 8G is proven to have favorable emission characteristics and have a lower driving voltage than the comparative light-emitting device 8g.

According to FIG. 65 to FIG. 69 and the above table, the light-emitting device 8R and the comparative light-emitting device 8r exhibited red light emission originating from OCPG-006. The light-emitting device 8R is proven to have favorable emission characteristics and have a lower driving voltage and higher current efficiency than the comparative light-emitting device 8r.

FIG. 70 to FIG. 75 and the above table show that the light-emitting device 8B and the comparative light-emitting device 8b exhibited blue light emission originating from 3,10PCA2Nbf(IV)-02. The light-emitting device 8B is proven to have favorable emission characteristics and have a lower driving voltage and higher current efficiency than the comparative light-emitting device 8b. Furthermore, it is also shown that the light-emitting device 8B has a high BI value and is a blue-light-emitting device with high efficiency.

The above description shows that the light-emitting devices 8G, 8R, and 8B have better characteristics than the comparative light-emitting devices 8g, 8r, and 8b, respectively. This is because the characteristics of the comparative light-emitting devices 8g, 8r, and 8b each including lithium in the electron-injection buffer region of the intermediate layer varied through a process of processing the organic compound layer by a photolithography method. Meanwhile, the light-emitting devices 8G, 8R, and 5B, which are the light-emitting devices of embodiments of the present invention, are confirmed to have small variations in characteristics even through a process of processing the organic compound layer by a photolithography method.

### <Reliability Test Result>

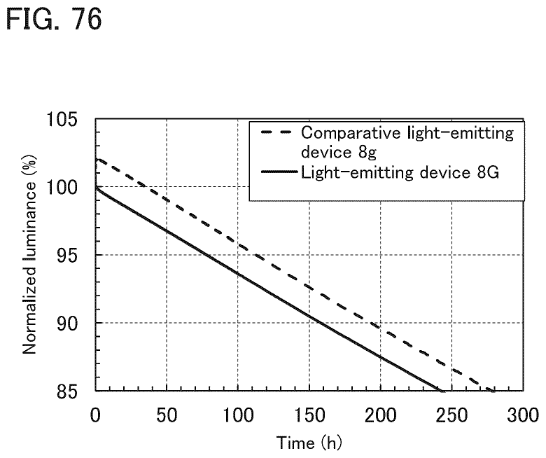

A reliability test was performed on each of the light-emitting devices 8. FIGS. 76 to 78 show a time-dependent change in normalized luminance at the time of constant current density driving (50 [mA/cm²]). In FIGS. 76 to 78, the vertical axis represents the luminance (%) normalized with the luminance at the time of the start of emission as 100%, and the horizontal axis represents the time (h).

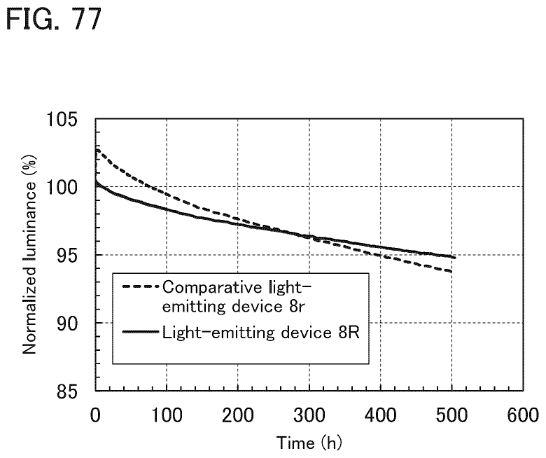

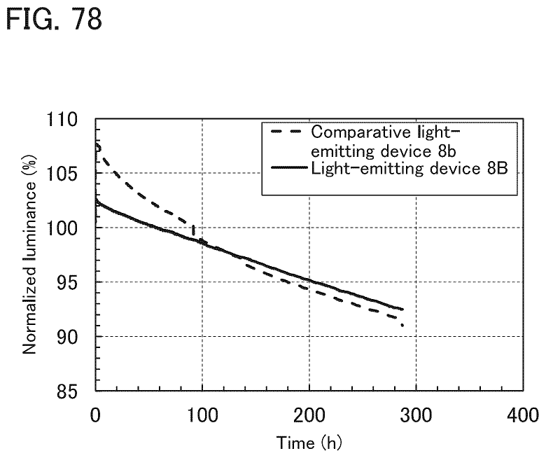

FIG. 76 shows the measurement results of the light-emitting device SG and the comparative light-emitting device 8g. FIG. 77 shows measurement results of the light-emitting device 8R and the comparative light-emitting device 8r. FIG. 78 shows measurement results of the light-emitting device 8B and the comparative light-emitting device 8b.

As shown in FIG. 76, FIG. 77, and FIG. 78, the comparative light-emitting devices 8g, 8r, and 8b each exhibited unstable behavior in which the luminance decreased after the luminance rapidly increased at the initial stage of driving. On the other hand, the light-emitting devices 8G, 8R, and 8B exhibited a gradual decrease in luminance from the initial driving stage and were driven as stable light-emitting devices.

In addition, LT95 (h), which is the time that has elapsed until the measured luminance decreases to 95% of the initial luminance, of the light-emitting device 8G was 78 hours. The LT95(h) of the light-emitting device 8R was 476 hours. The LT95(h) of the light-emitting device 8B was 204 hours.

The above results show that the light-emitting devices of embodiments of the present invention have favorable characteristics and particularly, a low driving voltage, high emission efficiency, and high reliability.

### Example 9

This example describes a display device manufactured by forming organic compound layers in all the pixels using the light-emitting device of one embodiment of the present invention so as to make a resolution of 3207 ppi.

The specifications of the display device are shown in the following table.

TABLE 33

| | |
|---|---|
| Screen diagonal | 1.50″ |
| Structure | OS LSI/SI LSI |
| Resolution | 3840 × 2880 |
| Pixel size | 7.92 um × 7.92 um |
| Pixel density | 3,207 ppi |
| Aperture ratio | 53.00% |
| Pixel arrangement | S-stripe |
| Coloring method | RGB side-by-side patterning |
| | in tandem OLED |
| Emission type | Top emission |
| Source driver | Integrated |
| Scan driver | Integrated |
| Luminance | 15,000 cd/m² |
| Color gamut | DCI-P3 96% |

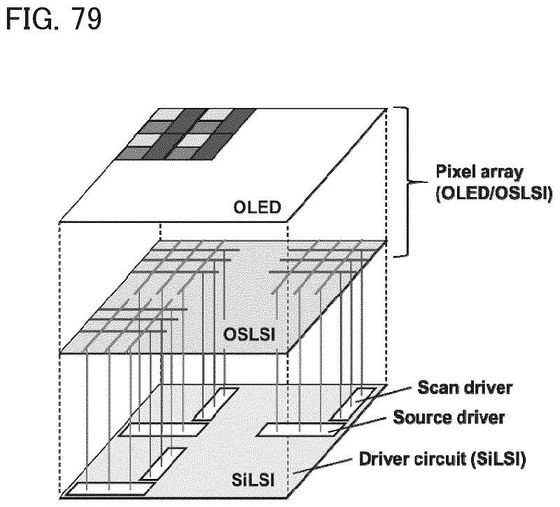

As shown in the above table, a structure in which transistors including an oxide semiconductor (OSFETs) was monolithically stacked over a CMOS circuit using Si transistors (Si CMOS) (denoted by OS LSI/Si LSI in the table) was used for the backplane of the display device. FIG. 79 is a conceptual diagram of the stacked-layer structure in the display device. With the use of a backplane having such a structure, a driver using Si transistors (denoted as a scan driver or a source driver in the drawing) is placed under a display region, which enables a smaller chip size and a larger number of chips taken, resulting in cost reduction.

Furthermore, in pixels of the display device, light-emitting devices each having a tandem structure were used, and subpixels of blue (B), green (G), and red (R) were formed by a photolithography process. The light-emitting devices of the subpixels of blue (B), green (G), and red (R) each include the organic compounds used for the light-emitting layers of the light-emitting devices 8B, 8G, and 8R described in Example 8, and include 6,6′(P-Bqn)2BPy, Hid2Phen, and Li₂O in the intermediate layer.

In the display device, the organic compound layer was patterned by a photolithography method; thus, a high resolution of 3207 ppi and a high aperture ratio of 53.0% were achieved as shown in the above table. In addition, separation of the organic compound layers on a subpixel basis can reduce a current leakage path between the subpixels and prevent color mixture due to light emission due to leakage current; hence, as shown in the above table, the display device achieves a 96% or higher coverage of DCI-P3 (Digital Cinema Initiatives P3) standard for digital cinema.

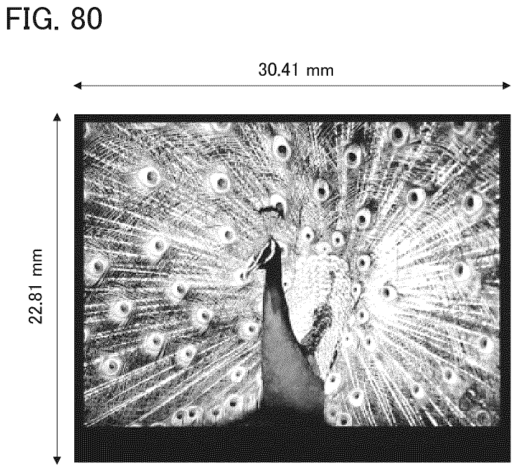

FIG. 80 shows a display result of the fabricated display device. The organic compound layers in all the pixels were formed by a photolithography process; however, there was no problem with the characteristics and circuit operation of the light-emitting devices and an extremely clear image was displayed.

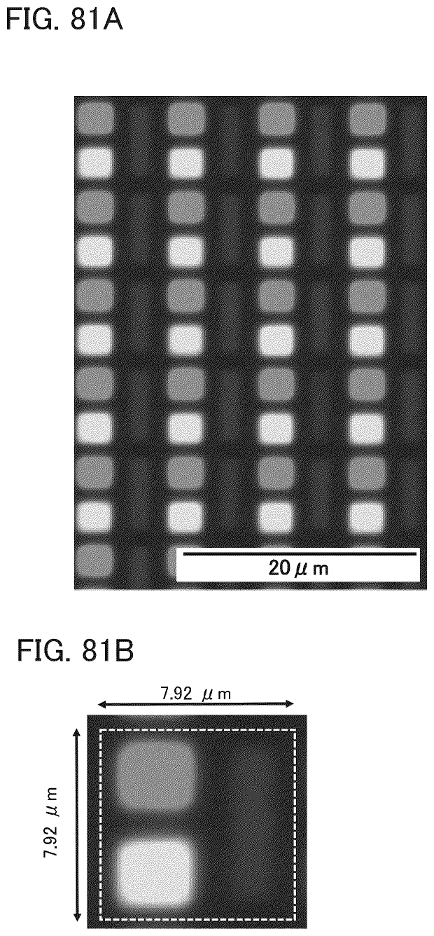

Next, optical micrographs of the pixels of the fabricated display are shown in FIGS. 81A and 81B. Note that FIG. 81B is an enlarged optical micrograph of one pixel of the pixels illustrated in FIG. 81A. The subpixels of red (R), green (G), and blue (B) formed by a photolithography process were observed to emit light normally. The aperture ratio in the dashed square in FIG. 81B was 53.0%.

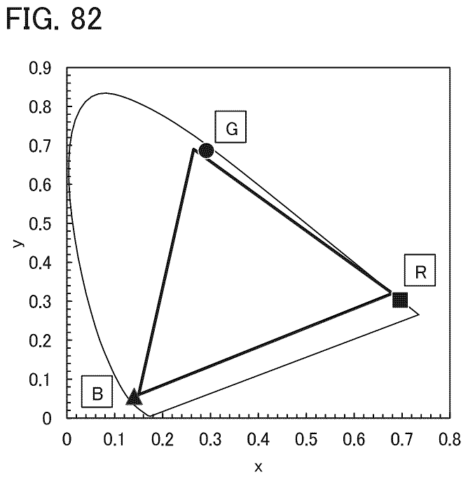

Next, FIG. 82 shows CIE 1931 chromaticity coordinates (three points of R, G, and B) of the fabricated display device with red (R), green (G), and blue (B) light emission. Note that measurement was performed from the front of the display device, and thus the chromaticity shown in FIG. 82 can be regarded as the chromaticity in the front direction (front chromaticity) of the display device. A horseshoe curve (solid line) representing a visible-light region and a color gamut (thick solid line) in the DCI-P3 standard are also shown in FIG. 82.

FIG. 82 shows that the display device of this example had an extremely high DCI-P3 coverage of 96% or higher. In general, one of problems of a high-resolution organic EL device is a reduction in color purity due to lateral leakage current, This is because a leakage current flows through an organic compound layer with high conductivity to an adjacent pixel. Thus, a problem of lateral leakage more significantly occurs in a display device using a tandem light-emitting device in which an intermediate layer with high conductivity is included in an organic compound layer, which might reduce color purity. Meanwhile, in the light-emitting device of one embodiment of the present invention, a current leakage path between pixels can be eliminated by processing by a photolithography method; thus, color mixture of light emission due to leakage current was prevented.

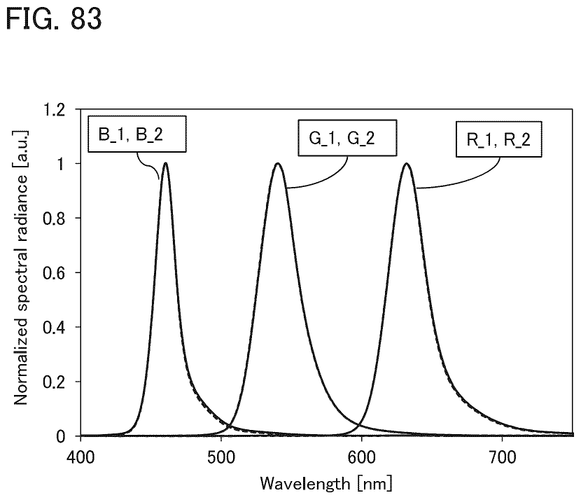

FIG. 83 shows electroluminescence spectra of the display device of this example. The vertical axis of the graph represents nonnalized spectral radiance (arbitrary unit: a.u.).

As shown in FIG. 83, the measurement was conducted at two kinds (high luminance and low luminance) of luminance for each color. R_1 and R_2 respectively indicate measurement results at 100 cdlm² and 1 cdlm², G_1 and G_2 respectively indicate measurement results at 100 cd/m² and 1 cd/m², and B_1 and B_2 respectively indicate measurement results at 100 cd/m² and 1 cd/m².

As shown in FIG. 83, it was found that nonnalized spectra in the red display, the green display, and the blue display in the high luminance conditions (R_1, G_1, and B_1) largely overlapped with those in the low luminance conditions (R_2, G_2, and B_2), respectively. That is, no color mixture due to lateral leakage was observed under the low luminance condition (1 cd/m²), and only the spectrum of emitted color was observed. It is thus proven that the use of the light-emitting device of one embodiment of the present invention can overcome the problem of the lateral leakage caused by the intermediate layer.

As described above, a high-resolution display device can be achieved by using the light-emitting device of one embodiment of the present invention,

### Example 10

In this example, the light-emitting devices 10 (the light-emitting device 10B, the light-emitting device 10G, and the light-emitting device 10R) were fabricated and their characteristics were evaluated. The light-emitting devices 10 each have a tandem structure including the intermediate layer that can be used for the light-emitting device of one embodiment of the present invention.

The light-emitting devices 10B, 10G, and 10R (light-emitting devices 10) each were fabricated by an MML process in which the organic compound layer was processed by a photolithography method. The light-emitting devices 10 were fabricated by forming organic compound layers so as to make a resolution of 3207 ppi. Structural Formulas of organic compounds used for the light-emitting devices 10 are shown below.

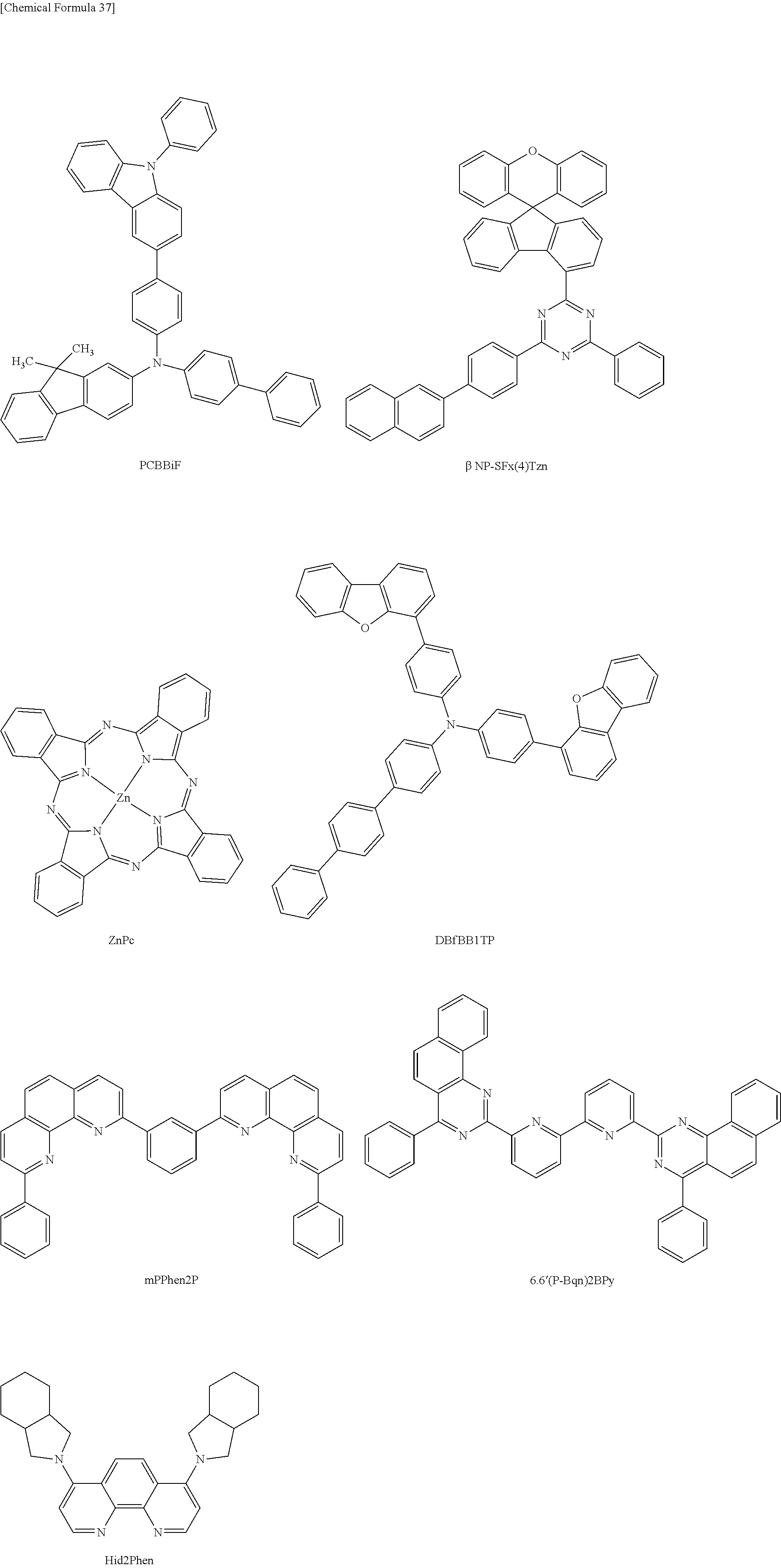

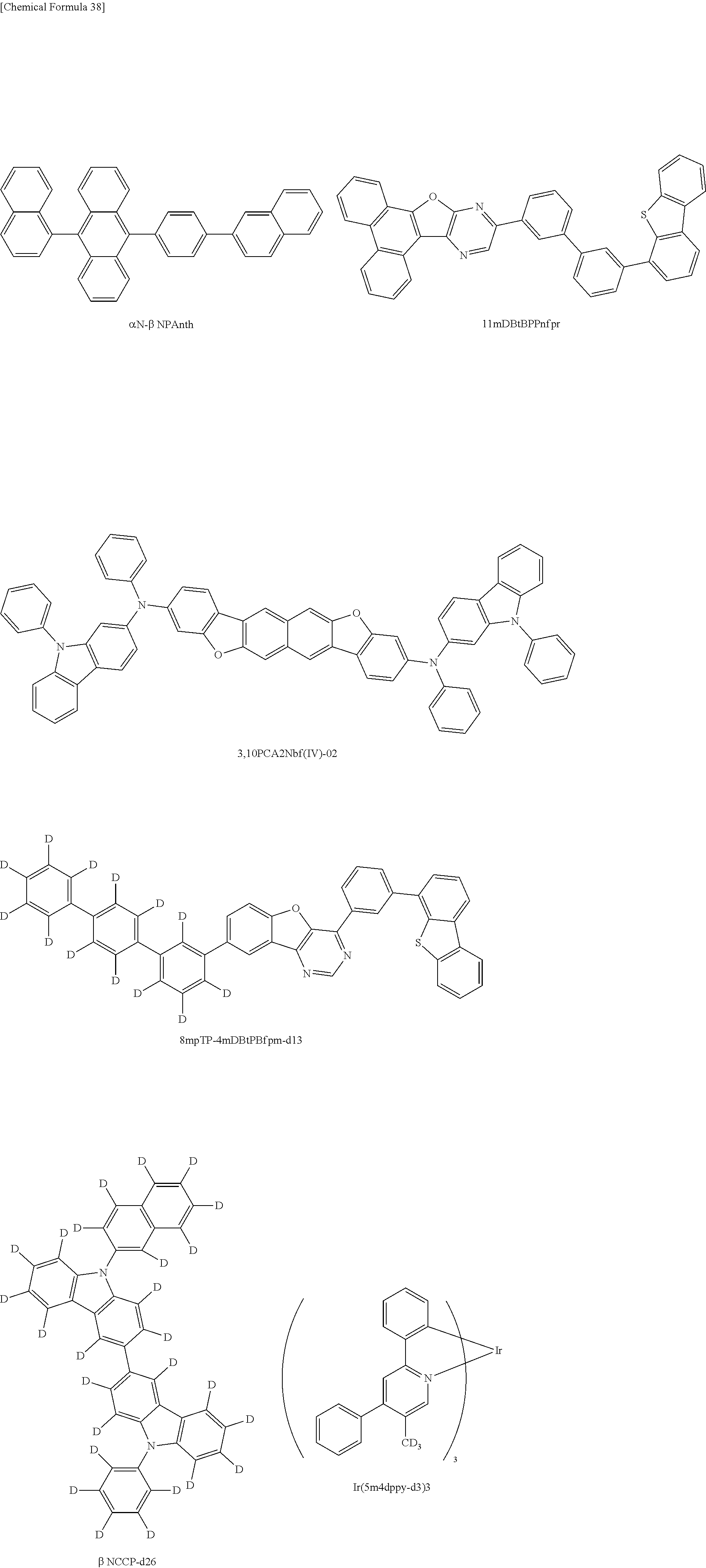

The light-emitting devices 10B, 10G, and 10R each have a tandem structure in which the first EL layer 903, the intermediate layer 905, the second EL layer 904, and the second electrode 902 are stacked over the first electrode 901 formed over the substrate 900 that is a silicon substrate, as illustrated in FIG. 18. Furthermore, the cap layer 909 is provided over the second electrode.

Here, in the case where the structures of the light-emitting devices 10B, 10G, and 10R are separately described, B, G, or R is sometimes added to each reference numeral. In other words, the first EL layer of the light-emitting device 10B is denoted by the first EL layer 903B.

The first EL layer 903 has a structure in which the hole-injection layer 910, the first hole-transport layer 911, the first light-emitting layer 912, and the first electron-transport layer 913 are stacked in this order. The intermediate layer 905 includes the electron-injection buffer region 914 and the layer 915 including an electron-relay region and a charge-generation region. The second EL layer 904 has a structure in which the second hole-transport layer 916, the second light-emitting layer 917, the second electron-transport layer 918, and the electron-injection layer 919 are stacked in this order.

### <Fabrication Method of Light-Emitting Device 10>

As a reflective electrode in the first electrode 901, a 50-nm-thick T₁ film, a 70-nm-thick Al film, and a 2-nm-thick T₁ film were first deposited over a silicon substrate from the substrate side. Second, as a transparent electrode in the first electrode 901, indium tin oxide containing silicon oxide (ITSO) was deposited to a thickness of 10 nm by a sputtering method. In this manner, the first electrode 901 was formed.

Note that the first electrodes were formed to make matrix arrangement of 251×251 pixels) in an area of 2 mm×2 mm. This shape and arrangement correspond to a resolution of 3207 ppi, and each pixel was formed to include three subpixels.

Next, in pretreatment for forming the light-emitting device over the substrate, a surface of the substrate was washed with water and surface treatment using a silylating agent such as hexamethyldisilazane (HMDS) was performed at 60° C.

After that, the substrate was transferred into a vacuum evaporation apparatus where the internal pressure was reduced to approximately 1×10⁻⁴ Pa, and was subjected to heat treatment at 170° C. for 60 minutes in a heating chamber of the vacuum evaporation apparatus, and then, the substrate was cooled down for approximately 30 minutes.

Components up to and including a second electron-transport layer 918B of the light-emitting device 10B were formed.

Then, the substrate provided with the first electrode 901 was fixed to a substrate holder provided in the vacuum evaporation apparatus such that the surface on which the first electrode 901 was formed faced downward. The hole-injection layer 910B was deposited to a thickness of nm over the first electrode 901 by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) by a resistance heating evaporation method so as to have a PCBBiF:OCHD-003 weight ratio of 1:0.03.

Subsequently, a first hole-transport layer 911B was deposited over the hole-injection layer 910B by evaporation of PCBBiF to a thickness of 20 nm, followed by evaporation of N,N-bis[4-(dibenzofuran-4-yl)phenyl]-4-amino-p-terphenyl (abbreviation: DBfBB1TP) to a thickness of 10 nm.

Next, a first light-emitting layer 912B was formed over the first hole-transport layer 911B. The first light-emitting layer 912B was deposited to a thickness of 25 nm by co-evaporation of 9-(1-naphthyl)-10-[4-(2-naphthyl)phenyl]anthracene (abbreviation: αN-βNPAnth) and 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) by a resistance heating evaporation method to have an αN-βNPAnth:3,10PCA2Nbf(IV)-02 weight ratio of 1:0.015.

Next, a first electron-transport layer 913B was deposited to a thickness of 10 nm over the first light-emitting layer 912B by evaporation of 2-[4-(2-naphthalenyl)phenyl]-4-phenyl-6-spiro[9H-fluorene-9,9′-[9H-]xanthen]-4-yH,3,5-triazine (abbreviation: βNP-SFx(4)Tzn).

Next, an intermediate layer 905B was provided. First, a layer to be an electron-injection buffer region 914B was formed to a thickness of 5 nm over the first electron-transport layer 913B by co-evaporation of 2,2′-(2,2′-bipyridine-6,6′-diyl)bis(4-phenylbenzo[h]quinazoline) (abbreviation: 6,6′(P-Bqn)2BPy), 4,7-di(2,3,3a,4,5,6,7,7a-octahydro-1H-isoindol-2-yl)-1,10-phenanthroline (abbreviation: Hid2Phen), and Li₂O by a resistance heating evaporation method so as to have a 6,6′(P-Bqn)2BPy:Hid2Phen: Li₂O volume ratio of 4:1:0.05.

Then, as the electron-relay region, copper phthalocyanine (abbreviation: CuPc) was deposited to a thickness of 2 nm. Next, as the charge-generation region, a layer 915B including the charge-generation region was deposited to a thickness of 10 nm by co-evaporation of PCBBiF and a fluorine-containing electron acceptor material with a molecular weight of 672 (OCHD-003) by a resistance heating evaporation method so as to have a PCBBiF:OCHD-003 weight ratio of 1:0.15.

Next, a second EL layer 904B was provided. First, a second hole-transport layer 916B was deposited by evaporation PCBBiF to a thickness of 30 nm, followed by evaporation of DBfBBITP to a thickness of 10 nm.

Next, a second light-emitting layer 917B was deposited to a thickness of 25 nm over the second hole-transport layer 916B by co-evaporation of αN-βNPAnth and 3,10PCA2Nbf(IV)-02 by a resistance heating evaporation method so as to have an αN-βNPAnth:3,10PCA2Nbf(JV)-02 weight ratio of 1:0.015.

Then, the second electron-transport layer 918B was deposited over the second light-emitting layer 917B by evaporation of βNP-SFx(4)Tzn to a thickness of 10 nm, followed by evaporation of 2,2′-(1,3-phenylene)bis(9-phenyl-1,10-phenanthroline) (abbreviation: mPPhen2P) to a thickness of 15 nm.

After the formation of the second electron-transport layer 918B, processing by a photolithography method and heat treatment were performed.

### <<First Processing by Photolithography Method>>

After the second electron-transport layer 918B was formed, the substrate was taken out from the vacuum evaporation apparatus and exposed to the air. Then, as the first sacrificial layer, a film of aluminum oxide was deposited to a thickness of 30 nm by an ALD method using trimethylaluminum (abbreviation: TMA) as a precursor and water vapor as an oxidizer.

Next, a film of tungsten serving as the second sacrificial layer was deposited to a thickness of 54 nm over the first sacrificial layer by a sputtering method.

Then, a resist was formed using a photoresist over the second sacrificial layer, and processing was performed such that an end portion of the second sacrificial layer was located in a similar manner to an end surface of the first electrode.

Specifically, the second sacrificial layer was processed using an etching gas containing sulfur hexafluoride (SF₆) using the resist as a mask, and then the first sacrificial layer was processed using an etching gas containing fluoroform (CHF₃), helium (He), and methane (CH₄). After that, the second electron-transport layer, the second light-emitting layer, the second hole-transport layer, the intermediate layer, the first electron-transport layer, the first light-emitting layer, the first hole-transport layer, and the hole-injection layer were processed using an etching gas containing oxygen (O₂).

The above is the description of the processing by a photolithography method. As described above, the processing by a photolithography method and treatment using water or a chemical solution containing water as a solvent were performed.

Then, components up to and including a second electron-transport layer 918G of the light-emitting device 10G were formed.

The substrate provided the components up to and including the second electron-transport layer 918B of the light-emitting device 10B was introduced into a vacuum evaporation apparatus where the internal pressure was reduced to approximately 1×10¹ Pa such that the surface on which the first electrode 901 was formed faced downward. After that, the hole-injection layer 910G was deposited to a thickness of 10 nm over the first electrode 901 by co-evaporation of PCBBiF and an electron acceptor material containing fluorine with a molecular weight of 672 (OCHD-003) so as to have a PCBBiF:OCHD-003 weight ratio of 1:0.03.

Next, a first hole-transport layer 911G was deposited to a thickness of 42.5 nm over the hole-injection layer 910G by evaporation of PCBBiF.

Next, a first light-emitting layer 912G was formed over the first hole-transport layer 911G. Then, the first light-emitting layer 912G was deposited to a thickness of 40 nm by co-evaporation of 8-(1,1′: 4′, 1″-terphenyl-3-yl-2,4,5,6,2′, 3′, 5′, 6′, 2″, 3″, 4″, 5″, 6″-d₁₃)-4-[3-(dibenzothiophen-4-yl)phenyl]-[1]benzofuro[3,2-d]pyrimidine (abbreviation: 8mpTP-4mDBtPBfpm-d₁₃), 9-(2-naphthyl-1,3,4,5,6,7,8-d)-9′-(phenyl-2,3,4,5,6-ds)-3,3′-bi-9H-carbazole-1,1′, 2,2′, 4,4′, 5,5′, 6,6′, 7,7′, 8,8′-d₁₄ (abbreviation: βNCCP-d26), andtris{2-[5-(methyl-d3)-4-phenyl-2-pyridinyl-κN]phenyl-κC}iridium(II) (abbreviation: ir(5m4dppy-d₃)₃) by a resistance heating evaporation method so as to have an 8mpTP-4mDBtPBfpm-d₁₃:βNCCP-d₂₆:Ir(5m4dppy-d₃)₃ weight ratio of 0.5:0.5:0.1.

Next, a first electron-transport layer 913G was deposited to a thickness of 10 nm over the first light-emitting layer 912G by evaporation of βNP-SFx(4)Tzn.

Next, an intermediate layer 905G was provided. First, a layer to be an electron-injection buffer region 914G was deposited to a thickness of 5 nm over the first electron-transport layer 913G by co-evaporation of 6,6′(P-Bqn)₂BPy, Hid2Phen, and Li₂O so as to have a 6,6′(P-Bqn)₂BPy:Hid2Phen:Li₂O volume ratio of 4:1:0.05.

Then, as the electron-relay region, ZnPc was deposited to a thickness of 2 nm. Next, as the charge-generation region, a layer 915G including the charge-generation region was deposited to a thickness of 10 nm by co-evaporation of PCBBiF and a fluorine-containing electron acceptor material with a molecular weight of 672 (OCHD-003) by a resistance heating evaporation method so as to have a PCBBiF:OCHD-003 weight ratio of 1:0.15.

Next, a second EL layer 904G was provided. First, a second hole-transport layer 916G was deposited to a thickness of 55 nm by evaporation of PCBBiF.

Next, a second light-emitting layer 917G was deposited to a thickness of 40 nm over the second hole-transport layer 916G by co-evaporation of 8mpTP-4mDBtPBfpm-d₃, P—NCCP-d26, and Ir(5m4dppy-d₃)3 by a resistance heating evaporation method so as to have an 8mpTP-4mDBtPBfpm-d₁:βNCCP-d₂6:Ir(5m4dppy-d₃)₃ weight ratio of 0.5:0.5:0.1.

Next, the second electron-transport layer 918G was deposited over the second light-emitting layer 917G by evaporation of βNP-SFx(4)Tzn to a thickness of 10 nm, followed by evaporation of mPPhen2P to a thickness of 15 nm.

After the formation of the second electron-transport layer 918G, processing by a photolithography method and heat treatment were performed.

### <<Second Processing by Photolithography Method>>

After the formation of the second electron-transport layer 918G, processing by a photolithography method and heat treatment were performed.

Specifically, treatment similar to the treatment described in <<First processing by photolithography method>> was performed. Accordingly, the processing by a photolithography method and treatment using water or a chemical solution containing water as a solvent were performed.

Next, the components up to and including a second electron-transport layer 918R of the light-emitting device 10R were formed.

The substrate provided with the components up to and including the second electron-transport layer 918B of the light-emitting device 10B and the second electron-transport layer 918G of the light-emitting device 10G was introduced into a vacuum evaporation apparatus where the pressure was reduced to approximately 1×10⁻⁴ Pa such that the surface on which the first electrode 901 was formed faced downward. After that, a hole-injection layer 910R was deposited to a thickness of 10 nm over the first electrode 901 by co-evaporation of PCBBiF and an electron acceptor material containing fluorine with a molecular weight of 672 (OCHD-003) so as to have a PCBBiF:OCHD-003 weight ratio of 1:0.03.

Next, a first hole-transport layer 911R was deposited to a thickness of 62.5 nm over the hole-injection layer 910R by evaporation of PCBBiF.

Next, a first light-emitting layer 912R was formed over the first hole-transport layer 911R. The first light-emitting layer 912R was deposited to a thickness of 40 nm by co-evaporation of 11-[3′-(dibenzothiophen-4-yl)bipheny-3-yl]phenanthro[9′, 10′: 4,5]furo[2,3-b]pyrazine (abbreviation: 11mDBtBPPnfpr), PCBBiF, and OCPG-006, which is a material emitting red phosphorescent light by a resistance-heating evaporation method so as to have a 11mDBtBPPnfpr: PCBBiF:OCPG-006 weight ratio of 0.7:0.3:0.05.

Next, a first electron-transport layer 913R was deposited to a thickness of 10 nm over the first light-emitting layer 912R by evaporation of βNP-SFx(4)Tzn.

Next, an intermediate layer 905R was provided. First, a layer to be an electron-injection buffer region 914R was deposited to a thickness of 5 nm over the first electron-transport layer 913R by co-evaporation of 6,6′(P-Bqn)₂BPy, Hid2Phen, and Li₂O so as to have a 6,6′(P-Bqn)₂BPy:Hid2Phen:Li₂O volume ratio of 4:1:0.05.

Then, as the electron-relay region, ZnPc was deposited to a thickness of 2 nm. Next, as the charge-generation region, a layer 915R including the charge-generation region was deposited to a thickness of 10 nm by co-evaporation of PCBBiF and a fluorine-containing electron acceptor material with a molecular weight of 672 (OCHD-003) by a resistance heating evaporation method so as to have a PCBBiF:OCHD-003 weight ratio of 1:0.15,

Next, a second EL layer 904R was provided. First, a second hole-transport layer 916R was deposited to a thickness of 65 nm by evaporation of PCBBiF.

Next, a second light-emitting layer 917R was deposited to a thickness of 40 nm over the second hole-transport layer 916R by co-evaporation of 11mDBtBPPnfpr, PCIBBiF, and OCPG-006 so as to have a 11mDBtBPPnfpr:PCBBiF:OCPG-006 weight ratio of 0.7:0.3:0.05 by a resistance heating evaporation method.

Next, the second electron-transport layer 918R was deposited over the second light-emitting layer 917R by evaporation of βNP-SFx(4)Tzn to a thickness of 20 nm, followed by evaporation of mPPhen2P to a thickness of 25 nm.

After the formation of the second electron-transport layer 918R, processing by a photolithography method and heat treatment were performed.

### <<Third Processing by Photolithography Method>>

After the formation of the second electron-transport layer 918R, processing by a photolithography method and heat treatment were performed.

Specifically, treatment similar to the treatment described in <<First processing by photolithography method>> was performed. Accordingly, the processing by a photolithography method and treatment using water or a chemical solution containing water as a solvent were performed.

### <<Heat Treatment>

Next, the organic compound layer was processed and then heat treatment was performed. Specifically, the second sacrificial layer was removed using an etching gas containing sulfur hexafluoride (SF₆), and the first sacrificial layer was left. Then, as a protective film, a film of aluminum oxide was formed to a thickness of 15 nm by an ALD method.

Next, a layer of a photosensitive high molecular material was formed over the first electrode over the protective film by a photolithography method. After heating was performed at 100° C. in an air atmosphere for 10 minutes, unnecessary portions of the first sacrificial layer and the protective film were removed using a mixed acid aqueous solution containing hydrofluoric acid (HF), so that the second electron-transport layer was exposed. At this time, the layer of the photosensitive high molecular material functions as a resist.

Then, the substrate was transferred into a vacuum evaporation apparatus where the internal pressure was reduced to approximately 1×10⁴ Pa, and heat treatment was performed at 100° C. for 90 minutes in a heating chamber of the vacuum evaporation apparatus.

The above is the description of heat treatment. As described above, the heat treatment and the treatment using water or a chemical solution containing water as a solvent were performed.

After the processing by a photolithography method and the heat treatment, the electron-injection layer 919 was deposited to a thickness of 1.5 nm over the second electron-transport layer 918 (the second electron-transport layer 918B, the second electron-transport layer 918G, and the second electron-transport layer 918R) by co-evaporation of lithium fluoride (LiF) and ytterbium (Yb) so as to have a LiF:Yb volume ratio of 2:1.

Next, the second electrode 902 was deposited to a thickness of 15 nm over the electron-injection layer 919 by co-evaporation of Ag and Mg so as to have an Ag:Mg volume ratio of 1:0.1. Note that the second electrode 902 is a transflective electrode having functions of transmitting light and reflecting light.

After that, as a cap layer, indium tin oxide (ITO) was deposited to a thickness of 70 nm by a sputtering method, whereby light extraction efficiency was improved.

Through the above process, the light-emitting devices 10 (the light-emitting devices 10B, 10G, and 10R) were fabricated.

The table below lists the structures of the light-emitting devices 10B, 10G, and 10R.

TABLE 34

| | Thickness | |
|---|---|---|
| | [nm] | Light-emitting device 10B |
| Cap layer | 70 | ITO |
| Second electrode | 15 | Ag:Mg (1:0.1) |
| Electron-injection | 1.5 | LIF:Yb (2:1) |
| layer | | |

Processing by photolithography was performed

| | | |
|---|---|---|
| Second electron- | 15 | mPPhen2P |
| transport layer | 10 | βNP-SFx(4)Tzn |
| Second light-emitting | 25 | αN-βNP Anth:3,10PCA2Nbf(IV)-02 |
| layer | | (1:0.015) |
| Second hole-transport | 10 | DBfBB1TP |
| layer | 30 | PCBBiF |
| Charge-generation | 10 | PCBBiF:OCHD-003 (1:0.15) |
| region | | |
| Electron relay region | 2 | ZnPc |
| Electron-injection | 5 | 6,6′(P-Bqn)2BPy:Hid2Phen:Li2O |
| buffer region | | (4:1:0.05) |
| First electron- | 10 | βNP-SFx(4)Tzn |
| transport layer | | |
| First light-emitting | 25 | αN-βNP Anth:3,10PCA2Nbf(IV)-02 |
| layer | | (1:0.015) |
| First hole-transport | 10 | DBfBB1TP |
| layer | 20 | PCBBiF |
| Hole-injection layer | 10 | PCBBiF:OCHD-003 (1:0.03) |
| First electrode | 10 | ITSO |
| | 2 | Ti |
| | 70 | Al |
| | 50 | Ti |

TABLE 35

| | Thickness | |
|---|---|---|
| | [nm] | Light-emitting device 10G |
| Cap layer | 70 | ITO |
| Second electrode | 15 | Ag:Mg (1:0.1) |
| Electron-injection | 1.5 | LiF:Yb (2:1) |
| layer | | |

Processing by photolithography was performed

| | | |
|---|---|---|
| Second electron- | 15 | mPPhen2P |
| transport layer | 10 | βNP-SFx(4)Tzn |
| Second | 40 | 8mpTP-4mDBtPBfpm-d₁₃:BNCCP-d₂₆: |
| light-emitting | | Ir(5m4dppy-d₃)₃ |
| layer | | (0.5:0.5:0.1) |
| Second | 55 | PCBBiF |
| hole-transport | | |
| layer | | |
| Charge-generation | 10 | PCBBiF:OCHD-003 (1:0.15) |
| region | | |
| Electron relay | 2 | ZnPc |
| region | | |
| Electron-injection | 5 | 6,6′(P-Bqn)2BPy:Hid2Phen:Li₂O |
| buffer region | | (4:1:0.05) |
| First electron- | 10 | βNP-SFx(4)Tzn |
| transport layer | | |
| First light-emitting | 40 | 8mpTP-4mDBtPBfpm-d₁₃:BNCCP-d₂₆: |
| layer | | Ir(5m4dppy-d₃)₃ |
| | | (0.5:0.5:0.1) |
| First hole-transport | 42.5 | PCBBiF |
| layer | | |
| Hole-injection layer | 10 | PCBBiF:OCHD-003 (1:0.03) |
| First electrode | 10 | ITSO |
| | 2 | Ti |
| | 70 | A1 |
| | 50 | Ti |

TABLE 36

| | Thickness | |
|---|---|---|
| | [nm] | Light-emitting device 10R |
| Cap layer | 70 | ITO |
| Second electrode | 15 | Ag:Mg (1:0.1) |
| Electron-injection | 1.5 | LiF:Yb (2:1) |
| layer | | |

Processing by photolithography was performed

| | | |
|---|---|---|
| Second electron- | 25 | mPPhen2P |
| transport layer | 20 | βNP-SFx(4)Tzn |
| Second light-emitting | 40 | 11mDBtBPPnfpr:PCBBiF:OCPG-006 |
| layer | | (0.7:0.3:0.05) |
| Second hole-transport | 65 | PCBBiF |
| layer | | |
| Charge-generation | 10 | PCBBiF:OCHD-003 (1:0.15) |
| region | | |
| Electron-relay region | 2 | ZnPc |
| Electron-injection | 5 | 6,6′(P-Bqn)2BPy:Hid2Phen:Li₂O |
| buffer region | | (4:1:0.05) |
| First electron- | 10 | βNP-SFx(4)Tzn |
| transport layer | | |
| First light-emitting | 40 | 11mDBtBPPnfpr:PCBBiF:OCPG-006 |
| layer | | (0.7:0.3:0.05) |
| First hole-transport | 62.5 | PCBBiF |
| layer | | |
| Hole-injection layer | 10 | PCBBiF:OCHD-003 (1:0.03) |
| First electrode | 10 | ITSO |
| | 2 | Ti |
| | 70 | Al |
| | 50 | Ti |

### <Device Characteristics>

The light-emitting devices 10 were each sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting devices 10 were measured,

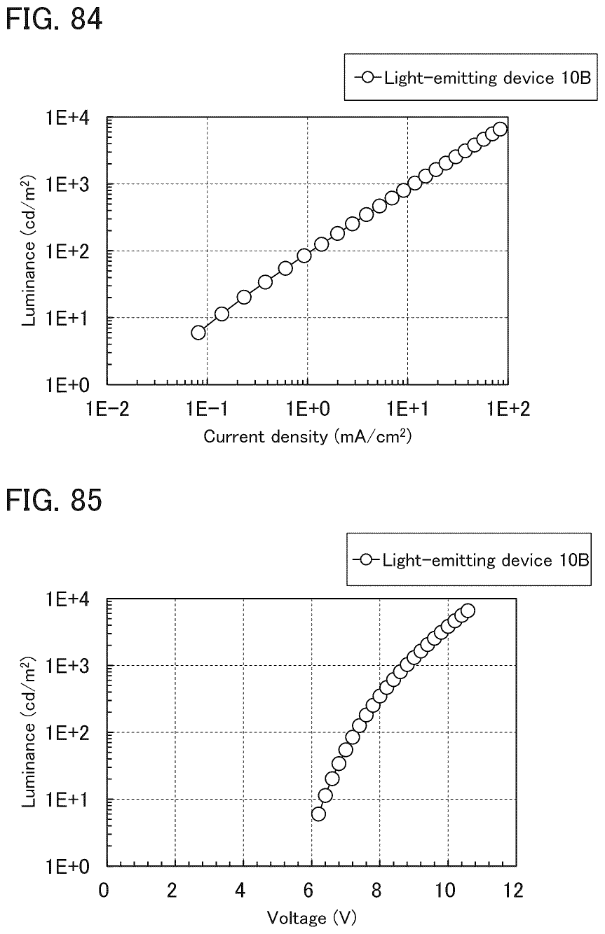

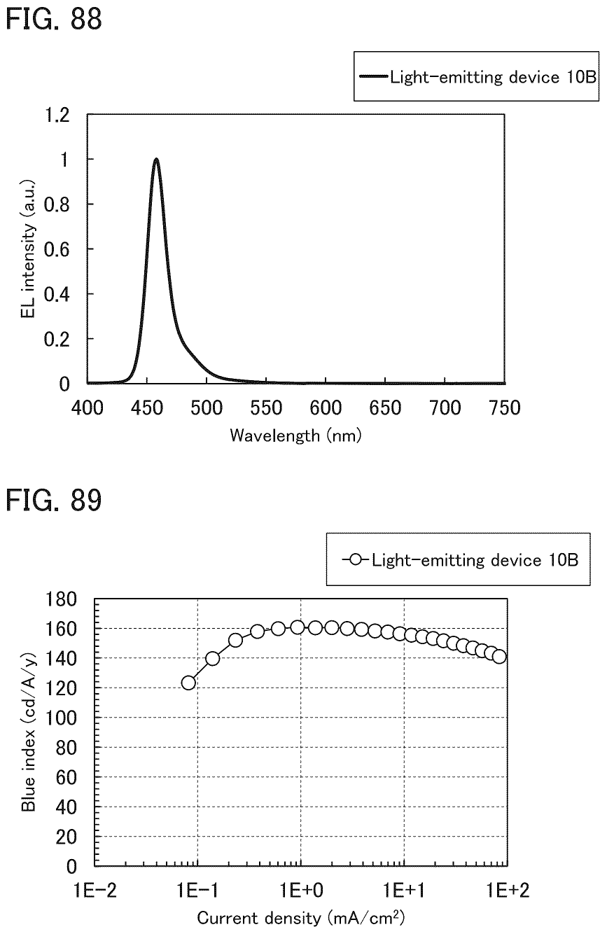

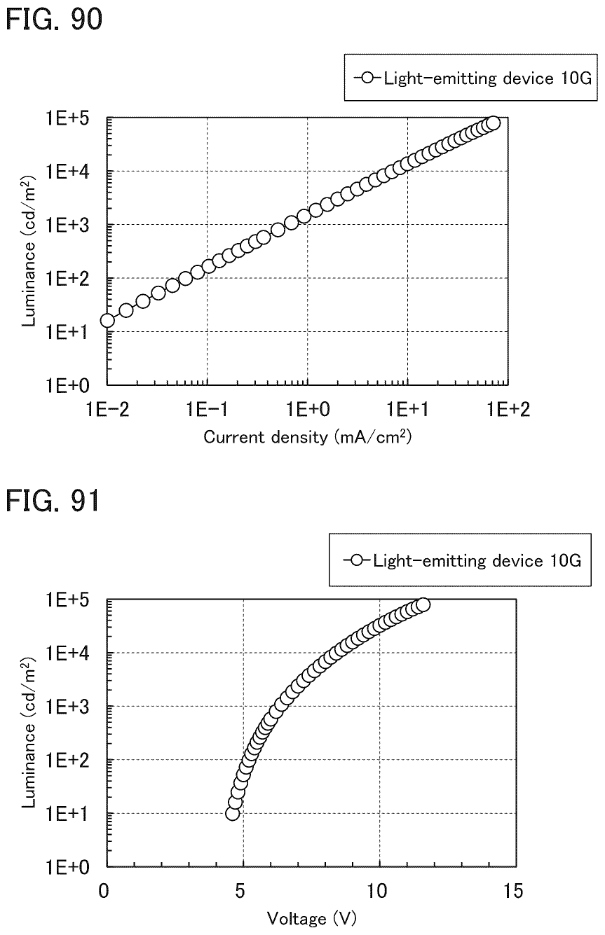

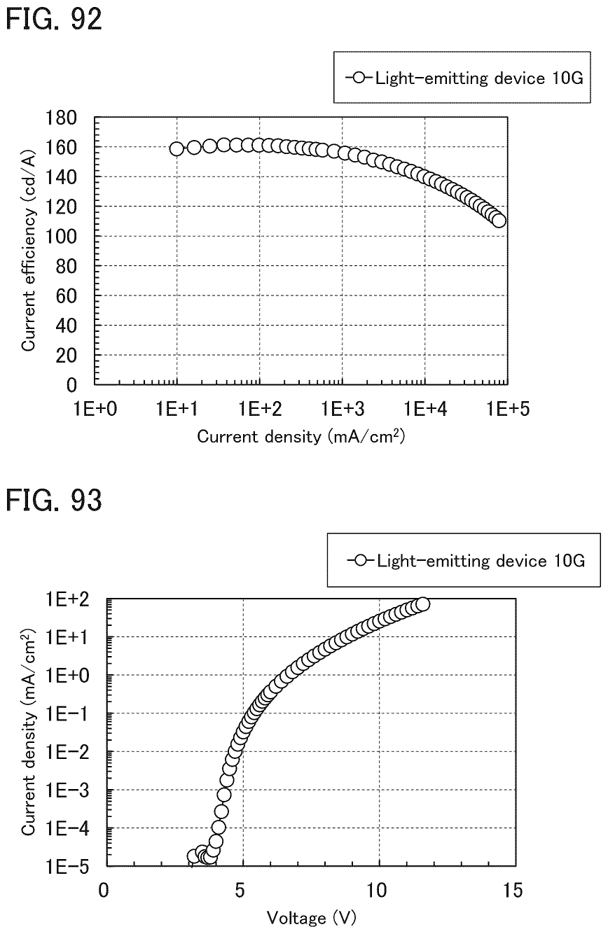

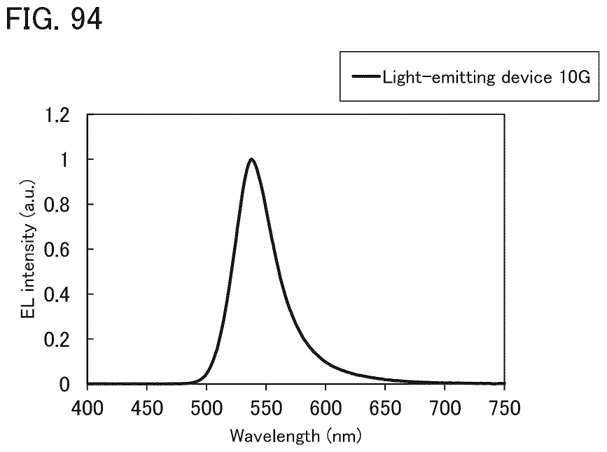

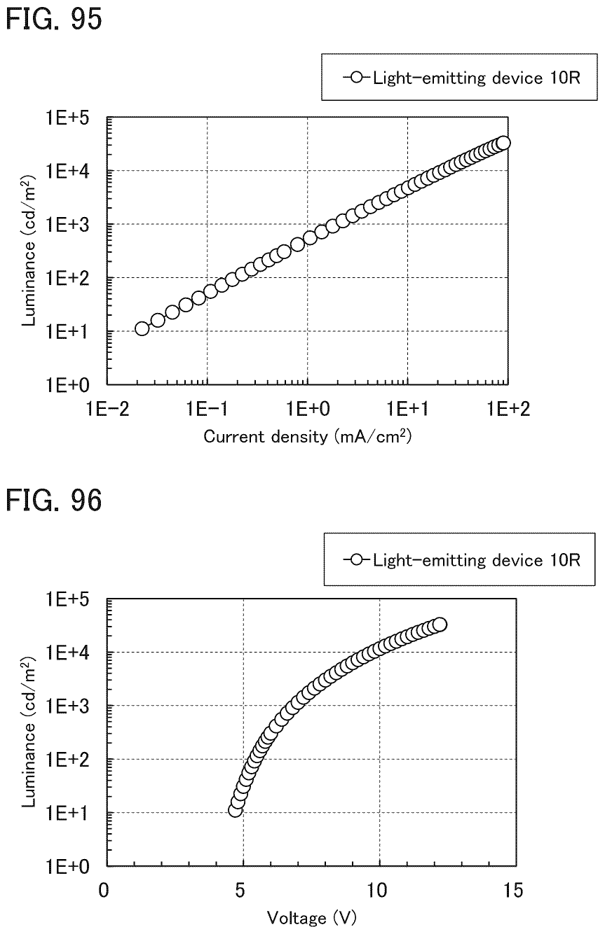

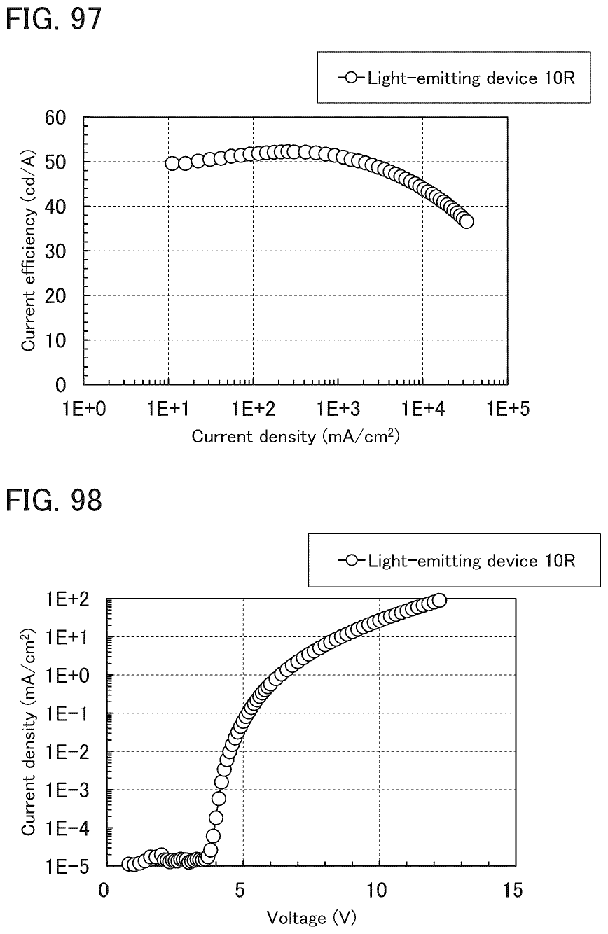

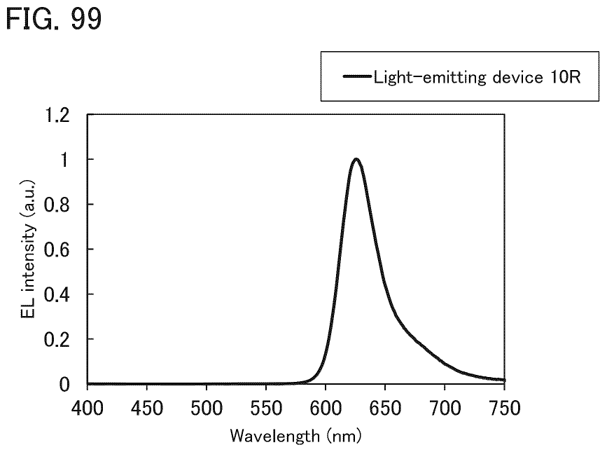

FIG. 84 shows the luminance-current density characteristics of the light-emitting device 101B, FIG. 85 shows the luminance—voltage characteristics of the light-emitting device 10B, 11G. 86 shows the current efficiency-current density characteristics of the light-emitting device 10B, FIG. 87 shows the current density-voltage characteristics of the light-emitting device 10B, FIG. 88 shows the electroluminescence spectrum of the light-emitting device 10B, and FIG. 89 shows the blue index-current density characteristics of the light-emitting device 10B. FIG. 90 shows the luminance-current density characteristics of the light-emitting device 10G. FIG. 91 shows the luminance-voltage characteristics of the light-emitting device 10G. FIG. 92 shows the current efficiency-current density characteristics t of the light-emitting device 10G. FIG. 93 shows the current density-voltage characteristics of the light-emitting device 10G. FIG. 94 shows the electroluminescence spectrum of the light-emitting device 10G. FIG. 95 shows the luminance-current density characteristics of the light-emitting device 10R. FIG. 96 shows the luminance-voltage characteristics of the light-emitting device 10R. FIG. 97 shows the current efficiency-current density characteristics of the light-emitting device 10R. FIG. 98 shows the current density-voltage characteristics of the light-emitting device 10R. FIG. 99 shows the electroluminescence spectrum of the light-emitting device 10R.

The following table shows the main characteristics of the light-emitting devices 10 at a current density of 10 mA/cm². The luminance, CIE chromaticity, and electroluminescence spectra were measured at normal temperature with a spectroradiometer (SR-ULIR, TOPCON TECHNOHOUSE CORPORATION).

TABLE 37

| | | | Current | | | | Current | |
|---|---|---|---|---|---|---|---|---|
| | Voltage | Current | density | Chromaticity | Chromaticity | Luminance | efficiency | BI value |
| | (V) | (mA) | (mA/cm²) | x | y | (cd/m²) | (cd/A) | (cd/A/y) |
| Light-emitting | 8.81 | 0.0700 | 10.000 | 0.31 | 0.66 | 13659 | 136.6 | — |
| device 10G | | | | | | | | |
| Light-emitting | 8.58 | 0.0444 | 10.000 | 0.69 | 0.31 | 4725 | 47.3 | — |
| device 10R | | | | | | | | |
| Light-emitting | 8.67 | 0.0956 | 10.000 | 0.14 | 0.06 | 879 | 8.8 | 156.1 |
| device 10B | | | | | | | | |

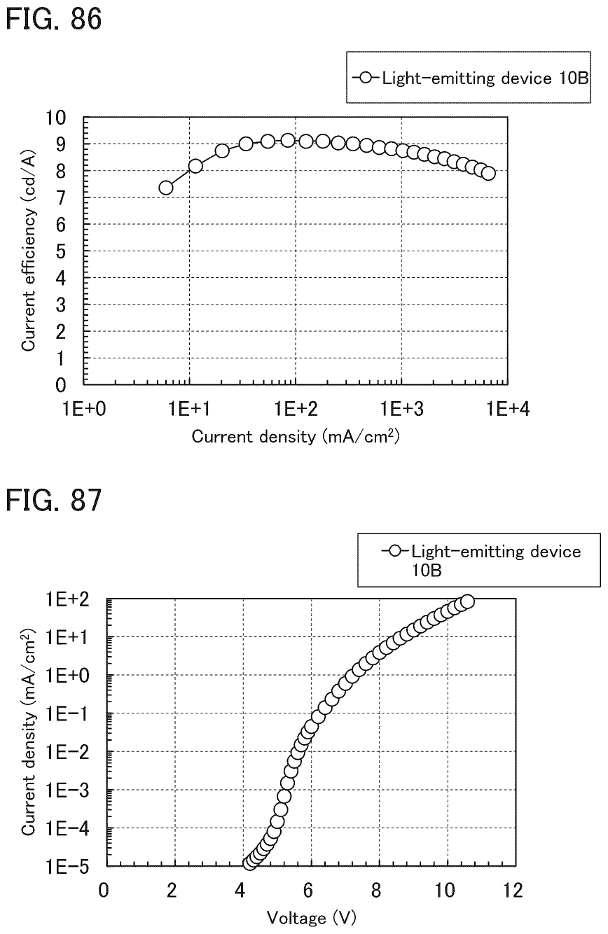

FIG. 84 to FIG. 89 and the above table show that the light-emitting device 10B exhibited blue light emission originating from 3,10PCA2Nbf(IV)-02. The light-emitting device 10B is proven to have favorable emission characteristics even after the processing by a photolithography method and the heat treatment were performed three times.

FIG. 90 to FIG. 94 and the above table show that the light-emitting device 10G exhibited green light emission originating from Ir(5m4dppy-d₃)₃. The light-emitting device 10G is proven to have favorable emission characteristics even after the processing by a photolithography method and the heat treatment were performed twice.

FIG. 95 to FIG. 99 and the above table show that the light-emitting device 10R exhibited red light emission originating from OCPG-006. The light-emitting device 10R is proven to have favorable emission characteristics even after the processing by a photolithography method and the heat treatment were performed once,

Thus, it is confirmed that the light-emitting devices 10G, 10R, and 10B, which are the light-emitting devices of embodiments of the present invention, have favorable characteristics even after the process of processing the organic compound layers by a photolithography method.

The above results confirm that the light-emitting devices of embodiments of the present invention have favorable characteristics.

### Example 11

In this example, light-emitting devices 11A and 11B of embodiments of the present invention were fabricated by a process involving exposure to the air, and the evaluation results of their characteristics are described below.

Structural Formulas of organic compounds used in common for the light-emitting devices 11A and 11B are shown below.

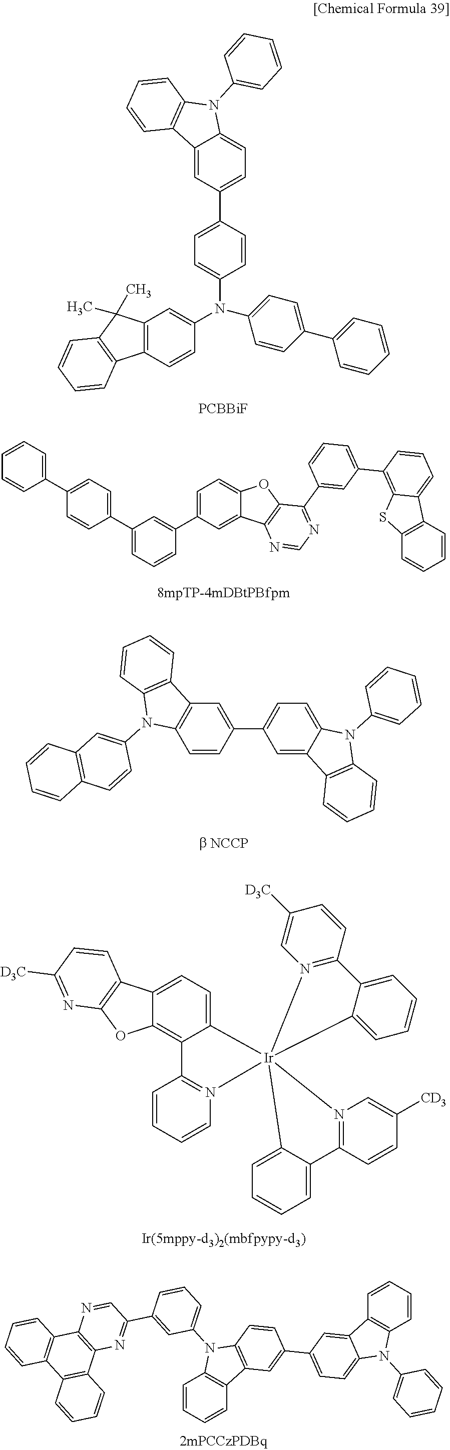

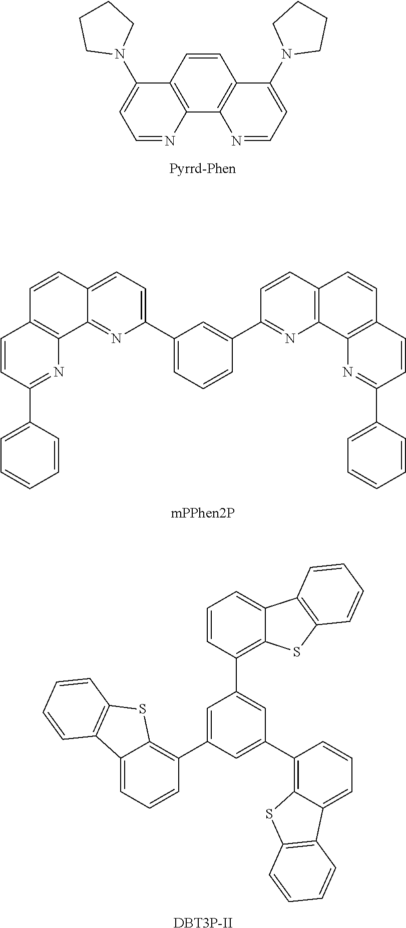 [SMILES: c1cc(N2CCCC2)c2ccc3c(N4CCCC4)ccnc3c2n1 ; c1ccc(-c2ccc3ccc4ccc(-c5cccc(-c6ccc7ccc8ccc(-c9ccccc9)nc8c7n6)c5)nc4c3n2)cc1 ; c1ccc2c(c1)sc1c(-c3cc(-c4cccc5c4sc4ccccc45)cc(-c4cccc5c4sc4ccccc45)c3)cccc12 ; "DBT3P-II"]

Structural Formulas of organic compounds used in the electron-transport layers of the light-emitting devices 11A and 11B are shown below.

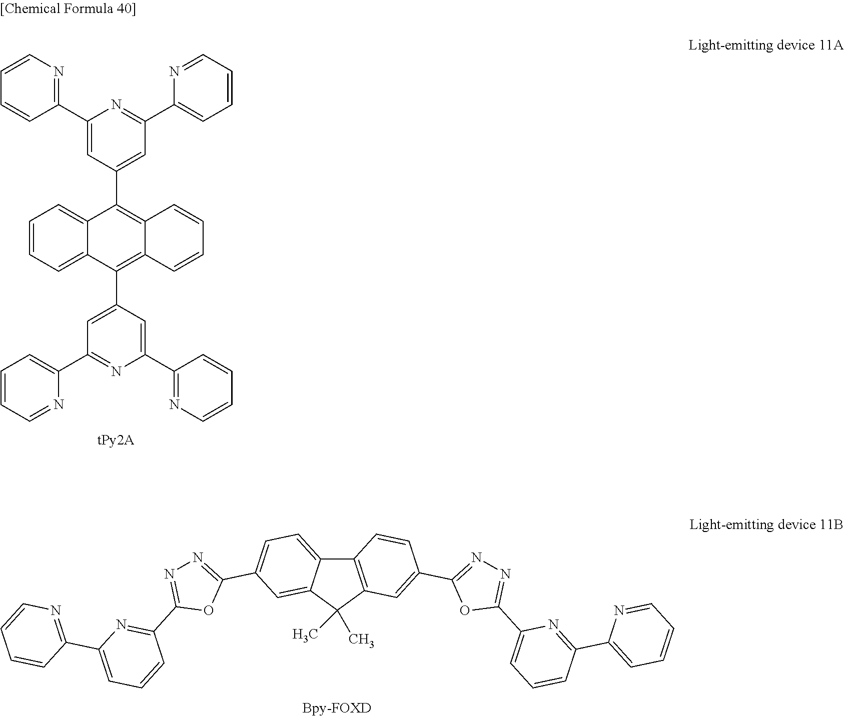 [SMILES: c1ccc(-c2cc(-c3c4ccccc4c(-c4cc(-c5ccccn5)nc(-c5ccccn5)c4)c4ccccc34)cc(-c3ccccn3)n2)nc1 ; CC1(C)c2cc(-c3nnc(-c4cccc(-c5ccccn5)n4)o3)ccc2-c2ccc(-c3nnc(-c4cccc(-c5ccccn5)n4)o3)cc21]

The light-emitting devices 11A and 11B each have a tandem structure in which the first EL layer 903, the intermediate layer 905, the second EL layer 904, and the second electrode 902 are stacked over a first electrode 901 formed over a substrate 900 that is a glass substrate, as illustrated in FIG. 18. Furthermore, the cap layer 909 is provided over the second electrode.

The first EL layer 903 has a structure in which the hole-injection layer 910, the first hole-transport layer 911, the first light-emitting layer 912, and the first electron-transport layer 913 are stacked in this order. The intermediate layer 905 includes the electron-injection buffer region 914 and the layer 915 including an electron-relay region and a charge-generation region. The second EL layer 904 has a structure in which the second hole-transport layer 916, the second light-emitting layer 917, the second electron-transport layer 918, and the electron-injection layer 919 are stacked in this order.

### <Fabrication Method of Light-Emitting Device 11A>

First, silver (Ag) was deposited to a thickness of 100 nm as a reflective electrode over the substrate 900 that was a glass substrate by a sputtering method, and then, indium tin oxide containing silicon oxide (1TSO) was deposited to a thickness of 85 nm as a transparent electrode by a sputtering method, whereby the first electrode 901 was formed. The electrode area was set to 4 mm² (2 mm×2 mm). Note that the first electrode is a transparent electrode, and the transparent electrode and the reflective electrode can be collectively regarded as the first electrode 901.

Next, the first EL layer 903 was provided. First, in pretreatment for forming the light-emitting device 11A over the substrate, a surface of the substrate was washed with water and baking was performed at 200° C. for 1 hour. Then, the substrate was transferred into a vacuum evaporation apparatus where the internal pressure was reduced to approximately 1×10⁻⁴ Pa, and vacuum baking was performed at 170° C. for 30 minutes in a heating chamber of the vacuum evaporation apparatus. After that, natural cooling was performed for approximately 30 minutes.

Then, the substrate provided with the first electrode 901 was fixed to a substrate holder provided in the vacuum evaporation apparatus such that the surface on which the first electrode 901 was formed faced downward. The hole-injection layer 910 was deposited to a thickness of nm over the first electrode 901 by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OC[ID-003) by a resistance heating evaporation method so as to have a PCBBiF:OCHD-003 weight ratio of 1:0.03.

Next, the first hole-transport layer 911 was deposited to a thickness of 85 nm over the hole-injection layer 910 by evaporation of PCBBiF.

Next, the first light-emitting layer 912 was formed over the first hole-transport layer 911. The first light-emitting layer 912 was deposited to a thickness of 40 nm by co-evaporation of 8-(1,1′:4′,1″-terphenyl-3-yl)-4-[3-(dibenzothiophen-4-yl)phenyl]-[1]benzofuro[3,2-d]pyrimidine (abbreviation: 8mpTP-4mDBtPBfpn), 9-(2-naphthyl)-9′-phenyl-91H,9′-3,3′-bicarbazole (abbreviation: βNCCP), and [2-d3-methyl-8-(2-pyridinyl-κN)benzofuro[2,3-b]pyridine-κC]bis[2-(5-d3-methyl-2-pyridinyHN2)phenyl-κC]iridium(III) (abbreviation: Ir(5mppy-d₃)₂(mbfpypy-d₃)) by a resistance heating evaporation method so as to have a 8mpTP-4mDBtPBfpm:βNCCP:Ir(5mppy-d₃)₂(mbfpypy-d₃) weight ratio of 0.5:0.5:0.1.

Then, the first electron-transport layer 913 was deposited to a thickness of 10 nm over the first light-emitting layer 912 by evaporation of 2-{3-[3-(N-phenyl-9H-carbazol-3-yl)-9H-carbazol-9-yl]phenyl}dibenzo[f,h]quinoxaline (abbreviation: 2mPCCzPDBq).

Next, the intermediate layer 905 was provided. First, a layer to be the electron-injection buffer region 914 was deposited to a thickness of 5 nm over the first electron-transport layer 913 by co-evaporation of 4,4″ ″-(9,10-anthryl)bis(2,2′:6′,2″-terpyridine) (abbreviation: tPy2A), 4,7-di-1-pyrrolidinyl-1,10-phenanthroline (abbreviation: Pyrrd-Phen), and Li₂O by a resistance heating evaporation method so as to have a tPy2A: Pyrrd-Phen:Li₂O volume ratio of 0.5:0.5:0.02.

Then, as the charge-generation region, the layer 915 including the charge-generation region was deposited to a thickness of 10 nm by co-evaporation of PCBBiF and a fluorine-containing electron acceptor material with a molecular weight of 672 (OCHD-003) by a resistance heating evaporation method so as to have a PCBBiF:OCHD-003 weight ratio of 1:0.15.

Next, the second EL layer 904 was provided. First, the second hole-transport layer 916 was deposited to a thickness of 50 nm by evaporation of PCBBiF.

Then, the second light-emitting layer 917 was deposited to a thickness of 40 nm by co-evaporation of 8mpTP-4mDBtPBfpm. βNCCP, and Ir(5mppy-d₃)₂(mbfpypy-d₃) by a resistance heating evaporation method so as to have a 8mpTP-4mDBtPBfpm::βNCCP:Ir(5mppy-d₃)₂(nbfpypy-d₃) weight ratio of 0.5:0.5:0.1.

Next, the second electron-transport layer 918 was deposited over the second light-emitting layer 917 by evaporation of 2mPCCzPDBq to a thickness of 20 nm, followed by evaporation of 2,2′-(1,3-phenylene)bis(9-phenyl-1,10-phenanthroline) (abbreviation: mPPhen2P) to a thickness of 20 nm.

Here, the substrate 900 was exposed to the air and placed in the air for 1 hour. After that, heat treatment was performed at 100° C. for 1 hour in a vacuum where the internal pressure was reduced to approximately 1×10- Pa. The heat treatment can remove moisture or the like attached by the above-described processing, the exposure to the air, or the like.

Next, the electron-injection layer 919 was deposited to a thickness of 1.5 nm over the second electron-transport layer 918 by co-evaporation of lithium fluoride (LiF) and ytterbium (Yb) so as to have a LiF:Yb volume ratio of 2:1.

Next, the second electrode 902 was deposited to a thickness of 15 nm over the electron-injection layer 919 by co-evaporation of Ag and Mg so as to have an Ag:Mg volume ratio of 1:0.1. Note that the second electrode 902 is a transflective electrode having functions of transmitting light and reflecting light.

Then, as the cap layer, 4,4′,4″-(benzene-1,3,5-triyl)tri(dibenzothiophene) (abbreviation: DBT3P-JJ) was deposited to a thickness of 70 nm by evaporation.

Through the above process, the light-emitting device 11A was fabricated.

### <Fabrication Method of Light-Emitting Device 11B>

Next, a method for fabricating the light-emitting device 11B is described.

The light-emitting device 11B is different from the light-emitting device 11A in the structure of the electron-injection buffer region 914. That is, in the light-emitting device 11B, a layer to be the electron-injection buffer region 914 was formed to a thickness of 5 nm over the first electron-transport layer 913 by co-evaporation of 2,7-bis(2,2′-bipyridine-6-yl)-1,3,4-oxadiazo-5-yl)-9,9-dimethylfluorene (abbreviation: BPy-FOXD), Pyrrd-Phen, and Li₂O by a resistance heating evaporation so as to have a BPy-FOXD:Pyrrd-Phen:Li₂O volume ratio of 0.5:0.5:0.02.

Other components were fabricated in a manner similar to those of the light-emitting device 11A.

The structures of the light-emitting devices 11A and 11B are listed in the table below.

TABLE 38

| | | |
|---|---|---|
| Thickness | Light-emitting | Light-emitting |
| [nm] | device 11A | device 11B |

| | | |
|---|---|---|
| Cap layer | 70 | DBT3P-II |
| Second electrode | 15 | Ag:Mg (1:0.1) |
| Electron-injection | 1.5 | LiF:Yb (2:1) |
| layer | | |

Exposure to the air

| Second electron- | 20 | mPPhen2P | |
|---|---|---|---|
| transport layer | 20 | 2mPCCzPDBq | |
| Second light-emitting | 40 | 8mpTP-4mDBtPBfpm:βNCCP:Ir(5mppy-d₃)₂(mbfpypy-d₃) | |
| layer | | (0.5:0.5:0.1) | |
| Second hole-transport | 50 | PCBBiF | |
| layer | | | |
| Charge-generation | 10 | PCBBiF:OCHD-003 (1:0.15) | |
| region | | | |
| Electron-injection | 5 | tPy2A:Pyrrd-Phen:Li₂O | BPy-FOXD:Pyrrd-Phen:Li₂O |
| buffer region | | (0.5:0.5:0.02) | (0.5:0.5:0.02) |

| | | |
|---|---|---|
| First electron- | 10 | 2mPCCzPDBq |
| transport layer | | |
| First light-emitting | 40 | 8mpTP-4mDBtPBfpm:βNCCP:Ir(5mppy-d₃)₂(mbfpypy-d₃) |
| layer | | (0.5:0.5:0.1) |
| First hole-transport | 85 | PCBBiF |
| layer | | |
| Hole-injection layer | 10 | PCBBiF:OCHD-003 (1:0.03) |
| First electrode | 85 | ITSO |
| | 100 | Ag |

Here, the HOMO and LUMO levels of tPy2A and BPy-FOXD were calculated with cyclic voltammetry (CV) measurement. An electrochemical analyzer (ALS model 600A or 600C, BAS Inc.) was used for the measurement. A solvent of the solution used in the measurement was dehydrated dimethylformamide (DMF). In the measurement, the potential of a working electrode with respect to a reference electrode was changed within an appropriate range, so that the oxidation peak potential and the reduction peak potential were obtained. A platinum electrode (PTE platinum electrode, BAS Inc.) was used as a working electrode, a platinum electrode (Pt counter electrode for VC-3 (5 cm), BAS Inc.) was used as an auxiliary electrode, and an Ag/Ag+- electrode (RE-7 nonaqueous reference electrode, BAS Inc.) was used as a reference electrode. The HOMO and LUMO levels of the compounds were calculated from the estimated redox potential of the reference electrode of −4.94 eV and the obtained peak potentials. As a result, the LUMO level of tPy2A was −2.91 eV, the LUMO level of BPy-FOXD was −2.94 eV, and the LUMO level of Pyrrd-Phen was −2.55 eV. This indicates that tPy² A and BPy-FOXD each have a lower LUMO level than Pyrrd-Phen.

### <Device Characteristics>

The light-emitting devices 11A and 11B were each sealed with a glass substrate in a glove box containing a nitrogen atmosphere so as not to be exposed to the air (a sealing material was applied to surround the devices and UV treatment and heat treatment at 80° C. for 1 hour were performed at the time of sealing), Then, the emission characteristics of the light-emitting devices 11A and 11B were measured.

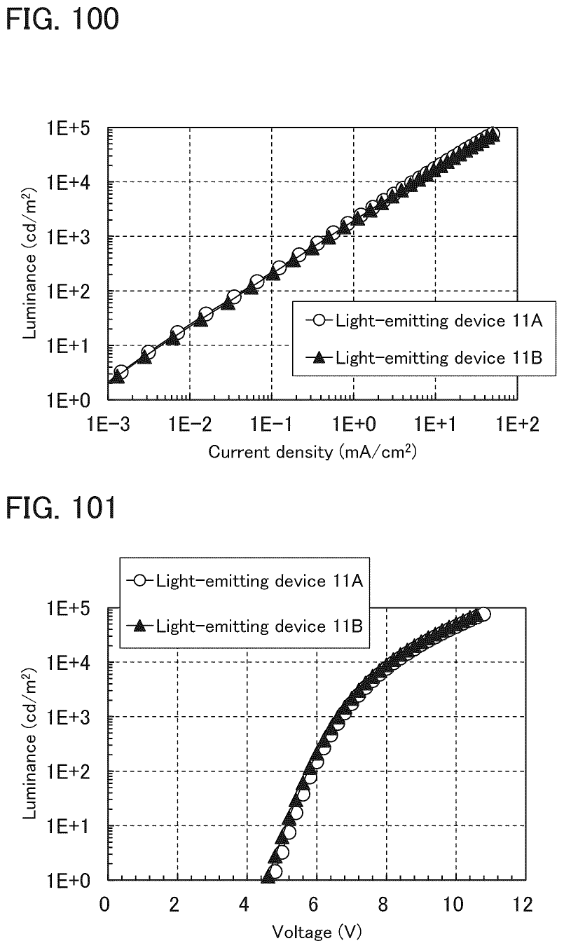

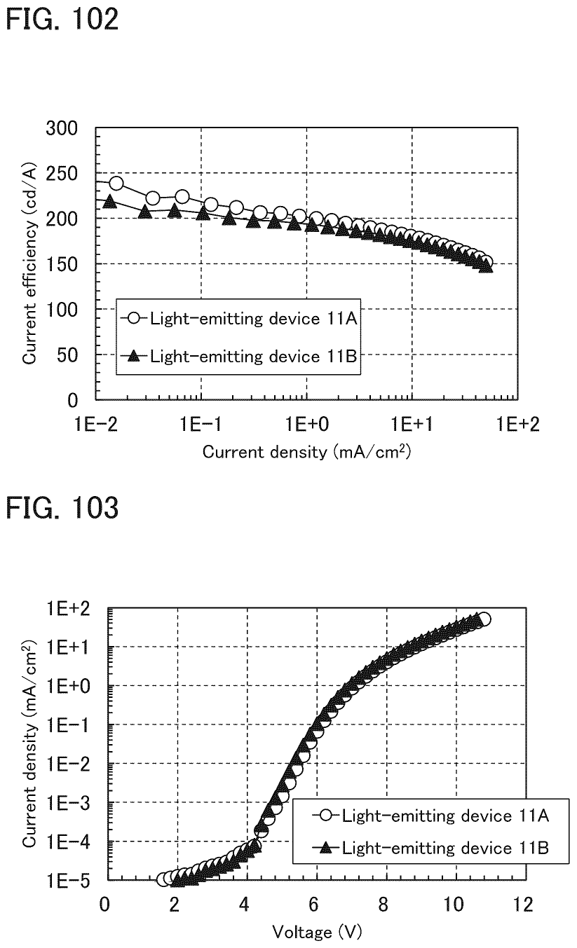

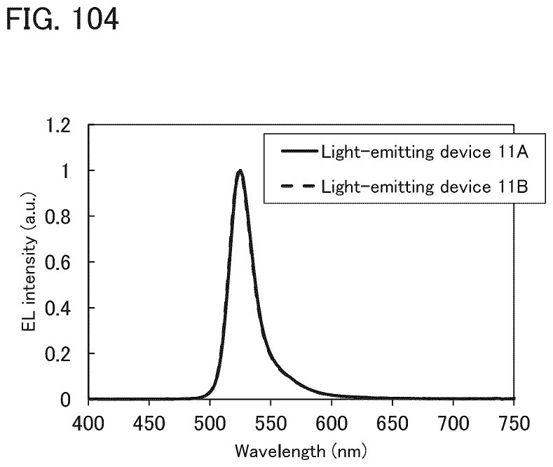

FIG. 100 shows the luminance-current density characteristics of the light-emitting devices 11A and 11B, FIG. 101 shows the luminance-voltage characteristics of the light-emitting devices 11A and 11B, FIG. 102 shows the current efficiency-current density characteristics of the light-emitting devices 11A and 11B, FIG. 103 shows the current density-voltage characteristics of the light-emitting devices 11A and 11B, and FIG. 104 shows the electroluminescence spectra of the light-emitting devices 11A and 11B. The main characteristics of the light-emitting devices 11A and 11B at a luminance of approximately 1000 cd/cm² are shown in the table below. Note that the luminance, CIE chromaticity, and electroluminescence spectra were measured with a spectroradiometer (SR-UL1R, TOPCON TECHNOHOUSE CORPORATION).

TABLE 39

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-emitting | 6.80 | 0.0227 | 0.567 | 0.21 | 0.74 | 1165 | 205.4 |
| device 11A | | | | | | | |
| Light-emitting | 6.60 | 0.0199 | 0.497 | 0.20 | 0.74 | 978 | 197.0 |
| device 11B | | | | | | | |

Furthermore, as shown in FIG. 104, the light-emitting devices 11A and 11B each emitted green light with peak wavelengths of 525 nm in their electroluminescence spectra.

FIG. 100 to FIG. 103 and the above table demonstrate that the light-emitting devices 11A and 11B are each a tandem light-emitting device with high current efficiency.

It is also shown that the light-emitting devices 11A and 11B are less likely to be degraded in characteristics and are driven at low voltage even after undergoing the process involving exposure to the air.

The above results prove that the light-emitting devices of embodiments of the present invention can each have favorable characteristics of a low driving voltage and high emission efficiency by using the organic compound having two or more heteroaromatic rings that are bonded or condensed to each other and include three or more heteroatoms in total.

### Example 12

In this example, the light-emitting devices 12A to 12F of embodiments of the present invention were fabricated through a process (MML process) including processing such as exposure to the air and etching. The evaluation results of their characteristics are described below.

Structural Formulas of organic compounds used in common for the light-emitting devices 12A to 12F are shown below.

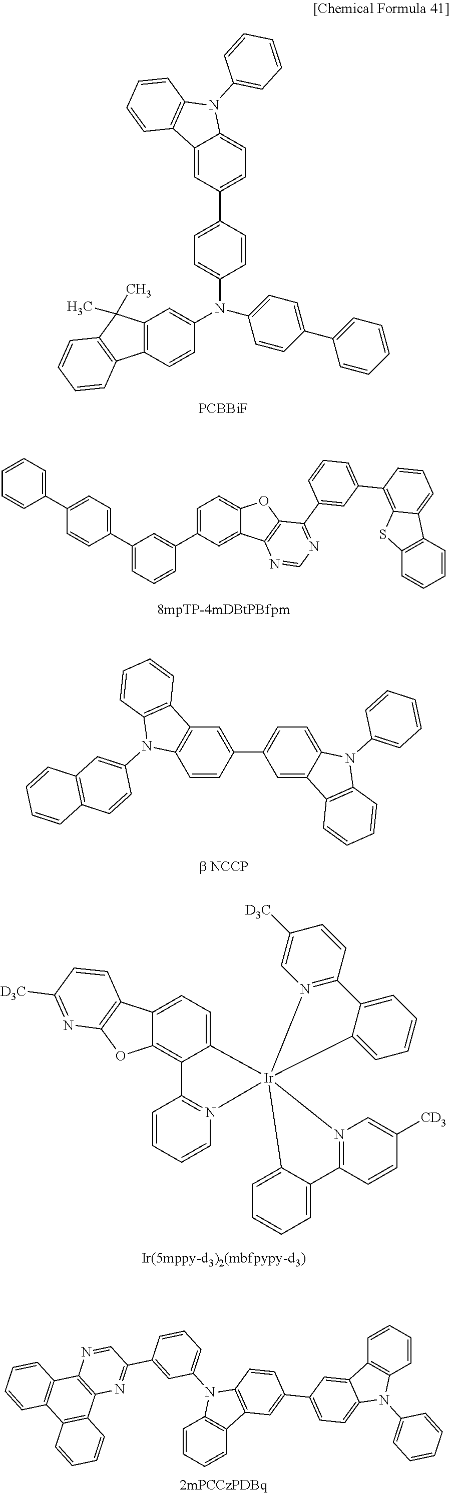

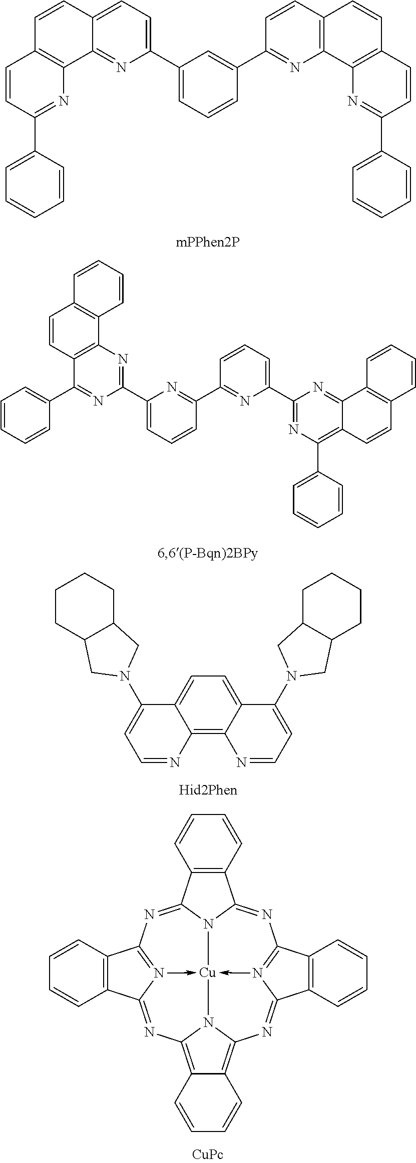

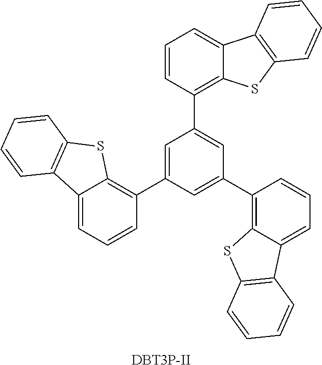 [SMILES: c1ccc2c(c1)sc1c(-c3cc(-c4cccc5c4sc4ccccc45)cc(-c4cccc5c4sc4ccccc45)c3)cccc12 ; "DBT3P-II"]

The light-emitting devices 12A to 12F each have a tandem structure in which the first EL layer 903, the intermediate layer 905, the second EL layer 904, and the second electrode 902 are stacked over the first electrode 901 formed over the substrate 900 that is a glass substrate, as illustrated in FIG. 18. Furthermore, the cap layer 909 is provided over the second electrode.

The first EL layer 903 has a structure in which the hole-injection layer 910, the first hole-transport layer 911, the first light-emitting layer 912, and the first electron-transport layer 913 are stacked in this order. The intermediate layer 905 includes the electron-injection buffer region 914 and the layer 915 including an electron-relay region and a charge-generation region. The second EL layer 904 has a structure in which the second hole-transport layer 916, the second light-emitting layer 917, the second electron-transport layer 918, and the electron-injection layer 919 are stacked in this order.

### <Fabrication Method of Light-Emitting Device 12A>

First, an alloy containing silver (Ag), palladium (Pd), and copper (Cu) (abbreviation: APC) was deposited to a thickness of 100 nm as a reflective electrode over the substrate 900 that was a glass substrate by a sputtering method, and then, indium tin oxide containing silicon oxide (ITSO) was deposited to a thickness of 85 nm as a transparent electrode by a sputtering method, whereby the first electrode 901 was formed. The electrode area was set to 4 mm² (2 mm×2 mm). Note that the first electrode is a transparent electrode, and the transparent electrode and the reflective electrode can be collectively regarded as the first electrode 901.

Next, the first EL layer 903 was provided. First, in pretreatment for forming the light-emitting device 12A over the substrate, a surface of the substrate was washed with water and baking was performed at 200° C. for 1 hour. Then, the substrate was transferred into a vacuum evaporation apparatus where the internal pressure was reduced to approximately 1×10⁻⁴ Pa, and vacuum baking was performed at 170° C. for 30 minutes in a heating chamber of the vacuum evaporation apparatus. After that, natural cooling was performed for approximately 30 minutes.

Then, the substrate provided with the first electrode 901 was fixed to a substrate holder provided in the vacuum evaporation apparatus such that the surface on which the first electrode 901 was formed faced downward. The hole-injection layer 910 was deposited to a thickness of nm over the first electrode 901 by co-evaporation of N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) by a resistance heating evaporation method so as to have a PCBBiF:OCHD-003 weight ratio of 1:0.03.

Next, the first hole-transport layer 911 was deposited to a thickness of 125 nm over the hole-injection layer 910 by evaporation of PCBBiF.

Next, the first light-emitting layer 912 was formed over the first hole-transport layer 911. The first light-emitting layer 912 was deposited to a thickness of 40 nm by co-evaporation of 8-(1,1′: 4′ 1″-terphenyl-3-yl)-4-[3-(dibenzothiophen-4-yl)phenyl]-1]benzofuro[3,2-d]pyrimidine (abbreviation: 8mpTP-4mDBtPBfpm), 9-(2-naphthyl)-9′-phenyl-9H,9′H1-3,3′-bicarbazole (abbreviation: βNCCP), and [2-d3-methyl-8-(2-pyridinyl-κN)benzofuro[2,3-b]pyridine-κC]bis[2-(5-d3-methyl-2-pyridinyl-κN²)phenyl-κC]iridium(III) (abbreviation: Ir(5mppy-d₃)₂(mbfpypy-d₃)) by a resistance heating evaporation method so as to have an 8mpTP-4mDBtPBfpm:βNCCP:Ir(5mppy-d₃)₂(mbfpypy-d₃) weight ratio of 0.5:0.5:0.1.

Then, the first electron-transport layer 913 was deposited to a thickness of 10 nm over the first light-emitting layer 912 by evaporation of 2-{3-[3-(N-phenyl-9H-carbazol-3-yl)-9H-carbazol-9-yl]phenyl}dibenzo[f,h]quinoxaline (abbreviation: 2mPCCzPDBq).

Next, the intermediate layer 905 was provided. First, a layer to be the electron-injection buffer region 914 was formed to a thickness of 5 nm over the first electron-transport layer 913 by co-evaporation of 2,2′-(2,2′-bipyridine-6,6′-diyl)bis(4-phenylbenzo[hlquinazoline) (abbreviation: 6,6′(P-Bqn)₂BPy), 4,7-di(2,3,3a,4,5,6,7,7a-octahydro-1H-isoindol-2-yl)-1,10-phenanthroline (abbreviation: Hid2Phen), and Li₂O by a resistance heating evaporation method so as to have a 6,6′(P-Bqn)₂BPy:Hid2Phen:Li₂O volume ratio of 0.5:0.5:0.02.

Then, as the electron-relay region, copper phthalocyanine (abbreviation: CuPc) was deposited to a thickness of 2 nm. Next, as the charge-generation region, the layer 915 including the charge-generation region was deposited to a thickness of 10 nm by co-evaporation of PCBBiF and a fluorine-containing electron acceptor material with a molecular weight of 672 (OCHD-003) by a resistance heating evaporation method so as to have a PCBBiF:OCHD-003 weight ratio of 1:0.15.

Next, the second EL layer 904 was provided. First, the second hole-transport layer 916 was deposited to a thickness of 50 nm by evaporation of PCBBiF.

Then, the second light-emitting layer 917 was deposited to a thickness of 40 nm by co-evaporation of 8mpTP-4mDBtPBfpm, βNCCP, and Ir(5mppy-d₃)₂(mbfpypy-d₃) by a resistance heating evaporation method so as to have a 8mpTP-4mDBtPBfpm:βNCCP:Ir(5mppy-d₃)₂(mbfpypy-d₃) weight ratio of 0.5:0.5:0.1.

Next, the second electron-transport layer 918 was deposited over the second light-emitting layer 917 by evaporation of 2mPCCzPDBq to a thickness of 20 nm, followed by evaporation of 2,2′-(1,3-phenylene)bis(9-phenyl-1,10-phenanthroline) (abbreviation: mPPhen2P) to a thickness of 20 nm.

Here, the substrate 900 was exposed to the air, then an aluminum oxide (AlOₓ) film was deposited a thickness of 30 nm by an ALD method, and molybdenum (Mo) was deposited to a thickness of 50 nm by a sputtering method. After that, a resist was formed using a photoresist, and the molybdenum was processed into a predetermined shape by a lithography method. Specifically, a slit with a width of 3 μm was formed at a position 3.5 μm away from the end portion of the first electrode 901.

Next, using the molybdenum as a mask, the stacked-layer structure formed of the aluminum oxide film, the first EL layer 903, the intermediate layer 905, the second hole-transport layer 916, the second light-emitting layer 917, and the second electron-transport layer 918 was processed into a predetermined shape. After that, molybdenum was removed by a dry etching method, and then the aluminum oxide film was removed. The aluminum oxide film was removed by wet etching using an acidic chemical solution.

Then, heat treatment was performed at 100° C. for 1 hour in a vacuum where the internal pressure was reduced to approximately 1×10⁻⁴ Pa. The heat treatment can remove moisture or the like attached by the above-described processing, the exposure to the air, or the like.

Next, the electron-injection layer 919 was deposited to a thickness of 1.5 nm over the second electron-transport layer 918 by co-evaporation of lithium fluoride (LiF) and ytterbium (Yb) so as to have a LiF:Yb volume ratio of 2:1.

Next, the second electrode 902 was deposited to a thickness of 15 nm over the electron-injection layer 919 by co-evaporation of Ag and Mg so as to have an Ag:Mg volume ratio of 1:0.1. Note that the second electrode 902 is a transflective electrode having functions of transmitting light and reflecting light.

Then, as the cap layer, 4,4′,4″-(benzene-1,3,5-triyl)tri(dibenzothiophene) (abbreviation: DBT3P-II) was deposited to a thickness of 70 nm by evaporation.

Through the above process, the light-emitting device 12A was fabricated.

<Fabrication Method of Light-Emitting Devices 12B to 12F>

Next, methods for fabricating the light-emitting devices 12B to 12F are described. The light-emitting devices 12B to 12F are different from the light-emitting device 12A in the structure of the electron-injection buffer region 914.

In the light-emitting device 12B, the layer to be the electron-injection buffer region 914 was deposited to a thickness of 5 nm over the first electron-transport layer 913 by co-evaporation of 6,6′(P-Bqn)₂BPy, Hid2Phen, and Ag (silver) by a resistance heating evaporation method so as to have a 6,6′(P-Bqn)₂BPy:Hid2Phen:Ag volume ratio of 0.5:0.5:0.02.

In the light-emitting device 12C, the layer to be the electron-injection buffer region 914 was deposited to a thickness of 5 nm over the first electron-transport layer 913 by co-evaporation of 6,6′(P-Bqn)₂BPy, Hid2Phen, and In (indium) by a resistance heating evaporation method so as to have a 6,6′(P-Bqn)₂BPy:Hid2Phen:In volume ratio of 0.5:0.5:0.02.

In the light-emitting device 12D, the layer to be the electron-injection buffer region 914 was deposited to a thickness of 5 nm over the first electron-transport layer 913 by co-evaporation of 6,6′(P-Bqn)₂BPy, Hid2Phen, and In₂O₃ (indium oxide) by a resistance heating evaporation method so as to have a 6,6′(P-Bqn)₂BPy:Hid2Phen:ln₂O₃ volume ratio of 0.5:0.5:0.02.

In the light-emitting device 12E, the layer to be the electron-injection buffer region 914 was deposited to a thickness of 5 nm over the first electron-transport layer 913 by co-evaporation of 6,6′(P-Bqn)₂BPy, Hid2Phen, and Yb (ytterbium) by a resistance heating evaporation method so as to have a 6,6′(P-Bqn)₂BPy:Hid2Phen: Yb volume ratio of 0.5:0.5:0.02.

In the light-emitting device 12F, the layer to be the electron-injection buffer region 914 was deposited to a thickness of 5 nm over the first electron-transport layer 913 by co-evaporation of 6,6′(P-Bqn)₂BPy, Hid2Phen, and Mg (magnesium) by a resistance heating evaporation method so as to have a 6,6′(P-Bqn)₂BPy:Hid2Phen:Mg volume ratio of 0.5:0.5:0.02.

Note that components other than the layer to be the electron-injection buffer region 914 in the light-emitting devices 12B to 12F were fabricated in a manner similar to those of the light-emitting device 12A.

The structures of the light-emitting devices 12A to 12F are listed in the table below. Note that Me in the table represents any of Li₂O, Ag, In, In₂O₃, Yb, and Mg.

TABLE 40

| Thickness | Light-emitting device | | | | | |
|---|---|---|---|---|---|---|
| [nm] | 12A | 12B | 12C | 12D | 12E | 12F |

| | | |
|---|---|---|
| Cap layer | 70 | DBT3P-II |
| Second electrode | 15 | Ag:Mg (1:0.1) |
| Electron-injection layer | 1.5 | LiF:Yb (2:1) |

Processing by photolithgraphy was performed

| Second electron- | 20 | mPPhen2P | | | | | |
|---|---|---|---|---|---|---|---|
| transport layer | 20 | 2mPCCzPDBq | | | | | |
| Second light-emitting | 40 | 8mpTP-4mDBtPBfpm:βNCCP:Ir(5mppy-d₃)₂(mbfpypy-d₃) | | | | | |
| layer | | (0.5:0.5:0.1) | | | | | |
| Second hole-transport | 50 | PCBBiF | | | | | |
| layer | | | | | | | |
| Charge-generation | 10 | PCBBiF:OCHD-003 (1:0.15) | | | | | |
| region | | | | | | | |
| Electron-relay region | 2 | CuPc | | | | | |
| Electron-injection buffer | 5 | 6,6′(P-Bqn)2BPy:Hid2Phen:Me (0.5:0.5:0.02) | | | | | |
| region | | Li₂O | Ag | In | In203 | Yb | Mg |

| | | |
|---|---|---|
| First electron-transport | 10 | 2mPCCzPDBq |
| layer | | |
| First light-emitting layer | 40 | 8mpTP-4mDBtPBfpm:βNCCP:Ir(5mppy-d₃)₂(mbfpypy-d₃) |
| | | (0.5:0.5:0.1) |
| First hole-transport layer | 125 | PCBBiF |
| Hole-injection layer | 10 | PCBBiF:OCHD-003 (1:0.03) |
| First electrode | 85 | ITSO |
| | 100 | APC |

Here, the HOMO and LUMO levels of 6,6′(P-Bqn)₂BPy and Hid2Phen were calculated with the use of cyclic voltammetry (CV) measurement. An electrochemical analyzer (ALS model 600A or 600C, BAS Inc.) was used for the measurement. A solvent of the solution used in the measurement was dehydrated dimnethylformamide (D3MF), In the measurement, the potential of a working electrode with respect to a reference electrode was changed within an appropriate range, so that the oxidation peak potential and the reduction peak potential were obtained. A platinum electrode (PTE platinum electrode, BAS Inc.) was used as a working electrode, a platinum electrode (Pt counter electrode for VC-3 (5 cm). BAS Inc.) was used as an auxiliary electrode, and an Ag/Ag+ electrode (RE-7 nonaqueous reference electrode, BAS Inc.) was used as a reference electrode. The HOMO and LUMO levels of the compounds were calculated from the estimated redox potential of the reference electrode of −4.94 eV and the obtained peak potentials. As a result, the LUMO level of 6,6′(P-Bqn)₂BPy was −2.92 eV and the LUMO level of Hid2Phen was −2.5 eV. This indicates that 6,6′(P-Bqn)₂BPy has a lower LUMO level than Hid2Phen.

### <Device Characteristics>

The light-emitting devices 12A to 12F were sealed using a glass substrate in a glove box containing a nitrogen atmosphere so as not to be exposed to the air (a sealing material was applied to surround the devices and UV treatment and heat treatment at 80° C. for 1 hour were performed at the time of sealing). Then, the emission characteristics of the light-emitting devices 12A to 12F were measured.

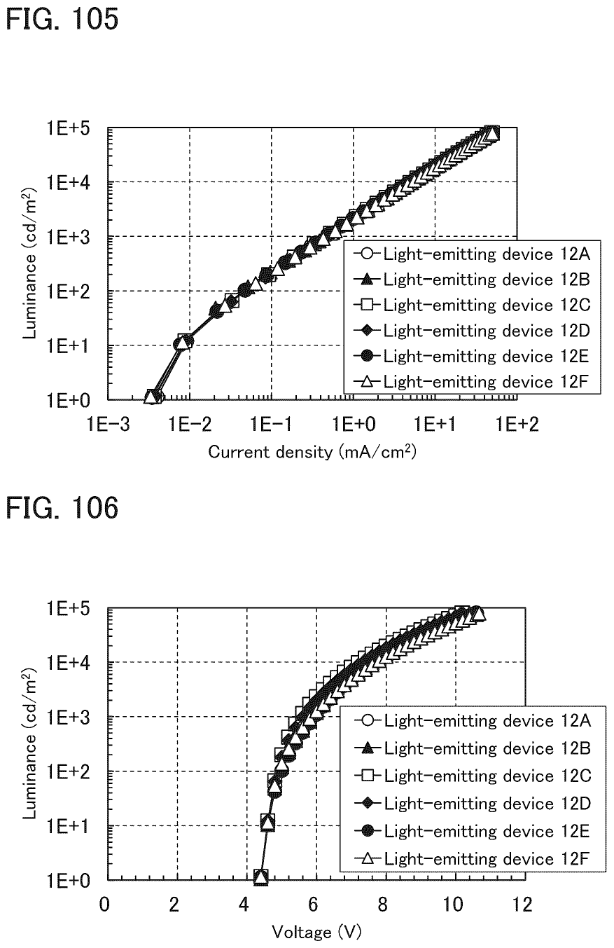

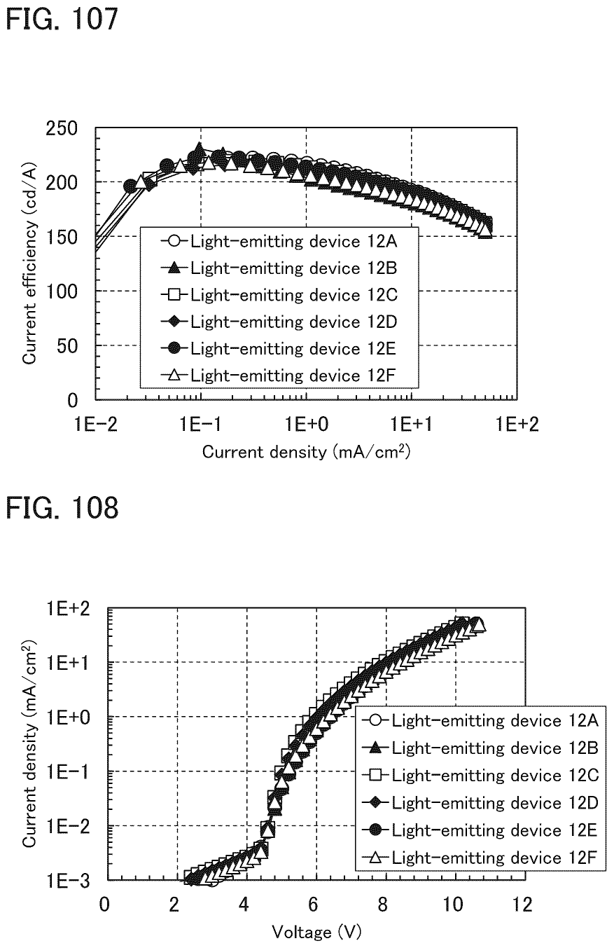

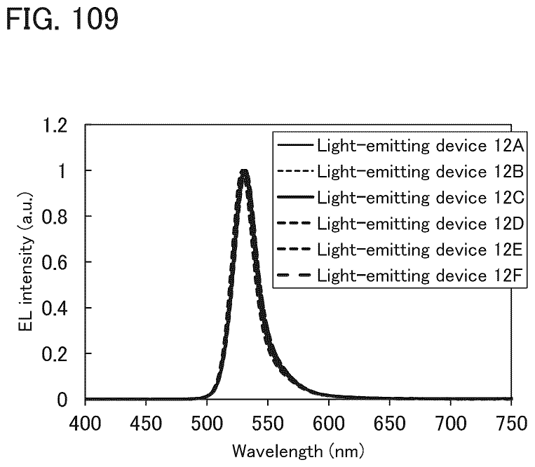

FIG. 105 shows the luminance-current density characteristics of the light-emitting devices 12A to 12F, FIG. 106 shows the luminance-voltage characteristics of the light-emitting devices 12A to 12F, FIG. 107 shows the current efficiency-current density characteristics of the light-emitting devices 12A to 12F, FIG. 108 shows the current density-voltage characteristics of the light-emitting devices 12A to 12F, and FIG. 109 shows the electroluminescence spectra of the light-emitting devices 12A to 12F. The main characteristics of the light-emitting devices 12A to 12F at a luminance of approximately 1000 cd/cm² are shown in the table below. Note that the luminance, CIE chromaticity, and electroluminescence spectra were measured with a spectroradiometer (SR-UL1R, TOPCON TECHNOHOUSE CORPORATION).

TABLE 41

| | | | Current | | | | Current |
|---|---|---|---|---|---|---|---|
| | Voltage | Current | density | Chromaticity | Chromaticity | Luminance | efficiency |
| | (V) | (mA) | (mA/cm²) | x | y | (cd/m²) | (cd/A) |
| Light-emitting device 12A | 5.60 | 0.0196 | 0.490 | 0.23 | 0.74 | 1082 | 220.7 |
| Light-emitting device 12B | 5.80 | 0.0154 | 0.385 | 0.24 | 0.73 | 827 | 214.9 |
| Light-emitting device 12C | 5.60 | 0.0211 | 0.527 | 0.23 | 0.73 | 1144 | 216.9 |
| Light-emitting device 12D | 5.60 | 0.0181 | 0.453 | 0.22 | 0.74 | 973 | 214.6 |
| Light-emitting device 12E | 6.00 | 0.0203 | 0.506 | 0.24 | 0.73 | 1103 | 217.8 |
| Light-emitting device 12F | 5.80 | 0.0172 | 0.429 | 0.23 | 0.74 | 916 | 213.2 |

Furthermore, as shown in FIG. 109, the light-emitting devices 12A to 12F each emitted green light with peak wavelengths of 530 nm in their electroluminescence spectra.

FIG. 105 to FIG. 108 and the above table show that the light-emitting devices 12A to 12F are tandem light-emitting devices having high current efficiency.

The light-emitting devices 12A to 12F are found to be driven at low voltage because degradation of characteristics can be inhibited even after undergoing the process including processing such as exposure to the air and etching.

Here, thin films containing organic compounds used for the intermediate layer 905 was evaluated by electron spin resonance (ESR) method.

Specifically, in the light-emitting device 12A, 6,6′(P-Bqn)₂BPy, −Iid2Phen, and Li₂O were deposited by co-evaporation to a thickness of 100 nm over a quartz substrate so as to have a 6,6′(P-Bqn)₂BPy:Hid2Phen:Li₂O volume ratio of 0.5:0.5:0.02; in the light-emitting device 12B, 6,6′(P-Bqn)₂BPy, Hid2Phen, and In were deposited by co-evaporation to a thickness of 100 nm over a quartz substrate so as to have a 6,6′(P-Bqn)₂BPy:Hid2Phen:In volume ratio of 0.5:0.5:0.02; and in the light-emitting device 12C, 6,6′(P-Bqn)₂BPy, Hid2Phen, and In₂O₃ were deposited over a quartz substrate by co-evaporation to a thickness of 100 nm so as to have a 6,6′(P-Bqn)₂BPy:[Hid2Phen:In₂O₃ volume ratio of 0.5:0.5:0.02. The electron spin resonance spectra of the light-emitting devices were measured at room temperature. Note that the measurement of the electron spin resonance spectrum using an ESR method was performed with an electron spin resonance spectrometer E500 (Bruker Corporation). The measurement was performed at room temperature under the conditions where the resonance frequency was 9.56 GHz, the output power was 1 mW, the modulated magnetic field was 50 mT, the modulation width was 0.5 mT, the time constant was 0.04 s, and the sweep time was 1 min. The result of measurement shows that a signal was observed at a g-factor of approximately 2.00 in each light-emitting device. The spin density of the light-emitting device 12A was 1×10²O spins/cm³, the spin density of the light-emitting device 12B was 1×10¹⁸ spins/cm³, and the spin density of the light-emitting device 12C was 5×10¹⁷ spins/cm³. In the case where the spin density is higher than or equal to 1×10¹⁷ spins/cm³, it is confirmed that the metal and the organic compounds are efficiently interacted with each other.

Furthermore, a thin film was deposited to a thickness of 100 nm over a quartz substrate by co-evaporation of PCBBiF and OCHD-003 so as to have a PCBBiF:OCHD-003 weight ratio of 1:0.1, and an electron spin resonance spectrum of the thin film was measured at room temperature. Note that the measurement of electron spin resonance spectrum using ESR spectroscopy was performed with an electron spin resonance spectrometer JES FA300 (JEOL Ltd.). The measurement was performed at room temperature under the conditions where the resonance frequency was 9.18 GHz, the output power was 1 mW, the modulated magnetic field was 50 mT, the modulation width was 0.5 mT, the time constant was 0.03 s, and the sweep time was 1 min. As a result, it was found that a signal was observed at a g-factor of approximately 2.00 and the spin density was 5×10¹⁹ spins/cm³. This shows that OCHD-003 has an electron-acceptor property with respect to PCBBiF and the layer including PCBBiF and OCHD-003 functions as a charge-generation layer.

### <Reliability Test Result>

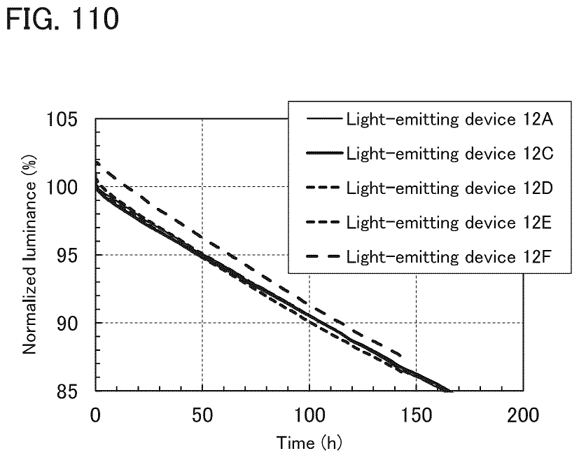

Moreover, a reliability test was conducted on the light-emitting device 12A and the light-emitting devices 12C to 12F. FIG. 110 shows a time-dependent change in normalized luminance at the time of constant current density driving (50 [mA/cm²]). In FIG. 110, the vertical axis represents the luminance (%) normalized with the luminance at the time of the start of light emission as 100%, and the horizontal axis represent the time (h).

As shown in FIG. 110, the value of LT90 (h), which is the time that has elapsed until the measured luminance decreases to 90% of the initial luminance, is 106 hours for the light-emitting device 12A, 106 hours for the light-emitting device 12C, 101 hours for the light-emitting device 12D, 106 hours for the light-emitting device 12E, and 115 hours for the light-emitting device 12F.

The above results show that when a typical metal, a transition metal, and a compound thereof are used in the light-emitting device of one embodiment of the present invention, a light-emitting device that has a low driving voltage, high emission efficiency, and high reliability can be provided.

### Reference Example 1

In this reference example, a method for synthesizing 4,7-bis[4-(1-pyrrolidinyl)phenyl]-1,10-phenanthroline (abbreviation: PrdP2Phen) used in Example 1 is described. The structure of PrdP2Phen is shown below.

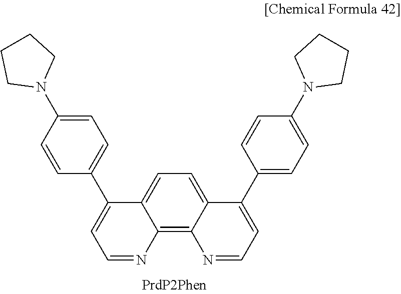 [SMILES: c1cc(-c2ccc(N3CCCC3)cc2)c2ccc3c(-c4ccc(N5CCCC5)cc4)ccnc3c2n1]

### <Synthesis of PrdP2Phen>

To a 100 mL three-neck flask were added 1.4 g (4.2 mmol) of 4,7-dibromo-1,10-phenanthroline, 2.5 g (9.2 mmol) of 2-[4-(1-pyrrolidinyl)phenyl]-4,4,5,5-tetramethyl-1,3,2-dioxaborolane, 0.48 mL (0.29 mmol) of tricyclohexylphosphine (an approximately 18% toluene solution), 3.0 g (14 mmol) of tripotassium phosphate, 25 mL of 1,4-dioxane, and 12 mL of water. The mixture was degassed by being stirred under reduced pressure. To this mixture was added 0.12 g (0.13 mmol) of tris(dibenzylideneacetone)dipalladium(0) (abbreviation: Pd₂(dba)₃), and the resulting mixture was stirred under a nitrogen stream at 100° C. for 12 hours. After the stirring, the mixture was cooled down to room temperature. A precipitated solid of the mixture was collected by suction filtration. To this solid was added 1,4-dioxane, followed by irradiation with ultrasonic waves and a solid was collected by suction filtration. Chloroform was added to this solid so that this solid was dissolved. Water was added to this solution and an organic layer was subjected to extraction with chloroform. The extracted solution was concentrated to give a solid. Toluene was added to the obtained solid, and ultrasonic wave irradiation was performed. A solid was collected by suction filtration to give 1.2 g of a target pale yellow solid in a yield of 60%, A synthesis scheme of PrdP2Phen is shown in Formula (a-1) below.

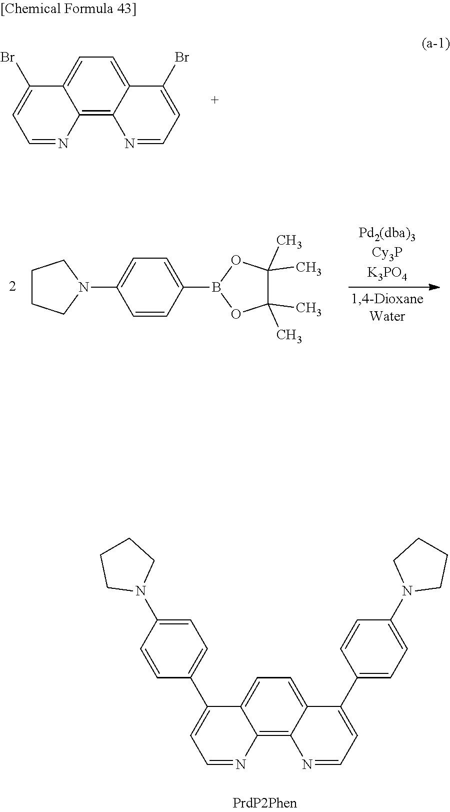 [SMILES: Brc1ccnc2c1ccc1c(Br)ccnc12 ; CC1(C)OB(c2ccc(N3CCCC3)cc2)OC1(C)C ; c1cc(-c2ccc(N3CCCC3)cc2)c2ccc3c(-c4ccc(N5CCCC5)cc4)ccnc3c2n1]

By a train sublimation method, 1.2 g of the obtained pale yellow solid was purified by sublimation. In the purification by sublimation, heating was performed for 20 hours at an argon flow rate of 18 mL/min, a pressure of 3.7 Pa, and a heating temperature of 280° C. As a result, 0.71 g of a target yellow solid was obtained at a collection rate of 59%.

Results of ¹H NMR measurement of PrdP2Phen after the purification by sublimation are shown below. The results reveal that PrdP2Phen was obtained.

¹ H NMR (CDCl₃, 300 MHz):δ=9.15 (d, J=4.5 Hz, 2H), 8.00 (s, 2H), 7.54 (d, J=4.5 Hz, 2H), 7.46 (d, J=8.7 Hz, 41), 6.71 (d, J=8.4 m/z, 4H), 3.41-3.37 (n, 8H), 2.09-2.04 (m, 8H).

### <Measurement of Glass Transition Temperature of PrdP2Phen>

The glass transition temperature (T_{g}) of PrdP2Phen was measured. Note that T_{g} was measured with a differential scanning calorimeter (DSC8500, PerkinElmer Japan Co., Ltd.) in a state where a powder was put on an aluminum cell and the temperature was increased at a rate of 40° C./min. The results showed that the T_{g} of PrdP2Phen was 130° C.

Next, a solubility test of PrdP2Phen was performed. Note that the solubility test was conducted at a pressure of one atmosphere at room temperature (RT).

### <Solubility Test of PrdP2Phen by LC-MS Analysis>

In the LC-MS analysis, liquid chromatography (LC) separation was carried out with ACQUITY UPLC (Waters Corporation), and MS analysis (mass spectrometry) was carried out with Xevo G2 Tof MS (Waters Corporation). Acquity UPLC BEH C8 (2.1×100 mm, 1.7 μm) was used as a column for the LC separation. Acetonitrile was used for Mobile Phase A and a 0.1% aqueous solution of formic acid was used for Mobile Phase B. The injection amount of the sample was 5.0 μL. Note that in the analysis, the wavelength of a photodiode array detector was set to 263 nm±1 nm.

In a 5-mL sample bottle, 1 mg of PrdP2Phen was put and 1 mL of water was added thereto. This mixture was irradiated with ultrasonic waves for 5 minutes. This mixture was filtered through a membrane filter to remove the solid, and the resulting filtrate was diluted by five times with acetonitrile. The obtained solution was subjected to LC-MS analysis.

As a result, the peak area value derived from PrdP2Phen failed to be obtained through the LC-MS analysis. This indicates that PrdP2Phen is an organic compound with extremely low solubility in water.

This application is based on Japanese Patent Application Serial No. 2023-177524 filed with Japan Patent Office on Oct. 13, 2023, Japanese Patent Application Serial No. 2023-195699 filed with Japan Patent Office on Nov. 17, 2023, Japanese Patent Application Serial No. 2024-025418 filed with Japan Patent Office on Feb. 22, 2024, Japanese Patent Application Serial No. 2024-031584 filed with Japan Patent Office on Mar. 1, 2024, and Japanese Patent Application Serial No. 2024-039587 filed with Japan Patent Office on Mar. 14, 2024, the entire contents of which are hereby incorporated by reference.

What is claimed is:

1. A light-emitting device comprising:
a first electrode;
a second electrode; and
an organic compound layer between the first electrode and the second electrode,
wherein the organic compound layer comprises a first light-emitting layer, a second light-emitting layer, and an intermediate layer,
wherein the intermediate layer is between the first light-emitting layer and the second light-emitting layer,
wherein the intermediate layer comprises a metal or a metal compound, a first organic compound, and a second organic compound different from the first organic compound,
wherein the first organic compound comprises a t-electron deficient heteroaromatic ring,
wherein the second organic compound comprises two or more heteroaromatic rings,
wherein the two or more heteroaromatic rings are bonded or condensed to each other and comprise three or more heteroatoms in total, and
wherein the second organic compound interacts with the metal or the metal compound by two or more of the three or more heteroatoms as a multidentate ligand.

2. The light-emitting device according to claim 1,
wherein the first organic compound and the metal or the metal compound form a donor level by interacting with each other as an electron donor to the second organic compound.

3. The light-emitting device according to claim 1,
wherein in the intermediate layer, a mass-to-charge ratio corresponding to a sum of a mass number of the first organic compound, a mass number of the second organic compound, and a mass number of the metal or the metal compound is detected by ToF-SIMS measurement.

4. A light-emitting device comprising:
a first electrode;
a second electrode; and
an organic compound layer between the first electrode and the second electrode,
wherein the organic compound layer comprises a first light-emitting layer, a second light-emitting layer, and an intermediate layer,
wherein the intermediate layer is between the first light-emitting layer and the second light-emitting layer,
wherein the intermediate layer comprises a metal or a metal compound, a first organic compound, and a second organic compound different from the first organic compound,
wherein the first organic compound comprises a c-electron deficient heteroaromatic ring,
wherein the second organic compound is an organic compound represented by General Formula (G1-1), and 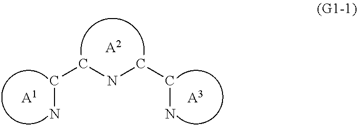
wherein A¹, A², and A³ each independently represent a substituted or unsubstituted heteroaromatic ring having 1 to 30 carbon atoms.

5. A light-emitting device comprising:
a first electrode:
a second electrode; and
an organic compound layer between the first electrode and the second electrode,
wherein the organic compound layer comprises a first light-emitting layer, a second light-emitting layer, and an intermediate layer,
wherein the intermediate layer is between the first light-emitting layer and the second light-emitting layer,
wherein the intermediate layer comprises a metal or a metal compound, a first organic compound, and a second organic compound different from the first organic compound,
wherein the first organic compound comprises a π-electron deficient heteroaromatic ring,
wherein the second organic compound is an organic compound represented by General Formula (G1-2), 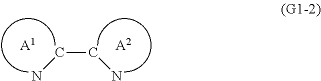
wherein A¹ and A² independently represent a substituted or unsubstituted heteroaromatic ring having 1 to 30 carbon atoms, and
wherein A¹ comprises two or more nitrogen atoms.

6. A light-emitting apparatus comprising:
a first light-emitting device and a second light-emitting device over the same insulating surface,
wherein the first light-emitting device is the light-emitting device according to claim 1,
wherein the second electrode is shared by the first light-emitting device and the second light-emitting device, and
wherein the first light-emitting layer, the intermediate layer, and the second light-emitting layer have the same or substantially the same outline.

7. The light-emitting device according to claim 1, wherein the second organic compound interacts with the metal or the metal compound by two or more of the three or more heteroatoms as a bidentate or a tridentate ligand.

8. The light-emitting device according to claim 1, wherein the heteroatoms are each a nitrogen atom.

9. A light-emitting apparatus comprising:
a first light-emitting device and a second light-emitting device over the same insulating surface,
wherein the first light-emitting device is the light-emitting device according to claim 4,
wherein the second electrode is shared by the first light-emitting device and the second light-emitting device, and
wherein the first light-emitting layer, the intermediate layer, and the second light-emitting layer have the same or substantially the same outline.

10. The light-emitting device according to claim 4, wherein the second organic compound interacts with the metal or the metal compound by nitrogen atoms as a tridentate ligand.

11. A light-emitting apparatus comprising:
a first light-emitting device and a second light-emitting device over the same insulating surface,
wherein the first light-emitting device is the light-emitting device according to claim 5,
wherein the second electrode is shared by the first light-emitting device and the second light-emitting device, and
wherein the first light-emitting layer, the intermediate layer, and the second light-emitting layer have the same or substantially the same outline.

12. The light-emitting device according to claim 5, wherein the second organic compound interacts with the metal or the metal compound by nitrogen atoms as a bidentate ligand.

13. The light-emitting device according to claim 1, wherein the heteroaromatic ring is a 7-electron deficient heteroaromatic ring.

14. The light-emitting device according to claim 1, wherein the heteroaromatic ring comprises at least one of a pyridine ring, a pyrazine ring, a pyrimidine ring, a pyridazine ring, a triazine ring, an imidazole ring, a pyrazole ring, an oxazole ring, a thiazole ring, and a triazole ring.

15. The light-emitting device according to claim 1, wherein at least one of the two or more heteroaromatic rings comprises a pyrazine ring, a pyrimidine ring, a pyridazine ring, or a triazine ring.

16. The light-emitting device according to claim 1, wherein the two or more heteroaromatic rings comprise three or more pyridine rings in total.

17. The light-emitting device according to claim 1, wherein the first organic compound comprises an electron-donating group.

18. The light-emitting device according to claim 17, wherein the electron-donating group comprises at least one of an alkyl group, an alkoxy group, an aryloxy group, an alkylamino group, an arylamino group, and a heterocyclic amino group.

19. The light-emitting device according to claim 1, wherein the first organic compound has an acid dissociation constant pKₐ of 8 or more.

20. The light-emitting device according to claim 1, wherein the first organic compound comprises a phenanthroline ring.

21. The light-emitting device according to claim 1, wherein the second organic compound has a glass transition temperature T_{g} of 100° C. or higher.

22. The light-emitting device according to claim 1, wherein a LUMO level of the second organic compound is lower than a LUMO level of the first organic compound.

23. The light-emitting device according to claim 1, wherein the metal is a metal belonging to Group 1, Group 3, Group 11, or Group 13 of the periodic table.
